(19) United States
(12) Patent Application Publication
(10) Pub. No.: US 2026/0171358 A1
(43) Pub. Date: Jun. 18, 2026

(54) APPARATUS FOR CONTROLLING POTENTIAL OF TARGET IN PLASMA AND METHOD FOR CONTROLLING POTENTIAL THEREOF

(71) Applicant: INNOVATION FOR CREATIVE DEVICES CO., LTD., Anseong-si (KR)

(72) Inventors: Pyung-Woo LEE, Gwacheon-si (KR); Seungho LEE, Yongin-si (KR); Hei Seob JEONG, Seoul (KR); Taeho SHIN, Chungju-si (KR); Bumsoo ON, Yongin-si (KR); Seung-Ik JUNG, Anseong-si (KR)

(21) Appl. No.: 19/380,902

(22) Filed: Nov. 5, 2025

Related U.S. Application Data
(63) Continuation of application No. PCT/KR2025/000724, filed on Jan. 13, 2025.

(30) Foreign Application Priority Data
Jan. 25, 2024 (KR) 10-2024-0011776
Mar. 22, 2024 (KR) 10-2024-0039573
Apr. 9, 2024 (KR) 10-2024-0047894

(51) Int. Cl. H01J 37/32; H01J 37/08

(52) U.S. Cl. CPC H01J 37/32091; H01J 37/08; H01J 37/32935

(57) ABSTRACT

A method for controlling a voltage of a target in a plasma apparatus having a structure in which an electrode, a dielectric, and the target are stacked includes applying an applied voltage V_{G} of a bipolar pulse to the electrode to find a maximum time tmax at which current flowing through the electrode becomes zero in a negative voltage region and calculating ion current density Ji incident on the target exposed to plasma using the maximum time tmax.

### CROSS-REFERENCE TO RELATED APPLICATIONS

This application is a continuation of and claims priority to PCT/KR2025/000724 filed on Jan. 1, 2025, which claims priority to Korea Patent Application No. 10-2024-0011776 filed on Jan. 25, 2024, 10-2024-0039573 filed on Mar. 22, 2024, 10-2024-0047894 filed on Apr. 9, 2024 the entireties of which are both hereby incorporated by reference.

### TECHNICAL FIELD

The present disclosure relates to a plasma apparatus, and more particularly, to controlling a potential of a target by applying a voltage to an electrode in an electrode/dielectric/target structure.

### BACKGROUND ART

A sputtering apparatus and an etching apparatus induce a potential on a target, causing plasma ions to impinge on the target and interact with the target.

A voltage may be directly applied to a target to control a voltage or potential of the target, but a large amount of current may flow and arcing may occur. Accordingly, conventionally, a potential is applied to the target through an electrode/dielectric/target structure.

The potential of the target is dependent on a structure of a target holder and a drive voltage applied to the electrode, and may be changed when a waveform of the drive voltage is changed. The potential of the target is correlated with ion energy.

### DISCLOSURE OF THE INVENTION

### Technical Problem

An aspect of the present disclosure is to control a potential of a target exposed to plasma in a capacitor structure of electrode/dielectric/target, based on a voltage applied to the electrode.

### Technical Solution

### [Claim 1] (1)

A method for controlling a voltage of a target in a plasma apparatus having a structure in which an electrode, a dielectric layer, and a target are stacked, the method comprising:
applying an applied voltage V_{G} of a bipolar pulse to the electrode to find a maximum time tmax at which current flowing through the electrode becomes zero in a negative voltage region; and
calculating ion current density Ji incident on the target exposed to plasma using the maximum time tmax.

### [Claim 2]

The method of claim 1, wherein
the ion current density Ji may be given as follow:

$${t}_{max} = - ( \frac{{V}_{0} - {V}_{G}^{+}}{{J}_{i}} ) {c}_{1}$$

where Vo is a measured voltage applied to the electrode, V_{G}+ is a positive applied voltage applied to the electrode, and c1 is capacitance per unit area of a dielectric between the electrode and the target.

### [Claim 3]

The method as set forth in claim 1, further comprising:
setting a potential Vs of the target based on the ion current density Ji.

### [Claim 4]

The method as set forth in claim 3, wherein
the potential Vs of the target may be given as follow:

$${V}_{s} = - {( \frac{{d}_{1}}{{ϵ}_{1}} )}^{2} {ϵ}_{2} {ρ}_{d} + ( {V}_{G} + \frac{{d}_{1}}{{ϵ}_{1}} {ρ}_{i} ) + \frac{{d}_{1}}{2 {ϵ}_{1}} \sqrt{2 {ϵ}_{2} {ρ}_{d}} \sqrt{{( \frac{{d}_{1}}{{ϵ}_{1}} \sqrt{2 {ε}_{2} {ρ}_{d}} )}^{2} - 4 ( {V}_{G} + \frac{{d}_{1}}{{ϵ}_{1}} {ρ}_{i} )}$$

$${ρ}_{d} = {J}_{i} / ( 0.61 {u}_{B} )$$

wherein ρ_{d} is charge density of plasma, V_{G} is an applied voltage applied to the electrode, u_{B} is Bohm speed, d1 is a thickness of the dielectric layer, ε1 is the dielectric constant of the dielectric layer, ε2 is a dielectric constant of a plasma sheath region. ρi is initial surface charge density accumulated on the target at a positive applied voltage.

### [Claim 5]

The method as set forth in claim 4, further comprising:
calculating a voltage variation ΔVs of the target at the applied voltage V_{G}.

$$Δ {V}_{s} = ( X + \frac{{d}_{1} {J}_{i}}{{ϵ}_{1}} ) τ [ 1 - \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} ]$$

where X is a voltage fluctuation dV/dt depending on a time interval τ in a negative period of the applied voltage V_{G}.

### [Claim 6]

The method as set forth in claim 1, further comprising:
applying a drive voltage of a bipolar waveform having an applied time of a negative applied voltage, shorter than the maximum time tmax.

### [Claim 7]

The method as set forth in claim 3, wherein
the potential Vs of the target is given as follow:

$${V}_{s} = {V}_{G} + \frac{{d}_{1} {ρ}_{i}}{{ϵ}_{1}} + \frac{{d}_{1}}{{ϵ}_{1}} {\{ 2 {ρ}_{0} {ϵ}_{2} [ 2 \frac{\sqrt{- a {V}_{s} + 1}}{a} - 2 \frac{1}{a} + \frac{k {T}_{e}}{q} [ {e}^{q \frac{{V}_{s}}{κ {τ}_{e}}} - 1 ] ] \}}^{1 / 2}$$

$$a = \frac{2 q}{M {u}_{B}^{2}}$$

$${u}_{B} = {( k {T}_{e} / M )}^{1 / 2}$$

where Te is an electron temperature, k is a Boltzmann constant, q is an absolute value of electron charge, and M is an ion mass.

### [Claim 8]

The method as set forth in claim 3, wherein
the potential Vs of the target may be given as follow:

$$- {V}_{s} = {\frac{1}{4} [ - \frac{{d}_{1} α}{{ϵ}_{1}} \sqrt{2 {ϵ}_{2} {ρ}_{d}} + \sqrt{{( \frac{{d}_{1} α}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )} ]}^{2}$$

where α is 0.3 to 0.5, ρ_{d} is charge density of plasma, V_{G} is an applied voltage applied to the electrode, d1 is a thickness of the dielectric layer, ε1 is a dielectric constant of a dielectric layer, ε2 is a dielectric constant of a plasma sheath region, and ρi is an initial surface charge density accumulated on the target at a positive drive voltage.

### [Claim 9]

The method as set forth in claim 4, wherein

$$\frac{{d}_{1}}{{ϵ}_{1}} \sqrt{2 {ϵ}_{2} {ρ}_{d}} < 1$$

$$\frac{{d}_{1}}{{ϵ}_{1}} \sqrt{2 {ϵ}_{2} {ρ}_{d}} < 0.1 .$$

### [Claim 10]

The method as set forth in claim 4, wherein

$$β = \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}}$$

$$β < 0.4 .$$

### [Claim 11]

The method as set forth in claim 1, wherein
current I_{G} flowing through the electrode and a maximum time tmax at which the current I_{G} becomes zero are given as follow:

$${t}_{max} = - ( {V}_{s 0} - {V}_{f} ) \frac{{C}_{1}}{{I}_{G 0}}$$

where Vₛ₀ is an initial voltage of the target, C1 is capacitance of the dielectric, V_{f} is a floating potential, and I_{G0} is current flowing through the electrode at a negative applied voltage.

### [Claim 12]

The method as set forth in claim 1, wherein
the current I_{G} flowing through the electrode is given as follow:

$${I}_{G} = {C}_{1} β X + {I}_{G 0}$$

$$β ≡ \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}}$$

$${I}_{G 0} = - {I}_{i} ( 1 - β )$$

$${I}_{G} = {C}_{1} β X - {I}_{i} ( 1 - β )$$

where X is a slope voltage applied in a negative applied voltage period, C1 is capacitance of the dielectric, ρ_{d} is charge density of plasma, V_{G} is an applied voltage applied to the electrode, d1 is a thickness of a dielectric layer, ε1 is a dielectric constant of the dielectric layer, ε2 is a dielectric constant of a plasma sheath region, and ρi is density of initial surface charges accumulated on the target at a positive drive voltage.

### [Claim 13]

The method of claim 12, wherein

$$β < 0.4 .$$

### [Claim 14]

The method of claim 1, wherein
an initial charged amount Qᵢ per unit area that is charged at a positive applied voltage of the target may be given as follow:

$${Q}_{i} = - \frac{{ϵ}_{1}}{{d}_{1}} {V}_{0}^{+} .$$

### [Claim 15]

The method of claim 1, wherein
the following condition is satisfied at a positive applied voltage V_{G}+ of the target:

$$\frac{( {d}_{1} / {ϵ}_{1} ) {J}_{i} τ}{2 {V}_{G}^{+}} < 0.1$$

wherein d1 is a thickness of the dielectric layer, ε1 is a dielectric constant of the dielectric layer, ε2 is a dielectric constant of a plasma sheath region. τ is a time period in which a negative applied voltage is applied.

### [Claim 16]

The method of claim 1, further comprising:
calculating charge density ρ_{d} of plasma.

$${β}^{′} ≡ \frac{{d}_{1}}{{ϵ}_{1}} \frac{\sqrt{2 {ε}_{2} {ρ}_{d}}}{\sqrt{{( \frac{{d}_{1}}{{ε}_{1}} \sqrt{2 {ϵ}_{2} {ρ}_{d}} )}^{2} - 4 ( {V}_{G} + \frac{{d}_{1}}{{ϵ}_{1}} {ρ}_{i} )}}$$

$${ρ}_{d} = \frac{4 {β}^{′2} ( {V}_{G} + \frac{{d}_{1}}{{ϵ}_{1}} {ρ}_{i} )}{2 {ϵ}_{2} [ {{β}^{′2} ( \frac{{d}_{1}}{{ϵ}_{1}} )}^{2} - 1 ]}$$

where ρ_{d} is charge density of plasma, d1 is a thickness of a dielectric layer, ε1 is a dielectric constant of the dielectric layer, ε2 is a dielectric constant of a plasma sheath region, V_{G} is ae negative applied voltage, and ρi is density of initial surface charges accumulated on the target at a positive drive voltage.

### [Claim 17]

The method further comprising:
applying a drive voltage of a bipolar waveform having an applied time of a negative applied voltage, shorter than the maximum time tmax; and
synchronizing a high-frequency sinusoidal wave with a negative voltage period of the drive voltage and applying the synchronized sinusoidal wave to the electrode.

### [Claim 1] (2)

A method for controlling a voltage of a target in a plasma apparatus having a structure in which an electrode, a dielectric layer, and a target are stacked, the method comprising:
applying a positive applied voltage V_{G}+ to the electrode and then calculating current density J_{G0} of current flowing through the electrode in a negative applied voltage period; and
calculating ion current density Jᵢ of current entering the target, exposed to the plasma, using the current density J_{G0}.

### [Claim 2]

The method as set forth in claim 1, wherein

$${J}_{G 0} = - {J}_{i} [ 1 - \frac{{d}_{1}}{{ϵ}_{1}} \frac{\sqrt{2 {ε}_{2} \frac{{J}_{i}}{0.6 {u}_{B}}}}{\sqrt{{( \frac{{d}_{1}}{{ϵ}_{1}} )}^{2} ( 2 {ε}_{2} \frac{{J}_{i}}{0.6 {u}_{B}} ) - ( {V}_{G} + \frac{{d}_{1}}{{ϵ}_{1}} {ρ}_{i} )}} ]$$

the method may be determined by the above equation,
where V_{G} is a drive voltage applied to the electrode, d1 is a thickness of a dielectric layer, ε1 is a dielectric constant of the dielectric layer, ε2 is a dielectric constant of a plasma sheath region, ρi is an initial surface charge density of charges accumulated on the target at a positive drive voltage, and u_{B} is Bohm speed.

### [Claim 3]

The method as set forth in claim 2, further comprising:
setting a slope voltage (dV_{G}/dt=X) in a negative applied voltage period corresponding to the ion current density Ji.

### [Claim 4]

The method as set forth in claim 3, wherein
the slope voltage (dV_{G}/dt=X) is (d1 Ji)/ε1.

### [Claim 1]

A method for controlling a voltage of a target in a plasma apparatus including a structure in which an electrode, a dielectric layer, and a target are stacked, the method including applying a bipolar pulse voltage V_{G} having a slope voltage X in a negative voltage period to the electrode,
wherein current I_{G} flowing through the electrode is given as follow:

$${I}_{G} = {C}_{1} β X + {I}_{G 0}$$

$$β ≡ \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}}$$

$${I}_{G 0} = - {I}_{i} ( 1 - β )$$

$${I}_{G} = {C}_{1} β X - {I}_{i} ( 1 - β )$$

$$- {I}_{i} = {C}_{1} β X - {I}_{i} ( 1 - β ) \to {I}_{i} = - {X}_{1} {C}_{1}$$

where C1 is capacitance caused by a dielectric, Ii is ion current entering a target, ρ_{d} is charge density of plasma, V_{G} is an applied voltage applied to the electrode, d1 is a thickness of a dielectric layer, ε1 is the dielectric constant of the dielectric layer, ε2 is a dielectric constant of a plasma sheath region, and ρi is initial surface charge density of charges accumulated on the target at a positive applied voltage.

### [Claim 2]

The method as set forth in claim 1, wherein
the current IG flowing through the electrode for the slope voltage is measured to calculate ion current density Ii and β from the above equation.

### [Claim 3]

The method as set forth in claim 1, wherein
C1 is given as a value obtained by multiplying capacitance, caused by a dielectric, by a correction factor α, and
the correction factor α ranges from 0.3 to 0.5.

### [Claim 1] (3)

A method for controlling a voltage of a target in a plasma apparatus having a structure in which an electrode, a dielectric layer, and a target are stacked, the method comprising: applying a bipolar pulse voltage V_{G} having a slope voltage X in a negative voltage period to the electrode, wherein
current (I_{G}) flowing through the electrode is given as follow:

$${I}_{G} = α {C}_{2} X - {I}_{i} [ 1 - \frac{{C}_{2} α}{{C}_{1}} ]$$

$${C}_{2} ≡ \frac{A \sqrt{2 {ϵ}_{2} {ρ}_{d}}}{\sqrt{{( \frac{{d}_{1} α}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}}$$

where C1 is capacitance of a dielectric layer, Ii is ion current entering the target, pa is charge density of plasma, V_{G} is an applied voltage applied to the electrode, d1 is a thickness of a dielectric layer, ε1 is a dielectric constant of the dielectric layer, ε2 is a dielectric constant of a plasma sheath region, ρi is initial surface charge density of charges accumulated on the target at a positive applied voltage, A is an area of the target, and
the correction factor α ranges from 0.3 to 0.5.

### [Claim 2]

The method as set forth in claim 1, wherein
current I_{G} flowing through the electrode for the slope voltage X is measured to calculate ion current density Ii and C2 from the above equation.

### [Claim 1] (4)

A method for controlling a voltage of a target in a plasma apparatus having a structure in which an electrode, a dielectric layer, and a target are stacked, the method comprising: applying a bipolar pulse voltage V_{G} having a slope voltage X in a negative voltage period to the electrode, wherein
a variation in potential ΔVs of the target is given as follow:

$${Δ V}_{s} = ( X + \frac{{d}_{1} {J}_{i}}{{ϵ}_{1}} ) τ [ 1 - \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} ]$$

Ji is ion current density entering the target, ρ_{d} is charge density of the plasma, V_{G} is an applied voltage applied to the electrode, d1 is a thickness of the dielectric layer, ε1 is a dielectric constant of the dielectric layer, ε2 is a dielectric constant of a plasma sheath region, and ρi is initial surface charge density of charges accumulated on the target at a positive applied voltage. X is a change amount of voltage dV/dt in a negative time period r of the bipolar pulse voltage V_{G}.

### [Claim 2]

The method as set forth in claim 1, wherein
a variation in the potential ΔVs of the target is changed by changing the slope voltage X, the ion current density Ji, or the negative time period r satisfy a set value.

### [Claim 1] (5-1)

A method for controlling a voltage of a target in a plasma apparatus having a structure in which an electrode, a dielectric layer, and a target are stacked, the method comprising:
applying a bipolar pulse voltage V_{G} to the electrode; and
changing plasma density to change a voltage Vs of the target.

### [Claim 2]

The method as set forth in claim 1, wherein
the changing of the plasma density to change the voltage of the target includes:
controlling power of a high-frequency power supply source generating plasma such that change plasma density is changed to change the voltage of the target corresponding to the bipolar pulse voltage V_{G}.

### [Claim 3]

The method as set forth in claim 1, wherein
a voltage Vs of the target is given as follow:

$${V}_{s} = - {( \frac{{d}_{1}}{{ϵ}_{1}} )}^{2} {ϵ}_{2} {ρ}_{d} + ( {V}_{G} + \frac{{d}_{1}}{{ϵ}_{1}} {ρ}_{i} ) + \frac{{d}_{1}}{2 {ϵ}_{1}} \sqrt{2 {ϵ}_{2} {ρ}_{d}} \sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}$$

wherein ρ_{d} is charge density of plasma, V_{G} is an applied voltage applied to the electrode, d1 is a thickness of a dielectric layer, ε1 is a dielectric constant of the dielectric layer, ε2 is a dielectric constant of a plasma sheath region, and ρi is initial surface charge density of charges accumulated on the target at a positive applied voltage.

### [Claim 4]

The method as set forth in claim 1, wherein
the voltage of the target is alternately changed below and above an etching threshold voltage by a high plasma density and a low plasma density, respectively.

### [Claim 1] (6-1)

A method for controlling a voltage of a target in a plasma apparatus having a structure in which an electrode, a dielectric layer, and a target are stacked, the method comprising:
connecting a first capacitor and a second capacitor in parallel to the electrode; and
alternately selecting one of the first capacitor and the second capacitor and connecting a bipolar power supply to the electrode to change a potential of the target.

### [Claim 2]

The method as set forth in claim 1, wherein
first capacitance of the first capacitor and second capacitance of the second capacitor are different from each other.

### [Claim 3]

The method as set forth in claim 1, comprising:
a first switch connected in series to the first capacitor and a second switch connected in series to the second capacitor,
wherein the first switch and the second switch are synchronized with the bipolar pulse power supply.

### [Claim 1] (7-1)

A method for controlling a voltage of a target in a plasma apparatus having a structure in which an electrode, a dielectric layer, and a target are stacked, the method comprising:
applying a low-frequency sinusoidal voltage V_{G} having an amplitude V and an angular frequency ω to the electrode; and
detecting current density J_{G} of current flowing through the electrode to calculate ion current density Ji flowing to the target.

$${J}_{G} = - {J}_{i} + \frac{{ϵ}_{1}}{{d}_{1}} [ \frac{{d}_{1}}{{ϵ}_{1}} \frac{\sqrt{2 {ϵ}_{2} {ρ}_{d}} ( \frac{{dV}_{G}}{dt} + \frac{{d}_{1}}{{ϵ}_{1}} {J}_{i} )}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} ]$$

$${J}_{G} = - {J}_{i} + [ \frac{\sqrt{2 {ϵ}_{2} {ρ}_{d}} ( V ωcos ( ω t ) + \frac{{d}_{1}}{{ϵ}_{1}} {J}_{i} )}{\sqrt{{( \frac{{d}_{1}}{{ϵ}_{1}} \sqrt{2 {ϵ}_{2} {ρ}_{d}} )}^{2} - 4 ( V sin ( ω t ) + \frac{{d}_{1}}{{ϵ}_{1}} {ρ}_{i} )}} ]$$

where ρ_{d} is charge density of plasma, V_{G} is an applied voltage applied to the electrode, d1 is a thickness of a dielectric layer, ε1 is a dielectric constant of the dielectric layer, ε2 is a dielectric constant of a plasma sheath region, and ρi is an initial surface charge density of charges accumulated on the target at a positive applied voltage.

### [Claim 2]

The method as set forth in claim 1, wherein
the current density J_{G} flowing through the electrode is fitted to calculate the initial surface charge density ρi of the target, the charge density ρ_{d} of the plasma, and the ion current density Ji.

### [Claim 3]

The method as set forth in claim 1, wherein
the current density J_{G} flowing through the electrode further includes an electron current density Je.

### [Claim 1] (8)

A method for controlling a voltage of a target in a plasma apparatus having a structure in which an electrode, a dielectric layer, and a target are stacked, the method comprising:
applying a bipolar low-frequency pulse voltage V_{G} to the electrode; and
applying a high-frequency voltage, synchronized with the bipolar low-frequency pulse voltage V_{G}, to the electrode.

### [Claim 2]

The method as set forth in claim 1, wherein
the applying of the high-frequency voltage to the electrode is synchronized with a negative period of the bipolar low-frequency pulse voltage V_{G}.

### [Claim 3]

The method as set forth in claim 1, wherein
an amplitude of the bipolar low-frequency pulse voltage V_{G} is larger than a full width of the high-frequency voltage.

### [Claim 1] (9)

A method for controlling a voltage of a target in a plasma apparatus having a structure in which an electrode, a dielectric layer, and a target are stacked, the method comprising:
applying a low-frequency sinusoidal voltage V_{G} to the electrode; and
applying a high-frequency sinusoidal voltage, synchronized with the low-frequency sinusoidal voltage V_{G}, to the electrode.

### [Claim 2]

The method as set forth in claim 1, wherein
the applying of the high-frequency voltage to the electrode is synchronized with a negative period of the low-frequency sinusoidal voltage V_{G}.

### [Claim 3]

The method as set forth in claim 1, wherein
an amplitude of the low-frequency sinusoidal voltage V_{G} is larger than a full width of the high-frequency voltage.

### [Claim 1] (10)

A method for controlling a voltage of a target in a plasma apparatus having a structure in which an electrode, a dielectric layer, and a target are stacked, the method comprising:
applying a bipolar low-frequency pulse voltage V_{G} to the electrode; and
applying a plasma potential Vp synchronized with the bipolar low-frequency pulse voltage V_{G}.

### [Claim 2]

The method as set forth in claim 1, wherein
the applying of the plasma potential Vp is synchronized with a negative period of the bipolar low-frequency pulse voltage V_{G}.

### [Claim 3]

The method as set forth in claim 1, wherein
the applying of the bipolar low-frequency pulse voltage V_{G} to the electrode has a slope voltage X in the negative voltage period.

### [Claim 4]

The method as set forth in claim 1, wherein
the plasma potential Vp changes immediately after the bipolar low-frequency pulse voltage V_{G} changes to a negative voltage.

### [Claim 5]

The method as set forth in claim 1, wherein
the applying of the bipolar low-frequency pulse voltage V_{G} to the electrode has a slope voltage X in a negative voltage period,
the plasma potential Vp has a constant slope Y over time,
the constant slope Y is given as follow: Y=X+Ji/ceff,
where Ji is ion current density of ions incident on the target, and ceff is effective capacitance per unit area between the electrode and the target.

### [Claim 1] (11)

A method for controlling a voltage of a target in a plasma apparatus having a structure in which an electrode, a dielectric layer, and a target are stacked, the method comprising:
applying a low-frequency sinusoidal voltage V_{G} to the electrode; and
applying a plasma potential synchronized with the low-frequency sinusoidal voltage V_{G}.

### [Claim 2]

The method as set forth in claim 1, wherein
the plasma potential has a high state and a low state, and
the plasma potential is synchronized with a positive maximum value of the low-frequency sinusoidal voltage V_{G}.

### [Claim 1] (12)

A method for controlling a voltage of a target in a plasma apparatus having a structure in which an electrode, a dielectric layer, and a target are stacked, the method comprising:
applying a low-frequency sinusoidal voltage V_{G} to the electrode; and
periodically applying a plasma potential having a high state and a low state synchronized with the low-frequency sinusoidal voltage V_{G}.

### [Claim 2]

The method as set forth in claim 1, wherein
a value obtained by subtracting the plasma potential Vp from a potential Vs of the target (Vs−Vp) decreases over time for a plurality of periods.

### [Claim 1] (13)

A method for controlling a voltage of a target in a plasma apparatus having a structure in which an electrode, a first dielectric layer, an electrostatic electrode, a second dielectric layer, and a target are stacked, the method comprising:
applying a low-frequency pulse voltage V_{G} to the electrode; and
providing charges, synchronized with the low-frequency pulse voltage V_{G}, to the electrostatic electrode.

### [Claim 2]

The method as set forth in claim 1, wherein
a charge charged to the electrostatic electrode has a positive value, and
an amount of charges accumulated on the target during a positive period of the low-frequency pulse voltage increases in proportion to the amount of the charges on the electrostatic electrode.

### [Claim 3]

The method as set forth in claim 1, wherein
a first dielectric constant of the first dielectric layer is smaller than a second dielectric constant of the second dielectric layer.

### [Claim 4]

The method as set forth in claim 1, wherein
a negative voltage of the low-frequency pulse voltage V_{G} and a pulse of the electrostatic electrode are synchronized.

### [Claim 1] (14)

A method for controlling a voltage of a target in a plasma apparatus having a structure in which an electrode, a first dielectric layer, an electrostatic electrode, a second dielectric layer, and a target are stacked, the method comprising: applying a bipolar pulse voltage V_{G} having a slope voltage X in a negative voltage period to the electrode, wherein
current I_{G} flowing through the electrode is given as follow:

$${I}_{G} = A \frac{\frac{d}{dt} ( {V}_{G} - {V}_{S} )}{[ \frac{{d}_{1}}{{ϵ}_{1}} + \frac{{d}_{2}}{{ϵ}_{2}} ]}$$

$${I}_{G} = AX [ \frac{\sqrt{2 {ϵ}_{3} {ρ}_{d}}}{\sqrt{\begin{matrix}{( [ \frac{{d}_{1}}{{ϵ}_{1}} + \frac{{d}_{2}}{{ϵ}_{2}} ] \sqrt{2 {ϵ}_{3} {ρ}_{d}} )}^{2} - \\ 4 ( {V}_{G} + \frac{{d}_{1}}{{ϵ}_{1}} {ρ}_{esc} + [ \frac{{d}_{1}}{{ϵ}_{1}} + \frac{{d}_{2}}{{ϵ}_{2}} ] {ρ}_{i} )\end{matrix}}} ] - {AJ}_{i} [ 1 - [ [ \frac{{d}_{1}}{{ϵ}_{1}} + \frac{{d}_{2}}{{ϵ}_{2}} ] \frac{\sqrt{2 {ϵ}_{3} {ρ}_{d}}}{\sqrt{\begin{matrix}{( [ \frac{{d}_{1}}{{ϵ}_{1}} + \frac{{d}_{2}}{{ϵ}_{2}} ] \sqrt{2 {ϵ}_{3} {ρ}_{d}} )}^{2} - \\ 4 ( {V}_{G} + \frac{{d}_{1}}{{ϵ}_{1}} {ρ}_{esc} + [ \frac{{d}_{1}}{{ϵ}_{1}} + \frac{{d}_{2}}{{ϵ}_{2}} ] {ρ}_{i} )\end{matrix}}} ] ]$$

where Ji is ion current density entering the target, ρ_{d} is charge density of plasma, V_{G} is an applied voltage applied to the electrode, d1 is a thickness of the first dielectric layer, ε1 is a dielectric constant of the first dielectric layer. d2 is a thickness of the second dielectric layer. ε2 is a dielectric constant of the second dielectric layer, ε3 is a dielectric constant of a plasma sheath region. ρi is an initial surface charge density of charges accumulated on the target at a positive applied voltage. ρ_{ESC} is a charge quantity per unit area charged on the electrostatic electrode. A is an area of the target. Vs is a potential of the target.

### [Claim 2]

The method as set forth in claim 1, wherein
a variation in potential ΔVs of the target is given as follow:

$$\frac{1}{{c}_{eff}} ≡ [ \frac{{d}_{1}}{{ϵ}_{1}} + \frac{{d}_{2}}{{ϵ}_{2}} ]$$

$$Δ {V}_{s} = {V}_{s} ( t = τ ) - {V}_{s} ( t = 0 )$$

$$Δ {V}_{s} = ( X + \frac{{J}_{i}}{{c}_{eff}} ) τ [ 1 - \frac{1}{{c}_{eff}} \frac{\sqrt{2 {ϵ}_{2} {ρ}_{d}}}{\sqrt{{( \frac{1}{{c}_{eff}} \sqrt{2 {ϵ}_{2} {ρ}_{d}} )}^{2} - 4 ( {V}_{G} + \frac{{d}_{1}}{{ϵ}_{1}} {ρ}_{esc} + \frac{1}{{c}_{eff}} {ρ}_{i} )}} ]$$

where r is a negative time period of the bipolar pulse voltage V_{G}.

### [Claim 1] (15)

A method for controlling a voltage of a target in a plasma apparatus having a structure in which an electrode, a first dielectric layer, an electrostatic electrode, a second dielectric layer, and a target are stacked, the method comprising:
applying a low-frequency sinusoidal voltage V_{G} to the electrode; and
providing charges, synchronized with the low-frequency pulse voltage V_{G}, to the electrostatic electrode.

### [Claim 2]

The method as set forth in claim 1, wherein
a positive maximum voltage of the low-frequency sinusoidal voltage V_{G} and the pulse of the electrostatic electrode are synchronized.

### [Claim 1] (16)

A plasma apparatus having a structure in which an electrode, a first dielectric layer, an electrostatic electrode, a second dielectric layer, and a target are stacked, the plasma apparatus comprising:
a first dielectric constant of the first dielectric layer is smaller than a dielectric constant of the second dielectric layer.

### [Claim 2]

The plasma apparatus of claim 1, further comprising:
a low-frequency pulse power supply configured to apply a low-frequency pulse voltage V_{G} to the electrode.

### [Claim 3]

The plasma apparatus of claim 1, further comprising:
a static pulse power supply configured to apply a pulse voltage to the electrostatic electrode.

### [Claim 4]

The plasma apparatus of claim 1, further comprising:
a low-frequency sinusoidal power supply for applying a low-frequency sinusoidal voltage V_{G} to the electrode.

### [Claim 1] (17)

A method for controlling a voltage of a target in a plasma apparatus having a structure in which a variable capacitor, an electrode, and a target are sequentially connected, a method comprising:
applying a low-frequency pulse voltage V_{G} to the variable capacitor; and
controlling a voltage of the target that is a dielectric.

### [Claim 2]

The method as set forth in claim 1, wherein
in the controlling of the voltage of the target,
a voltage variation ΔVs of the voltage of the target is given as follow:

$$Δ {V}_{s} = {V}_{s} ( t = τ ) - {V}_{s} ( t = 0 )$$

$$Δ {V}_{s} = ( X + \frac{{J}_{i}}{{c}_{eff}} ) τ [ 1 - \frac{1}{{c}_{eff}} \frac{\sqrt{2 {ϵ}_{3} {ρ}_{d}}}{\sqrt{{( \frac{1}{{c}_{eff}} \sqrt{2 {ϵ}_{3} {ρ}_{d}} )}^{2} - 4 ( {V}_{G} + \frac{1}{{c}_{eff}} {ρ}_{i} )}} ]$$

$$\frac{1}{{c}_{eff}} ≡ [ \frac{{d}_{2}}{{ϵ}_{2}} + \frac{{S}_{2}}{{C}_{1}} ]$$

where Ji is ion current density entering the target, ρ_{d} is charge density of plasma, V_{G} is an applied voltage applied to the electrode, d2 is a thickness of the target, ε2 is a dielectric constant of the target, C1 is capacitance of the variable capacitor, S2 is an area of the target, ε3 is a dielectric constant of a plasma sheath region, ρi is initial surface charge density of charges accumulated on the target at a positive applied voltage, Vs is a potential of the target, and τ is a negative time period of the low-frequency pulse voltage V_{G}.

### [Claim 3]

The method as set forth in claim 1, wherein
current I_{G} flowing through the variable capacitor is given as follow:

$$\frac{1}{{c}_{eff}} ≡ [ \frac{{d}_{2}}{{ϵ}_{2}} + \frac{{S}_{2}}{{C}_{1}} ]$$

$${I}_{G} = {S}_{2} {c}_{eff} X - {S}_{2} {c}_{eff} ( X + \frac{{J}_{i}}{{c}_{eff}} ) [ 1 - \frac{1}{{c}_{eff}} \frac{\sqrt{2 {ϵ}_{3} {ρ}_{d}}}{\sqrt{{( \frac{1}{{c}_{eff}} \sqrt{2 {ϵ}_{3} {ρ}_{d}} )}^{2} - 4 ( {V}_{G} + \frac{1}{{c}_{eff}} {ρ}_{i} )}} ]$$

where Ji is ion current density entering the target, ρ_{d} is charge density of plasma, V_{G} is an applied voltage applied to the electrode, d2 is a thickness of the target, ε2 is a dielectric constant of the target, C1 is capacitance of the variable capacitor, S2 is an area of the target, ε3 is a dielectric constant of a plasma sheath region, and ρi is initial surface charge density of charges accumulated on the target at a positive applied voltage.

### [Claim 1] (18)

A method for controlling a voltage of a target in a plasma apparatus having a structure in which a variable capacitor, an electrode, and a target are sequentially connected, a method comprising:
applying a low-frequency pulse voltage V_{G} to the variable capacitor; and
controlling a voltage of the target that is a conductor.

### [Claim 2]

The method as set forth in claim 1, wherein
in the controlling of the voltage of the target that is a conductor,
the voltage variation of the target that is a conductor is given as follow:

$$Δ {V}_{s} = {V}_{s} ( t = τ ) - {V}_{s} ( t = 0 )$$

$$Δ {V}_{s} = ( X + \frac{{S}_{2} {J}_{i}}{{C}_{1}} ) τ [ 1 - \frac{{S}_{2}}{{C}_{1}} \frac{\sqrt{2 {ϵ}_{2} {ρ}_{d}}}{\sqrt{{( \frac{{S}_{2}}{{C}_{1}} \sqrt{2 {ϵ}_{2} {ρ}_{d}} )}^{2} - 4 ( {V}_{G} + \frac{{S}_{2}}{{C}_{1}} {ρ}_{i} )}} ]$$

where Ji is ion current density entering the target, ρ_{d} is charge density of plasma, V_{G} is an applied voltage to the electrode, C1 is capacitance of the variable capacitor, S2 is an area of the target, ε2 is a dielectric constant of a plasma sheath region, and ρi is initial surface charge density of charges accumulated on the target at a positive applied voltage.

### [Claim 3]

The method as set forth in claim 1, wherein
current flowing through the variable capacitor is given as follows,

$${I}_{G} = {S}_{2} \frac{\sqrt{2 {ϵ}_{2} {ρ}_{d}}}{\sqrt{{( \frac{{S}_{2}}{{C}_{1}} \sqrt{2 {ϵ}_{2} {ρ}_{d}} )}^{2} - 4 ( {V}_{G} + \frac{{S}_{2}}{{C}_{1}} {ρ}_{i} )}} X - ( {J}_{i} {S}_{2} ) [ 1 - \frac{{S}_{2}}{{C}_{1}} \frac{\sqrt{2 {ϵ}_{2} {ρ}_{d}}}{\sqrt{{( \frac{{S}_{2}}{{C}_{1}} \sqrt{2 {ϵ}_{2} {ρ}_{d}} )}^{2} - 4 ( {V}_{G} + \frac{{S}_{2}}{{C}_{1}} {ρ}_{i} )}} ]$$

where Ji is ion current density entering the target, ρ_{d} is plasma charge density, V_{G} is an applied voltage to the electrode, C1 is capacitance of the variable capacitor, S2 is an area of the target, ε2 is a dielectric constant of a plasma sheath region, and ρi is initial surface charge density of charges accumulated on the target at a positive applied voltage.

### [Claim 1] (19)

A method for controlling a voltage of a target in a plasma apparatus having a structure in which a variable capacitor, an electrode, a dielectric, and a target are sequentially connected, a method comprising:
applying a low-frequency pulse voltage V_{G} to the variable capacitor; and
controlling a voltage of the target that is a conductor.

### [Claim 2]

The method as set forth in claim 1, wherein
in the controlling of the voltage of the target that is a conductor,

$$\frac{1}{{c}_{eff}} ≡ [ \frac{{d}_{1}}{{ϵ}_{1}} + \frac{{S}_{2}}{{C}_{4}} ]$$

$$Δ {V}_{s} = {V}_{s} ( t = τ ) - {V}_{s} ( t = 0 )$$

$$Δ {V}_{s} = ( X + \frac{{J}_{i}}{{c}_{eff}} ) τ [ 1 - \frac{1}{{c}_{eff}} \frac{\sqrt{2 {ϵ}_{2} {ρ}_{d}}}{\sqrt{{( \frac{1}{{c}_{eff}} \sqrt{2 {ϵ}_{2} {ρ}_{d}} )}^{2} - 4 ( {V}_{G} + \frac{1}{{c}_{eff}} {ρ}_{i} )}} ]$$

a voltage variation ΔVs of the voltage of the target is given as follows,
where Ji is ion current density entering the target, ρ_{d} is plasma charge density, V_{G} is the applied voltage to the electrode, C4 is capacitance of the variable capacitor, S2 is an area of the target, ε2 is a dielectric constant of a plasma sheath region, ρi is initial surface charge density of charges accumulated on the target at a positive applied voltage, d1 is a thickness of the dielectric, and ε1 is a dielectric constant of the dielectric.

### [Claim 3]

The method as set forth in claim 1, wherein
current I_{G} flowing through the variable capacitor is given as follow:

$$\frac{1}{{c}_{eff}} ≡ [ \frac{{d}_{1}}{{ϵ}_{1}} + \frac{{S}_{2}}{{C}_{4}} ]$$

$${I}_{G} = {S}_{2} {c}_{eff} \frac{d}{dt} ( {V}_{G} - {V}_{S} )$$

$${I}_{G} = {S}_{2} {c}_{eff} X - {S}_{2} {c}_{eff} ( X + \frac{{J}_{i}}{{c}_{eff}} ) [ 1 - \frac{1}{{c}_{eff}} \frac{\sqrt{2 {ϵ}_{3} {ρ}_{d}}}{\sqrt{{( \frac{1}{{c}_{eff}} \sqrt{2 {ϵ}_{3} {ρ}_{d}} )}^{2} - 4 ( {V}_{G} + \frac{1}{{c}_{eff}} {ρ}_{i} )}} ]$$

where Ji is ion current density entering the target, ρ_{d} is plasma charge density, V_{G} is an applied voltage to the electrode, C4 is capacitance of the variable capacitor, S2 is an area of the target, ε2 is a dielectric constant of a plasma sheath region, ρi is initial surface charge density of charges accumulated on the target at a positive applied voltage, d1 is a thickness of the dielectric, and ε1 is a dielectric constant of the dielectric.

### [Claim 1] (20)

A plasma processing apparatus comprising: a plasma chamber;
a high-frequency power supply connected to a first electrode disposed within the chamber to generate plasma;
a target holder including a second electrode, a dielectric layer, and a target and disposed within the chamber;
a third electrode exposed within the chamber; and
an auxiliary low-frequency power supply configured to control a plasma potential of the third electrode that periodically has a high state and a low state.

### [Claim 2]

The plasma processing apparatus as set forth in claim 1, wherein
the plasma potential is synchronized with a bipolar low-frequency pulse voltage V_{G} applied to the second electrode.

### [Claim 3]

The plasma processing apparatus as set forth in claim 1, wherein
a bipolar low-frequency pulse voltage V_{G} is applied to the second electrode,
the bipolar low-frequency pulse voltage V_{G} has a slope voltage X in a negative voltage period,
the plasma potential Vp has a constant slope Y over time, and

$$Y = X + Ji / ceff ,$$

where Ji is ion current density incident on the target, and ceff is effective capacitance per unit area between the second electrode and the target.

### [Claim 1] (21)

A plasma processing apparatus comprising: a plasma chamber;
an auxiliary low-frequency power supply connected to a first electrode, disposed within the chamber, to control a plasma potential that periodically has a high state and a low state;
a target holder including a second electrode, a dielectric layer, and a target and disposed within the chamber;
a low-frequency power supply connected to the second electrode; and
a high-frequency power supply connected to the second electrode to generate plasma

### [Claim 2]

The plasma processing apparatus as set forth in claim 1, wherein
the plasma potential is synchronized with a bipolar low-frequency pulse voltage V_{G} applied to the second electrode.

### [Claim 3]

The plasma processing apparatus as set forth in claim 1, wherein
a bipolar low-frequency pulse voltage V_{G} is applied to the second electrode,
the bipolar low-frequency pulse voltage V_{G} has a slope voltage X in a negative voltage period,
a plasma potential Vp has a constant slope Y over time, and

$$Y = X + Ji / ceff ,$$

where Ji is ion current density incident on the target, and ceff is effective capacitance per unit area between the second electrode and the target.

### [Claim 1] (22)

A plasma processing apparatus comprising: a plasma chamber;
a high-frequency power supply connected to a first electrode, disposed within the chamber, to generate plasma;
an auxiliary low-frequency power supply connected to the first electrode to control a plasma potential that periodically has a high state and a low state;
a target holder including a second electrode, a dielectric layer, a target disposed within the chamber, and disposed within the chamber; and
a low-frequency power supply connected to the second electrode to control a voltage of the target.

### [Claim 2]

The plasma processing apparatus as set forth in claim 1, wherein
the plasma potential is synchronized with the bipolar low-frequency pulse voltage V_{G} applied to the second electrode.

### [Claim 3]

The plasma processing apparatus as set forth in claim 1, wherein
a bipolar low-frequency pulse voltage V_{G} is applied to the second electrode,
the bipolar low-frequency pulse voltage V_{G} has a slope voltage X in a negative voltage period,
the plasma potential Vp has a constant slope Y over time, and

$$Y = X + Ji / ceff ,$$

where Ji is ion current density incident on the target, and ceff is effective capacitance per unit area between the second electrode and the target.

### [Claim 1] (23-1)

A plasma processing apparatus comprising: a plasma chamber;
a high-frequency power supply connected to a first electrode disposed within the chamber to generate inductively-coupled plasma;
an auxiliary low-frequency power supply disposed within the chamber to periodically have a high state and a low state and control a plasma potential;
a target holder including an electrode, a dielectric layer, and a target and disposed within the chamber; and
a low-frequency power supply connected to the electrode to control a voltage of the target.

### [Claim 2]

The plasma processing apparatus as set forth in claim 1, wherein
the plasma potential is synchronized with a bipolar low-frequency pulsed voltage V_{G} applied to the second electrode.

### [Claim 3]

The plasma processing apparatus as set forth in claim 1, wherein
a bipolar low-frequency pulsed voltage V_{G} is applied to the electrode,
the bipolar low-frequency pulsed voltage V_{G} has a slope voltage X in a negative voltage period,
the plasma potential Vp has a constant slope Y over time, and

$$Y = X + Ji / ceff ,$$

where Ji is ion current density incident on the target, and ceff is effective capacitance per unit area between the second electrode and the target.

### [Claim 1] (24)

A plasma processing apparatus comprising: a plasma chamber;
a plasma source for generating plasma in the chamber;
a target holder including an electrode, a first dielectric layer, an electrostatic electrode, a second dielectric layer, and a target and disposed within the chamber;
a low-frequency power supply connected to the electrode; and
an electrostatic electrode power supply connected to the electrostatic electrode,
wherein a voltage waveform of the electrostatic electrode is synchronized with a voltage waveform of the low-frequency power supply to control a potential of the target.

### [Claim 2]

The apparatus as set forth in claim 1, wherein
the voltage of the target is given as follow:

$$\frac{1}{{c}_{eff}} ≡ [ \frac{{d}_{1}}{{ϵ}_{1}} + \frac{{d}_{2}}{{ϵ}_{2}} ]$$

$${V}_{s} = - {\frac{1}{4} [ - \frac{1}{{c}_{eff}} \sqrt{2 {ϵ}_{3} {ρ}_{d}} + \sqrt{{( \frac{1}{{c}_{eff}} \sqrt{2 {ϵ}_{3} {ρ}_{d}} )}^{2} - 4 ( {V}_{G} + \frac{1}{{c}_{eff}} {ρ}_{i} + \frac{{d}_{1} {ρ}_{esc}}{{ε}_{1}} )} ]}^{2}$$

where ρ_{d} is plasma charge density, V_{G} is an applied voltage applied to the electrode, d1 is a thickness of the first dielectric layer, ε1 is a dielectric constant of the first dielectric layer, d2 is a thickness of the second dielectric layer, ε2 is a dielectric constant of the second dielectric layer, ε3 is a dielectric constant of a plasma sheath region, ρi is initial surface charge density of charges accumulated on the target at a positive applied voltage, and ρ_{ESC} is a charge per unit area charged on the electrostatic electrode.

### [Claim 1] (25)

A method for controlling a voltage of a target in a plasma apparatus having a structure in which an electrode, a dielectric layer, and a target are stacked, a method comprising:
applying a sinusoidal voltage to the electrode to measure current flowing through the electrode over time; and
fitting the current to extract an amount of charges charged with the charge and plasma charge density.

### [Claim 2]

The method as set forth in claim 1, further comprising:
calculating the voltage Vs of the target.

### [Claim 3]

The method as set forth in claim 1, wherein
plasma contacting the target has a plasma potential and varies over time,
the method further comprising measuring the plasma potential or fitting current flowing through the electrode to calculate the plasma potential.

### [Claim 4]

The method as set forth in claim 3, further comprising:
calculating the voltage of the target using the plasma potential.

### [Claim 5]

The method as set forth in claim 4, further comprising:
calculating energy of ions incident on the target using the voltage of the target.

### [Claim 6]

The method as set forth in claim 1, further comprising:
controlling the plasma potential of the plasma contacting the target.

### [Claim 7]

The method as set forth in claim 1, further comprising:
controlling a plasma power supply generating plasma such that the plasma charge density is controlled to control a potential of the target.

### [Claim 1] (26)

A method for controlling a voltage of a target in a plasma apparatus having a structure in which an electrode, a dielectric layer, and a target are stacked, a method comprising:
applying a sinusoidal voltage to the electrode to measure current flowing through the electrode over time;
calculating plasma charge density; and
fitting the current to extract charges charged on the target.

### [Claim 2]

The method as set forth in claim 1, wherein
plasma contacting the target has a plasma potential and varies over time, and
the method further comprising: measuring the plasma potential or fitting the current flowing through the electrode to calculate the plasma potential.

### [Claim 3]

The method as set forth in claim 2, further comprising:
calculating the potential of the target using the plasma potential.

### [Claim 4]

The method as set forth in claim 3, further comprising:
calculating energy of ions incident on the target using the voltage of the target.

### [Claim 5]

The method as set forth in claim 1, further comprising:
controlling a plasma potential of plasma contacting the target.

### [Claim 1] (27)

A method for controlling a voltage of a target in a plasma apparatus having a structure in which an electrode, a dielectric layer, and a target are stacked, the method comprising:
applying a sinusoidal voltage to the electrode to measure current flowing through the electrode over time;
calculating a plasma potential using an area ratio of the target and a grounded electrode; and
fitting the current to extract an amount of charges charged on the target and the plasma charge density.

### [Claim 1] (28)

A method for controlling a voltage of a target in a plasma apparatus having a structure in which an electrode, a dielectric layer, and a target are stacked, wherein
a potential of the target is given as follow:

$${V}_{s} = - {( \frac{{d}_{1}}{{ϵ}_{1}} )}^{2} {ϵ}_{2} {ρ}_{d} + ( {V}_{G} + \frac{{d}_{1}}{{ϵ}_{1}} {ρ}_{i} ) + \frac{{d}_{1}}{2 {ϵ}_{1}} \sqrt{2 {ϵ}_{2} {ρ}_{d}} \sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}$$

where ρ_{d} is plasma charge density, V_{G} is an applied voltage applied to the electrode, d1 is a thickness of the dielectric layer, ε1 is a dielectric constant of the dielectric layer, ε2 is a dielectric constant of a plasma sheath region, and ρi is initial surface charge density of charges accumulated on the target at a positive applied voltage.

### [Claim 1] (29)

A method for controlling a voltage of a target in a plasma apparatus having a structure in which an electrode, a dielectric layer, and a target are stacked, wherein
a potential Vs of the target is given as follow:

$${V}_{s} - {V}_{p} = - {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )} ]}^{2}$$

where ρ_{d} is plasma charge density, V_{G} is an applied voltage applied to the electrode, d1 is a thickness of the dielectric layer, ε1 is a dielectric constant of the dielectric layer, ε2 is a dielectric constant of a plasma sheath region, ρi is initial surface charge density of charges accumulated on the target at a positive applied voltage, and Vp is a plasma potential.

### [Claim 1] (30)

A method for controlling a voltage of a target in a plasma apparatus having a structure in which an electrode, a dielectric layer, and a target are stacked, wherein
a plasma potential of plasma adjacent to the target is controlled by an auxiliary electrode, adjusting the plasma potential, to control a potential difference (Vs−Vp) between the potential of the target and the plasma potential.

### [Claim 2]

The method as set forth in claim 1, wherein
a voltage applied to the electrode is a pulse DC voltage, and the plasma potential is synchronized with a negative period of the pulse DC voltage.

### [Claim 1] (31)

A method for operating a plasma apparatus having a structure in which an electrode, a dielectric layer, and a target are stacked, the method comprising:
applying a first DC pulse voltage including a first slope voltage X to the electrode; and
applying a second DC pulse voltage including a second slope voltage Y to an auxiliary electrode, controlling the plasma potential, to change a plasma potential of plasma adjacent to the target over time.

### [Claim 2]

The method as set forth in claim 1, wherein

Y is given as follow:

$$Y = X + Ji {/}_{ceff} ,$$

the first DC pulse voltage is synchronized with the second DC pulse voltage,
where c_{eff} is effective capacitance per unit area between the target and the electrode, and Ji is ion current density incident on the target.

### [Claim 1] (32)

A plasma apparatus having an electrode/dielectric layer/target structure, wherein

$$\frac{{d}_{1}}{{ϵ}_{1}} \sqrt{2 {ϵ}_{2} {ρ}_{d}} \leq 5$$

The plasma apparatus satisfies the condition,
where ρ_{d} is charge density of plasma, d1 is a thickness of the dielectric layer, ε1 is a dielectric constant of the dielectric layer, and ε2 is a dielectric constant of a plasma sheath region.

The plasma apparatus satisfying the condition.

### [Claim 1] (33)

A plasma apparatus having an electrode/dielectric layer/target structure, wherein

$$\frac{{d}_{1}}{{ϵ}_{d}} {J}_{i} \frac{π}{V ω} \leq 0.1$$

the plasma apparatus satisfies the condition,
where d1 is a thickness of the dielectric layer, ε1 is a dielectric constant of the dielectric layer, Ji is ion current density, V is an amplitude of an applied voltage, and ω is an angular frequency of the applied voltage.

### [Claim 1] (34)

A plasma apparatus having an electrode/dielectric layer/target structure, wherein

$$\frac{{d}_{1}}{{ϵ}_{1}} ( \frac{{J}_{i} {t}_{th}}{V} ) \leq 0.1$$

The plasma apparatus satisfying the condition,
where d1 is a thickness of the dielectric layer, ε1 is a dielectric constant of the dielectric layer, Ji is ion current density, V is an amplitude of the applied voltage, and tₜₕ is an application time of a negative applied voltage.

### [Claim 1] (35)

A plasma apparatus having an electrode/dielectric layer/target structure, wherein

$${[ \frac{{d}_{1}}{{ϵ}_{1}} \sqrt{2 {ϵ}_{2} {ρ}_{d}} ]}^{2} < 4 V$$

The plasma apparatus satisfying the condition,
where ρ_{d} is charge density of plasma, d1 is a thickness of the dielectric layer, ε1 is a dielectric constant of the dielectric layer, ε2 is a dielectric constant of a plasma sheath region, and V is an amplitude of an applied voltage.

### [Claim 1] (36)

A plasma apparatus having an electrode/dielectric layer/target structure, wherein

$$\frac{\sqrt{2 {ϵ}_{2} {ρ}_{d}} ( V ωcosω t )}{\sqrt{{( \frac{{d}_{1}}{{ϵ}_{1}} \sqrt{2 {ϵ}_{2} {ρ}_{d}} )}^{2} - 4 ( V sin ω t - {V}_{p} + \frac{{d}_{1}}{{ϵ}_{1}} {ρ}_{i} )}} > V ω \frac{{C}_{4}}{A} cos ω t$$

The plasma apparatus satisfying the condition,
ρ_{d} is charge density of plasma, d1 is s thickness of the dielectric layer, ε1 is a dielectric constant of the dielectric layer, ε2 is a dielectric constant of a plasma sheath region, V is an amplitude of an applied voltage, ω is an angular frequency of the applied voltage, ρi is surface charge density of charges accumulated on the target at a positive applied voltage, Vp is a plasma potential, and C4 is capacitance of a parasitic capacitor connected in parallel to the electrode.

### Advantageous Effects

As set forth above, according to example embodiments, a potential of a target exposed to plasma based on a voltage applied to an electrode in a capacitor structure of electrode/dielectric/target may be controlled.

### BRIEF DESCRIPTION OF THE DRAWINGS

FIG. 1 is a conceptual diagram illustrating a plasma apparatus according to an example embodiment of the present disclosure.

FIGS. 2 and 3 are conceptual diagrams illustrating an electrode, a dielectric, a target, and plasma illustrated in FIG. 1.

FIG. 4 is a graph illustrating a potential of a target based on a pulse voltage waveform alternating between positive and negative voltages.

FIGS. 5A to 5C are diagrams illustrating a plasma sheath structure when a thickness of the target is negligible.

FIG. 6 is a graph illustrating an applied voltage V_{G} of an electrode relative to a voltage Vs of a target based on a matrix model, an electron temperature-considered model, and a Child-Langmuir (C-L) model.

FIG. 7 is a graph illustrating the voltage Vs of a target according to an applied voltage V_{G} of an electrode, based on a matrix model with modified coordinate axes, an electron temperature-considered model, and the Child-Langmuir model.

FIG. 8 is a graph illustrating a relationship between a voltage of a target and an applied voltage by taking a floating potential into account.

FIG. 9 is a diagram illustrating current I_{G} flowing through an electrode and a voltage Vs of a target based on a bipolar pulse applied voltage waveform of the electrode.

FIG. 10 is a diagram illustrating a thickness of a plasma sheath over time for a negative applied voltage V_{G}⁻ of an electrode.

FIG. 11 is a diagram illustrating the negative sum of a charged amount of a plasma sheath and surface charge density of a target over time at a negative applied voltage V_{G}⁻ of the electrode.

FIG. 12 is a graph illustrating various characteristics based on an applied voltage of an electrode.

FIG. 13 is a graph illustrating a voltage of a target relative to an applied voltage.

FIG. 14 is a graph illustrating charge density of each region.

FIG. 15 is a graph illustrating a charged amount Qi of the target, a plasma sheath charged amount Qsh, and a sum QT of Qi and Qsh relative to an applied voltage V_{G} of an electrode.

FIG. 16 is a graph illustrating a charged amount Qi of the target and a charged amount of a plasma sheath Qsh based on an applied voltage of an electrode.

FIG. 17 is a graph illustrating a relationship between maximum time tmax and ion current density.

FIG. 18 is a graph illustrating an inverse of maximum time tmax relative to ion current density.

FIG. 19 is a diagram illustrating a relationship between maximum time tmax and capacitance per unit area.

FIG. 20 is a normalized graph of a voltage Vs of a target relative to a positive applied voltage V_{G}+.

FIG. 21 is a graph illustrating current I_{G} flowing through an electrode relative to an applied voltage V_{G} of an electrode when there is no slope voltage (X=0).

FIG. 22 is a graph illustrating β relative to the applied voltage of the electrode when there is no slope voltage (X=0).

FIG. 23 is a graph illustrating the gain (1−β).

FIG. 24 is a graph illustrating current of an electrode based on an applied voltage of the electrode.

FIG. 25 is a diagram illustrating a ratio of an absolute value I_{G0}/Ii of an electrode current I_{G} to ion current Ii based on plasma density.

FIG. 26 is a diagram illustrating a relationship between current density J_{G0} flowing through an electrode and ion current density Ji.

FIG. 27 is a graph illustrating the voltage of the target relative to the applied voltage of the electrode.

FIG. 28 is a diagram illustrating current I_{G} of an electrode relative to a slope voltage X.

FIG. 29 is a diagram illustrating a variation ΔVs of a voltage of a target based on a slope voltage X.

FIG. 30 is a diagram illustrating a variation ΔVs of a voltage of a target based on plasma density.

FIG. 31 is a conceptual diagram illustrating a plasma system according to an example embodiment of the present disclosure.

FIG. 32 is a graph illustrating current of an electrode relative to a slope voltage when an auxiliary capacitor C4 is present.

FIG. 33 is a graph illustrating a voltage of a target relative to a low-frequency applied voltage of an electrode according to an example embodiment of the present disclosure.

FIG. 34 is a graph illustrating a charged amount Qi of a target relative to an applied voltage of an electrode according to an example embodiment of the present disclosure.

FIG. 35 is a graph illustrating the charged amount and potential relative to the applied voltage of the electrode according to an example embodiment of the present disclosure.

FIG. 36 is a diagram illustrating a potential of a target for driving a low-frequency pulse slope voltage.

FIG. 37 is a diagram illustrating a charged amount of a target and a charged amount of a plasma sheath for driving a low-frequency pulse slope voltage.

FIGS. 38 to 41 are flowcharts illustrating an operation method for driving a low-frequency pulse.

FIG. 42 is a diagram illustrating a voltage of a target based on driving of a low-frequency pulse voltage.

FIG. 43 is a diagram illustrating a potential of a target relative to a plasma density.

FIG. 44 is a graph illustrating the potential of the target relative to the plasma density.

FIG. 45 is a diagram illustrating a potential of a target relative to plasma density.

FIG. 46 is a graph illustrating a potential of a target relative to plasma density.

FIG. 47 is a diagram illustrating a potential of a target relative to plasma density.

FIG. 48 is a diagram illustrating a potential of a target relative to a drive voltage waveform of an electrode.

FIG. 49 is a diagram illustrating a potential of a target relative to a drive voltage waveform of an electrode.

FIG. 50 is a conceptual diagram illustrating a plasma apparatus including a capacitor connected to an electrode.

FIG. 51 is a diagram illustrating a potential of a target based on capacitance of a capacitor connected to the electrode of FIG. 50.

FIG. 52 is a diagram illustrating a potential of a target and current flowing through an electrode at a sinusoidal applied voltage.

FIG. 53 is a diagram illustrating current flowing through an electrode at a sinusoidal applied voltage.

FIG. 54 represents the potential of the target at a sinusoidal applied voltage.

FIG. 55 is a diagram illustrating the potential of the target at a sinusoidal applied voltage.

FIG. 56 is a diagram illustrating a potential of a target at a sinusoidal applied voltage based on plasma density.

Referring to FIG. 56, as plasma density increases, the absolute value of the target potential (Vs) decreases.

FIG. 57 is a plasma system illustrating the applied voltage of an electrode with high-frequency modulation.

FIG. 58 is a diagram illustrating the voltage of the target based on the applied voltage of the electrode with high-frequency modulation.

FIG. 59 is a diagram illustrating the voltage of the target under a low-frequency pulse applied voltage with high-frequency modulation of the electrode.

FIG. 60 represents the waveform of a low-frequency pulse synchronized with a high-frequency sinusoidal waveform and the potential of the target.

FIG. 61 is a diagram illustrating a potential of a target when a low-frequency sinusoidal voltage and a high-frequency sinusoidal voltage are applied to an electrode.

FIG. 62 is a diagram illustrating a potential Vs of a target when a low-frequency sinusoidal voltage and a high-frequency sinusoidal voltage are simultaneously applied to an electrode.

FIG. 63 is a conceptual diagram illustrating a voltage of a target considering a plasma potential.

FIG. 64 is graphs illustrating a voltage of a target based on an applied voltage of an electrode, considering a plasma potential.

FIG. 65 is a diagram illustrating a charged amount of a target based on an applied voltage of an electrode, considering a plasma potential.

FIG. 66 is a flowchart illustrating an operation of driving an electrode of a plasma apparatus.

FIG. 67 is a diagram illustrating a potential of a target based on a pulse applied voltage when a plasma potential is present.

FIG. 68 is a diagram illustrating a potential of a target based on a pulse applied voltage when a plasma potential changes over time.

FIG. 69 is a diagram illustrating a value obtained by subtracting a plasma potential from a potential of a target based on a pulse applied voltage when a plasma potential changes over time.

FIG. 70 is a diagram illustrating a charged amount of a target based on a pulse applied voltage when a plasma potential changes over time.

FIG. 71 is a flowchart illustrating driving of an applied voltage of an electrode in a plasma apparatus.

FIG. 72 is a diagram illustrating a potential of a target when a plasma potential remains constant.

FIG. 73 is a diagram illustrating a potential of a target when a plasma potential oscillates over time.

FIG. 74 is a diagram illustrating a potential of a target synchronized with a drive voltage and a plasma potential.

FIG. 75 is a diagram illustrating the value obtained by subtracting a plasma potential from a potential of a target synchronized with a drive voltage.

FIG. 76 is a diagram illustrating the potential of the target synchronized with the drive voltage and plasma potential.

FIG. 77 is a diagram illustrating a potential of a target synchronized with a pulse drive voltage and a plasma potential.

FIG. 78 is a diagram illustrating a potential of a target synchronized with a drive voltage and a plasma potential.

FIG. 79 is a diagram illustrating a charged amount of a target synchronized with a drive voltage and a plasma potential.

FIG. 80 is a diagram illustrating a potential of a target synchronized with a drive voltage and a plasma potential.

FIG. 81 is a diagram illustrating a potential of a target synchronized with a drive voltage and a plasma potential.

FIG. 82 is a diagram illustrating a potential of a target synchronized with a drive voltage and a plasma potential.

FIG. 83 is a diagram illustrating a potential of a target synchronized with a drive voltage and a plasma potential.

FIG. 84 is a diagram illustrating a potential of a target synchronized with a drive voltage and a plasma potential.

FIG. 85 is a diagram illustrating a potential of a target when a plasma potential is constant and a sinusoidal drive voltage is applied.

FIG. 86 is a diagram illustrating a potential of a target where a sinusoidal plasma potential is synchronized with a sinusoidal drive voltage.

FIG. 87 is a diagram illustrating a current waveform flowing through an electrode when a sinusoidal plasma potential is synchronized with a sinusoidal drive voltage.

FIG. 88 is a diagram illustrating a potential of a target when sinusoidal plasma potential is synchronized with a sinusoidal drive voltage.

FIG. 89 is a diagram illustrating a potential of a target over time when a sinusoidal plasma potential is synchronized with a sinusoidal drive voltage.

FIG. 90 is a diagram illustrating a potential of a target when a sinusoidal plasma potential is synchronized with a sinusoidal drive voltage.

FIGS. 91 to 94 are conceptual diagrams, each illustrating a plasma apparatus modifying a plasma potential.

FIG. 95 is a conceptual diagram illustrating a plasma system including an electrostatic electrode and an electrode.

FIG. 96 is a conceptual diagram illustrating an electrode, a first dielectric, an electrostatic electrode, a second dielectric, and a plasma sheath.

FIG. 97 is a graph illustrating a potential of a target based on an applied voltage of an electrode.

FIG. 98 is a diagram illustrating a charged amount of a target based on an applied voltage of an electrode.

FIG. 99 is a diagram illustrating a charged amount of a target based on a charged amount of an electrostatic electrode.

FIG. 100 is a diagram illustrating surface charge density ρᵢ of a target based on a thickness d1 of a first region when an electrostatic electrode has a positive charged amount ρ_{esc}.

FIG. 101 is a diagram illustrating surface charge density ρᵢ of a target based on a thickness d1 of a first region when an electrostatic electrode has a negative charged amount ρ_{esc}.

FIG. 102 is a diagram illustrating a potential of a target when a charged amount of an electrostatic electrode changes over time.

FIG. 103 is a graph illustrating a potential of a target based on an applied voltage of an electrode.

FIG. 104 is a diagram illustrating a potential of a target based on an applied voltage of an electrode.

FIG. 105 is a diagram illustrating a potential of a target based on an applied voltage of an electrode.

FIG. 106 is a flowchart illustrating a method for controlling a voltage of a target.

FIG. 107 is a diagram illustrating a potential of a target based on an applied voltage of an electrode when a charged amount of an electrostatic electrode has a pulse form.

FIG. 108 is a diagram illustrating the potential of a target based on an applied voltage of an electrode when the charged amount of the electrostatic electrode has a pulse form.

FIG. 109 is a conceptual diagram illustrating a plasma apparatus according to an example embodiment of the present disclosure.

FIG. 110 is a conceptual diagram illustrating an electrode, a dielectric, a target, and plasma.

FIG. 111 is a diagram illustrating a potential of a target based on an applied voltage of the electrode in the structure of FIG. 110.

FIG. 112 is a conceptual diagram illustrating a plasma system including an electrostatic electrode.

FIGS. 113 to 116 are conceptual diagrams, each illustrating a plasma system including a variable capacitor.

FIGS. 117 and 118 are conceptual diagrams, each illustrating a method for controlling a voltage of a target according to an example embodiment of the present disclosure.

FIG. 119 is a conceptual diagram distinguishing waveforms of displacement current under conditions according to an example embodiment of the present disclosure.

FIG. 120 is a conceptual diagram classifying ion energy distributions for each region based on ion current density Ji according to an example embodiment of the present disclosure.

FIG. 121 is a graph illustrating damping conditions based on an angular frequency ω of a bias power supply and an applied voltage V.

FIG. 122 is a graph illustrating damping conditions based on the product of an angular frequency ω of a bias power supply and an applied voltage V, and ion current density Ji.

FIG. 123 is a diagram illustrating a waveform of a potential Vs of a target based on ion current density at a sinusoidal applied voltage.

FIGS. 124 and 125 are diagrams illustrating a potential of a target based on capacitance per unit area (ε1/d1) between the target and an electrode at a sinusoidal applied voltage.

FIG. 126 is a diagram illustrating a potential Vs of a target based on capacitance per unit area (ε1/d1) between the target and an electrode at a bipolar DC pulse applied voltage.

FIG. 127 is a diagram illustrating a potential Vs of a target based on ion current density at a bipolar DC pulse applied voltage.

FIG. 128 is a diagram illustrating a potential Vs of a target based on capacitance per unit area (ε1/d1) at a bipolar DC pulse applied voltage.

FIG. 129 is a diagram illustrating a potential Vs of a target based on a slope voltage (X=dV/dt) at a bipolar DC pulse applied voltage.

FIG. 130 is a diagram illustrating a waveform of a potential Vs and a current waveform of a target at a sinusoidal applied voltage based on conditions.

FIG. 131 is a diagram illustrating a waveform of a potential Vs and a current waveform of a target at a sinusoidal applied voltage based on conditions.

FIG. 132 is a diagram illustrating a waveform of a potential Vs and a current waveform of a target under a sinusoidal applied voltage based on conditions.

### MODE FOR CARRYING OUT THE INVENTION

Plasma is widely used in various applications such as luminescence, semiconductor processing, coating, deposition, etching, sputtering, ion implantation, or surface treatment.

According to the present disclosure, a potential and current of a target exposed to plasma may be calculated and controlled through a structure applying a potential to the target via a capacitor or a dielectric. Various examples of controlling the potential of the target will be described. In particular, the potential of the target is closely related to ion energy.

Hereinafter, example embodiments of the inventive concepts may, however, be embodied in many different forms and should not be construed as being limited to the embodiments set forth herein. Rather, the embodiments are provided so that the present disclosure will be thorough and complete, and will fully convey the concept of example embodiments to those of ordinary skill in the art. In the drawings, components are exaggerated for clarity. Like reference numerals in the drawings denote like elements and, therefore, repetitive description thereof will be omitted.

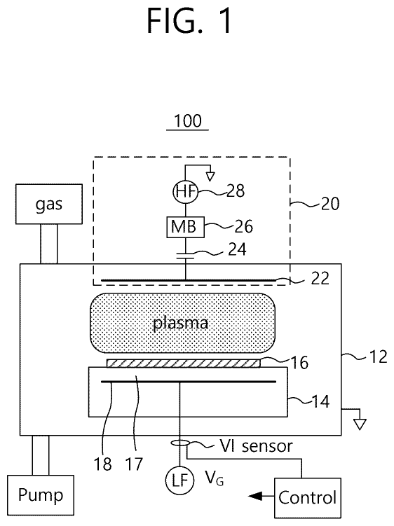

FIG. 1 is a conceptual diagram illustrating a plasma apparatus according to an example embodiment of the present disclosure.

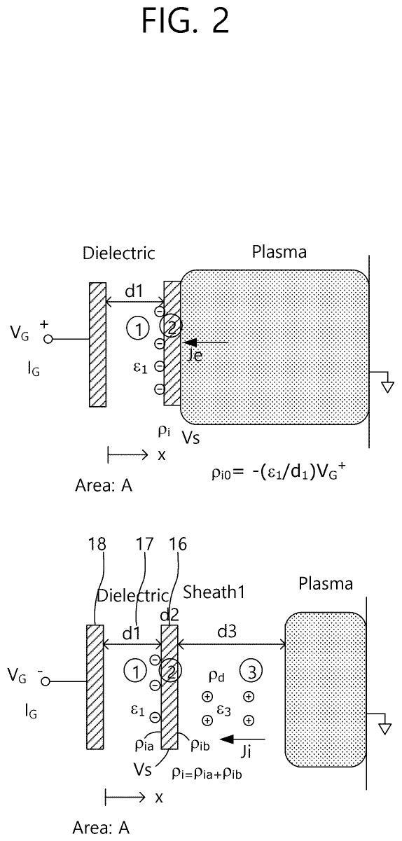

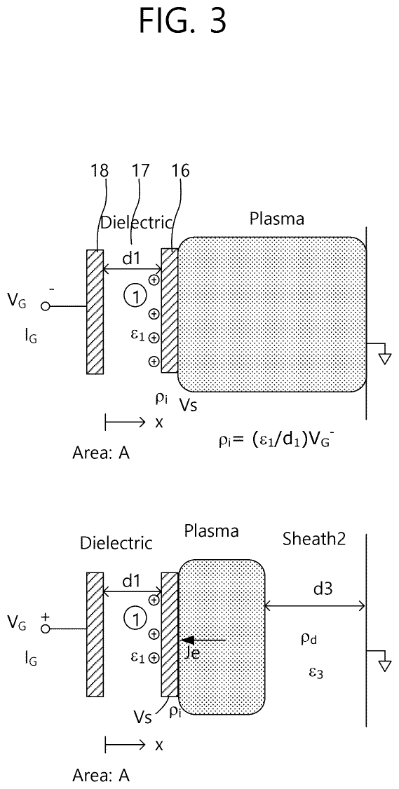

FIGS. 2 and 3 are conceptual diagrams illustrating an electrode, a dielectric, a target, and plasma illustrated in FIG. 1.

Referring to FIGS. 1 to 3, a plasma system 100 includes a chamber 12, a plasma source 20 generating plasma within the chamber 12, and a target holder 14 mounting a target 16. The target 16 may be a semiconductor substrate, a dielectric substrate, or a workpiece. The chamber 12 may be formed of a dielectric material or a metal material and may be grounded. The plasma source 20 may include a high-frequency power supply 28, a plasma electrode 22, an impedance matching network 26 disposed between the plasma electrode 22 and the high-frequency power supply 28, and a capacitor 24 disposed between the impedance matching network 26 and the plasma electrode 22. Gas may be injected into the chamber 12 and evacuated by a vacuum system.

The plasma source 20 may be a high-frequency capacitively coupled plasma source, a high-frequency inductively coupled plasma source, or a very high-frequency plasma source.

The target holder 14 may have a structure in which an electrode 18, a dielectric 17, and a target 16 are sequentially stacked. The plasma may contact the target 16. A plasma sheath may be formed between the target 16 and the plasma. The target 16 may be a conductor, a dielectric, or a semiconductor.

A voltage/current sensor may measure at least one of current and voltage flowing through the electrode 18. An output of a voltage/current sensor may be calculated by a control unit, and the control unit may control a plasma system (for example, a low-frequency power supply) using the equations described below.

For example, an applied voltage V_{G} may be applied to the electrode 18, the target 16 may be a semiconductor or a conductor, and the target 16 may accumulate electrons or positive ions on a surface thereof. A plasma sheath may be formed between the plasma and the target 16. The plasma sheath may be treated as a space having positive space charges. The target 16 may perform at least one of sputtering, etching, ion implantation, deposition, and surface treatment.

A low-frequency power supply LF may apply an applied voltage V_{G} or a driving voltage to the electrode 18. The low-frequency power supply LF may be a pulsed low-frequency power supply or a sinusoidal low-frequency power supply. A boundary between a high frequency and a low frequency may be 10 MHz. The boundary between the high frequency and the low frequency may be an ion plasma frequency. The high-frequency power supply (HF) 28 may generate plasma by stochastic heating, and the low-frequency power supply LF may control a potential Vs of the target 16.

A thickness d3 of the plasma sheath varies depending on the applied voltage V_{G}. The dielectric 17 is a first region, the target 16 is a second region, and the plasma sheath is a third region. A thickness of the dielectric is d1, and a thickness of the target is d2. The voltage of the target 16 is Vs, and surface charge density thereof is ρi. A dielectric constant of the first region is ε1, and a dielectric constant of the third region is 3. A dielectric constant of the plasma sheath 3 may be a dielectric constant of vacuum. An area of the electrode 18 and the target 16 is A.

A general solution of a voltage V1 in the first region, a general solution of a voltage V2 in the second region, and a general solution of a voltage V3 in the third region are given as follows. In addition, an electric field ε1 of the first region and an electric field ε3 of the third region are given as follows. The origin of a coordinate system is the electrode, and x is coordinates of the Cartesian coordinate system.

### [Considering the Matrix Model]

A matrix model regards the charge density ρ_{d} of the plasma sheath as a constant that does not depend on a position.

$${V}_{1} = {A}_{1} x + {A}_{2} \to \vec{{E}_{1}} = - {A}_{1} \qquad [ Equation 1 ]$$

$${V}_{2} = {B}_{1}$$

$${V}_{3} = - \frac{{ρ}_{d}}{2 {ϵ}_{3}} {x}^{2} + {C}_{1} x + {C}_{2} \to \vec{{E}_{3}} = \frac{{ρ}_{d} x}{{ϵ}_{3}} - {C}_{1}$$

where ρ_{d} is charge density of the plasma sheath or plasma. A1, A2, B1, C1, and C2 are unknowns. When boundary conditions and initial conditions are used, A1, A2, B1, C1, and C2 may be given as follows. An initial condition is that the electric field ε3 is zero at the boundary between the plasma and the plasma sheath. The target 16 is a conductor, and the first surface charge density of the surface opposing the dielectric 17 is Pia, while the second surface charge density of the surface opposing the plasma sheath is ρ_{ib}. The sum of the first charge density and the second surface charge density is the surface charge density ρi.

$${ρ}_{i} = {ρ}_{ia} + {ρ}_{ib} \qquad [ Equation 2 ]$$

$${A}_{1} = \frac{{ρ}_{i} + {ρ}_{d} {d}_{3}}{{ϵ}_{1}} \qquad [ Equation 3 ]$$

$${A}_{2} = {V}_{G}$$

$${C}_{1} = \frac{{ρ}_{d}}{{ϵ}_{3}} ( {d}_{1} + {d}_{2} + {d}_{3} )$$

$${C}_{2} = \frac{{d}_{1} ( {ρ}_{i} + {ρ}_{d} {d}_{3} )}{{ϵ}_{1}} + {V}_{G} + \frac{{ρ}_{d}}{2 {ϵ}_{3}} {( {d}_{1} + {d}_{2} )}^{2} - \frac{{ρ}_{d}}{{ϵ}_{3}} ( {d}_{1} + {d}_{2} ) ( {d}_{1} + {d}_{2} + {d}_{3} )$$

An electric field in each region is given as follow:

$$\vec{{E}_{1}} = - \frac{{ρ}_{i} + {ρ}_{d} {d}_{3}}{{ϵ}_{1}} \qquad [ Equation 4 ]$$

$$\vec{{E}_{3}} = \frac{{ρ}_{d}}{{ϵ}_{2}} [ x - ( {d}_{1} + {d}_{2} + {d}_{3} ) ]$$

The voltage or potential Vs of the target 16 is given as follow:

$${V}_{s} = {V}_{G} + \frac{{d}_{1}}{{ϵ}_{1}} [ {ρ}_{i} + {ρ}_{d} {d}_{3} ] \qquad [ Equation 5 ]$$

For example, the thickness d3 of the plasma sheath is calculated and the voltage Vs of the target 16 is given as negative values, as follows:

$$- {V}_{S} = \frac{{ρ}_{d}}{2 {ϵ}_{3}} {d}_{3}^{2} \to {d}_{3} = \sqrt{\frac{- 2 {ϵ}_{3} {V}_{s}}{{ρ}_{d}}} \qquad [ Equation 6 ]$$

$${V}_{s} = {V}_{G} + \frac{{d}_{1}}{{ϵ}_{1}} [ {ρ}_{i} + {ρ}_{d} {d}_{3} ]$$

$${V}_{s} = {V}_{G} + \frac{{d}_{1}}{{ϵ}_{1}} {ρ}_{i} + \frac{{d}_{1}}{{ϵ}_{1}} \sqrt{- 2 {ϵ}_{3} {V}_{s} {ρ}_{d}}$$

$$- {V}_{s} = {\frac{1}{4} [ - \frac{{d}_{1}}{{ϵ}_{1}} \sqrt{2 {ϵ}_{3} {ρ}_{d}} + \sqrt{{( \frac{{d}_{1}}{{ϵ}_{1}} \sqrt{2 {ϵ}_{3} {ρ}_{d}} )}^{2} - 4 ( {V}_{G} + \frac{{d}_{1}}{{ϵ}_{1}} {ρ}_{i} )} ]}^{2}$$

$${V}_{s} = - {( \frac{{d}_{1}}{{ϵ}_{1}} )}^{2} {ϵ}_{3} {ρ}_{d} + ( {V}_{G} + \frac{{d}_{1}}{{ϵ}_{1}} {ρ}_{i} ) + \frac{{d}_{1}}{2 {ϵ}_{1}} \sqrt{2 {ϵ}_{3} {ρ}_{d}} \sqrt{{( \frac{{d}_{1}}{{ϵ}_{1}} \sqrt{2 {ϵ}_{3} {ρ}_{d}} )}^{2} - 4 ( {V}_{G} + \frac{{d}_{1}}{{ϵ}_{1}} {ρ}_{i} )}$$

When the thickness d3 of the plasma sheath is zero, for example, when the electrode 18 is in an equilibrium state with a positive voltage V_{G}⁺, the target 16 and the electrode 18 may be treated as a capacitor with a dielectric 17. In this case, the initial surface charge density ρᵢ of the target 16 caused by the positive applied voltage V_{G}+ may be given as follows:

$$\frac{{ρ}_{i} {d}_{1}}{{ϵ}_{1}} = - {V}_{G}^{+} at {d}_{3} = 0 \qquad [ Equation 7 ]$$

When the electrode 18 is in an equilibrium state at a positive applied voltage V_{G}+, the target 16 may be initially charged with a negative charge. When the applied voltage V_{G} of the electrode 18 suddenly transitions from a positive value V_{G}+ to a negative value V_{G}−, the target 16 may transition to the negative voltage while maintaining the negative charge. In this case, a plasma sheath may be formed, and a displacement current may flow through the electrode 18.

FIG. 3 is a diagram illustrating the case in which a negative voltage is applied to an electrode to be in an equilibrium state.

Referring to FIG. 3, when a negative applied voltage V_{G}− is continuously applied to the electrode 18, the target 16 may be charged with a positive charge due to the introduction of ion current density Ji, the voltage of the target 16 becomes zero, and the plasma sheath disappears. In this case, it operates simply as a capacitor at Vs=0, and an amount of positive charges on the target 16 is given as follows:

$$\frac{{ρ}_{i} {d}_{1}}{{ϵ}_{1}} = - {V}_{G}^{-} at {d}_{3} = 0 \qquad [ Equation 8 ]$$

When the applied voltage of the electrode 18 suddenly transitions from a negative value V_{G}− to a positive value V_{G}+, the target 16 may transition to a positive voltage while maintaining a positive charge. In this case, when the potential Vs of the target is greater than or equal to zero at a positive applied voltage, the plasma and the target 16 may simultaneously increase in potential to form a second plasma sheath on a grounded chamber wall. Electrons may be rapidly introduced into the target 16, causing the second plasma sheath to disappear and the target 16 to be charged with a negative charge.

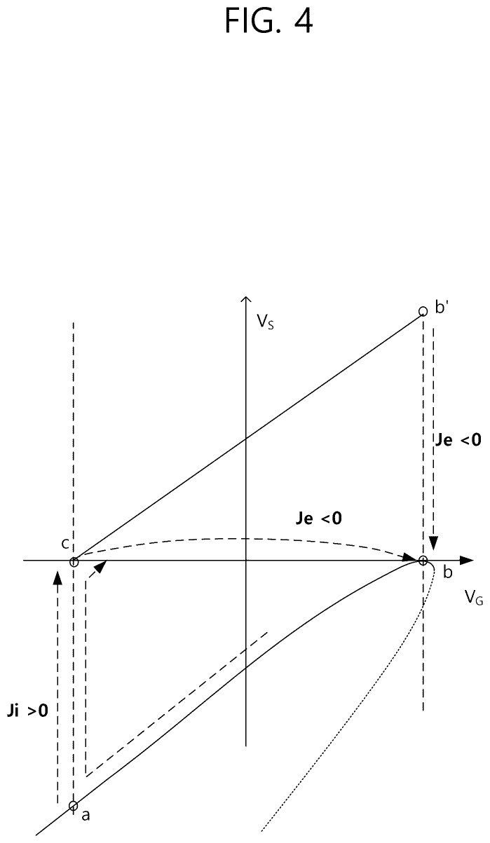

FIG. 4 is a graph illustrating a potential of a target based on a pulse voltage waveform alternating between positive and negative voltages.

Referring to FIG. 4, when a negative applied voltage V_{G}− is continuously applied to the electrode 18, the target 16 is charged with positive charges due to the introduction of ion current density Ji, and the voltage Vs of the target 16 becomes zero and the plasma sheath disappears at point c.

When the applied voltage of the electrode 18 suddenly transitions from a negative value V_{G}− to a positive value V_{G}+, the applied voltage may transition from point c to point b along a different path instead of transitioning from point c to b′-b. Since electrons have a significantly high mobility, they respond immediately to a change in applied voltage.

When the applied voltage of the electrode 18 suddenly transitions from a negative value to a positive value and electrons are not rapidly introduced into the target 16, the voltage Vs of the target 16 is given as follows at point b′, and a new second plasma sheath is formed on the ground. When the target is charged with positive charges and the applied voltage of the electrode 18 suddenly transitions from a negative value to a positive value, the potential of the target approaches the plasma potential Vp, and the plasma potential increases.

$$Vs = Vp \qquad [ Equation 9 ]$$

However, when electrons are rapidly introduced into the target 16, the voltage Vs of the target 16 transitions from point c to point b.

When a positive voltage is applied to the electrode 18, the target 16 is negatively charged in an equilibrium state. When the applied voltage of the electrode 18 suddenly transitions from point b to point a, from a positive value to a negative value, a plasma sheath is formed and the ion current density Ji slowly charges the target 16 to a positive value through the plasma sheath.

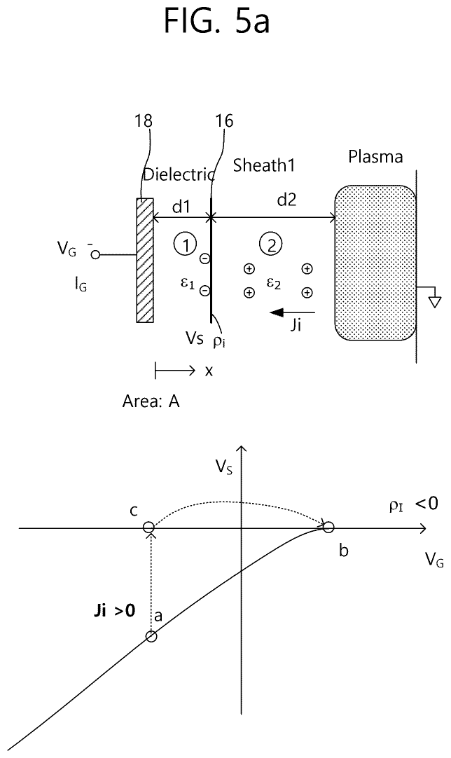

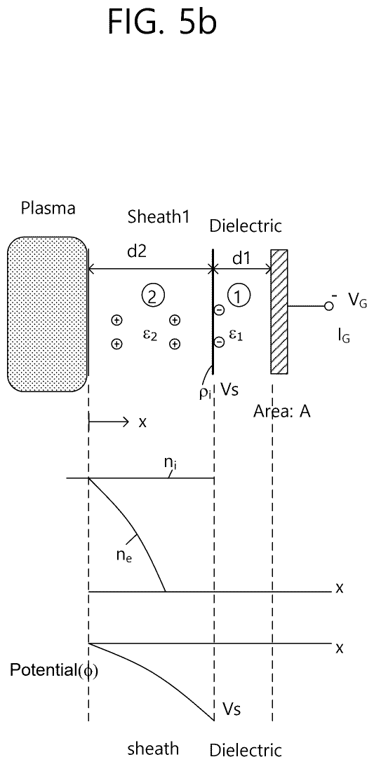

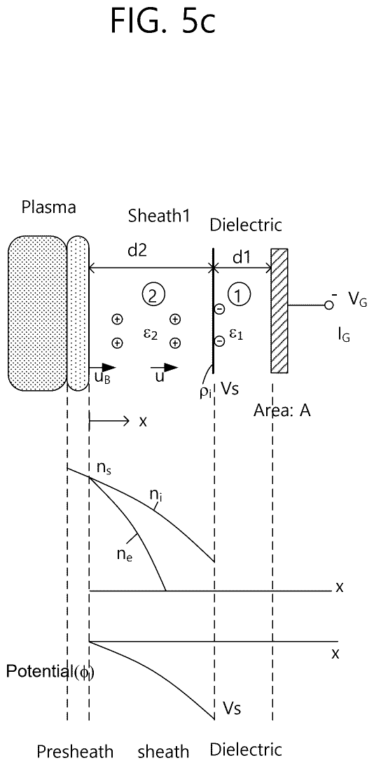

FIG. 5A is a diagram illustrating a plasma sheath structure when the thickness of the target is negligible.

Referring to FIG. 5A, the plasma system 100 may include a chamber 12, a plasma source 20 generating plasma within the chamber 12, and a target holder 14 mounting the target 16. The target 16 may be a semiconductor substrate, a dielectric substrate, a sputtering target, an edge ring, a focus ring, or a workpiece arranged around the substrate. The chamber 12 is formed of a dielectric material or a metal material, and the metal chamber may be grounded. The plasma source 20 may include a high-frequency power supply (HF) 28, a plasma electrode 22, an impedance matching network 26 disposed between the plasma electrode and the high-frequency power supply, and a capacitor 24 disposed between the impedance matching network and the plasma electrode. Gas may be injected into the chamber 12 and may be evacuated by a vacuum system.

A voltage V_{G} may be applied to the electrode 18, the target 16 may be a semiconductor or conductor, and the target 16 may have a surface on which electrons or positive ions are accumulated. A plasma sheath may be formed between the plasma and the target 16. The plasma sheath may be treated as a region with a positive space charge. A thickness d2 of the plasma sheath varies depending on the voltage V_{G}. The dielectric region is a first region, and the plasma sheath is a second region. A thickness of the dielectric 17 is d1. When the target 16 is a conductor, the thickness of the target 16 may be negligible. A thickness of the plasma sheath is d2. A voltage of the target 16 is Vs. Surface charge density of the target 16 is ρᵢ. A dielectric constant of the first region may be ε1, and a dielectric constant of the plasma sheath may be ε2 that is a dielectric constant of vacuum.

General solutions for the voltage in the first region V1 and the second region V2 are given as follows. Additionally, an electric field ε1 in the first region and am electric field ε2 the second region are given as follows. An origin of the coordinate system is at the electrode, and x is the coordinate in the rectangular coordinate system.

$${V}_{1} = {A}_{1} x + {A}_{2} \to \vec{{E}_{1}} = - {A}_{1} \qquad [ Equation 10 ]$$

$${V}_{2} = - \frac{{ρ}_{d}}{2 {ϵ}_{2}} {x}^{2} + {B}_{1} x + {B}_{2} \to \vec{{E}_{2}} = \frac{{ρ}_{d} x}{{ϵ}_{2}} - {B}_{1}$$

where charge density in the plasma sheath is ρ_{d}. A1, A2, B1, and B2 are unknowns.

If boundary conditions and initial conditions are used, A1, A2, B1, and B2 may be determined as follows. As an initial condition, an electric field ε2 is assumed to be zero at the boundary between the plasma and the plasma sheath.

$${A}_{1} = \frac{{ρ}_{i} + {ρ}_{d} {d}_{2}}{{ϵ}_{1}} \qquad [ Equation 11 ]$$

$${A}_{2} = {V}_{G}$$

$${B}_{1} = \frac{{ρ}_{d}}{{ϵ}_{2}} ( {d}_{1} + {d}_{2} )$$

$${B}_{2} = \frac{{ρ}_{i} {d}_{1}}{{ϵ}_{1}} + {V}_{G} + \frac{{ρ}_{d} {d}_{1}}{2 {ϵ}_{1} {ϵ}_{2}} ( 2 {ϵ}_{2} {d}_{2} - {ϵ}_{1} {d}_{1} - 2 {ϵ}_{1} {d}_{2} )$$

An electric field in each region is given as follows:

$$\vec{{E}_{1}} = - \frac{{ρ}_{i} + {ρ}_{d} {d}_{2}}{{ϵ}_{1}} \qquad [ Equation 12 ]$$

$$\vec{{E}_{2}} = \frac{{ρ}_{d}}{{ϵ}_{2}} [ x - ( {d}_{1} + {d}_{2} ) ]$$

The voltage Vs of the target 16 is given as follows:

$${V}_{s} = {V}_{G} + \frac{{d}_{1}}{{ϵ}_{1}} [ {ρ}_{i} + {ρ}_{d} {d}_{2} ] \qquad [ Equation 13 ]$$

In an equilibrium state while a positive applied voltage V_{G}+ is applied to the electrode 18, the electrode 18 and the target 16 become a simple capacitor, and the charged amount ρi of the target 16 is given as follows:

$$\frac{{ρ}_{i} {d}_{1}}{{ϵ}_{1}} = - {V}_{G}^{+} at {d}_{2} = 0 \qquad [ Equation 14 ]$$

On the other hand, the thickness d2 of the plasma sheath and the surface potential Vs of the target 16 are given as follows:

$$- {V}_{s} = \frac{{ρ}_{d}}{2 {ϵ}_{2}} \to {d}_{2}^{2} \to {d}_{2} = \sqrt{\frac{- 2 {ϵ}_{2} {V}_{s}}{{ρ}_{d}}} \qquad [ Equation 15 ]$$

$${V}_{s} = {V}_{G} + \frac{{d}_{1}}{{ϵ}_{1}} [ {ρ}_{i} + {ρ}_{d} {d}_{2} ]$$

$${V}_{s} = {V}_{G} + \frac{{d}_{1}}{{ϵ}_{1}} {ρ}_{i} + \frac{{d}_{1}}{{ϵ}_{1}} \sqrt{- 2 {ϵ}_{2} {V}_{s} {ρ}_{d}}$$

The surface potential Vs of the target 16 is given as follows:

$$[ Equation 16 ]$$

$$- {V}_{s} = {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )} ]}^{2}$$

$${V}_{s} = - {( \frac{{d}_{1}}{{ϵ}_{1}} )}^{2} {ϵ}_{2} {ρ}_{d} + ( {V}_{G} + \frac{{d}_{1}}{{ϵ}_{1}} {ρ}_{i} ) + \frac{{d}_{1}}{2 {ϵ}_{1}} \sqrt{2 {ϵ}_{2} {ρ}_{d}} \sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}$$

The voltage Vs of the target 16 has two solutions based on a quadratic formula, but a positive sign is selected such that the voltage Vs of the target 16 includes zero. The voltage Vs of the target 16 has a negative value due to the initial negative charge, which causes a DC bias. The plasma charge density ρ_{d} may be measured using a Langmuir probe or the like. When the plasma charge density ρ_{d} is known, the voltage Vs of the target 16 may be calculated. When the target is a conductor, the same result is obtained as when the thickness of the target is negligible.

The matrix model, the model considering the electron temperature, and the Child-Langmuir model are compared.

### [Considering Electron Temperature]

FIG. 5B is a diagram illustrating a plasma sheath structure when a thickness of a target is negligible.

Referring to FIG. 5B, Poisson's equation is modified as follows. An electric field is zero in a plasma region, and the electric field is Es at a boundary between the plasma sheath and the target 16. The plasma potential is assumed to be zero. Also, a potential φ is zero in the plasma region and Vs at the boundary between the plasma sheath and the target. When the boundary condition of Gauss's law are used, surface charge density ρₛ charged on the surface of the target 16 is determined by Es. q is a positive unit charge, k is a Boltzmann constant, and Te an electron temperature. An origin of the coordinate system is at the boundary between the plasma and the sheath.

$$\frac{{d}^{2} φ}{{dx}^{2}} = - \frac{q ( {n}_{i} - {n}_{e} )}{{ϵ}_{2}} \qquad [ Equation 17 ]$$

$$\frac{{d}^{2} φ}{{dx}^{2}} = - \frac{{ρ}_{d}}{{ϵ}_{2}} \to E \frac{dE}{d φ} = - \frac{{ρ}_{d}}{{ϵ}_{2}}$$

$${ρ}_{d} = {ρ}_{0} [ 1 - {e}^{( \frac{{qV}_{s}}{{kT}_{e}} )} ]$$

$$\frac{{E}_{s}^{2}}{2} = \frac{{ρ}_{0}}{{ϵ}_{2}} [ - {V}_{s} + \frac{{kT}_{e}}{q} [ {e}^{( \frac{{qV}_{s}}{{kT}_{e}} )} - 1 ] ]$$

$${E}_{s} = {\{ \frac{2 {ρ}_{0}}{{ϵ}_{2}} [ - {V}_{s} + \frac{{kT}_{e}}{q} [ {e}^{( \frac{{qV}_{s}}{{kT}_{e}} )} - 1 ] ] \}}^{1 / 2}$$

$${ρ}_{s} = {ϵ}_{2} {E}_{s}$$

The voltage Vs of the target 16 is given as follows:

$${V}_{s} = {V}_{G} + \frac{{d}_{1} {ρ}_{i}}{{ϵ}_{1}} + \frac{{d}_{1}}{{ϵ}_{1}} {ρ}_{s} \qquad [ Equation 18 ]$$

$${V}_{s} = {V}_{G} + \frac{{d}_{1} {ρ}_{i}}{{ϵ}_{1}} + \frac{{d}_{1}}{{ϵ}_{1}} {\{ 2 {ϵ}_{2} {ρ}_{0} [ - {V}_{s} + \frac{{kT}_{e}}{q} [ {e}^{( \frac{{qV}_{s}}{{kT}_{e}} )} - 1 ] ] \}}^{1 / 2}$$

### [Considering the Child-Langmuir Model]

FIG. 5C is a diagram illustrating a plasma sheath structure when a thickness of a target is negligible.

Referring to FIG. 5C, the Child-Langmuir model has a Bohm velocity u_{B}, and ions start with the Bohm velocity at a boundary between a plasma presheath and a plasma sheath and are accelerated in the plasma sheath due to energy conservation and flux conservation. A plasma potential Vp is assumed to be zero. An electric field is zero in the plasma region, and the electric field is Es at a boundary between the plasma sheath and the target 16. Also, a potential φ is zero in the plasma region and Vs at the boundary between the plasma sheath and the target. When the boundary condition of Gauss's law is used, surface charge density ρₛ charged on a surface of the target 16 is determined by Es. q is a positive unit charge, k is a Boltzmann constant, and Te is an electron temperature. M is an ion mass. ρ₀ is charge density in the presheath. ρ₀ may be 0.61 times the charge density of the plasma. An origin of the coordinate system is at the boundary between the plasma and the sheath.

$$\frac{{d}^{2} φ}{{dx}^{2}} = - \frac{q ( {n}_{i} - {n}_{e} )}{{ϵ}_{2}} \qquad [ Equation 19 ]$$

$$\frac{{d}^{2} φ}{{dx}^{2}} = - \frac{{ρ}_{d}}{{ϵ}_{2}} \to E \frac{dE}{d φ} = - \frac{{ρ}_{d}}{{ϵ}_{2}}$$

$${ρ}_{d} = {ρ}_{0} [ {( 1 - \frac{2 q φ}{{Mu}_{B}^{2}} )}^{- 1 / 2} - {e}^{( \frac{{qV}_{s}}{{kT}_{e}} )} ]$$

$$\frac{{E}_{s}^{2}}{2} = \frac{{ρ}_{0}}{{ϵ}_{2}} [ 2 \frac{\sqrt{- {aV}_{s} + 1}}{a} - 2 \frac{1}{a} + \frac{{kT}_{e}}{q} [ {e}^{( \frac{{qV}_{s}}{{kT}_{e}} )} - 1 ] ]$$

$$a = \frac{2 q}{{Mu}_{B}^{2}}$$

$${u}_{B} = {( {kT}_{e} / M )}^{1 / 2}$$

$${E}_{s} = {\{ 2 \frac{{ρ}_{0}}{{ϵ}_{2}} [ 2 \frac{\sqrt{- {aV}_{s} + 1}}{a} - 2 \frac{1}{a} + \frac{{kT}_{e}}{q} [ {e}^{( \frac{{qV}_{s}}{{kT}_{e}} )} - 1 ] ] \}}^{1 / 2}$$

$${ρ}_{s} = {ϵ}_{2} {E}_{s}$$

A voltage Vs of the target 16 is given as follows.

$${V}_{s} = {V}_{G} + \frac{{d}_{1} {ρ}_{i}}{{ϵ}_{1}} + \frac{{d}_{1}}{{ϵ}_{1}} {ρ}_{s} \qquad [ Equation 20 ]$$

$${V}_{s} = {V}_{G} + \frac{{d}_{1} {ρ}_{i}}{{ϵ}_{1}} + \frac{{d}_{1}}{{ϵ}_{1}} {\{ 2 {ϵ}_{2} {ρ}_{0} [ 2 \frac{\sqrt{- {aV}_{s} + 1}}{a} - 2 \frac{1}{a} + \frac{{kT}_{e}}{q} [ {e}^{( \frac{{qV}_{s}}{{kT}_{e}} )} - 1 ] ] \}}^{1 / 2}$$

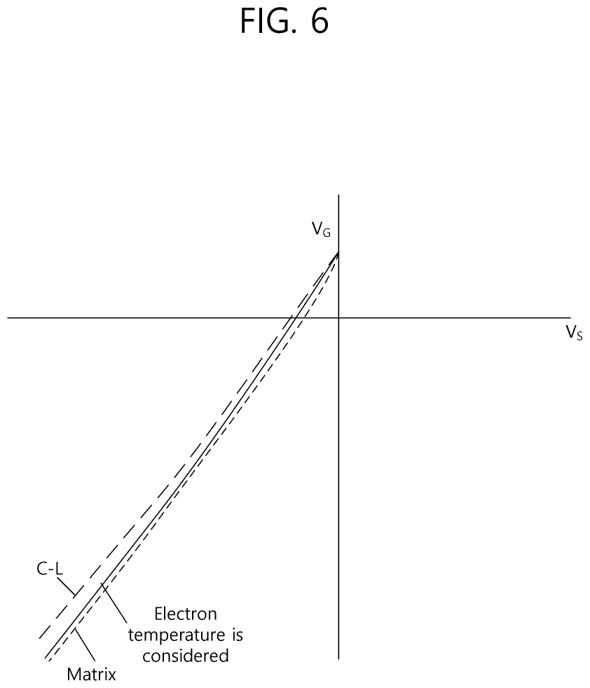

FIG. 6 is a graph illustrating an applied voltage V_{G} of an electrode as a function of a voltage Vs of a target based on the matrix model, the model considering the electron temperature, and the Child-Langmuir C-L model.

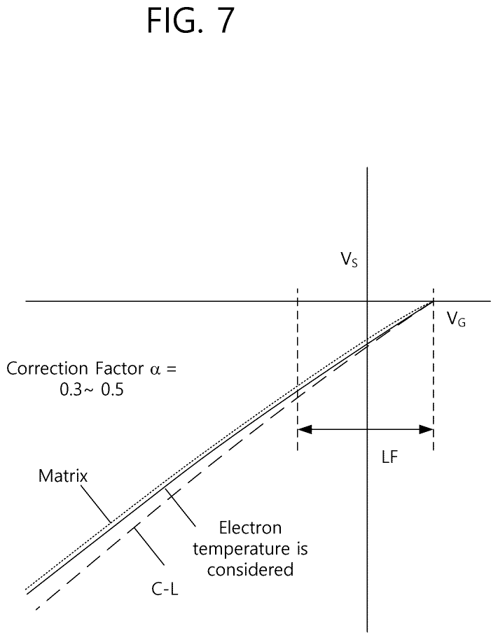

FIG. 7 is a graph illustrating a voltage Vs of a target as a function of an applied voltage V_{G} of an electrode based on the matrix model, the model considering the electron temperature, and the Child-Langmuir model, with the change of axes.

Referring to FIGS. 6 and 7, the matrix model and the model considering the electron temperature shows the same voltage Vs of the target 16 for the same electrode voltage, except in a region affected by the electron temperature. However, the Child-Langmuir model shows a lower voltage Vs compared to the matrix model for the same applied voltage of the electrode.

When a correction factor α is added to the voltage Vs of the target 16 based on the Child-Langmuir model, the voltage Vs of the target 16 based on the Child-Langmuir model is given as follows.

### [C-L Model Corrected to Matrix Model α=0.3˜0.5 α=0.33]

$$- {V}_{s} = {V}_{G} + \frac{{d}_{1} {ρ}_{i}}{{ϵ}_{1}} + \frac{{d}_{1} α}{{ϵ}_{1}} {ρ}_{s} \sqrt{2 {ϵ}_{2} {V}_{s} {ρ}_{d}} \qquad Equation 21 ]$$

$$- {V}_{s} = {\frac{1}{4} [ - \frac{{d}_{1} α}{{ϵ}_{1}} \sqrt{2 {ϵ}_{2} {ρ}_{d}} + \sqrt{{( \frac{{d}_{1} α}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )} ]}^{2}$$

The voltage Vs of the target 16 based on the Child-Langmuir model appears to have increased capacitance per unit area (ε1/d1) of the dielectric 17. The correction factor α depends on the applied voltage of the electrode 18, and when the applied voltage of the electrode 18 is several tens of volts, the correction factor α is around 0.5. When the applied voltage of the electrode is several hundred volts, the correction factor α is around 0.3.

### [Capacitance of the Sheath]

The capacitance per unit area of the plasma sheath cₛₕ is given as follows.

$$Δ {V}_{G} = - \frac{{Q}_{i}}{{c}_{1}} - \frac{{Q}_{sh}}{{c}_{1}} + Δ {V}_{S}$$

$$Δ {V}_{G} = \frac{Δ {Q}_{G}}{{c}_{1}} + Δ {V}_{S}$$

$$\frac{Δ {V}_{G}}{Δ {Q}_{G}} = \frac{1}{{c}_{1}} + \frac{Δ {V}_{S}}{Δ {Q}_{G}}$$

$$\frac{Δ {Q}_{G}}{Δ {V}_{S}} = - \frac{Δ {Q}_{sh}}{Δ {V}_{S}}$$

$${Q}_{sh} = \sqrt{2 {ϵ}_{2} {ρ}_{d} ( - {V}_{S} )}$$

$$\frac{Δ {Q}_{G}}{Δ {V}_{S}} = - \frac{Δ {Q}_{sh}}{Δ {V}_{S}} = \frac{{dQ}_{sh}}{d ( - {V}_{S} )} = \sqrt{2 {ϵ}_{2} {ρ}_{d}} \frac{d \sqrt{( - {V}_{S} )}}{d ( - {V}_{S} )} = \frac{\sqrt{2 {ϵ}_{2} {ρ}_{d}}}{2 ( \sqrt{- {V}_{S}} )}$$

$$\frac{Δ {Q}_{G}}{Δ {V}_{S}} = {c}_{sh} = \frac{\sqrt{2 {ϵ}_{2} {ρ}_{d}}}{[ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )} ]}$$

### [Considering Electron Temperature and Floating Potential]

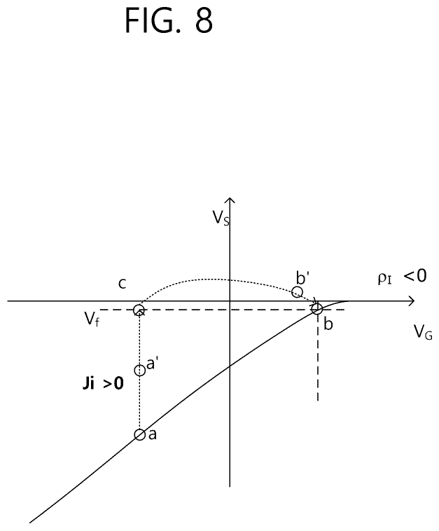

FIG. 8 is a graph illustrating a relationship between a voltage of a target and an applied voltage, considering a floating potential.

Referring to FIG. 8, when an electron temperature Te and a floating potential V_{f} are considered, V_{GF} is an additional applied voltage required to generate a floating potential V_{f}. A potential Vs of the target 16 is given as follows:

$${V}_{S} = {V}_{GF} + {V}_{G} + \frac{{d}_{1} {ρ}_{i}}{{ϵ}_{1}} + \frac{{d}_{1}}{{ϵ}_{1}} {ρ}_{S} \sqrt{- 2 {ϵ}_{2} {V}_{S} {ρ}_{d}} \qquad [ Equation 22 ]$$

$$- {V}_{S} = {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} + {V}_{GF} )} ]}^{2}$$

The floating potential V_{f} represents an initial potential state of the target 16 in an equilibrium state. Therefore, at a positive applied voltage V_{G}+, the potential Vs of the target 16 is offset from zero and has a floating potential V_{f}. For example, the target 16 may be overcharged with negative charges for the floating potential V_{f}. The floating potential V_{f} may be measured using a Langmuir probe, or may be theoretically predicted.

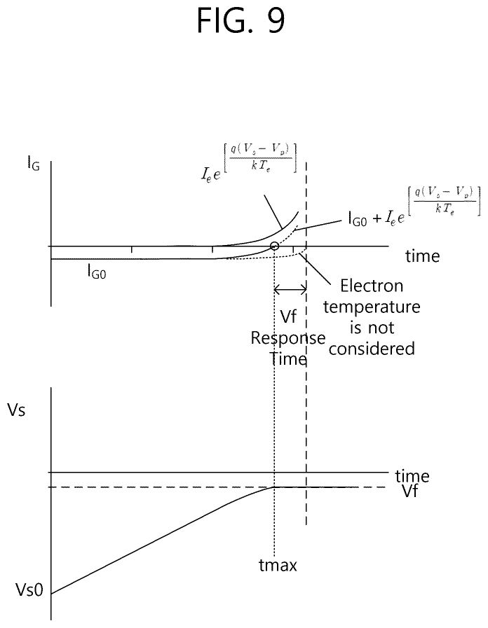

FIG. 9 is a diagram illustrating current I_{G} flowing through an electrode and a voltage Vs of a target based on a bipolar pulse applied voltage waveform of the electrode.

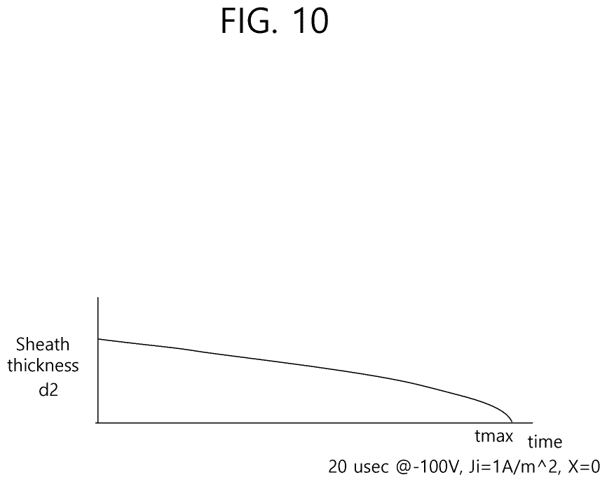

FIG. 10 is a diagram illustrating a thickness of a plasma sheath over time for a negative applied voltage V_{G}⁻ of an electrode.

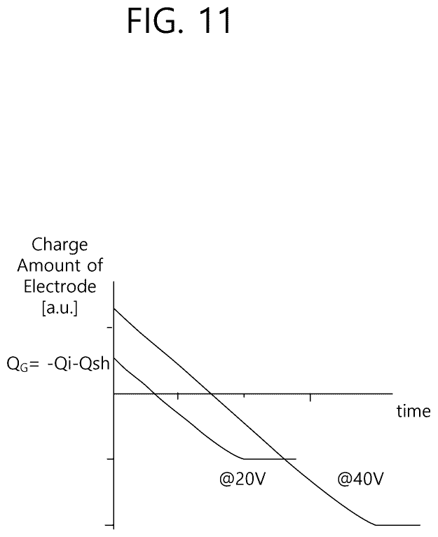

FIG. 11 is a diagram illustrating the negative sum of a charged amount of a plasma sheath and surface charge density of a target over time at a negative applied voltage V_{G}− of the electrode.

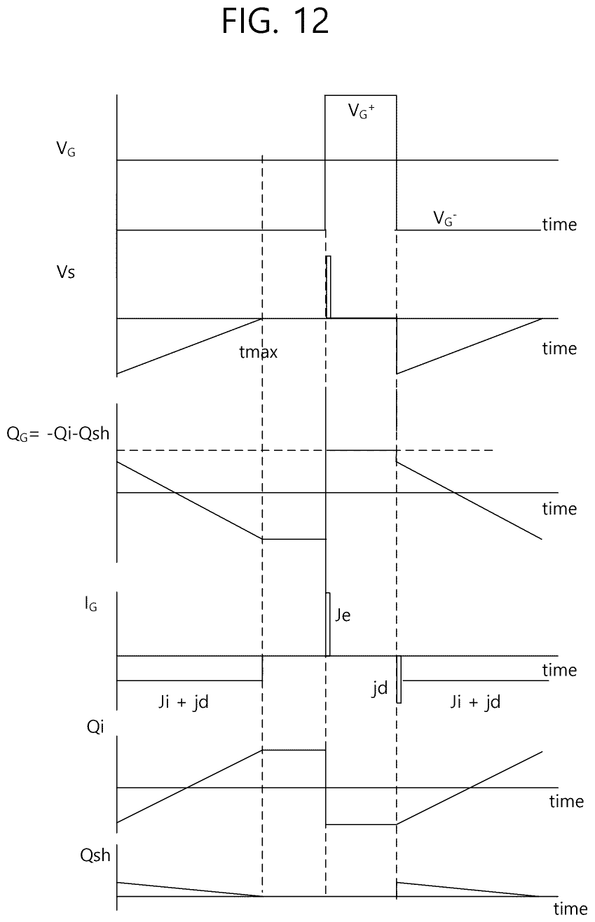

FIG. 12 is a graph illustrating various characteristics based on an applied voltage of an electrode.

Referring to FIGS. 9 to 12, when a positive value V_{G}+ is applied to the electrode 18, the target 16 is negatively charged in an equilibrium state. When the applied voltage of the electrode 18 suddenly transitions from a positive value V_{G}+ to a negative value V_{G}−, a plasma sheath is formed, and an ion current density Ji flows through the plasma sheath to the electrode 18. In addition, as the ion current density Ji flows and the target 16 is charged with positive charges, a displacement current flows simultaneously. Accordingly, the current I_{G0} flowing through the electrode 18 is represented as the sum of the ion current density Ji and the displacement current Ja.

On the other hand, when a negative value V_{G}− is continuously applied to the electrode 18, the target 16 reaches an equilibrium state due to the ion current density Ji, and no current flows through the electrode 18 anymore. In this case, the charge of the target 16 has a positive value and is given by the voltage V_{G}− of the electrode 18. The sum of the charge of the plasma sheath and the negative of the surface charge density of the target is the charge of the electrode Q_{G}.

Referring to FIGS. 9 to 12, after a negative applied voltage is applied, a cation current density (Ji>0) is incident on the target 16 through the plasma sheath and accumulates thereon. Accordingly, after a negative applied voltage V_{G}− is applied, an absolute value of the voltage Vs of the target 16 decreases with time, and the absolute value of the voltage Vs of the target 16 becomes zero at the maximum time tmax.

In the matrix model, after a negative applied voltage V_{G}− is applied, an absolute value of the voltage Vs of the target 16 decreases with time, and the maximum time tmax at which the voltage Vs of the target 16 becomes zero is given as follows. The applied voltage is assumed to have a slope voltage (X=dV/dt) over time from a predetermined measured voltage value V₀.

$$( {V}_{G} + \frac{{d}_{1}}{{ϵ}_{1}} {ρ}_{i} ) = {v}_{0} + {Xt}_{max} + \frac{{d}_{1}}{{ϵ}_{1}} ( {ρ}_{i 0} + {J}_{i} {t}_{max} ) = 0 \qquad [ Equation 23 ]$$

$${t}_{max} = - \frac{{V}_{0} + \frac{{d}_{1}}{{ϵ}_{1}} {ρ}_{i 0}}{X + \frac{{d}_{1}}{{ϵ}_{1}} {J}_{i}}$$

Accordingly, the maximum time tmax depends on an initial negative charge ρᵢ₀ charged at a positive applied voltage V_{G}+, a capacitance per unit area (ε1/d1=c1) of the dielectric 17, a measured voltage V₀, the slope voltage X, and ion current density Ji.

Initial negative charges ρᵢ₀ and Qᵢ₀ charged at a positive applied voltage V_{G}+ is given as follows:

$$\frac{- {d}_{1}}{{ϵ}_{1}} {ρ}_{i 0} = {V}_{G}^{+} ; {V}_{G}^{+} > 0 ;$$

When the electron temperature Te is negligible, the maximum time tmax is represented as follows:

$${t}_{max} = - \frac{{V}_{0} - {V}_{G}^{+}}{X + \frac{{d}_{1}}{{ϵ}_{1}} {J}_{i}}$$

$${t}_{max} = - \frac{2 {V}_{0} {c}_{1}}{{J}_{i}} if X = 0 , {V}_{G}^{+} = - {V}_{0} > 0$$

where c₁ is a capacitance per unit area of the dielectric 17. When there is no slope voltage (X=dV/dt), the maximum time tmax is given as follows. When the maximum time tmax is measured at the measured voltage V₀, the ion current density Ji may be obtained.

$${t}_{max} = - \frac{2 {V}_{0} {c}_{1}}{{J}_{i}} if X = 0 , {V}_{G}^{+} = - {V}_{0} > 0 \qquad [ Equation 24 ]$$

$${J}_{i} = - \frac{2 {V}_{0} {c}_{1}}{{t}_{max}}$$

The current I_{G} flowing through the electrode 18 is given as follows. In the matrix model, the current I_{G} of the electrode 18 is given by a time derivative of the surface charge density ρ_{G} of the electrode 18, as follows. Here, A is an area of the electrode 18 and the target 16.

$${I}_{G} = \frac{d ( {ρ}_{G} A )}{dt} = - \frac{d [ {ρ}_{i} + {ρ}_{d} {d}_{2} ] A}{dt} \qquad [ Equation 25 ]$$

$${I}_{G} = \frac{{ϵ}_{1} A}{{d}_{1}} \frac{d}{d} ( {V}_{G} - {V}_{S} )$$

When a constant negative applied voltage V_{G}− is applied to the electrode 18, the current I_{G} flowing through the electrode 18 includes the ion current density Ji or ion current Ii and the electron current (Ie component) due to the electron temperature Te, and is given as follows:

$${ρ}_{i} = {ρ}_{i 0} + {J}_{i} t \qquad [ Equation 26 ]$$

$${I}_{G 0} = - {I}_{i} [ 1 - β ]$$

$$β ≡ \frac{1}{{C}_{1}} \frac{A \sqrt{2 {ϵ}_{2} {ρ}_{c i}}}{\sqrt{{( \frac{{d}_{1}}{{ϵ}_{1}} \sqrt{2 {ϵ}_{2} {ρ}_{d}} )}^{2} - 4 ( {V}_{G}^{-} + \frac{{d}_{1}}{{ϵ}_{1}} ( {ρ}_{io} + {J}_{i} t ) )}}$$

$${I}_{G} = - {I}_{i} [ 1 - β ] + {I}_{ei} {e}^{[ \frac{q ( {V}_{s} - {V}_{p} )}{{kT}_{e}} ]}$$

where Vp is a plasma potential, and Te is an electron temperature. C₁ is capacitance of the dielectric 17.

When the current I_{G} flowing through the electrode 18 due to the electron current Ie and the ion current Ii is zero, the current I_{G} of the electrode 18 is given as follows at a floating potential V_{f} of the target. Iei is an electron flux in a direction of the target. vₑ is an average velocity of electrons. u_{B} is the Bohm velocity.

$${I}_{G} = 0 = - {I}_{i} [ 1 - β ] + {I}_{ei} {e}^{[ \frac{q ( {V}_{f} - {V}_{p} )}{{kT}_{e}} ]}$$

$$( {V}_{f} - {V}_{p} ) \approx \frac{{kT}_{e}}{q} [ ln ( \frac{{I}_{i}}{{I}_{ei}} ) ] = \frac{{kT}_{e}}{q} [ ln ( 4 \times 0.61 \times \frac{{u}_{B}}{{v}_{e}} ) ] \approx - 4.0 \frac{{kT}_{e}}{q} if {V}_{p} = 0$$

Accordingly, the target 16 has a floating potential V_{f} in an equilibrium state in which the current I_{G} of the electrode is zero.

When an applied voltage is fixed to the electrode 18 and current (Ie component) generated by electrons flowing through the electrode 18 is included, the current I_{G} is presented as follows:

$${I}_{G} = \frac{{ϵ}_{1} A}{{d}_{1}} \frac{d}{d} ( {V}_{G} - {V}_{S} ) = - {C}_{1} \frac{{dV}_{s}}{dt} \qquad [ Equation 27 ]$$

$$- {C}_{1} \frac{{dV}_{s}}{dt} = - {I}_{i} [ 1 - β ] + {I}_{ei} {e}^{[ \frac{q ( {V}_{s} - {V}_{p} )}{{kT}_{e}} ]}$$

It is assumed that β has a constant value at the applied voltage. In this case, the potential Vs of the target 16 is given as follows:

$${C}_{1} \frac{{dV}_{s}}{dt} = {l}_{i} [ 1 - β ] - {I}_{ei} {e}^{[ \frac{q ( {V}_{s} - {V}_{p} )}{{kT}_{e}} ]} \qquad [ Equation 28 ]$$

$$x ≡ \frac{q ( {V}_{s} - {V}_{p} )}{{kT}_{e}}$$

$$\frac{dx}{dt} = \frac{{I}_{i}}{{C}_{1}} [ 1 - β ] \frac{q}{{kT}_{e}} - \frac{q}{{kT}_{e} {C}_{1}} {I}_{ei} {e}^{x}$$

$$γ ≡ \frac{{I}_{i}}{{C}_{1}} [ 1 - β ] \frac{q}{{kT}_{e}}$$

$$δ ≡ - \frac{q}{{kT}_{e} {C}_{1}} {I}_{ei}$$

$$\frac{dx}{dt} = γ + δ {e}^{x}$$

$$\int \frac{dx}{γ + δ {e}^{x}} = \int dt$$

$$\frac{x}{γ} - \frac{1}{γ} ln [ δ {e}^{x} + γ ] = t + C$$

$$x - ln [ δ {e}^{x} + γ ] = ( t + C ) γ$$

$$x \approx ( t + C ) γ$$

where C is an integration constant.

When a normalized potential χ of the target 16 has a negative value, an absolute value of the normalized potential χ of the target 16 represents a result of linearly decreasing with time t. Therefore, when the plasma potential Vp is zero, the time tmax at which the current I_{G} flowing through the electrode 18 becomes zero is given as follows:

$${t}_{max} = - \frac{{V}_{s 0} - {V}_{f}}{\frac{{I}_{i}}{{C}_{1}} [ 1 - β ]} \qquad [ Equation 29 ]$$

$${t}_{max} = - ( {V}_{s 0} - {V}_{f} ) \frac{{C}_{1}}{{I}_{G 0}}$$

An initial voltage Vso of the target 16 is given as follows:

$${V}_{s 0} = - {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( {V}_{G}^{-} - {V}_{G}^{+} )} ]}^{2}$$

Accordingly, the initial voltage Vso of the target 16 may be obtained when the maximum time tmax and the current I_{G0} flowing through the electrode 18 are measured. The charge density of the plasma may be obtained from the initial voltage of the target. Also, the initial voltage Vso of the target 16 may be obtained and the plasma density may be obtained when the maximum time tmax and the current I_{G0} flowing through the electrode 18 is measured and the floating potential V_{f} is measured or considered.

Also, the plasma charge density pa, electron temperature Te, floating potential V_{f}, and plasma potential Vp may be measured using a Langmuir probe. Conversely, when the plasma charge density ρ_{d} and the current I_{G0} flowing through the electrode 18 are known, the maximum time tmax may be obtained.

When the floating potential V_{f} is negligible, the maximum time tmax is given as follows:

$${t}_{max} = - \frac{2 {V}_{0} {c}_{1}}{{J}_{i}} if X = 0 , {V}_{G}^{+} = - {V}_{0} > 0$$

$${J}_{i} = - \frac{2 {V}_{0} {c}_{1}}{{t}_{max}}$$

When the floating potential V_{f} is considered, the maximum time tₘₐₓ is given as follows:

$${t}_{max} = - \frac{{V}_{s 0} - {V}_{f}}{\frac{{I}_{i}}{{C}_{1}} [ 1 - β ]} \qquad [ Equation 30 ]$$

When a negative applied voltage V_{G}− is applied to the electrode 18, current I_{G0} of the electrode 18 decreases the absolute value of the voltage Vs of the target 16 as the ion current density Ji charges the target 16, the current I_{G0} of the electrode has a nearly constant value I_{G0} over time, and the current I_{G0} of the electrode becomes zero when the potential Vs of the target reaches zero or floating potential.

The ion current density Ji is given by plasma charge density ρ_{d} and Bohm velocity us based on the Child-Langmuir model. Accordingly, when the ion current density Ji is determined, the plasma charge density ρ_{d} may be obtained. Here, k is a Boltzmann constant, and Te is an electron temperature.

$${J}_{i} = - \frac{2 {V}_{0} {c}_{1}}{{t}_{ma x}} = 0.61 {u}_{B} {ρ}_{d} \qquad [ Equation 31 ]$$

$${u}_{B} = \sqrt{\frac{k {T}_{e}}{M}}$$

$${ρ}_{d} = {J}_{i} / ( 0.61 {u}_{B} )$$

Also, a plasma sheath charged amount Qsh is given as a charge per unit area in the plasma sheath as, follows:

$${Q}_{s h} = \sqrt{2 {ϵ}_{2} {ρ}_{d} ( - {V}_{s} )} \qquad [ Equation 32 ]$$

In an equilibrium state while a positive applied voltage V_{G}+ is applied to the electrode 18, the plasma sheath charged amount Qsh is zero or (proximate to zero), and when the electrode suddenly transitions from a positive applied voltage V_{G}+ to a negative applied voltage V_{G}−, the plasma sheath charged amount Qsh depends on the voltage Vs of the target.

In an equilibrium state when a positive applied voltage V_{G}+ is applied to the electrode 18, the charges Qᵢ₀ and ρi of the target 16 have a negative value. When the electrode 18 suddenly transitions from a positive applied voltage V_{G}+ to a negative applied voltage V_{G}−, a charged amount Qᵢ₀ of the target 16 is maintained at the same value. When the charged amount Qᵢ of the target 16 changes due to the ion current density Ji while remaining at a negative applied voltage V_{G}−, the plasma sheath charged amount Qsh changes accordingly. The change in the charged amount Qᵢ of the target over time results from the ion current density Ji, and the change in the plasma sheath charged amount Qsh over time induces displacement current.

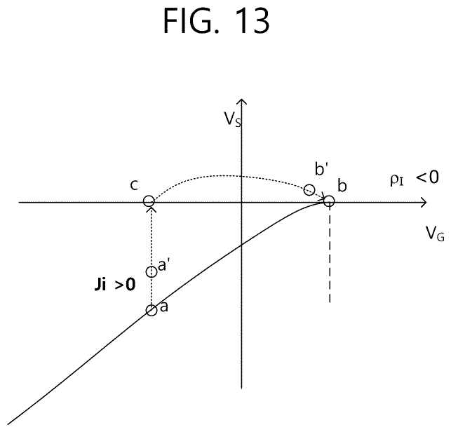

FIG. 13 is a graph illustrating a voltage of a target relative to an applied voltage.

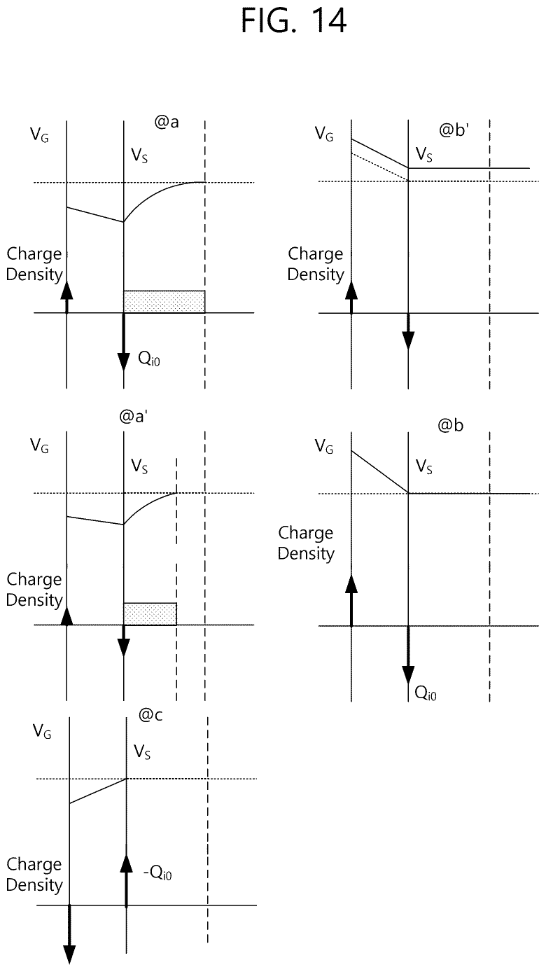

FIG. 14 is a graph illustrating charge density of each region.

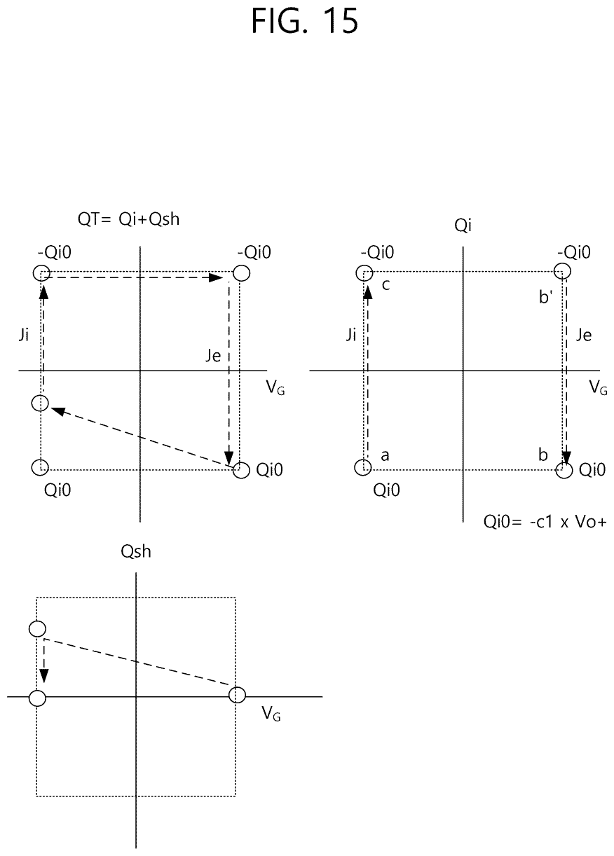

FIG. 15 is a graph illustrating a charged amount Qᵢ of the target 16, a charged amount of a plasma sheath Qsh, and a sum QT of Qᵢ and Qsh relative to an applied voltage V_{G} of an electrode.

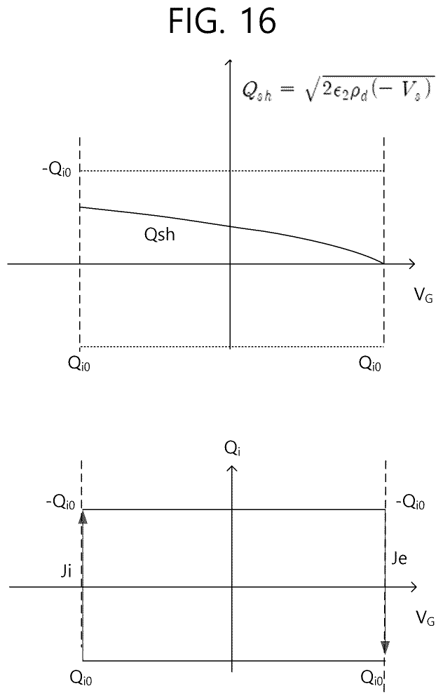

FIG. 16 is a graph illustrating a charged amount Qᵢ of the target and a plasma sheath charged amount Qsh based on an applied voltage of an electrode.

Referring to FIGS. 13 to 16, the plasma sheath charged amount Qsh gradually increases as an applied voltage of the electrode 18 decreases to a negative value. When a bipolar applied voltage is alternately applied with a small period, the bipolar applied voltage mainly operates at states of points a and b.

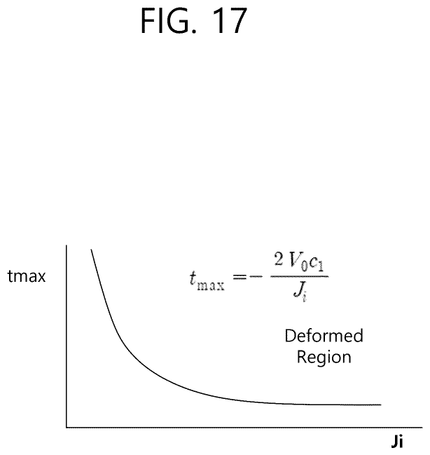

FIG. 17 is a graph illustrating a relationship between maximum time tmax and ion current density.

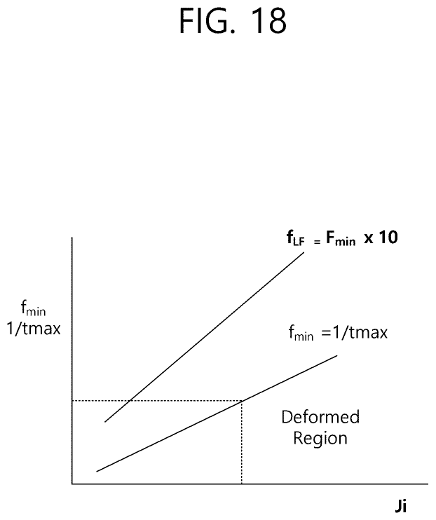

FIG. 18 is a graph illustrating an inverse of maximum time tmax relative to ion current density.

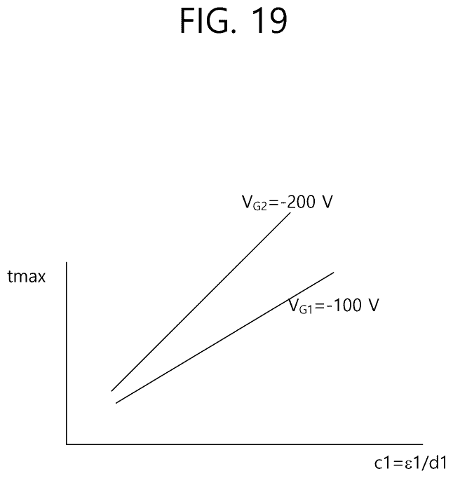

FIG. 19 is a diagram illustrating a relationship between maximum time tmax and capacitance per unit area.

Referring to FIGS. 17 to 19, the ion current density Ji and the maximum time tmax are in inverse proportion. Accordingly, the maximum time tmax decreases for high-density plasmas or large ion current densities Ji. When a time interval τ during which a negative applied voltage is applied is greater than the maximum time tmax, the voltage Vs of the target has a zero value, so that the voltage Vs of the target is severely distorted.

Therefore, the time interval τ during which a negative voltage is applied in a bipolar applied voltage waveform may be sufficiently smaller than the maximum time tmax. For example, the time interval τ during which a negative voltage is applied in the bipolar applied voltage waveform may be 1/10 of the maximum time tmax. A frequency f_{LF} of the bipolar applied voltage may be 10 times or more a reciprocal of the maximum time tmax.

$$\frac{( {d}_{1} / {ϵ}_{1} ) {J}_{i} τ}{2 {V}_{G}^{+}} < 0.1 \qquad [ Equation 33 ]$$

Also, the maximum time tmax may depend on a capacitance per unit area (c1=ε1/d1) of a dielectric. The maximum time tmax may depend on an applied voltage V_{G} of an electrode. Accordingly, the frequency f_{LF} of the bipolar applied voltage may be determined by the ion current density Ji, the capacitance per unit area (c1=ε1/d1) of the dielectric 17, and the applied voltage to significantly reduce the waveform distortion of the voltage Vs of the target.

In a discovery mode, the applied bipolar pulse voltage has a sufficiently low frequency to determine the maximum time tmax. In a drive mode, a driving frequency of the bipolar pulse is increased using the ion current density Ji, maximum time tmax, or current density J_{G0} obtained in the discovery mode to prevent the voltage Vs of the target from decreasing rapidly over time. Meanwhile, the bipolar pulse may be corrected to have a slope voltage X in the drive mode.

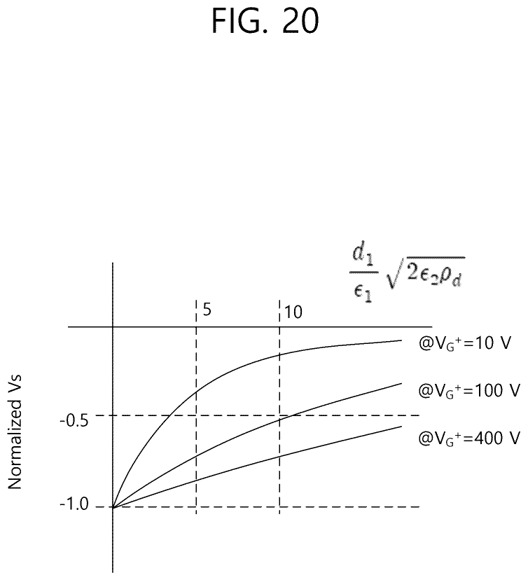

FIG. 20 is a normalized graph of a voltage Vs of a target relative to a positive applied voltage V_{G}+.

Referring to FIG. 20, the potential Vs of the target depends on.

$$\frac{{d}_{1}}{{ϵ}_{1}} \sqrt{2 {ϵ}_{2} {ρ}_{d}} .$$

For example, an absolute value of the voltage Vs of the target 16 may preferably have the following condition to have a value, similar to the applied voltage V_{G}+.

$$\frac{{d}_{1}}{{ϵ}_{1}} \sqrt{2 {ϵ}_{2} {ρ}_{d}} < 0.1 \qquad [ Equation 34 ]$$

$$\frac{{d}_{1}}{{ϵ}_{1}} \sqrt{2 {ϵ}_{2} {ρ}_{d}} < 1$$

$$\frac{{d}_{1}}{{ϵ}_{1}} \sqrt{2 {ϵ}_{2} {ρ}_{d}} < 5$$

Also, as the applied voltage V_{G}+ increases, the normalized voltage Vs of the target becomes less sensitive to

$$\frac{{d}_{1}}{{ϵ}_{1}} \sqrt{2 {ϵ}_{2} {ρ}_{d}} .$$

Therefore, when the applied voltage V_{G}+ is less than several tens of volts,

$$\frac{{d}_{1}}{{ϵ}_{1}} \sqrt{2 {ϵ}_{2} {ρ}_{d}}$$

may be preferably less than 5.

When the applied voltage V_{G}+ is several hundred volts or more,

$$\frac{{d}_{1}}{{ϵ}_{1}} \sqrt{2 {ϵ}_{2} {ρ}_{d}}$$

may be preferably less than 10.

When the applied voltage V_{G}+ is constant, an absolute value of the voltage Vs of the target decreases as the plasma density increases.

$$\frac{{d}_{1}}{{ϵ}_{1}} \sqrt{2 {ϵ}_{2} {ρ}_{d}}$$

may be 1 or less to use 90% of the absolute value of the voltage Vs of the target.

Also, when the applied voltage V_{G}+ is constant, the absolute value of the voltage Vs of the target 16 increases as the capacitance per unit area (c1=ε1/d1) of the dielectric 17 increases. Therefore, the capacitance per unit area of the dielectric 17 may be preferably as large as possible.

### [Matrix Model]

In the matrix model, the current I_{G} of the electrode 18 is given by the time derivative of the surface charge density ρ_{G} of the electrode 18, as follows. Here, A is an area of the target and electrode.

$${I}_{G} = \frac{d ( {ρ}_{G} A )}{dt} = - \frac{d [ {ρ}_{i} + {ρ}_{d} {d}_{2} ] A}{dt} \qquad [ Equation 35 ]$$

$${I}_{G} = \frac{{ϵ}_{1} A}{{d}_{1}} \frac{d}{d} ( {V}_{G} - {V}_{s} )$$

The voltage Vs of the target 16 is given as follows:

$${V}_{s} = - {( \frac{{d}_{1}}{{ϵ}_{1}} )}^{2} {ϵ}_{2} {ρ}_{d} + ( {V}_{G} + \frac{{d}_{1}}{{ϵ}_{1}} {ρ}_{i} ) + \frac{{d}_{1}}{2 {ϵ}_{1}} \sqrt{2 {ϵ}_{2} {ρ}_{d}} \sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )} \qquad [ Equation 36 ]$$

When the applied voltage V_{G} of the electrode 18 has a slope voltage (X=dV_{G}/dt), the time derivative of the potential Vs of the target 16 is given as follows:

$$X ≡ \frac{{dV}_{G}}{dt} ; {V}_{G} = {V}_{G 0} + Xt \qquad [ Equation 37 ]$$

$$\frac{d {V}_{s}}{dt} = ( X + \frac{{d}_{i} {I}_{i}}{{ϵ}_{1} A} ) [ 1 - \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} ]$$

The current I_{G} of the electrode 18 is given as follows. Here, C1 is the capacitance of the dielectric 17.

$${I}_{G} = {C}_{1} \frac{d}{d} ( {V}_{G} - {V}_{s} ) \qquad [ Equation 38 ]$$

$${I}_{G} = {C}_{1} X - {C}_{1} ( X + \frac{{d}_{1} {I}_{i}}{{ϵ}_{1} A} ) [ 1 - \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i}} )} ]$$

$${I}_{G} = {C}_{1} \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} X + {C}_{1} \frac{- {d}_{1} {I}_{i}}{{ϵ}_{1} A} [ 1 - \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} ]$$

$${I}_{G} = {C}_{1} βX - {I}_{i} [ 1 - β ]$$

$${C}_{1} β ≡ \frac{A \sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}}$$

The current I_{G} of the electrode 18 is given as follows:

$${I}_{G} = {C}_{1} β X + {I}_{G 0} \qquad [ Equation 39 ]$$

$$β ≡ \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}}$$

$${I}_{G 0} = - {I}_{i} ( 1 - β )$$

$${I}_{G} = {C}_{1} β X - {I}_{i} ( 1 - β )$$

$$- {I}_{i} = {C}_{1} β X - {I}_{i} ( 1 - β ) \to {I}_{i} = - {X}_{1} {C}_{1}$$

In a conventional range of applied voltage, p may be 0.4 to 0.01.

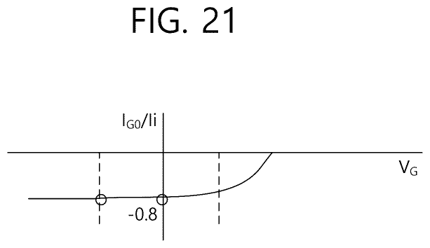

FIG. 21 is a graph illustrating current I_{G} flowing through an electrode relative to an applied voltage V_{G} of an electrode when there is no slope voltage (X=0).

Referring to FIG. 21, a ratio of the electrode current to the ion current (I_{G0}/Ii=β−1) has a constant negative value at a negative applied voltage and increases to zero as the applied voltage increases to a positive value.

Also, (1−β) may be a gain. For example, a derivative of the voltage Vs of the target with respect to the applied voltage V_{G} represents the gain. The gain is almost constant when the applied voltage V_{G} has a negative value. When the applied voltage V_{G} has a positive value, the gain may decrease.

$$\frac{{dV}_{s}}{{dV}_{G}} = 1 - [ \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} ] \qquad [ Equation 40 ]$$

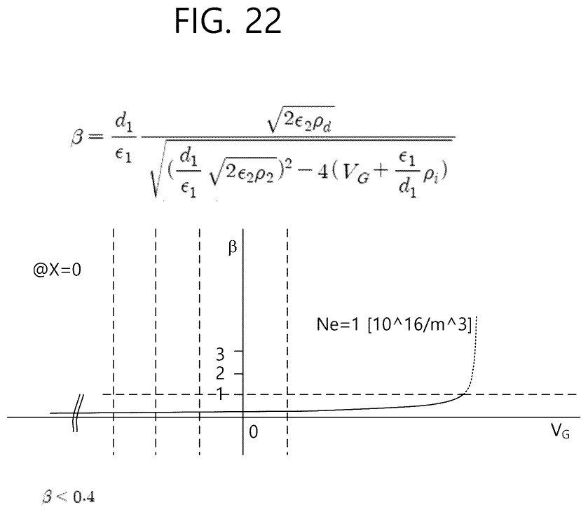

FIG. 22 is a graph illustrating β relative to the applied voltage of the electrode when there is no slope voltage (X=0).

Referring to FIG. 22, β≤0.4 at a negative applied voltage. Preferably, β≤0.2. β may be interpreted as a ratio of an effective capacitance to a capacitance of the dielectric.

Capacitance of a plasma sheath increases as plasma density increases at a negative voltage. Accordingly, β increases at a negative voltage as the plasma density increases.

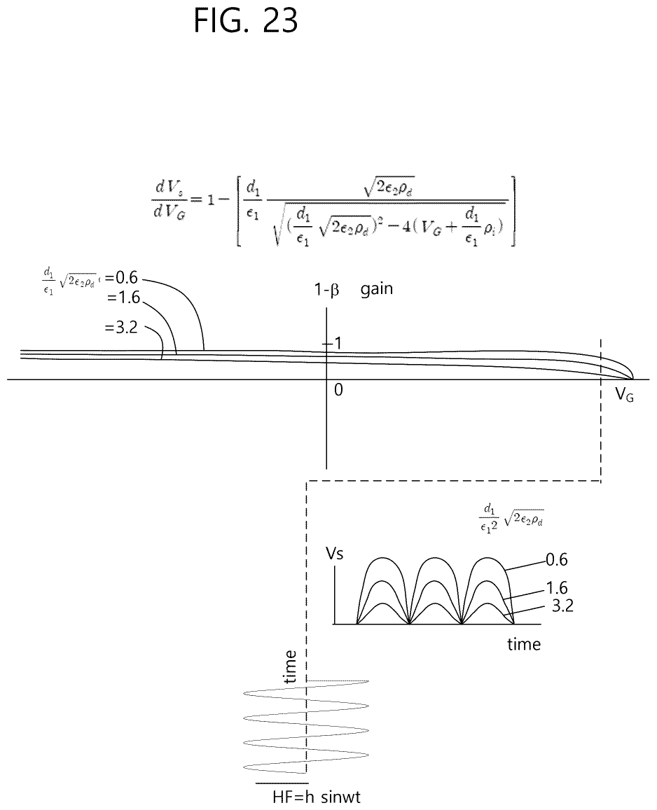

FIG. 23 is a graph illustrating a gain (1−β).

Referring to FIG. 23,

$$\frac{{d}_{1}}{{ϵ}_{1}} \sqrt{2 {ϵ}_{2} {ρ}_{d}} = 0.6 , 1.6 , 3.2 .$$

In this case, the gain (1−β) decrease at a positive applied voltage, and when a sine wave with a small amplitude is applied near a maximum applied voltage, a voltage of a target is severely distorted from the sine wave. Such waveform distortion may generate harmonics and adversely affect plasma. Therefore, when a bipolar pulse and a high-frequency sine wave (HF=h sin ωt) are applied together to the electrode 18, the high-frequency sine wave may have a low gain at a positive applied voltage and be severely distorted.

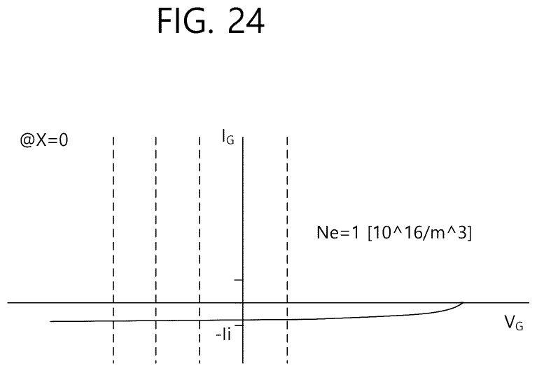

FIG. 24 is a graph illustrating current of an electrode based on an applied voltage of the electrode.

Referring to FIG. 24, when there is no slope voltage (X=0), an absolute value of current I_{G} of an electrode has a smaller value than an absolute value of ion current Ii at a negative applied voltage. A difference between the values may be significantly small.

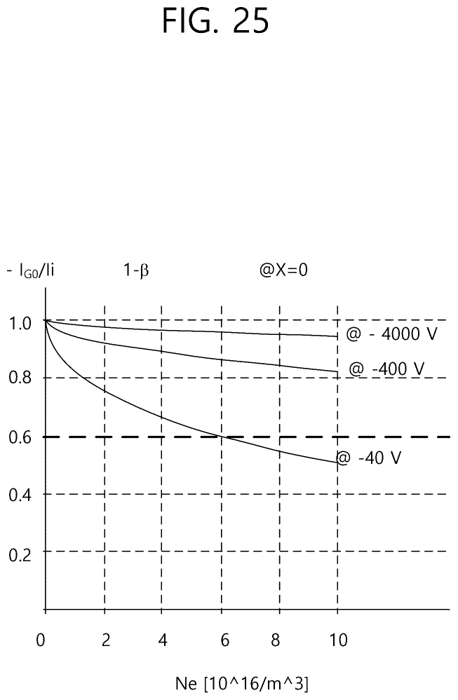

FIG. 25 is a diagram illustrating a ratio of an absolute value I_{G0}/Ii of an electrode current I_{G} to ion current Ii based on plasma density.

Referring to FIG. 25, the ratio (−IG0/Ii) approaches 1 as a negative applied voltage increases. Therefore, the ratio (−IG0/Ii) may approach 1 at a negative applied voltage of −several hundred volts. On the other hand, the ratio (−IG0/Ii) may decrease to less than 0.6. When the applied voltage is 40V, 80V is applied by the bipolar pulse, and when the plasma density Ne is 10\hat{ }17/m\hat{ }3, it has a value of about 0.5. On the other hand, when the applied voltage is 400V, 800V may be applied by the bipolar pulse, and when Ne is 10\hat{ }17/m\hat{ }3, it has a value of about 0.82. On the other hand, when the applied voltage is 4000V, 8000V is applied by the bipolar pulse, and when Ne is 10\hat{ }17/m\hat{ }3, it has a value of about 0.95.

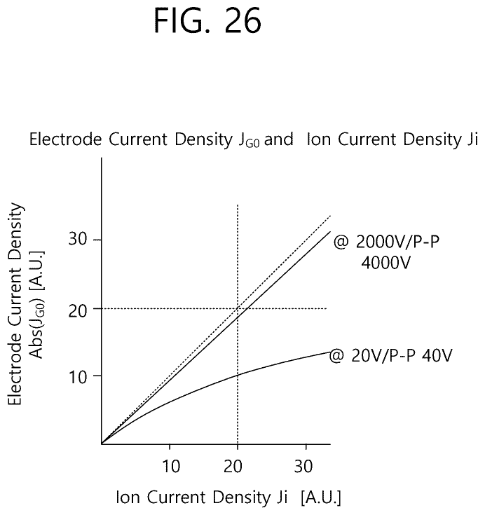

FIG. 26 is a diagram illustrating a relationship between current density J_{G0} flowing through an electrode and ion current density Ji.

Referring to FIG. 26, when there is no slope voltage (X=0), the current density J_{G0} flowing through an electrode 18 with respect to the ion current density Ji is given as follows:

$${I}_{G 0} = - {I}_{i} ( 1 - β ) \qquad [ Equation 41 ]$$

$$β = \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}}$$

$${J}_{G 0} = - {J}_{i} ( 1 - \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} )$$

$${J}_{i} = 0.61 {ρ}_{d} {u}_{B}$$

$${ρ}_{d} = \frac{{J}_{i}}{0.61 {u}_{B}}$$

$${J}_{G 0} = - {J}_{i} ( 1 - \frac{{d}_{1}}{{ϵ}_{1}} \frac{\sqrt{2 {ϵ}_{2} \frac{{J}_{i}}{0.61 {u}_{B}}}}{\sqrt{{( \frac{{d}_{1}}{{ϵ}_{1}} )}^{2} ( 2 {ϵ}_{2} \frac{{J}_{i}}{0.61 {u}_{B}} ) - 4 ( {V}_{G} + \frac{{d}_{1}}{{ϵ}_{1}} {ρ}_{i} )}} )$$

When the current density J_{G0} flowing through the electrode 18 is obtained, the ion current density Ji is given at a predetermined negative applied voltage V_{G}. When a peak-to-peak voltage 40V of a bipolar pulse is small, the current density J_{G0} exhibits a large difference from the ion current density Ji. On the other hand, when the peak-to-peak voltage 4000V of the bipolar pulse is large, the current density J_{G0} does not exhibit a difference from the ion current density Ji.

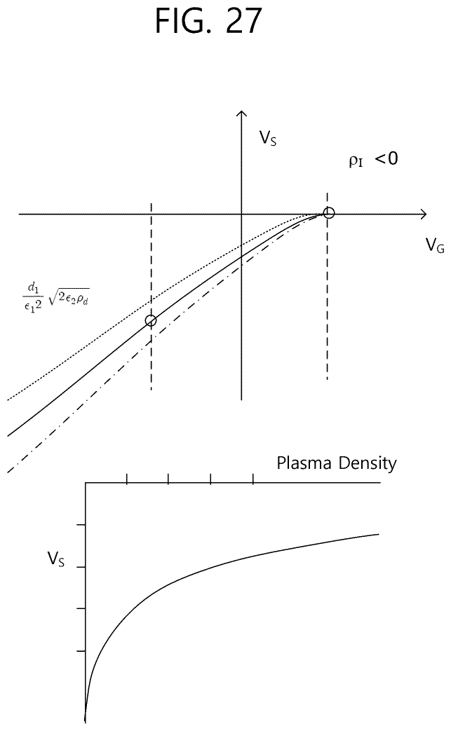

FIG. 27 is a graph illustrating a voltage of a target based on an applied voltage of an electrode.

Referring to FIG. 27, when plasma density increases for a given capacitance per unit area (ε1/d1) of a dielectric 17, an absolute value of a voltage Vs of a target 16 decreases. Accordingly, the plasma density may be maintained below a predetermined value to increase the absolute value of the voltage Vs of the target 16.

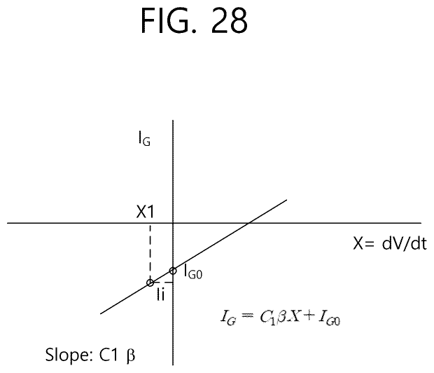

FIG. 28 is a diagram illustrating current I_{G} of an electrode relative to a slope voltage X.

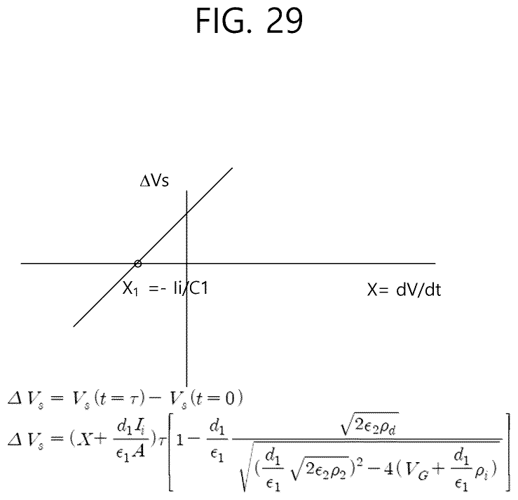

FIG. 29 is a diagram illustrating a variation ΔVs of a voltage of a target based on a slope voltage X.

Referring to FIGS. 28 and 29, current I_{G} of an electrode 18 based on a slope voltage X is given as follows:

$${ρ}_{i} = {ρ}_{i 0} + {J}_{i} t \qquad [ Equation 42 ]$$

$${V}_{G} = {V}_{G 0} + X t$$

where ρᵢ₀ is an initial value charged at a positive applied voltage. V_{G0} is an initial value of the negative applied voltage. τ is a time interval during which a negative applied voltage is applied. Also, when using the matrix model, a change in voltage ΔVs of the target 16 is given as follows:

$$Δ {V}_{s} = {V}_{s} ( t = τ ) - {V}_{s} ( t = 0 ) \qquad [ Equation 43 ]$$

$${V}_{s} ( t = τ ) = - {( \frac{{d}_{1}}{{ϵ}_{1}} )}^{2} {ϵ}_{2} {ρ}_{d} + ( {V}_{G 0} + X τ + \frac{{d}_{1}}{{ϵ}_{1}} ( {ρ}_{i 0} + {J}_{i} τ ) ) + \frac{{d}_{1}}{2 {ϵ}_{1}} \sqrt{2 {ϵ}_{2} {ρ}_{d}} \sqrt{{( \frac{{d}_{1}}{{ϵ}_{1}} \sqrt{2 {ϵ}_{2} {ρ}_{d}} )}^{2} - 4 ( {V}_{G 0} + X τ + \frac{{d}_{1}}{{ϵ}_{1}} ( {ρ}_{i 0} + {J}_{i} τ ) )}$$

$${V}_{s} ( t = 0 ) = - {( \frac{{d}_{1}}{{ϵ}_{1}} )}^{2} {ϵ}_{2} {ρ}_{d} + ( {V}_{G 0} + \frac{{d}_{1}}{{ϵ}_{1}} ( {ρ}_{i 0} ) ) + \frac{{d}_{1}}{2 {ϵ}_{1}} \sqrt{2 {ϵ}_{2} {ρ}_{d}} \sqrt{{( \frac{{d}_{1}}{{ϵ}_{1}} \sqrt{2 {ϵ}_{2} {ρ}_{d}} )}^{2} - 4 ( {V}_{G 0} + \frac{{d}_{1}}{{ϵ}_{1}} ( {ρ}_{i 0} ) )}$$

$$Δ {V}_{s} = ( X τ + \frac{{d}_{1}}{{ϵ}_{1}} ( {J}_{i} τ ) ) ) + \frac{{d}_{1}}{{ϵ}_{1} 2} \sqrt{2 {ϵ}_{2} {ρ}_{d}} \sqrt{{( \frac{{d}_{1}}{{ϵ}_{1}} \sqrt{2 {ϵ}_{2} {ρ}_{d}} )}^{2} - 4 ( {V}_{G 0} + X τ + \frac{{d}_{1}}{{ϵ}_{1}} ( {ρ}_{i 0} + {J}_{i} τ ) )} - \frac{{d}_{1}}{{ϵ}_{1} 2} \sqrt{2 {ϵ}_{2} {ρ}_{d}} \sqrt{{( \frac{{d}_{1}}{{ϵ}_{1}} \sqrt{2 {ϵ}_{2} {ρ}_{d}} )}^{2} - 4 ( {V}_{G 0} + \frac{{d}_{1}}{{ϵ}_{1}} {ρ}_{i 0} )}$$

$$Y ≡ \frac{{d}_{1}}{{ϵ}_{1} 2} \sqrt{2 {ϵ}_{2} {ρ}_{d}} \sqrt{{( \frac{{d}_{1}}{{ϵ}_{1}} \sqrt{2 {ϵ}_{2} {ρ}_{d}} )}^{2} - 4 ( {V}_{G 0} + \frac{{d}_{1}}{{ϵ}_{1}} {ρ}_{i 0} )}$$

$$Δ {V}_{s} = ( X τ + \frac{{d}_{1}}{{ϵ}_{1}} ( {J}_{i} τ ) ) + Y [ - 1 + \frac{\sqrt{{( \frac{{d}_{1}}{{ϵ}_{1}} \sqrt{2 {ϵ}_{2} {ρ}_{d}} )}^{2} - 4 ( {V}_{G 0} + X τ + \frac{{d}_{1}}{{ϵ}_{1}} ( {ρ}_{i 0} + {J}_{i} τ ) )}}{\sqrt{{( \frac{{d}_{1}}{{ϵ}_{1}} \sqrt{2 {ϵ}_{2} {ρ}_{d}} )}^{2} - 4 ( {V}_{G 0} + \frac{{d}_{1}}{{ϵ}_{1}} {ρ}_{i 0} )}} ]$$

$$Z ≡ {( \frac{{d}_{1}}{{ϵ}_{1}} \sqrt{2 {ϵ}_{2} {ρ}_{d}} )}^{2} - 4 ( {V}_{G 0} + \frac{{d}_{1}}{{ϵ}_{1}} {ρ}_{i 0} )$$

$$Δ {V}_{s} = ( X τ + \frac{{d}_{1}}{{ϵ}_{1}} ( {J}_{i} τ ) ) + Y [ - 1 + \sqrt{1 - 4 ( \frac{X τ + \frac{{d}_{1} {J}_{i} τ}{{ϵ}_{1}}}{Z} )} ]$$

$$Δ {V}_{s} \approx ( X τ + \frac{{d}_{1}}{{ϵ}_{1}} ( {J}_{i} τ ) ) + Y [ - 1 + 1 + \frac{1}{2} ( - 4 ) ( \frac{X τ + \frac{{d}_{1} {J}_{i} τ}{{ϵ}_{1}}}{Z} ) ]$$

$$Δ {V}_{s} \approx ( X τ + \frac{{d}_{1}}{{ϵ}_{1}} ( {J}_{i} τ ) ) - 2 Y \frac{X τ + \frac{{d}_{1}}{{ϵ}_{1}} ( {J}_{i} τ )}{Z}$$

$$Δ {V}_{s} \approx ( X τ + \frac{{d}_{1}}{{ϵ}_{1}} ( {J}_{i} τ ) ) [ 1 - 2 \frac{Y}{Z} ]$$

$$Δ {V}_{s} = ( X + \frac{{d}_{1} {I}_{i}}{{ϵ}_{1} A} ) τ [ 1 - \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G 0} + \frac{{d}_{1}}{{ϵ}_{1}} {ρ}_{i 0} )}} ]$$

$$Δ {V}_{s} = ( X + \frac{{d}_{1} {I}_{i}}{{ϵ}_{1} A} ) τ [ 1 - β ]$$

$$if Δ {V}_{s} = 0 , then {X}_{1} = - \frac{{I}_{i}}{{C}_{1}}$$

When the ion current Ii or ion current density Ji is known, the potential Vs of the target 16 may be obtained. Accordingly, when the ion current Ii or ion current density Ji is known, the slope voltage X1 regarding the change in voltage ΔVs of the target 16 as zero may be obtained.

When the slope voltage X is set to correspond to the current I_{G0} flowing through the electrode 18 in the case of absence of the slope voltage (X=0), it is given as follows:

$$X {C}_{1} = {I}_{G 0}$$

In this case, the change in voltage ΔVs of the target is given as follows:

$$Δ {V}_{s} = ( X + \frac{{I}_{i}}{{C}_{1}} ) τ [ 1 - β ] \qquad [ Equation 44 ]$$

$$Δ {V}_{s} = ( \frac{{I}_{G 0}}{{C}_{1}} + \frac{{I}_{i}}{{C}_{1}} ) τ [ 1 - β ]$$

$$Δ {V}_{s} = ( \frac{- {I}_{i}}{{C}_{1}} ( 1 - β ) + \frac{{I}_{i}}{{C}_{1}} ) τ [ 1 - β ]$$

$$Δ {V}_{s} = β ( \frac{{I}_{i}}{{C}_{1}} ) τ [ 1 - β ]$$

When the slope voltage X is set to correspond to the current I_{G0} flowing through the electrode 18 in the case of absence of the slope voltage (X=0), if the applied voltage V_{G} of the bipolar pulse is several hundred volts or more, p approaches zero. Therefore, the change in voltage ΔVs of the target 16 approaches zero.

### [Correcting Child-Langmuir Model to Matrix Model]

When the Child-Langmuir model is corrected with a correction factor α of the matrix model, a change in voltage ΔVs of the target 16 is given as follows:

$$Δ {V}_{s} = {V}_{s} ( t = τ ) - {V}_{s} ( t = 0 ) \qquad [ Equation 45 ]$$

$$Δ {V}_{s} = ( X + \frac{{d}_{1} {I}_{i}}{{ϵ}_{1} A} ) τ [ 1 - \frac{{d}_{1} α}{{ϵ}_{1}} \frac{\sqrt{2 {ϵ}_{2} {ρ}_{d}}}{\sqrt{{( \frac{{d}_{1} α}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} ]$$

Accordingly, when the correction is performed using the Child-Langmuir model, the change in voltage ΔVs of the target 16 increases more compared to the matrix model.

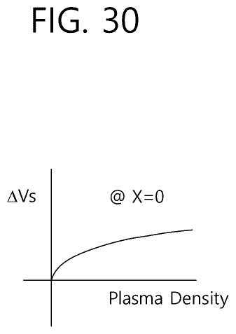

FIG. 30 is a diagram illustrating a variation ΔVs of a voltage of a target based on plasma density.

Referring to FIG. 30, when there is no slope voltage (X=0), high-density plasma has a smaller change in voltage ΔVs of the target compared to a low-density plasma. The voltage Vs of the target 16 may represent an ion energy distribution function.

### [Calculation of Plasma Density or Plasma Charge Density]

β and β′ are defined as follows:

$$β ≡ \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} \qquad [ Equation 46 ]$$

$${β}^{′} ≡ \frac{{C}_{1} β}{A} = \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}}$$

The plasma charge density ρ_{d} is given in the matrix model as follows:

$${ρ}_{d} = \frac{4 {β}^{′2} ( {V}_{G}^{-} + \frac{{d}_{1}}{{ϵ}_{1}} {ρ}_{i} )}{2 {ϵ}_{2} [ {{β}^{′2} ( \frac{{d}_{1}}{{ϵ}_{1}} )}^{2} - 1 ]} \qquad [ Equation 47 ]$$

$${ρ}_{i} = - {C}_{1} {V}_{G}^{+}$$

### [Correction of C-L Model Using Matrix Model: Correction Factor α]

When a correction is performed with the correction factor α, the current of the electrode I_{G} is given as follows:

$${I}_{G} = {C}_{1} \frac{d}{d} ( {V}_{0} - {V}_{s} ) \qquad [ Equation 48 ]$$

$${I}_{G} = {C}_{1} X - {C}_{1} ( X + \frac{{d}_{1} {I}_{i}}{{ϵ}_{1} A} ) [ 1 - \frac{{d}_{1} α}{{ϵ}_{1}} \frac{\sqrt{2 {ϵ}_{2} {ρ}_{d}}}{\sqrt{{( \frac{{d}_{1} α}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} ]$$

$${I}_{G} = {C}_{1} \frac{{d}_{1} α}{{ϵ}_{1}} \frac{\sqrt{2 {ϵ}_{2} {ρ}_{d}}}{\sqrt{{( \frac{{d}_{1} α}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} X + {C}_{1} \frac{- {d}_{1} {I}_{i}}{{ϵ}_{1} A} [ 1 - \frac{{d}_{1} α}{{ϵ}_{1}} \frac{\sqrt{2 {ϵ}_{2} {ρ}_{d}}}{\sqrt{{( \frac{{d}_{1} α}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} ]$$

$${I}_{G} = α {C}_{2} X - {I}_{i} [ 1 - \frac{{C}_{2} α}{{C}_{1}} ]$$

$${C}_{2} ≡ \frac{A \sqrt{2 {ϵ}_{2} {ρ}_{d}}}{\sqrt{{( \frac{{d}_{1} α}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}}$$

The correction factor α may be 0.3 to 0.5. The correction factor α may be around 0.4 at several tens of volts and 0.3 at several hundred volts.

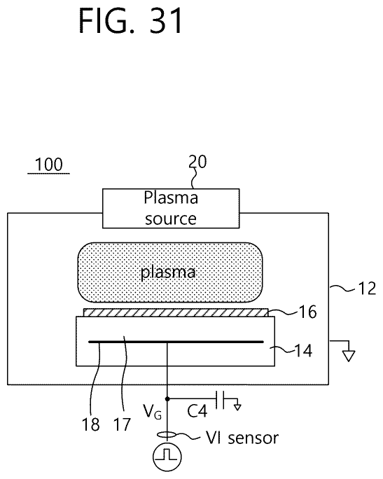

FIG. 31 is a conceptual diagram illustrating a plasma system according to an example embodiment of the present disclosure.

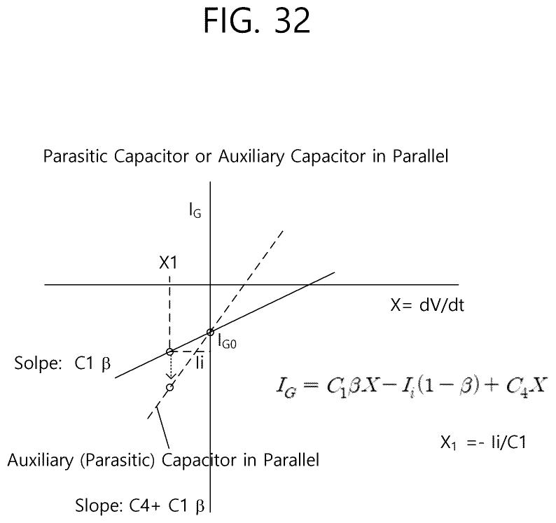

FIG. 32 is a graph illustrating current of an electrode relative to a slope voltage when an auxiliary capacitor C4 is present.

Referring to FIGS. 31 and 32, the electrode is connected to the ground through an auxiliary capacitor C4. The auxiliary capacitor C4 may be a parasitic capacitor.

When a parasitic capacitance or an auxiliary capacitor C4 is connected in parallel to the electrode, current I_{G} flowing through the electrode 18 is given as follows:

### [Matrix Model]

$${I}_{G} = {C}_{1} β X - {I}_{i} ( 1 - β ) + {C}_{4} X \qquad [ Equation 49 ]$$

$${I}_{G} - ( {C}_{4} + {C}_{1} ) X = {C}_{1} β X - {C}_{1} X - {I}_{i} ( 1 - β )$$

$${I}_{G} - ( {C}_{4} + {C}_{1} ) X = ( β - 1 ) {C}_{1} X - {I}_{i} ( 1 - β )$$

$${I}_{G} - ( {C}_{4} + {C}_{1} ) X = - ( 1 - β ) [ {C}_{1} X + {I}_{i} ]$$

$${I}_{G} - ( {C}_{4} + {C}_{1} ) {X}_{1} = - ( 1 - β ) [ {C}_{1} {X}_{1} + {I}_{i} ] = 0$$

A slope of the electrode current I_{G} increases due to the auxiliary capacitor C4. When X1C₁=−Iᵢ, the ion current Ii may be obtained. When an auxiliary capacitor C4 is present, the slope of the electrode current I_{G} depends on the auxiliary capacitor C4.

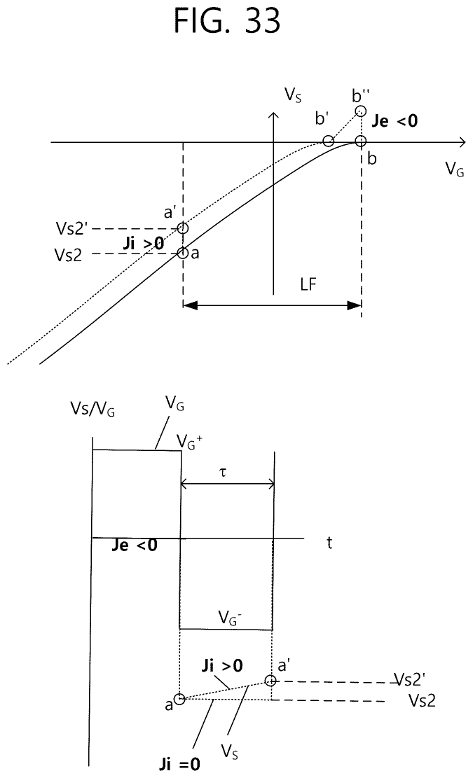

FIG. 33 is a graph illustrating a voltage of a target relative to a low-frequency applied voltage of an electrode according to an example embodiment of the present disclosure.

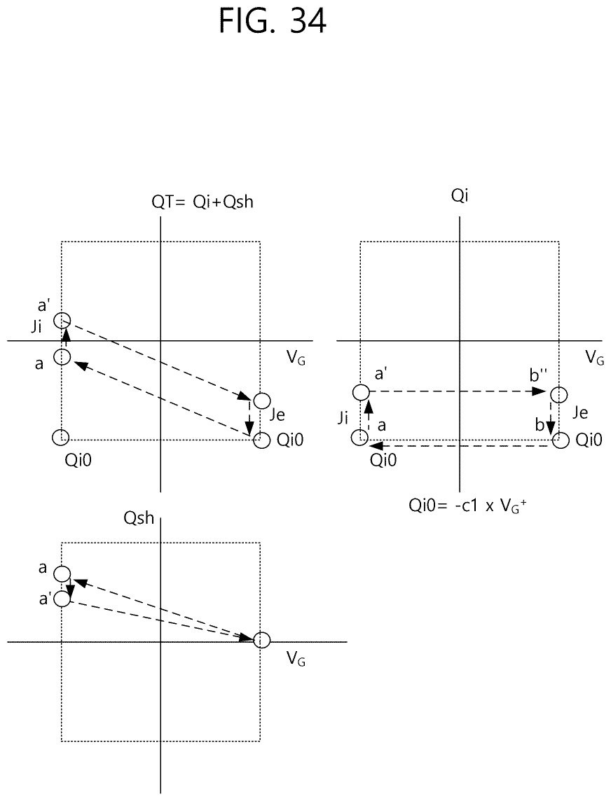

FIG. 34 is a graph illustrating a charged amount Qi of a target relative to an applied voltage of an electrode according to an example embodiment of the present disclosure.

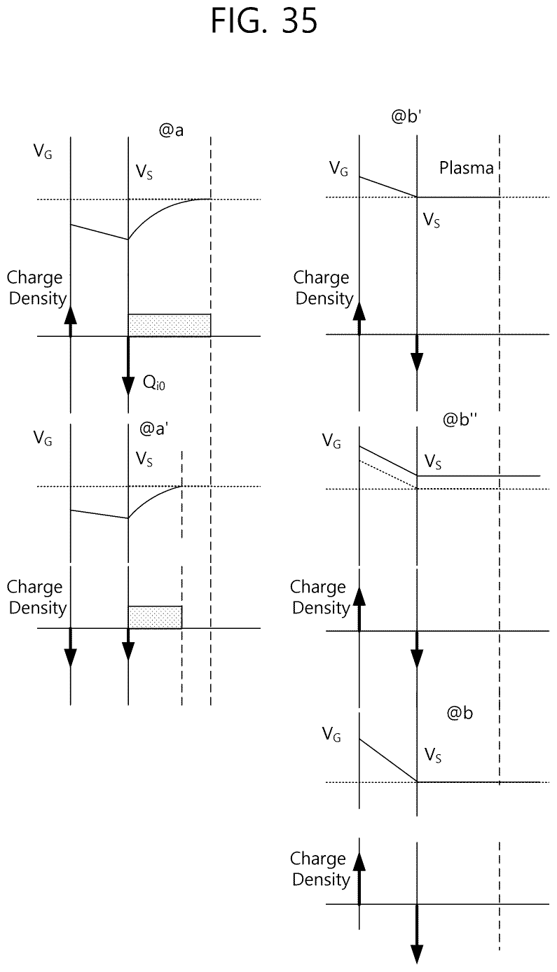

FIG. 35 is a graph illustrating the charged amount and potential relative to the applied voltage of the electrode according to an example embodiment of the present disclosure.

Referring to FIGS. 33 to 35, a period of the applied voltage V_{G} is sufficiently smaller than maximum time tmax. When ion current density Ji is incident through a plasma sheath at a negative applied voltage V_{G}−, an absolute value of a potential Vs of a target 16 decreases. For example, the absolute value changes from point a to point a′. Accordingly, the ion energy distribution has a broadened linewidth. A duration τ of the negative applied voltage V_{G}− is sufficiently smaller than the maximum time tmax. For example, the duration τ may be 1/10 or less of the maximum time tmax. The maximum time tmax may be several tens of microseconds to several tens of milliseconds (usec). The duration τ may be several usec to several hundred usec.

$$τ < 0.1 {t}_{m ax} \qquad [ Equation 50 ]$$

When the applied voltage changes rapidly from a negative value V_{G}− to a positive value V_{G}+, a charged amount Qi of the target 16 remains the same, and a charged amount Qsh of the plasma sheath decreases to zero. Also, at points b′ and b″, the electron current density Je rapidly flows into the target, and the target 16 is charged with a negative value.

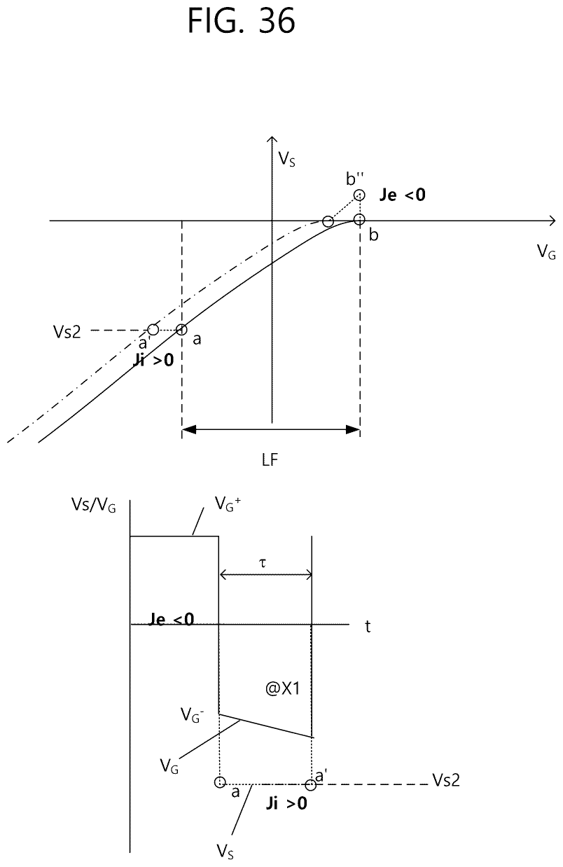

FIG. 36 is a diagram illustrating a potential of a target for driving a low-frequency pulse slope voltage.

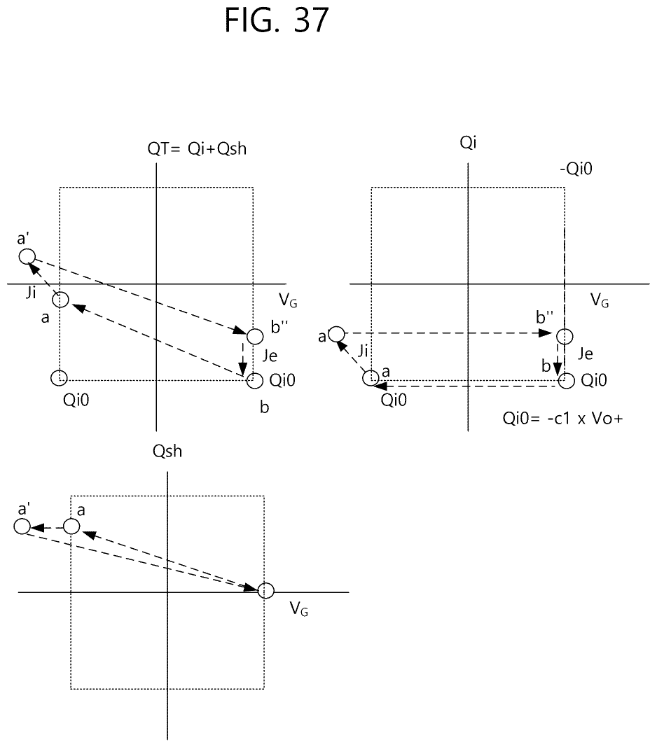

FIG. 37 is a diagram illustrating a charged amount of a target and a charged amount of a plasma sheath for driving a low-frequency pulse slope voltage.

Referring to FIGS. 36 and 37, a period of an applied voltage is sufficiently smaller than maximum time tmax. When ion current density Ji is incident through a plasma sheath at a negative applied voltage, an absolute value of a potential Vs of a target 16 decreases. However, when a slope voltage X1 is present at a negative applied voltage, the voltage Vs of the target 16 may be maintained to be constant. For example, the absolute value changes from point a to point a′. The charge Qsh of the plasma sheath may be maintained to be constant in a slope voltage region. In the slope voltage region, the absolute value of the charge Qi of the target 16 decreases as the ion current density Ji is incident.

When an applied voltage of an electrode 18 suddenly transitions from a negative value V_{G}− to a positive value V_{G}+, the charge d amount Qi of the target is maintained, and the charged amount of the plasma sheath decreases to zero. Also, the electron current is incident from the plasma to the target, and the charged amount of the target reaches a negative value.

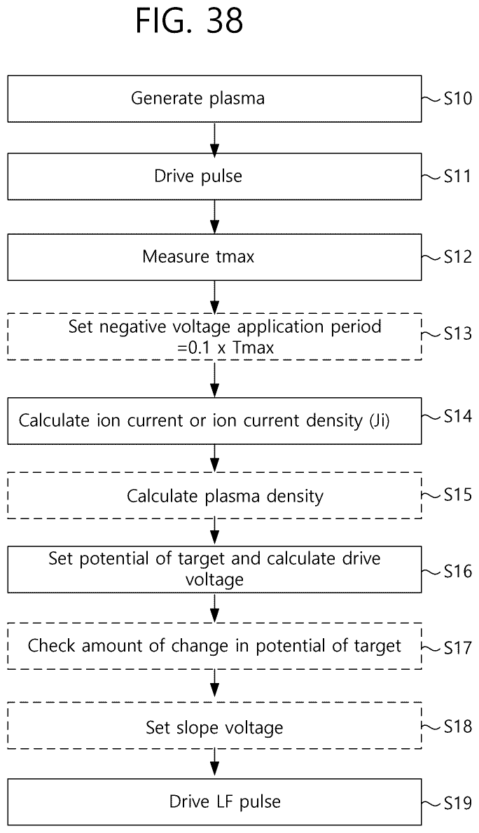

FIG. 38 is a flowchart illustrating an operation method for driving a low-frequency pulse.

Referring to FIG. 38, plasma is generated (S10). Then, a bipolar pulse voltage is applied to an electrode 18 (S11). A negative pulse period is set to be sufficiently large to measure the maximum time tmax at which the current flowing through the electrode becomes zero (S12). Ion current density is calculated using a relationship between the maximum time tmax and the ion current density Ji (S14). The time during which a negative voltage is applied at the driving voltage is set to be sufficiently smaller than the maximum time tmax (S13). Plasma charge density ρ_{d} is calculated using the ion current density Ji. A voltage Vs of the target is set (S16). The voltage Vs of the target determines ion energy. A driving voltage waveform corresponding to the voltage Vs of the target is determined (S16). A change in voltage ΔVs of the target 16, caused by the ion current density Ji, is checked (S17). A slope voltage X is determined to correct the change in voltage ΔVs of the target caused by the ion current density Ji (S18). The low-frequency pulse waveform is driven (S19).

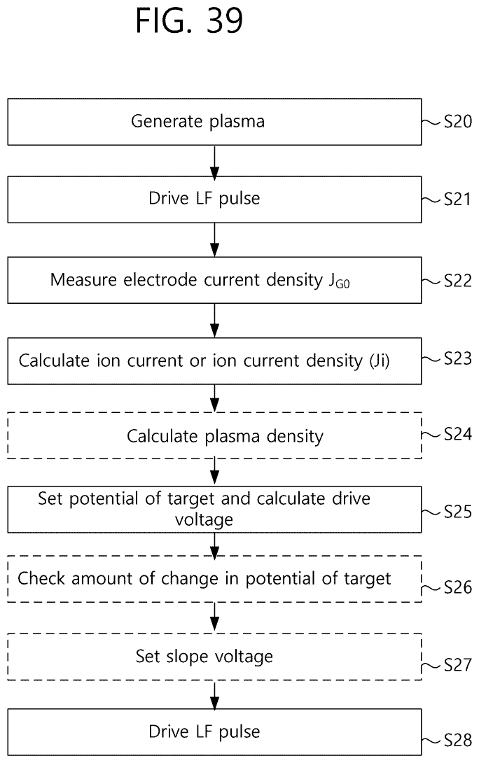

FIG. 39 is a flowchart illustrating an operation method for driving a low-frequency pulse.

Referring to FIG. 39, plasma is generated (S20). Then, a bipolar low-frequency pulse voltage is applied to an electrode (S21). Current I_{G0} flowing through the electrode 18 is measured in a negative pulse period. The ion current density Ji is calculated using a relationship between the current I_{G0} of the electrode 18 and the ion current density Ji (S23). Time τ during which a negative voltage is applied at a driving voltage is set to be sufficiently smaller than the maximum time tmax determined by the ion current density Ji. Plasma charge density ρ_{d} is calculated using the ion current density Ji (S24). The voltage Vs of the target is set (S25). The voltage Vs of the target determines the ion energy. A driving voltage waveform corresponding to the voltage Vs of the target is determined (S25). A change in voltage ΔVs of the target 16, caused by the ion current density Ji, is checked (S26). A slope voltage X is determined to correct the change in voltage Vs of the target caused by the ion current density Ji (S27). A low-frequency pulse waveform is driven (S28).

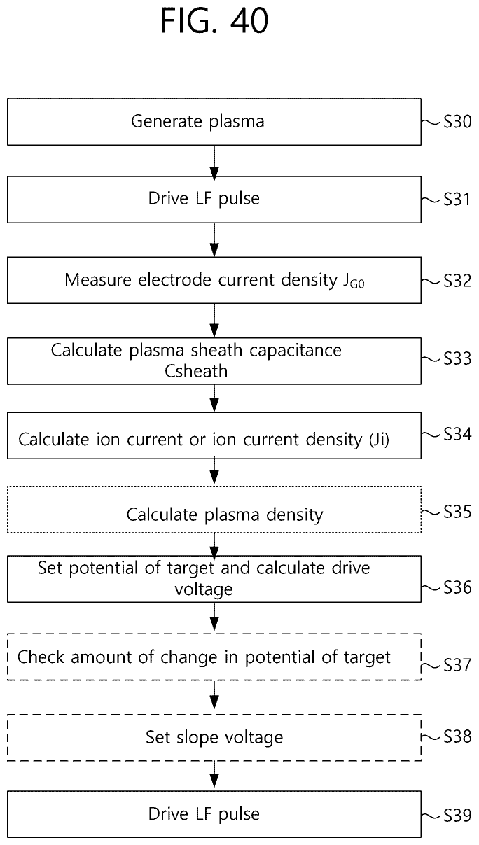

FIG. 40 is a flowchart illustrating an operation method for driving a low-frequency pulse.

Referring to FIG. 40, plasma is generated (S30). Then, a bipolar low-frequency pulse voltage is applied to an electrode 18 (S31). Current I_{G0} flowing through the electrode 18 is measured in a negative pulse period. Ion current density Ji is calculated using a relationship between the current I_{G0} of the electrode and capacitance Csheath of a plasma sheath (S34). The capacitance Csheath of the plasma sheath may be measured directly or calculated using plasma charge density ρ_{d}. Time τ during which a negative voltage is applied at a driving voltage is set to be sufficiently smaller than maximum time tmax determined by the ion current density Ji. The plasma charge density ρ_{d} is calculated using the ion current density Ji (S35). A voltage Vs of the target is set (S36). The voltage Vs of the target determines ion energy. A driving voltage waveform corresponding to the voltage Vs of the target is determined (S36). A change in voltage ΔVs of the target 16, caused by the ion current density Ji, is checked (S37). A slope voltage X is determined to correct the change in voltage ΔVs of the target caused by the ion current density Ji (S38). A low-frequency pulse waveform is driven (S39).

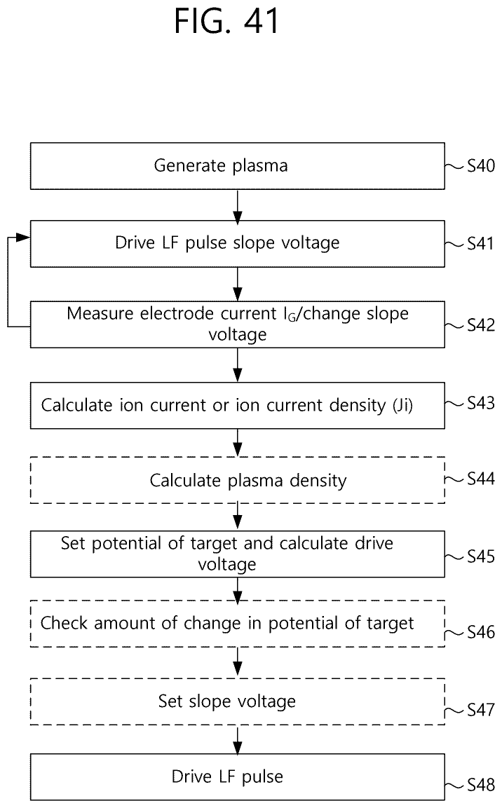

FIG. 41 is a flowchart illustrating an operation method for driving a low-frequency pulse.

Referring to FIG. 41, plasma is generated (S40). Then, a bipolar low-frequency pulse voltage is applied to an electrode 16 (S41). A driving voltage with a slope voltage is applied in a negative pulse period, and current I_{G} flowing through the electrode is measured (S42). A slope voltage X is changed, and a driving voltage with a slope voltage X is applied in the negative pulse period, and the current I_{G} flowing through the electrode is measured. Capacitance Csheath of a plasma sheath is calculated using a relationship between the current I_{G} of the electrode 16 and the slope voltage X. When the slope voltage X is zero, ion current density Ji is calculated using a relationship between the current I_{G0} flowing through the electrode and the capacitance Csheath of the plasma sheath (S43). Time r during which a negative voltage is applied at the driving voltage is set to be sufficiently smaller than maximum time tmax determined by the ion current density Ji. Plasma charge density ρ_{d} is calculated using the ion current density Ji (S44). A voltage Vs of the target is set (S45). The voltage Vs of the target determines ion energy. A driving voltage waveform corresponding to the voltage Vs of the target is determined (S45). A change in voltage ΔVs of the target 16, caused by the ion current density Ji, is checked. The slope voltage X is determined to correct the change in voltage ΔVs of the target caused by the ion current density Ji (S47). A low-frequency pulse waveform is driven (S48).

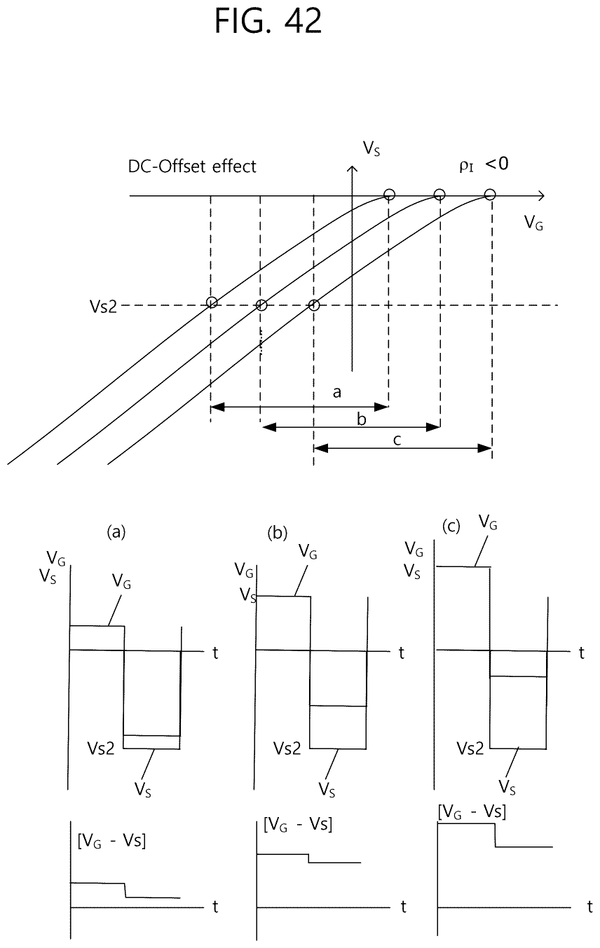

FIG. 42 is a diagram illustrating a voltage of a target based on driving of a low-frequency pulse voltage.

Referring to FIG. 42, a low-frequency pulse voltage may have three forms for the same peak-to-peak value. The three cases include a case in which the magnitude of a positive voltage is smaller than the magnitude of a negative voltage, a case in which the magnitude of a positive voltage is equal to the magnitude of a negative voltage, and a case in which the magnitude of a positive voltage is larger than the magnitude of a negative voltage. In all of the three cases, the potential Vs of the target 16 is the same in a negative voltage region. In all of the three cases, the charged amount Qi and ρi of the target 16 is different at a positive applied voltage V_{G}+. A voltage difference (V_{G}−Vs) applied to the dielectric 17 is different at the positive applied voltage V_{G}+. When the magnitude of the positive voltage is larger than the magnitude of the negative voltage, a large voltage may be applied to the dielectric 17, so that electrostatic force may increase but dielectric breakdown is likely to occur.

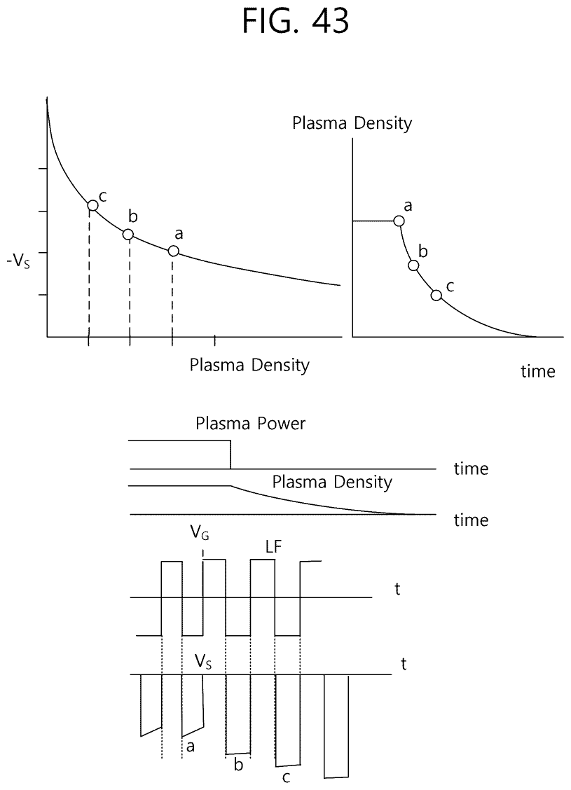

FIG. 43 is a diagram illustrating a potential of a target relative to a plasma density.

Referring to FIG. 43, an absolute value of a voltage Vs of a target decreases as plasma density increases. For example, when plasma power decreases suddenly, the plasma density decreases over time. In this case, when a bipolar pulse voltage is applied to the electrode 18, the absolute value of the voltage Vs of the target increases. Therefore, the plasma power or plasma density may be modulated over time to increase the absolute value of the voltage Vs of the target.

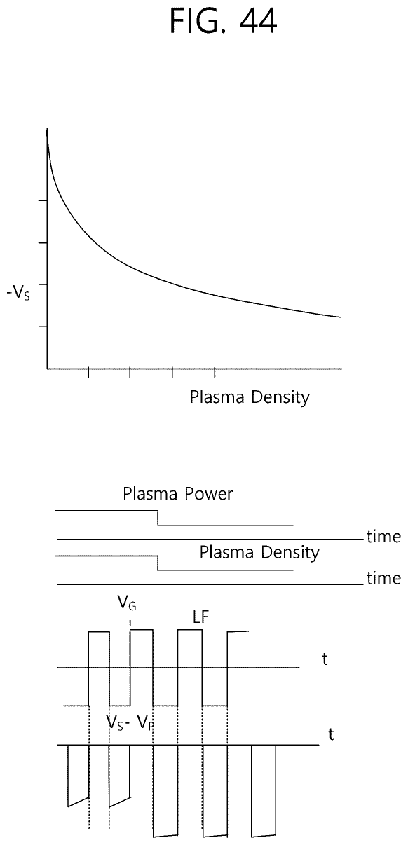

FIG. 44 is a graph illustrating the potential of the target relative to the plasma density.

Referring to FIG. 44, an absolute value of a potential Vs of a target decreases as plasma density increases. For example, when plasma power is reduced at a certain point, plasma density decreases. In this case, when a bipolar pulse voltage is applied to an electrode 16, the absolute value of the voltage Vs of the target increases. Accordingly, the plasma power or plasma density may be modulated over time to increase or decrease the absolute value of the voltage Vs of the target.

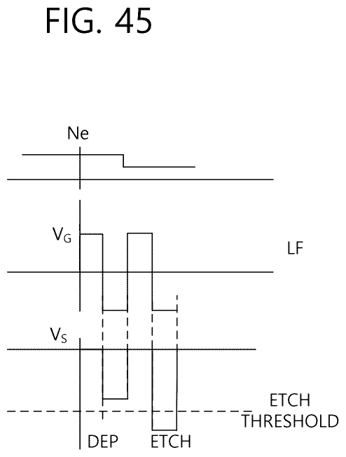

FIG. 45 is a diagram illustrating a potential of a target relative to plasma density.

Referring to FIG. 45, an absolute value of a voltage Vs of a target decreases as plasma density increases. For example, when plasma power is reduced at a certain point, the plasma density decreases. In this case, when a bipolar pulse voltage is applied to an electrode 18, the absolute value of a potential Vs of the target increases. Accordingly, the absolute value of the potential Vs of the target may be increased to be larger than or equal to an etching threshold. For example, when the plasma density is high, a material may be deposited on a surface of the target 16; and when plasma density is low, a material may be etched from the surface of the target 16. The etching threshold varies depending on the material but may be between tens and hundreds of volts.

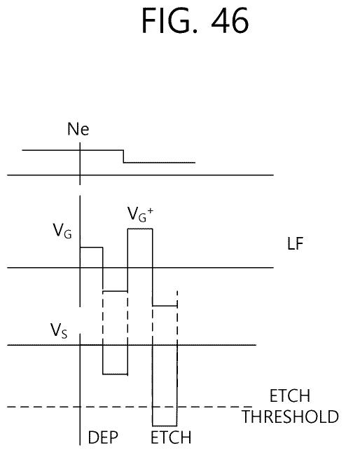

FIG. 46 is a graph illustrating a potential of a target relative to plasma density.

Referring to FIG. 46, an absolute value of a potential Vs of a target decreases as plasma density increases. For example, when plasma power is reduced at a certain point, the plasma density decreases. In this case, when a bipolar pulse voltage is applied to an electrode, the absolute value of a potential of the target increases. Accordingly, the absolute value of the voltage Vs of the target may be increased to be larger than or equal to an etching threshold. For example, when the plasma density is high, a positive applied voltage of a bipolar pulse may be reduced to deposit a material on a surface of the target 16; and when the plasma density is low, an applied voltage V_{G} of the bipolar pulse may be increased to etch a material from the surface of the target 16. The etching threshold may vary depending on the material, but may be between tens and hundreds of volts.

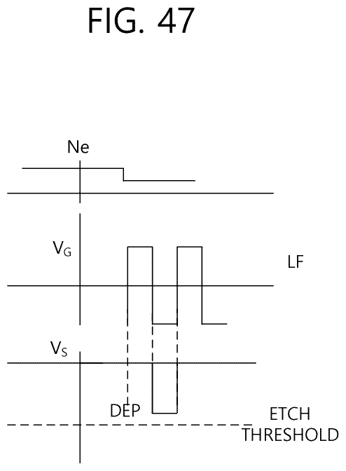

FIG. 47 is a diagram illustrating a potential of a target relative to plasma density.

Referring to FIG. 47, an absolute value of a potential of a target decreases as plasma density increases. For example, when plasma power is reduced at a certain point, plasma density decreases. In this case, when a bipolar pulse voltage is applied to an electrode, the absolute value of the potential of the target increases. Accordingly, the absolute value of the potential Vs of the target Vs may be maintained to be smaller than or equal to an etching threshold. For example, when the plasma density is high, an applied voltage of a bipolar pulse may be reduced to deposit a material on a surface of the target; and when the plasma density is low, the applied voltage of the bipolar pulse may be increased to transfer ion energy lower than or equal to the etching threshold to the surface material of the target. As a result, a deposition temperature may be reduced.

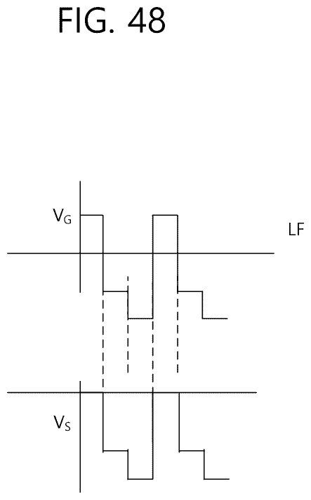

FIG. 48 is a diagram illustrating a potential of a target relative to a drive voltage waveform of an electrode.

Referring to FIG. 48, when a driving voltage waveform of an electrode 18 has a staircase shape in a negative voltage region, a potential of a target may have a corresponding staircase shape.

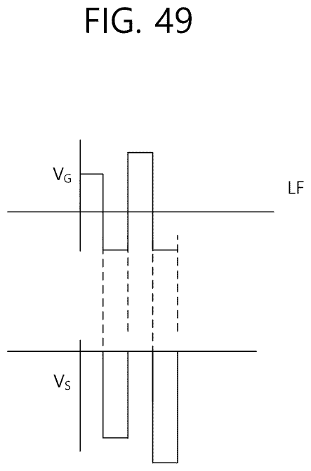

FIG. 49 is a diagram illustrating a potential of a target relative to a drive voltage waveform of an electrode.

Referring to FIG. 49, when a driving voltage waveform of an electrode 18 has the same height in a negative voltage region but different heights in a positive voltage region, a potential of a target may have different values depending on a height of the positive voltage region.

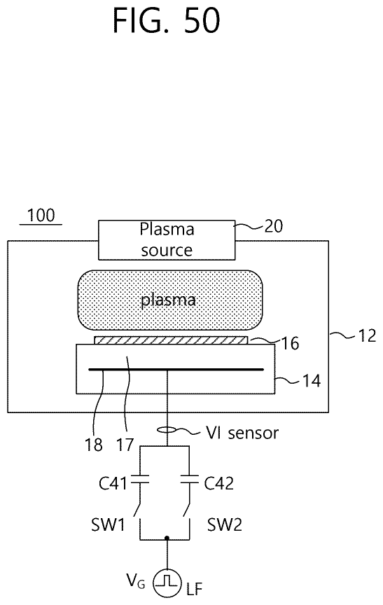

FIG. 50 is a conceptual diagram illustrating a plasma apparatus including a capacitor connected to an electrode.

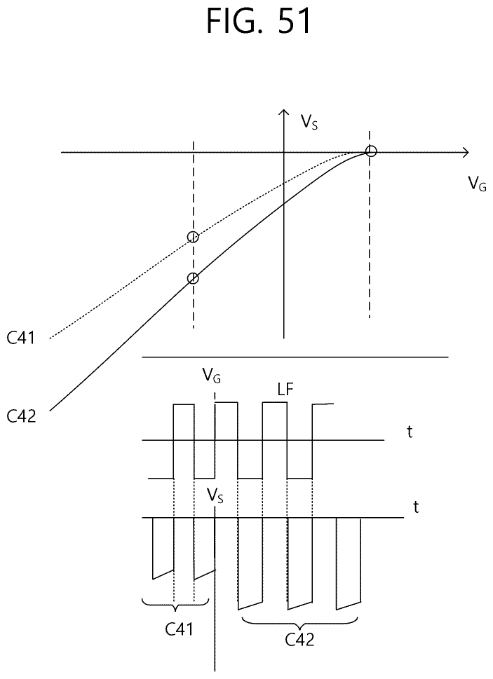

FIG. 51 is a diagram illustrating a potential of a target based on capacitance of a capacitor connected to the electrode of FIG. 50.

Referring to FIGS. 50 and 51, a plasma system 100 includes a chamber 12, a plasma source 20 generating plasma within the chamber 12, and a target holder 14 mounting a target 16.

A first capacitor C41 is connected in parallel to a second capacitor C42 through a first switch SW1 and a second switch SW2, respectively, between an electrode 18 and a low-frequency pulse power supply LF. The first switch SW1 and the second switch SW2 operate, allowing only one of the first capacitor C41 and the second capacitor C42 to operate. Accordingly, when the driving voltage applied to the electrode 18 is the same, a potential of a target Vs varies depending on first capacitance of the first capacitor C41 and second capacitance of the second capacitor C42.

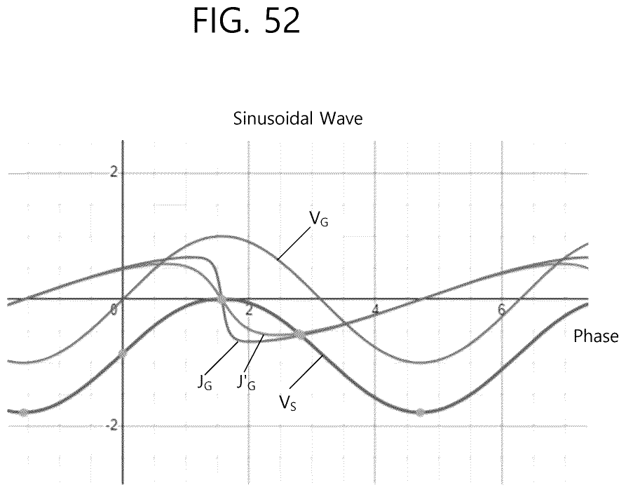

FIG. 52 is a diagram illustrating a potential of a target and current flowing through an electrode at a sinusoidal applied voltage.

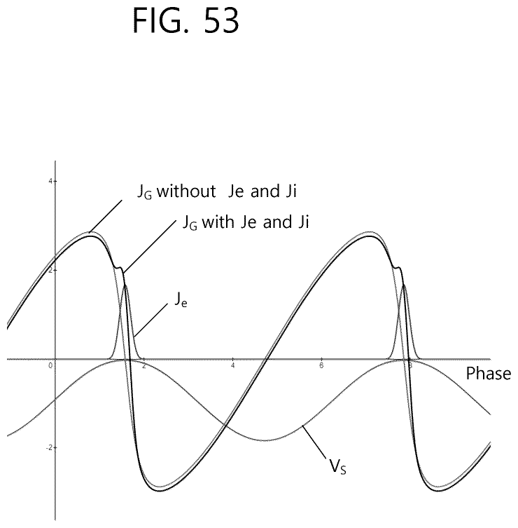

FIG. 53 is a diagram illustrating current flowing through an electrode at a sinusoidal applied voltage.

Referring to FIG. 52, current I_{G} or current density J_{G} flowing through an electrode 18 at a sinusoidal applied voltage is represented as follows. ω is an angular frequency of the sinusoidal applied voltage.

[Considering sinusoidal voltage]

$$\frac{{dV}_{s}}{dt} = \frac{{dV}_{G}}{dt} + \frac{{d}_{1}}{{ϵ}_{1}} {J}_{i} - [ \frac{{d}_{1}}{{ϵ}_{1}} \frac{\sqrt{2 {ϵ}_{2} {ρ}_{d}} ( \frac{{dV}_{G}}{dt} + \frac{{d}_{1}}{{ϵ}_{1}} {J}_{i} )}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} ] \qquad [ Equation 51 ]$$

$${V}_{G} = V sin ω t$$

$${I}_{G} = {C}_{1} \frac{d}{d} ( {V}_{G} - {V}_{s} )$$

$${I}_{G} = {C}_{1} \frac{{dV}_{G}}{dt} - {C}_{1} [ \frac{{dV}_{G}}{dt} + \frac{{d}_{1}}{{ϵ}_{1}} {J}_{i} - [ \frac{{d}_{1}}{{ϵ}_{1}} \frac{\sqrt{2 {ϵ}_{2} {ρ}_{d}} ( \frac{{dV}_{G}}{dt} + \frac{{d}_{1}}{{ϵ}_{1}} {J}_{i} )}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} ] ]$$

$${J}_{G} = - {J}_{i} + {c}_{1} [ \frac{{d}_{1}}{{ϵ}_{1}} \frac{\sqrt{2 {ϵ}_{2} {ρ}_{d}} ( \frac{{dV}_{G}}{dt} + \frac{{d}_{1}}{{ϵ}_{1}} {J}_{i} )}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} ]$$

$${J}_{G} = - {J}_{i} + [ \frac{\sqrt{2 {ϵ}_{2} {ρ}_{d}} ( V ω cos ω t + \frac{{d}_{1}}{{ϵ}_{1}} {J}_{i} )}{\sqrt{{( \frac{{d}_{1}}{{ϵ}_{1}} \sqrt{2 {ϵ}_{2} {ρ}_{d}} )}^{2} - 4 ( V sin ω t + \frac{{d}_{1}}{{ϵ}_{1}} {ρ}_{i} )}} ]$$

Current I_{G} or current density J_{G} flowing through an electrode 18 includes an ion current component Ji and a displacement current component (a second component). The current density J_{G} flowing through the electrode 18 is distorted from a sinusoidal waveform and approaches a sawtooth waveform. When an overcharge charge ρᵢ or a floating potential is introduced, current density J′_{G} flowing through the electrode 18 approaches a sinusoidal waveform.

Referring to FIG. 53, when electron current density Je is added, current density J_{G} of the electrode is given as follows:

$${J}_{G} = - {J}_{i} + [ \frac{\sqrt{2 {ϵ}_{2} {ρ}_{d}} ( V ω cos ω t + \frac{{d}_{1}}{{ϵ}_{1}} {J}_{i} )}{\sqrt{{( \frac{{d}_{1}}{{ϵ}_{1}} \sqrt{2 {ϵ}_{2} {ρ}_{d}} )}^{2} - 4 ( V sin ω t + \frac{{d}_{1}}{{ϵ}_{1}} {ρ}_{i} )}} ] + {J}_{e} \qquad [ Equation 52 ]$$

$${J}_{e} = {J}_{e i} {e}^{\frac{q ( {V}_{s} - {V}_{p} )}{k {T}_{e}}}$$

where Vp is a plasma potential, k is a Boltzmann constant, and Te is an electron temperature. The electron current density Je depends on an electron flux Jei and the potential of the target Vs. The electron temperature Te and plasma potential Vp are already known values. The potential of the target Vs is calculated using a previously derived equation.

When the potential of the target Vs approaches the plasma potential Vp, the electron current density Je flows into the target. As a result, the current density of the electrode J_{G} is changed. Accordingly, measuring and fitting the current density of the electrode J_{G} may be performed to obtain an overcharge state ρi of the target 16, charge density ρ_{d} of the plasma, and ion current density Ji.

When the electron current density Je and ion current density Ji are negligible and a certain frequency condition is applied, the current density is given as follows:

$${J}_{G} \approx [ \frac{\sqrt{2 {ϵ}_{2} {ρ}_{d}} ( V ω cos ω t + \frac{{d}_{1}}{{ϵ}_{1}} {J}_{i} )}{\sqrt{{( \frac{{d}_{1}}{{ϵ}_{1}} \sqrt{2 {ϵ}_{2} {ρ}_{d}} )}^{2} - 4 ( V sin ω t + \frac{{d}_{1}}{{ϵ}_{1}} {ρ}_{i} )}} ] \qquad [ Equation 53 ]$$

$$if V ω ≫ \frac{{d}_{1}}{{ϵ}_{1}} {J}_{i} ; \sqrt{2 {ϵ}_{2} {ρ}_{d}} V ω ≫ abs ( {J}_{i} )$$

For example, the angular frequency ω of the applied voltage may be sufficiently large to neglect the ion current density Ji. Also, the electron temperature Te may be sufficiently low to neglect the electron current density component.

The displacement current component of the current density J_{G} flowing through the electrode 18 depends on the overcharge state ρi of the target 16 and the charge density ρ_{d} of the plasma. Accordingly, measuring and fitting the displacement current component of the current density J_{G} of the electrode may be performed to obtain the charged amount ρi of the target 16 and the charge density ρ_{d} of the plasma.

### [Method of Obtaining Potential Vs of Target 16 by Measuring Sinusoidal Current]

The current I_{G} or current density J_{G} flowing through the electrode is obtained by fitting using the above equation. The initial charge ρi of the target and the charge density ρ_{d} of the plasma are obtained. When the charge density ρ_{d} of the plasma is obtained, the potential Vs of the target 16 and the variation of the potential ΔVs may be obtained.

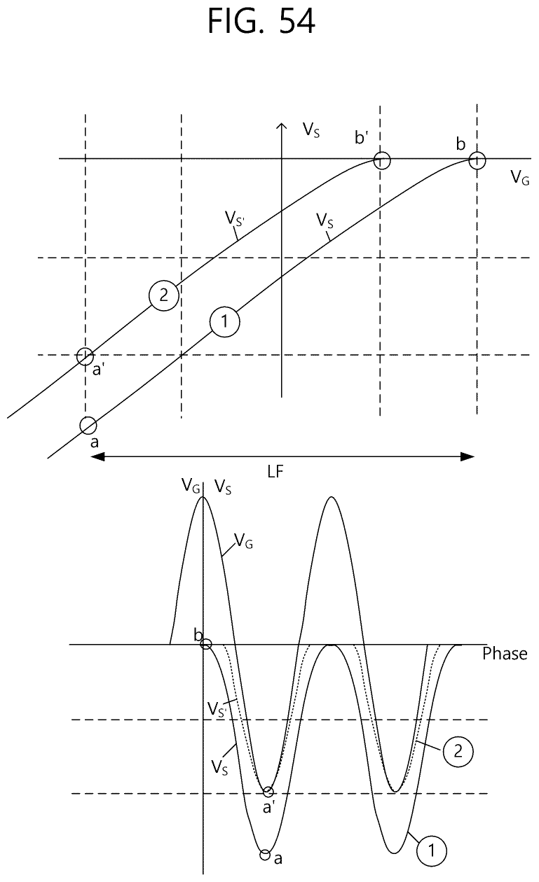

FIG. 54 represents the potential of the target at a sinusoidal applied voltage.

Referring to FIG. 54, curve 1 represents a potential curve of the target 16 in an equilibrium state. Curve 2 represents a potential curve of the target that is slightly charged with positive charges by the ion current density Ji. For example, a potential of the target Vs starts from point b on curve 1 at a positive applied voltage, passes through point a′ of curve 2, and returns to point b′ and point b, which are the positive applied voltages of curve 2. The potential Vs of the target has a flat shape in a voltage region in which the potential Vs becomes zero.

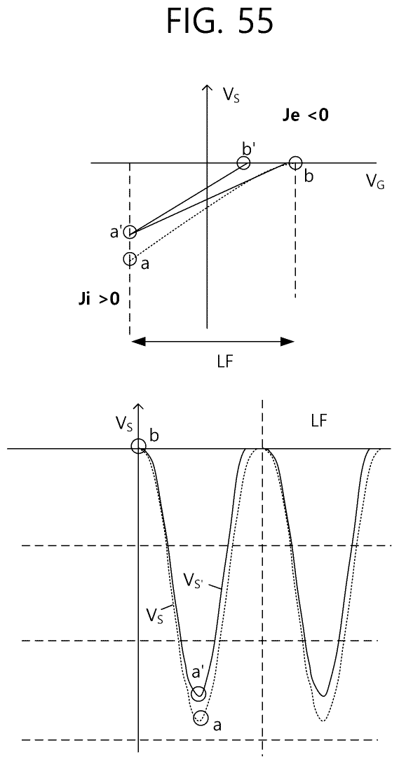

FIG. 55 is a diagram illustrating the potential of the target at a sinusoidal applied voltage.

Referring to FIG. 55, as a sinusoidal applied voltage decreases from a positive applied voltage to a negative applied voltage, a potential curve of the target 16 changes from a to a′ due to the influx of ion current density Ji. Accordingly, a potential Vs' of the target has an asymmetric shape. As the plasma density or ion current density Ji increases, the potential Vs of the target is more distorted near a maximum value of the positive applied voltage.

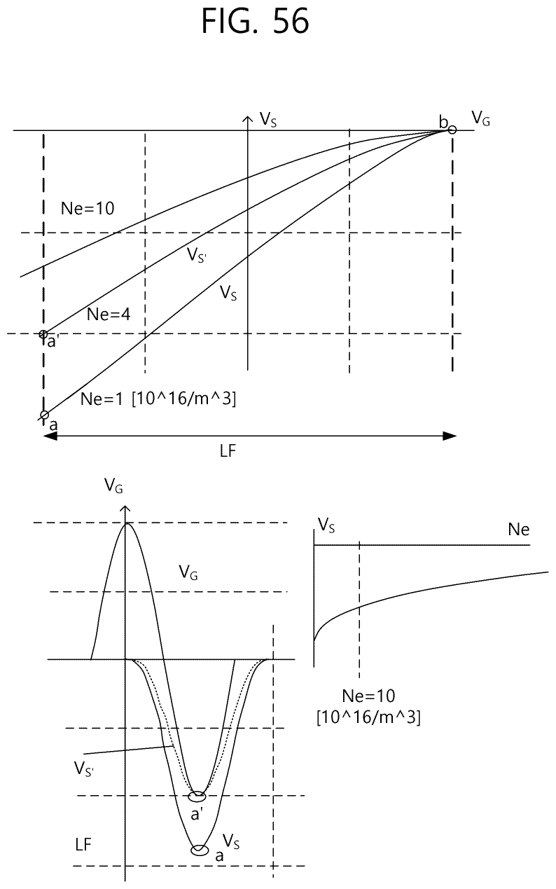

FIG. 56 is a diagram illustrating a potential of a target at a sinusoidal applied voltage based on plasma density.

Referring to FIG. 56, as plasma density increases, the absolute value of the target potential (Vs) decreases.

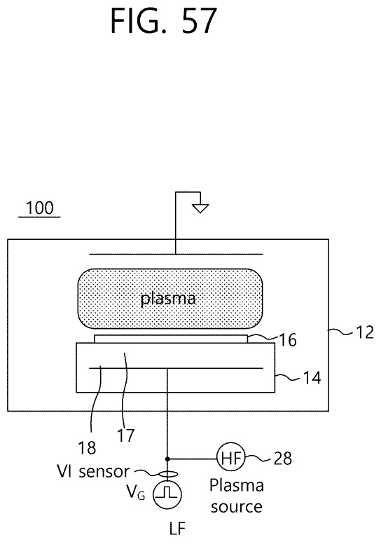

FIG. 57 is a plasma system illustrating the applied voltage of an electrode with high-frequency modulation.

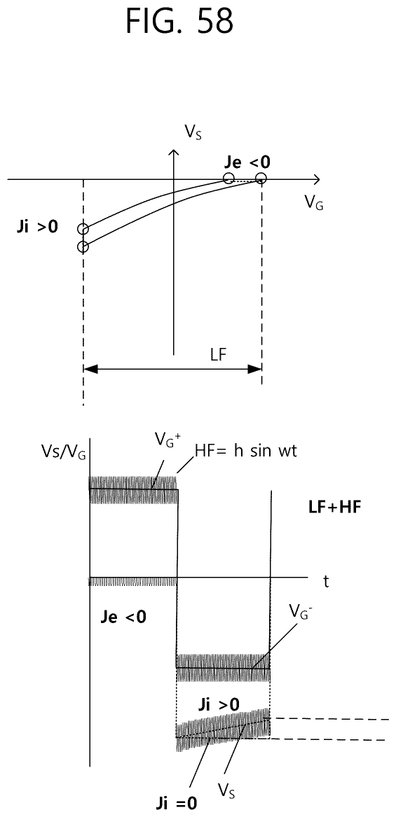

FIG. 58 is a diagram illustrating the voltage of the target based on the applied voltage of the electrode with high-frequency modulation.

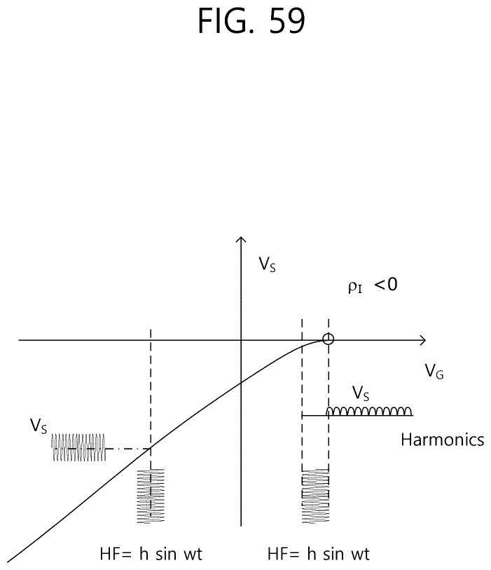

FIG. 59 is a diagram illustrating the voltage of the target under a low-frequency pulse applied voltage with high-frequency modulation of the electrode.

Referring to FIGS. 57 to 59, a high-frequency sinusoidal power supply HF is used for high-frequency modulation. An output of a low-frequency pulse power supply LF and an output of the high-frequency sinusoidal power supply HF are applied to the electrode 18. In this case, current I_{G} flowing through the electrode 18 is given as follows. The high-frequency sinusoidal power supply HF is a plasma generation power supply, and the high-frequency may be 13 MHz or higher.

### [Small Signal High-Frequency Modulation]

$$- {V}_{s} = {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )} ]}^{2} \qquad [ Equation 54 ]$$

$${V}_{G} = {V}_{0} + h sin ω t ; {V}_{0} < 0$$

$${I}_{G} = {C}_{1} \frac{d}{d} ( {V}_{G} - {V}_{s} )$$

$${I}_{G} = {C}_{1} \frac{{dV}_{G}}{dt} - {C}_{1} [ \frac{{dV}_{G}}{dt} + \frac{{d}_{1}}{{ϵ}_{1}} {J}_{i} - [ \frac{{d}_{1}}{{ϵ}_{1}} \frac{\sqrt{2 {ϵ}_{2} {ρ}_{d}} ( \frac{{dV}_{G}}{dt} + \frac{{d}_{1}}{{ϵ}_{1}} {J}_{i} )}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} ] ]$$

$${J}_{G} = - {J}_{i} + {c}_{1} [ \frac{{d}_{1}}{{ϵ}_{1}} \frac{\sqrt{2 {ϵ}_{2} {ρ}_{d}} ( \frac{{dV}_{G}}{dt} + \frac{{d}_{1}}{{ϵ}_{1}} {J}_{i} )}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} ] + {J}_{e}$$

$${J}_{G} = - {J}_{i} + [ \frac{\sqrt{2 {ϵ}_{2} {ρ}_{d}} ( h ω cos ω t + \frac{{d}_{1}}{{ϵ}_{1}} {J}_{i} )}{\sqrt{{( \frac{{d}_{1}}{{ϵ}_{1}} \sqrt{2 {ϵ}_{2} {ρ}_{d}} )}^{2} - 4 ( {V}_{0} + h sin ω t + \frac{{d}_{1}}{{ϵ}_{1}} {ρ}_{i} )}} ] + {J}_{e}$$

When a high-frequency sinusoidal wave HF is applied at a positive applied voltage of the low-frequency pulse, a voltage Vs of a target is distorted from a high-frequency sinusoidal wave. Such a distortion generates harmonics, causing the system to be unstable.

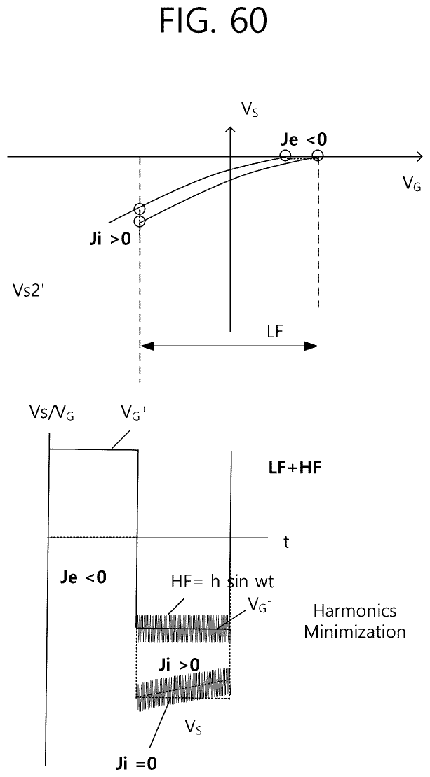

FIG. 60 represents the waveform of a low-frequency pulse synchronized with a high-frequency sinusoidal waveform and the potential of the target.

Referring to FIG. 60, a low-frequency pulse waveform is a bipolar pulse waveform, and a high-frequency sinusoidal wave is not applied to a positive voltage region. On the other hand, a high-frequency sinusoidal wave is applied to a negative voltage region. The high-frequency sinusoidal wave may generate plasma through stochastic heating. In addition, as the high-frequency sinusoidal wave is applied to the negative voltage region, the formation of harmonics may be suppressed to stabilize the system.

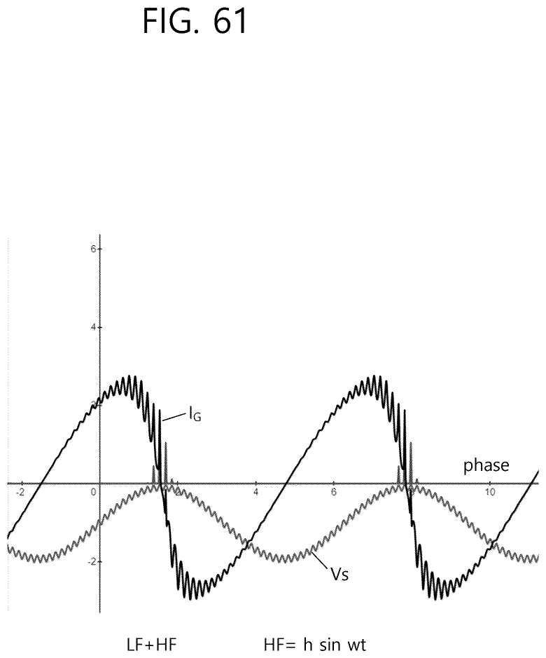

FIG. 61 is a diagram illustrating a potential of a target when a low-frequency sinusoidal voltage and a high-frequency sinusoidal voltage are applied to an electrode.

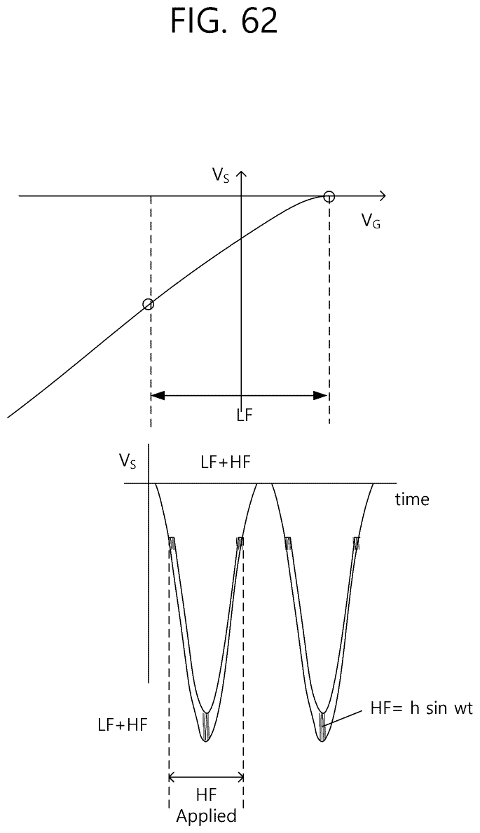

FIG. 62 is a diagram illustrating a potential Vs of a target when a low-frequency sinusoidal voltage and a high-frequency sinusoidal voltage are simultaneously applied to an electrode.

Referring to FIG. 61, when a high-frequency sinusoidal wave HF is applied at a positive applied voltage of a low-frequency sinusoidal wave LF, the voltage Vs of the target 16 may be distorted from the high-frequency sinusoidal wave. Such distortion generates harmonics, causing the system to be unstable.

Also, the current density J_{G} flowing through the electrode 18 varies with an envelope due to the high frequency during the positive applied voltage. The envelope of the current I_{G} is significantly sensitive to the initial charge ρi of the target. The initial charge ρi of the target 16 may be obtained using the envelope of the current I_{G}. Electron current density Je depends on the potential of the target Vs or the initial charge ρi of the target 16. Measuring and fitting the current density J_{G} flowing through the electrode 18 may be performed to obtain plasma charge density ρ_{d} and initial charged amount ρi of the target 16.

Referring to FIG. 62, in a low-frequency sinusoidal waveform, a high-frequency sinusoidal waveform is not applied in a positive maximum applied voltage period. On the other hand, a high-frequency sinusoidal waveform is applied in a negative applied voltage period. The high-frequency sinusoidal waveform may generate plasma through stochastic heating. When the high-frequency sinusoidal waveform is applied in the negative applied voltage period, the formation of harmonics may be suppressed to stabilize the system.

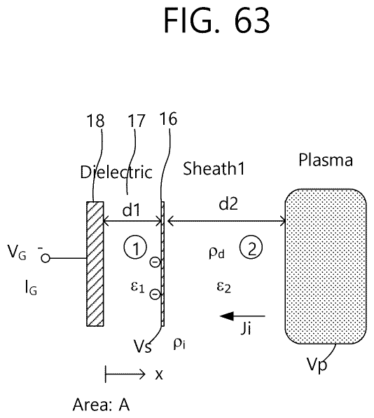

FIG. 63 is a conceptual diagram illustrating a voltage of a target considering a plasma potential.

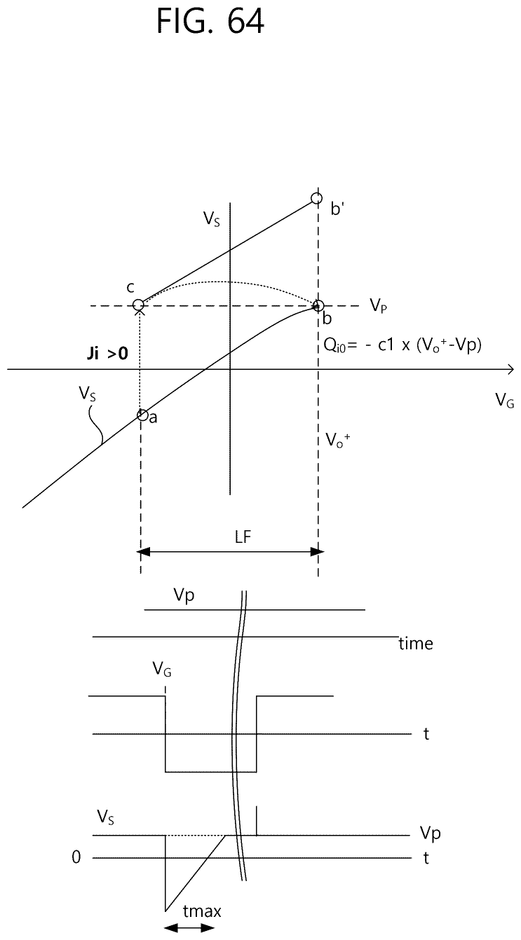

FIG. 64 is graphs illustrating a voltage of a target based on an applied voltage of an electrode, considering a plasma potential.

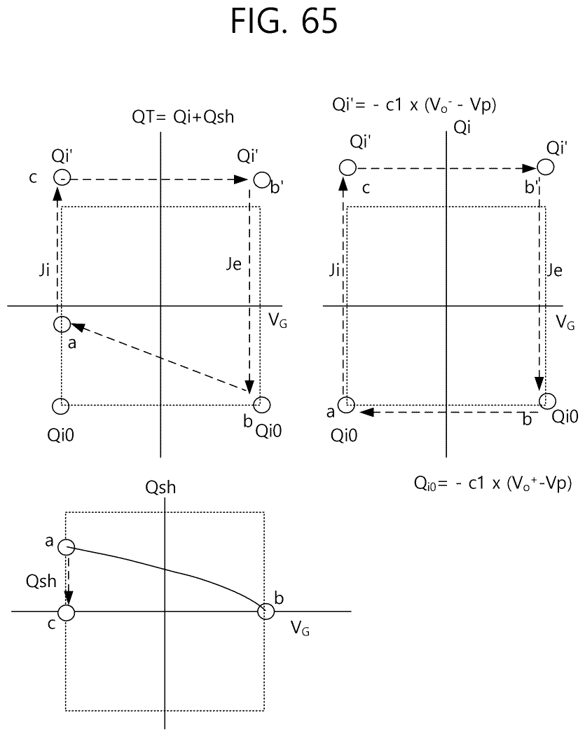

FIG. 65 is a diagram illustrating a charged amount of a target based on an applied voltage of an electrode, considering a plasma potential.

Referring to FIGS. 63 to 65, a plasma system 100 includes a chamber 12, a plasma source 20 generating plasma within the chamber 12, and a target holder 14 mounting a target 16.

The plasma has a plasma potential Vp. When a matrix model is used, a potential of the target 16 is given as follows. Ion energy of ions incident on the target 16 is given as a value obtained by subtracting the plasma potential Vp from the potential of the target 16 (Vs−Vp). The plasma potential Vp and plasma charge density may be measured using a Langmuir probe, or the like. The potential of the target 16 is given as follows:

### [Treatment in Case of Plasma Potential]

### [Matrix Model]

$${V}_{s} = {V}_{G} + \frac{{d}_{1}}{{ϵ}_{1}} [ {ρ}_{i} + {ρ}_{d} {d}_{2} ] \qquad [ Equation 55 ]$$

$${V}_{s} - {V}_{p} = - \frac{{ρ}_{d}}{2 {ϵ}_{2}} {d}_{2}^{2} \to {d}_{2} = \sqrt{\frac{- 2 {ϵ}_{2} ( {V}_{s} - {V}_{p} )}{{ρ}_{d}}}$$

$${V}_{s} - {V}_{p} = {V}_{G} - {V}_{p} + \frac{{d}_{1}}{{ϵ}_{1}} {ρ}_{i} + \frac{{d}_{1}}{{ϵ}_{1}} \sqrt{- 2 {ϵ}_{2} ( {V}_{s} - {V}_{p} ) {ρ}_{d}}$$

$${V}_{s} - {V}_{p} = - {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )} ]}^{2}$$

$${V}_{s} - {V}_{p} = - {( \frac{{d}_{1}}{{ϵ}_{1}} )}^{2} {ϵ}_{2} {ρ}_{d} + ( {V}_{G} - {V}_{p} + \frac{{d}_{1}}{{ϵ}_{1}} {ρ}_{i} ) + \frac{{d}_{1}}{2 {ϵ}_{1}} \sqrt{2 {ϵ}_{2} {ρ}_{d}} \sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )}$$

When a positive applied voltage V_{G}+ is applied, in an equilibrium state (Vs−Vp=0), as a simple capacitor, charged amounts Qi and ρi are given as follows.

$${V}_{G}^{+} - {V}_{p} = - \frac{{d}_{1}}{{ϵ}_{1}} {ρ}_{i} \qquad [ Equation 56 ]$$

When a negative applied voltage V_{G}− is applied, the potential of the target 16 reaches a plasma potential Vp or a floating potential V_{f} due to the ion current density Ji. In this case, a maximum time tmax for the potential of the target Vs to reach the plasma potential Vp is given as follows:

$$( {V}_{G} - {V}_{p} + \frac{{d}_{1}}{{ϵ}_{1}} {ρ}_{i} ) = {V}_{0} + {Xt}_{m ax} - {V}_{p} + \frac{{d}_{1}}{{ϵ}_{1}} ( {ρ}_{i 0} + {J}_{i} {t}_{ma x} ) \qquad [ Equation 57 ]$$

$${t}_{ma x} = - \frac{{V}_{0} - {V}_{p} + \frac{{d}_{1}}{{ϵ}_{1}} {ρ}_{i 0}}{X + \frac{{d}_{1}}{{ϵ}_{1}} {J}_{i}}$$

$$- \frac{{d}_{1}}{{ϵ}_{1}} {ρ}_{i 0} = {V}_{0}^{+} - {V}_{p} ; {V}_{0}^{+} > 0 ;$$

$${t}_{ma x} = - \frac{2 {V}_{0} {c}_{1}}{{J}_{i}} if X = 0 , {V}_{0} < 0$$

When the plasma potential Vp and floating potential V_{f} are taken into consideration, the maximum time tmax may be given as follows:

$${t}_{m ax} = - \frac{{V}_{s 0} - {V}_{f} - {V}_{p}}{\frac{{I}_{i}}{{C}_{1}} [ 1 - β ]}$$

When a negative applied voltage V_{G}− is applied, charged amounts Qi and ρi of the target increases over time due to the ion current density Ji or ion current Ii to have a positive value. When the potential of the target Vs is the plasma potential Vp, the charged amount Qi of the target 16 is given as follows:

$${V}_{G}^{-} - {V}_{p} = - \frac{{d}_{1}}{{ϵ}_{1}} {ρ}_{i}$$

An absolute value of the charged amounts Qi and ρi of the target 16 is larger than an absolute value of the charge due to electrons at a positive applied voltage.

When a negative applied voltage is applied, the plasma potential Vp may increase in proportion to the ion current density Ji such that a difference between the potential of the target Vs and the plasma potential Vp (Vs−Vp) is maintained to be constant.

$${V}_{G} = {V}_{G 0} + Xt ; {V}_{p} = {V}_{p 0} + Yt$$

$$Y = X + \frac{{d}_{1}}{{ϵ}_{1}} {J}_{i}$$

When the plasma potential Vp is taken into consideration, the current I_{G} flowing through the electrode 18 is given as follows:

$${I}_{G} = {C}_{1} \frac{d}{d} ( {V}_{G} - {V}_{s} ) \qquad [ Equation 58 ]$$

$${I}_{G} = {C}_{1} X - {C}_{1} ( X + \frac{{d}_{1} {I}_{i}}{{ϵ}_{1} A} ) [ 1 - \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )}} ] - {C}_{1} \frac{{d}_{1}}{{ϵ}_{1}} \frac{\sqrt{2 {ϵ}_{2} {ρ}_{d}} ( {dV}_{p} / dt )}{\sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )}}$$

$${I}_{G} = {C}_{1} \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )}} ( X - d {V}_{p} / dt ) + {C}_{1} \frac{- {d}_{1} {I}_{i}}{{ϵ}_{1} A} [ 1 - \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )}} ]$$

$${I}_{G} = {C}_{1} βX + {I}_{G 0}$$

$$β = \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ρ}_{1}} {ρ}_{i} )}}$$

$${I}_{G 0} = - {I}_{i} ( 1 - β )$$

$${I}_{G} = {C}_{1} β X - {I}_{i} ( 1 - β )$$

$$- {I}_{i} = {C}_{1} β X - {I}_{i} ( 1 - β ) \to {I}_{i} = - {X}_{1} {C}_{1}$$

When a time derivative of the plasma potential (dVp/dt) is taken into consideration, an AC component of the current I_{G} flowing through the electrode 18 depends on the time derivative of the plasma potential (dVp/dt). Accordingly, when the plasma potential is known, B may be obtained.

In the case of generation by a high-frequency plasma source, current is represented in terms of a driving frequency of the high-frequency plasma. When a driving frequency component of the high-frequency plasma is extracted from the current, information on the plasma potential and plasma charge density may be extracted.

A variation ΔVs in the voltage of the target 18 is given as follows:

$$Δ {V}_{s} = {V}_{s} ( t = τ ) - {V}_{s} ( t = 0 ) \qquad [ Equation 59 ]$$

$$Δ {V}_{s} = ( X + \frac{{d}_{1} {I}_{i}}{{ϵ}_{1} A} ) τ [ 1 - \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )}} ]$$

$$Δ {V}_{s} = ( X + \frac{{d}_{1} {J}_{i}}{{ϵ}_{1}} ) τ [ 1 - \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )}} ]$$

When the variation ΔVp is present in the plasma potential, a variation in the difference between the potential of the target and the plasma potential variation in ion energy is given as follows:

$$Δ ( {V}_{s} - {V}_{p} ) = ( X + \frac{{d}_{1} {J}_{i}}{{ϵ}_{1}} ) τ [ 1 - \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )}} ] - Δ {V}_{p}$$

Accordingly, a negative voltage may be applied to an additional auxiliary electrode to reduce the variation in the plasma potential.

A slope voltage may be applied to the plasma potential by an additional auxiliary electrode to reduce the variation in the difference between the potential of the target and the plasma potential (variation in ion energy).

$${V}_{G} = {V}_{G 0} + Xt ; {V}_{p} = {V}_{p 0} + Yt$$

$$Y = X + \frac{{d}_{1}}{{ϵ}_{1}} {J}_{i}$$

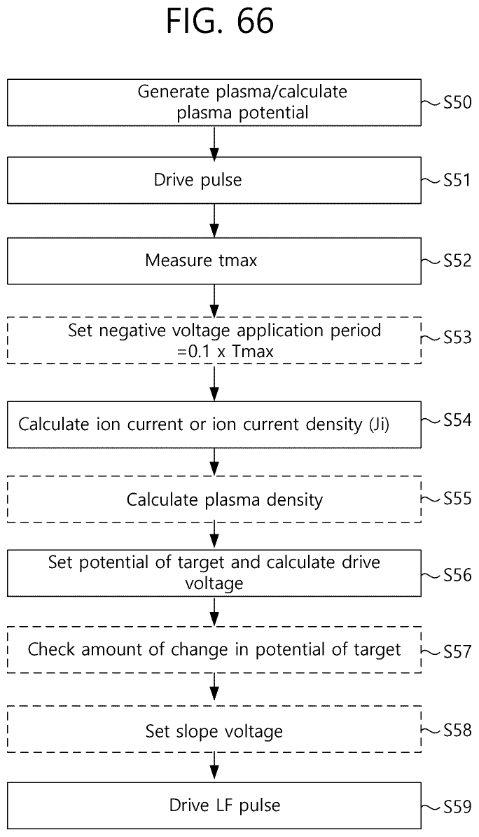

FIG. 66 is a flowchart illustrating an operation of driving an electrode of a plasma apparatus.

Referring to FIG. 66, plasma is generated, and a plasma potential Vp is measured. The plasma potential Vp may be an already known value. Then, a bipolar pulse voltage is applied to an electrode. The negative pulse section is set to be sufficiently large to measure the maximum time tmax at which the current flowing through the electrode becomes zero. The ion current density Ji is obtained using the relationship between the maximum time tmax and the ion current density Ji. Time during which a negative voltage is applied in the driving voltage is set to be sufficiently smaller than the maximum time tmax. The plasma charge density ρ_{d} is calculated using the ion current density Ji. The voltage Vs of the target 16 is set. The voltage Vs of the target determines the ion energy. A waveform of the driving voltage corresponding to the voltage Vs of the target is determined. A variation ΔVs in the voltage of the target, caused by the driving voltage and ion current density Ji, is checked. A slope voltage X is determined to correct the variation ΔVs in the voltage of the target caused by the driving voltage and ion current density Ji. A low-frequency pulse waveform is driven.

According to a modified embodiment of the present disclosure, the operation may be performed using various operation methods, and redundant descriptions are omitted.

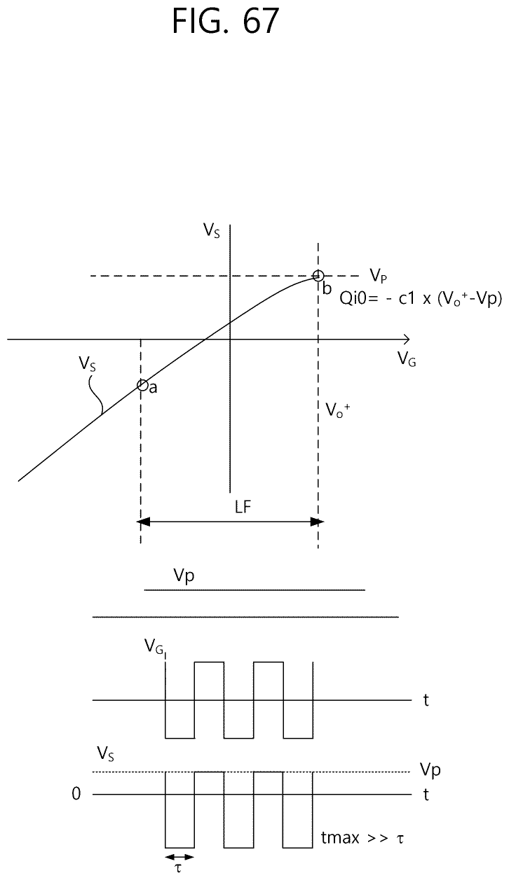

FIG. 67 is a diagram illustrating a potential of a target based on a pulse applied voltage when a plasma potential is present.

Referring to FIG. 67, a potential of the target Vs behaves similarly to the case of absence of a plasma potential. A value obtained by subtracting the plasma potential Vp from the potential of the target Vs (Vs−Vp) is the same as in the case of the absence of plasma potential. However, a difference lies in the initial charge ρi of the target 16.

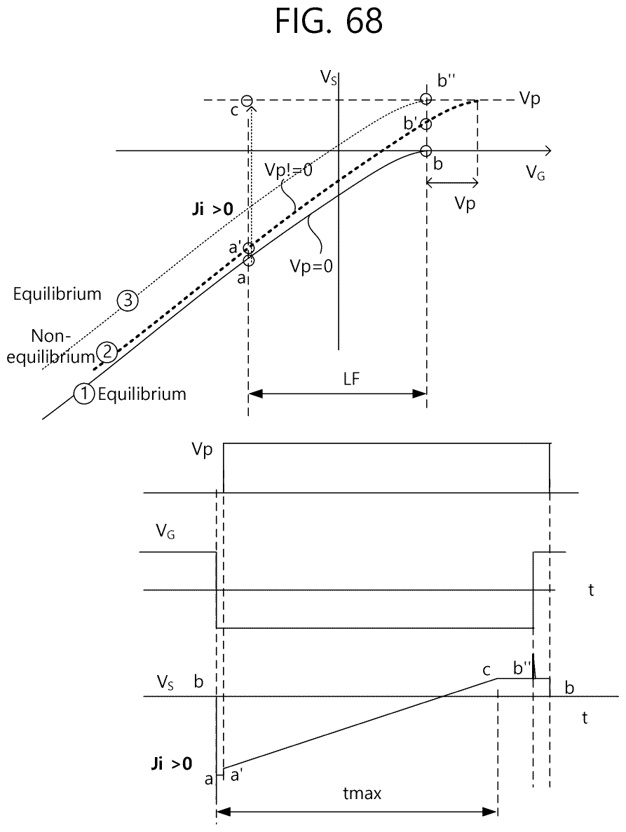

FIG. 68 is a diagram illustrating a potential of a target based on a pulse applied voltage when a plasma potential changes over time.

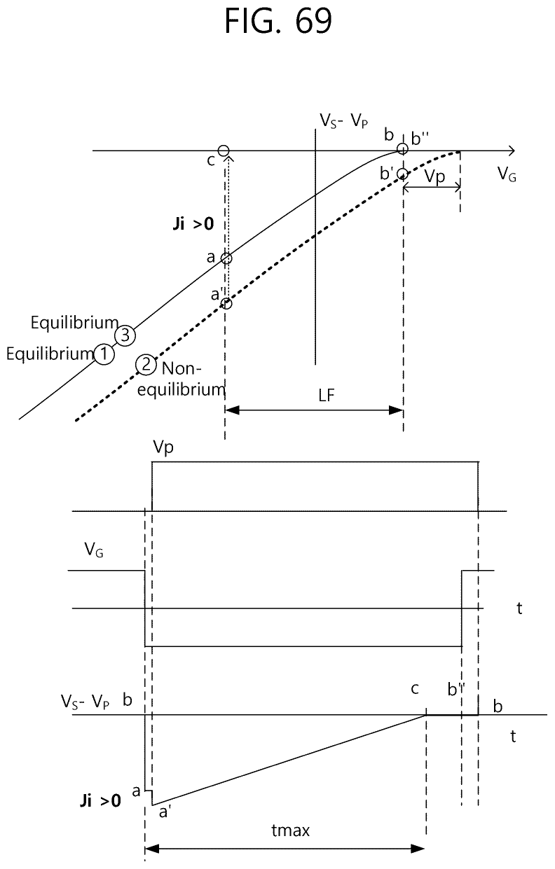

FIG. 69 is a diagram illustrating a value obtained by subtracting a plasma potential from a potential of a target based on a pulse applied voltage when a plasma potential changes over time.

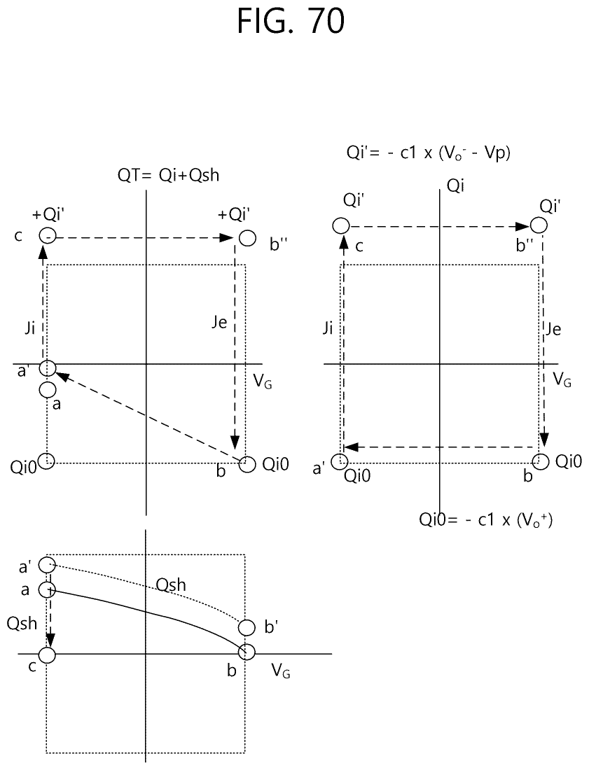

FIG. 70 is a diagram illustrating a charged amount of a target based on a pulse applied voltage when a plasma potential changes over time.

Referring to FIGS. 68 to 70, it is assumed that a plasma potential Vp has a positive value for a predetermined period and is zero for the remaining period. When the plasma potential Vp is zero, the potential of the target Vs follows curve 1 in an equilibrium state. Also, when the plasma potential Vp has a predetermined positive value, the potential of the target Vs follows curve 3 in the equilibrium state.

When the plasma potential Vp is zero and the applied voltage transitions rapidly from a positive value Vₒ+ to a negative value Vₒ−, a charged amount of the target is Qᵢₒ=−c1V₀+. When the plasma potential Vp is rapidly changed to have a positive value while the target has this charge, the potential of the target Vp follows a non-equilibrium curve 2. Accordingly, the potential of the target Vs moves from point a to a′, and as the ion current density flows into the target, the potential of the target Vs moves to point c. At point c, the potential of the target Vs is the plasma potential, and the charged amount is given by Q=−c1 (V₀−−Vp).

When considering the value obtained by subtracting the plasma potential from the potential of the target (Vs−Vp), the ion energy increases by approximately the plasma potential due to the plasma potential. For example, electrons are accumulated on the target at a positive applied voltage Vₒ+, and the applied voltage is then changed such that electrons no longer flow into the electrode. In this state, the plasma potential is changed.

A value obtained by subtracting the plasma potential from the potential of the target (Vs−Vp), or the ion energy, increases when the plasma potential is increased while initially increasing the charged amount of the target. For example, after reaching an equilibrium state at a positive applied voltage to initially charge the target, the applied voltage is changed to a negative applied voltage and the plasma potential is then changed. When the plasma potential is changed, the potential of the target is changed until reaching the equilibrium state because the potential of the target is in a non-equilibrium state.

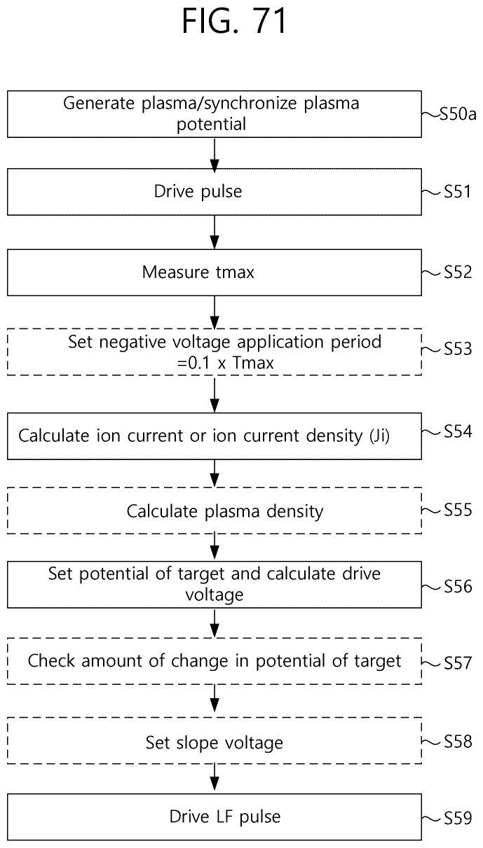

FIG. 71 is a flowchart illustrating driving of an applied voltage of an electrode in a plasma apparatus.

Referring to FIG. 71, plasma is generated and the plasma potential is synchronized with the driving voltage. Then, a bipolar pulse voltage is applied to the electrode. The negative pulse section is set to be sufficiently large to measure the maximum time tmax at which the current flowing through the electrode becomes zero. The ion current density is obtained using the relationship between the maximum time tmax and the ion current density. The time for which a negative voltage is applied in the driving voltage is set to be sufficiently smaller than the maximum time tmax. The plasma density is calculated using the ion current density. The voltage of the target is set. The voltage of the target determines the ion energy. The waveform of the driving voltage corresponding to the voltage of the target is determined. The variation in the voltage of the target, caused by the ion current density, is checked. A slope voltage is determined to correct the variation in the voltage of the target caused by the ion current density. A low-frequency pulse waveform is driven.

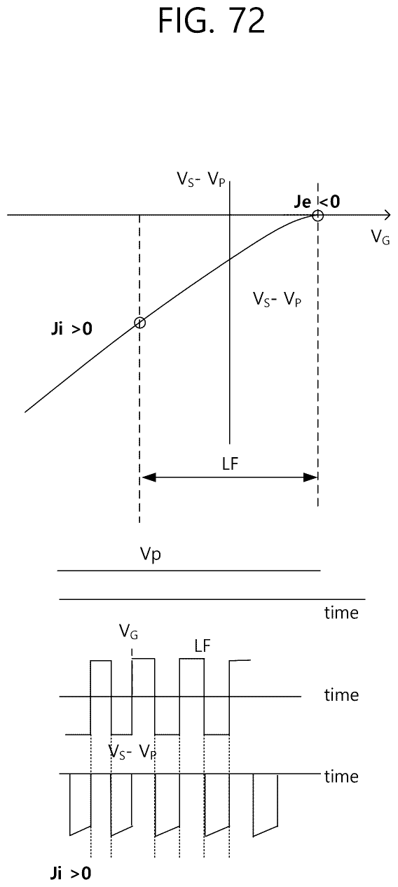

FIG. 72 is a diagram illustrating a potential of a target when a plasma potential remains constant.

Referring to FIG. 72, ion energy (Vs−Vp) is constant regardless of a value of a plasma potential.

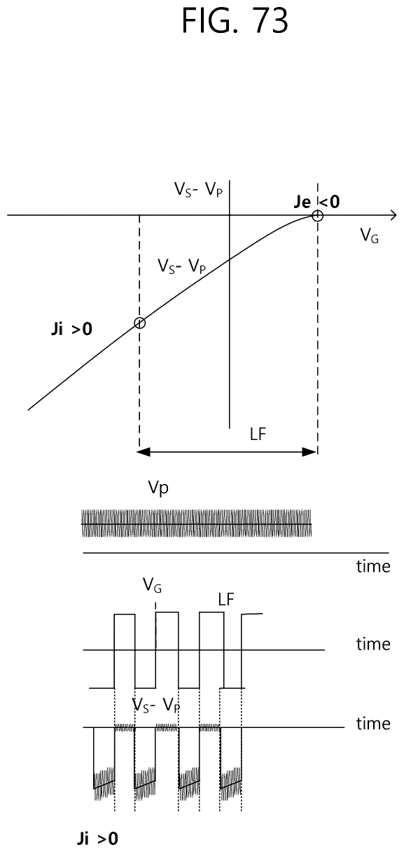

FIG. 73 is a diagram illustrating a potential of a target when a plasma potential oscillates over time.

Referring to FIG. 73, a plasma potential oscillates with an amplitude B and angular frequency ωₚ at a reference value Vₚ₀. A plasma potential Vp is given as follows:

$${V}_{p} = {V}_{p 0} + B sin ( {ω}_{p} t )$$

$$V ω > B {ω}_{p}$$

$$V ω > 0.1 B {ω}_{p}$$

A low-frequency pulse waveform has an amplitude V and a constant angular frequency ω. In this case, a potential Vs of a target is given as follows:

$${V}_{s} - {V}_{p} = - {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )} ]}^{2}$$

Accordingly, the ion energy (Vs−Vp) oscillates at an angular frequency ω. An ion energy distribution depends on the plasma potential Vp.

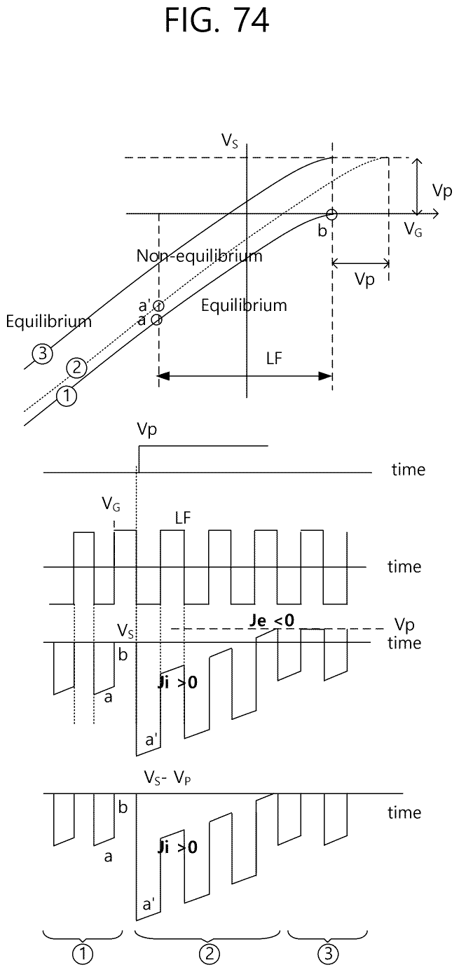

FIG. 74 is a diagram illustrating a potential of a target synchronized with a drive voltage and a plasma potential.

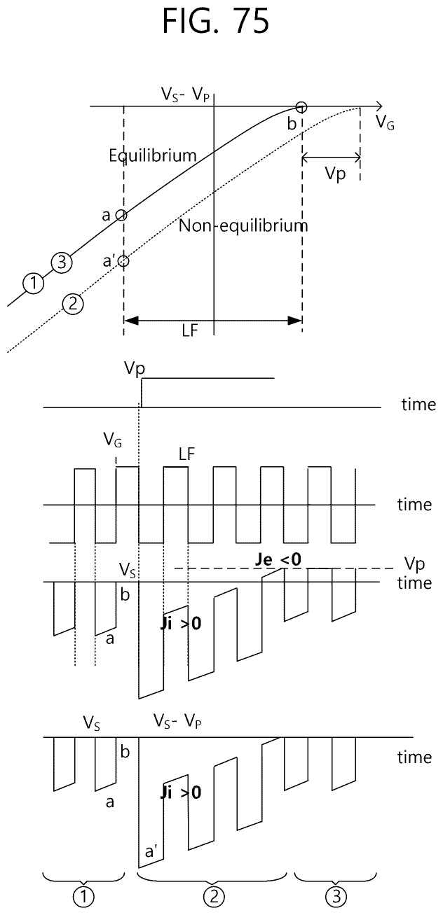

FIG. 75 is a diagram illustrating the value obtained by subtracting a plasma potential from a potential of a target synchronized with a drive voltage.

Referring to FIGS. 74 and 75, it is assumed that a plasma potential Vp has a positive value for a certain period and is zero for the remaining period. When the plasma potential Vp is zero, the potential of the target Vs follows curve 1 in an equilibrium state. Also, when the plasma potential Vp has a predetermined positive value, the potential of the target Vs follows curve 3 in the equilibrium state.

When the applied voltage transitions rapidly from a positive value Vₒ+ to a negative value Vₒ− while the plasma potential Vp is zero, a charged amount of the target has Qᵢ₀=−c₁(V₀³⁰ −Vₚ). When the plasma potential Vp is rapidly changed to have a positive value while the charged amount of the target has this value, the potential of the target follows curve 2. Therefore, the potential of the target Vs moves from point a to point a′. When the applied voltage transitions rapidly from a negative value Vₒ− to a positive value Vₒ+, the potential of the target Vs follows curve 2 and does not reach an equilibrium state. As the ion current density Ji is introduced, the charged amount of the target changes. Ultimately, when the potential of the target Vs reaches the plasma potential, electrons are introduced and thus the potential reaches the equilibrium state along curve 3.

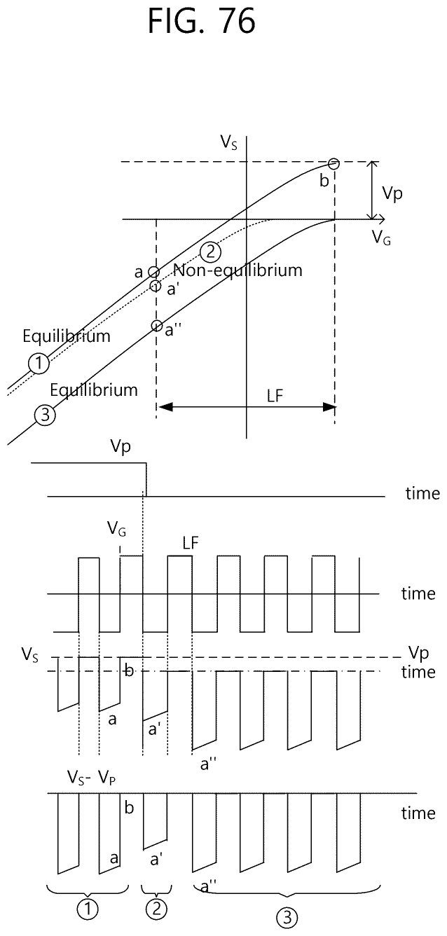

FIG. 76 is a diagram illustrating the potential of the target synchronized with the drive voltage and plasma potential.

Referring to FIG. 76, it is assumed that a plasma potential has a positive value for a certain duration and zero for the remaining period. When the plasma potential has a constant positive value, a potential of a target follows curve 1 in an equilibrium state. In addition, when the plasma potential is zero, the potential of the target follows curve 3 n the equilibrium state.

When a driving voltage transitions rapidly from a positive value Vₒ+ to a negative value Vₒ− while the plasma potential has a positive value, a charged amount of the target has Qᵢ₀=−c1 (V₀⁺−Vₚ). When the plasma potential is rapidly changed to have a value of zero while the target has this charged amount, the potential of the target follows curve 2. Accordingly, the potential Vs of the target moves from point a to point a′. When the driving voltage transitions rapidly from the negative value Vₒ− to the positive value Vo+, the potential of the target follows curve 2 and reaches an equilibrium state in which the potential of the target is zero. For example, when the potential of the target reaches zero, electrons are introduced and thus the potential reaches an equilibrium state along curve 3.

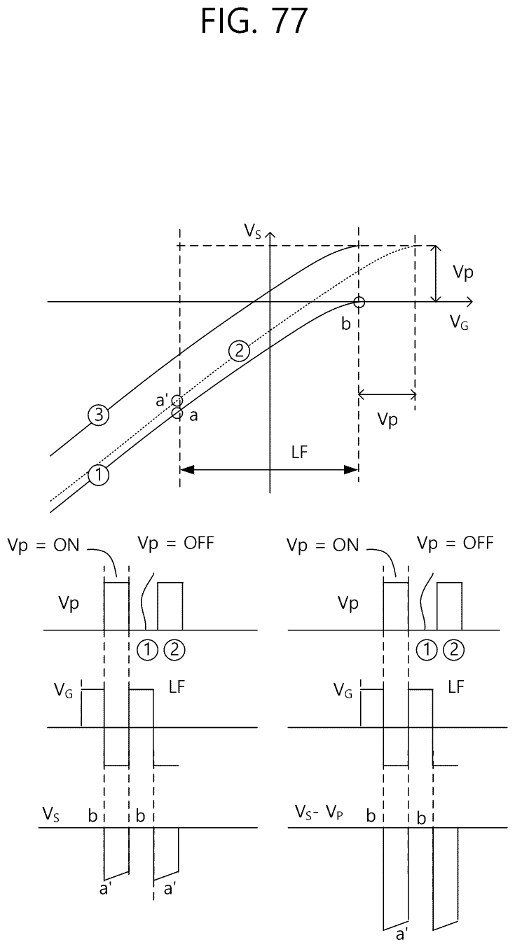

FIG. 77 is a diagram illustrating a potential of a target synchronized with a pulse drive voltage and a plasma potential.

Referring to FIG. 77, a plasma potential Vp is zero while a pulse driving voltage has a positive value. The plasma potential Vp has a positive value while the driving voltage has a negative value.

When the plasma potential Vp is zero, the potential of the target follows curve 1 in an equilibrium state. Moreover, when the plasma potential Vp has a predetermined positive value, the potential of the target Vs follows curve 3 in the equilibrium state.

When an applied voltage has a positive value while the plasma potential Vp is zero, a charged amount of the target is Qᵢ₀=−c₁V₀³⁰ . When the applied voltage transitions rapidly from a positive value Vₒ+ to a negative value Vₒ−, the charged amount of the target has Qᵢ₀=−c₁V₀^{+.} When the plasma potential Vp is rapidly changed to have a positive value while the target has this charge, the potential of the target Vs follows curve 2. Accordingly, the potential of the target Vs moves from point a to point a′.

When the plasma potential Vp transitions to a state in which the plasma potential is zero while the applied voltage transitions rapidly from a negative value Vₒ− to a positive value Vₒ+, the potential of the target follows curve 1 and reaches the equilibrium state.

For example, the ion energy (Vs−Vp) increases only during a period in which the applied voltage has a negative value Vₒ−.

In additional, the plasma potential may have a slope voltage to increase over time. To this end, an auxiliary electrode may apply a positive bias voltage.

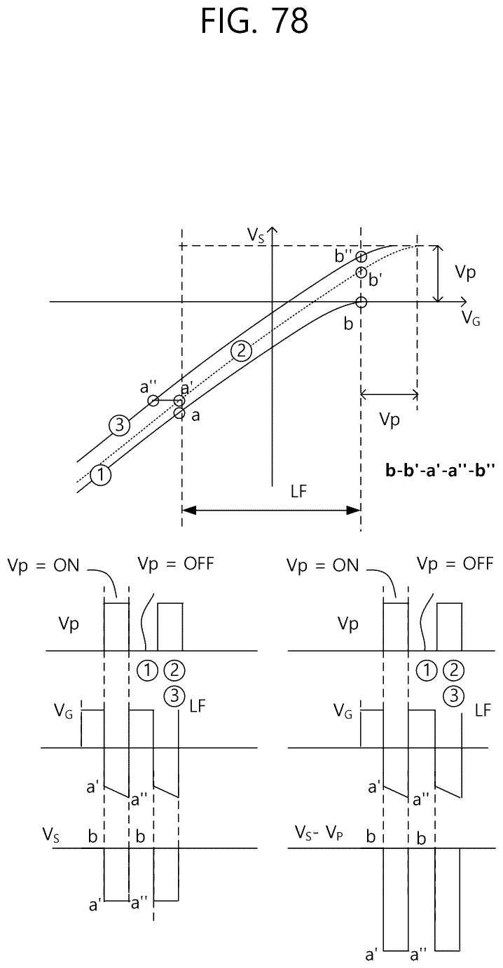

FIG. 78 is a diagram illustrating a potential of a target synchronized with a drive voltage and a plasma potential.

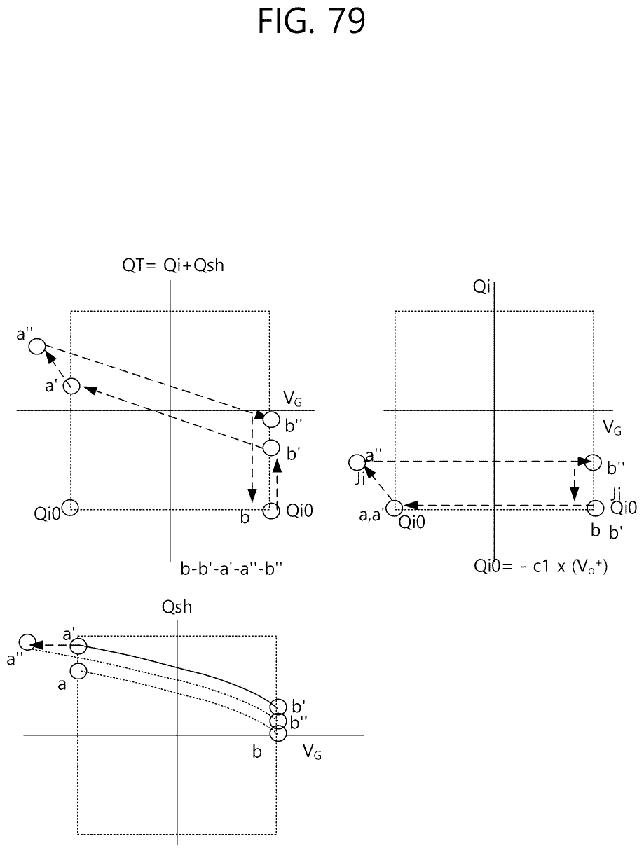

FIG. 79 is a diagram illustrating a charged amount of a target synchronized with a drive voltage and a plasma potential.

Referring to FIGS. 78 and 79, the plasma potential Vp is zero while the driving voltage has a positive value. The plasma potential Vp has a positive value while the driving voltage has a negative value. The driving voltage has a slope voltage while the driving voltage has a negative value. In this case, the potential of the target Vs has a constant value while the driving voltage has a negative value.

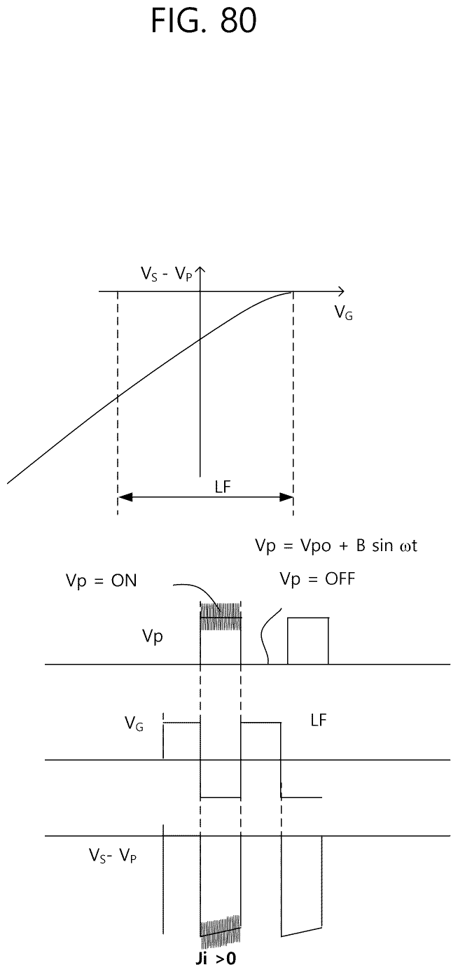

FIG. 80 is a diagram illustrating a potential of a target synchronized with a drive voltage and a plasma potential.

Referring to FIG. 80, while a driving voltage has a positive value, a plasma potential Vp is zero. While the driving voltage has a negative vale, the plasma potential Vp has a positive value. While the driving voltage has the negative value, the plasma potential Vp oscillates with a constant amplitude at the positive value. In this case, the potential of the target Vs depends on the oscillation of the plasma potential while the driving voltage has a negative value.

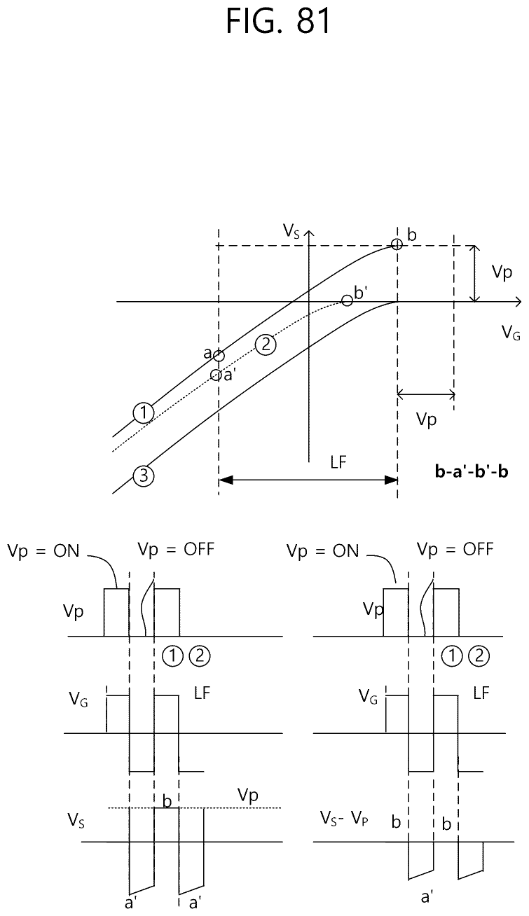

FIG. 81 is a diagram illustrating a potential of a target synchronized with a drive voltage and a plasma potential.

Referring to FIG. 81, while a driving voltage has a positive value, a plasma potential Vp has a positive value. When the driving voltage has a negative value, the plasma potential Vp is zero.

When the plasma potential Vp has a positive value, the potential of the target Vs follows curve 1 in an equilibrium state. Moreover, when the plasma potential Vp is zero, the potential of the target Vs follows curve 3 in the equilibrium state.

When the plasma potential Vp has a positive value and an applied voltage has a positive value, the charged amount of the target is Qᵢ₀=−c₁(V₀³⁰ −Vₚ). When the applied voltage transitions rapidly from a positive value Vₒ+ to a negative value Vₒ−, the charged amount of the target has Qᵢ₀=−c₁(V₀⁺−Vₚ). When the plasma potential Vp is suddenly changed to have a value of zero while the target has this charge, the potential of the target Vs follows curve 2. Accordingly, the potential of the target Vs moves from point a to point a′.

When the plasma potential Vp transitions to a state of a positive value while the applied voltage transitions rapidly from a negative value Vₒ− to a positive value Vₒ+, the potential of the target Vs follows curve 1 and reaches an equilibrium state.

For example, the ion energy (Vs−Vp) decreases only during a period in which the applied voltage has the negative value Vₒ−.

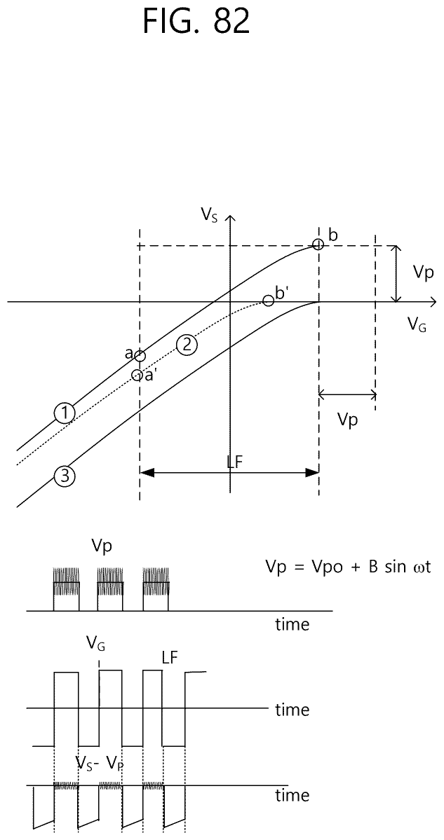

FIG. 82 is a diagram illustrating a potential of a target synchronized with a drive voltage and a plasma potential.

Referring to FIG. 82, while a driving voltage has a positive value, a plasma potential Vp has a positive value. While the driving voltage has a negative value, the plasma potential Vp has a value of zero.

When the plasma potential Vp has a positive value, a potential of a target follows curve 1 in an equilibrium state. Moreover, when the plasma potential Vp has a value of zero, the potential Vs of the target follows curve 3 in the equilibrium state. While the driving voltage has a positive value, the plasma potential Vp oscillates with a constant amplitude at a positive value. In this case, the potential of the target Vs oscillates near zero.

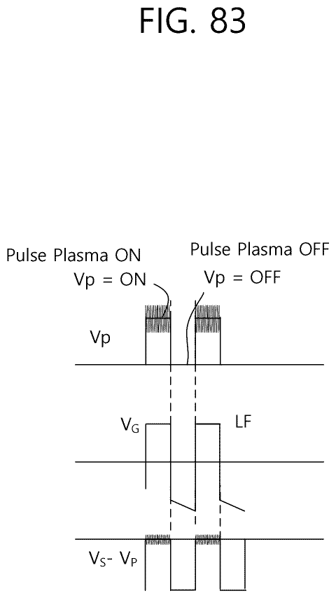

FIG. 83 is a diagram illustrating a potential of a target synchronized with a drive voltage and a plasma potential.

Referencing FIG. 83, when the driving voltage has a positive value, the plasma potential Vp has a positive value. While the driving voltage has a negative value, the plasma potential Vp has a value of zero.

When the plasma potential Vp has a positive value, the potential of the target follows curve 1 in an equilibrium state. Moreover, when the plasma potential Vp has a value of zero, the potential Vs of the target follows curve 3 in the equilibrium state. While the driving voltage has a positive value, the plasma potential Vp oscillates with a constant amplitude at a positive value. While the driving voltage has a negative value, the driving voltage has a slope voltage. In this case, the potential Vs of the target has a constant value while the driving voltage has the negative value.

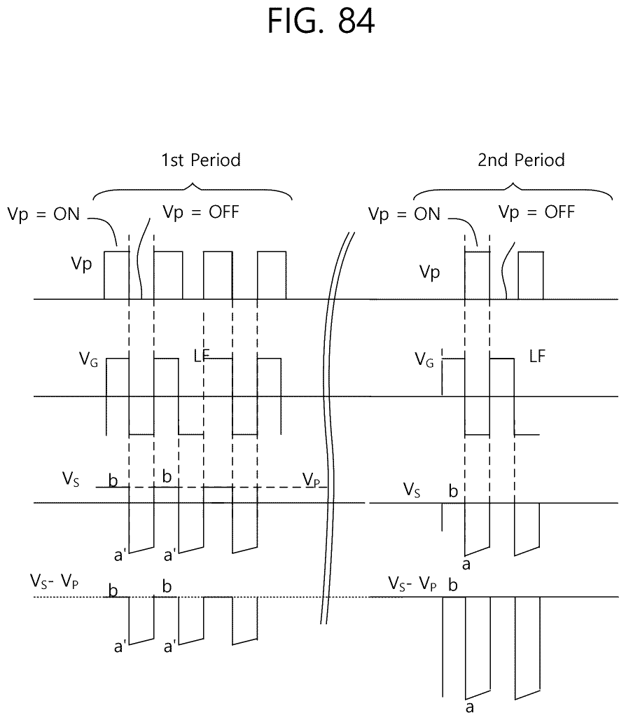

FIG. 84 is a diagram illustrating a potential of a target synchronized with a drive voltage and a plasma potential.

Referring to FIG. 84, in a first time period, a plasma potential Vp has a positive value while an applied voltage has a positive value. In a second time period, the plasma potential Vp has a positive value while the applied voltage has a negative value. When synchronization timing is changed, ion energy (Vs−Vp) may be controlled.

The plasma potential Vp has a value of zero for a predetermined period and has a positive value for the remaining period. Accordingly, the plasma potential Vp alternates with a specific frequency. A period of a sinusoidal applied voltage is much shorter than a period of the plasma potential.

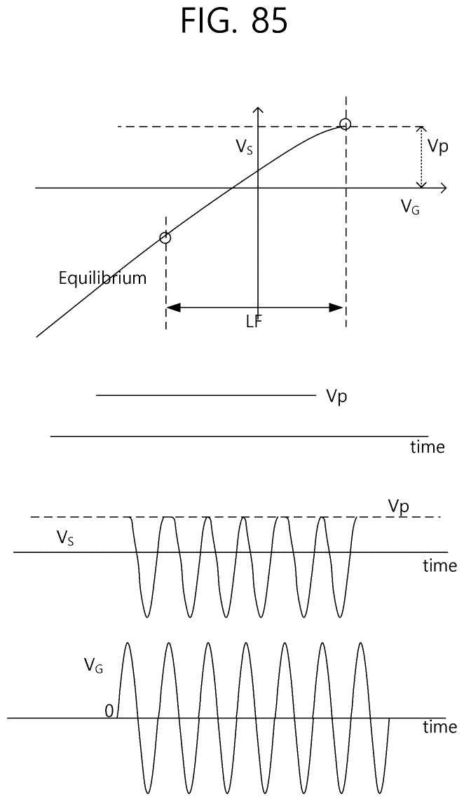

FIG. 85 is a diagram illustrating a potential of a target when a plasma potential is constant and a sinusoidal drive voltage is applied.

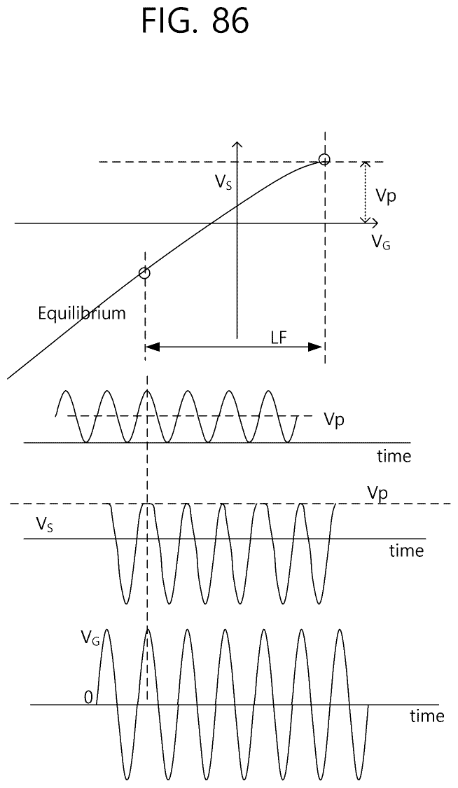

FIG. 86 is a diagram illustrating a potential of a target where a sinusoidal plasma potential is synchronized with a sinusoidal drive voltage.

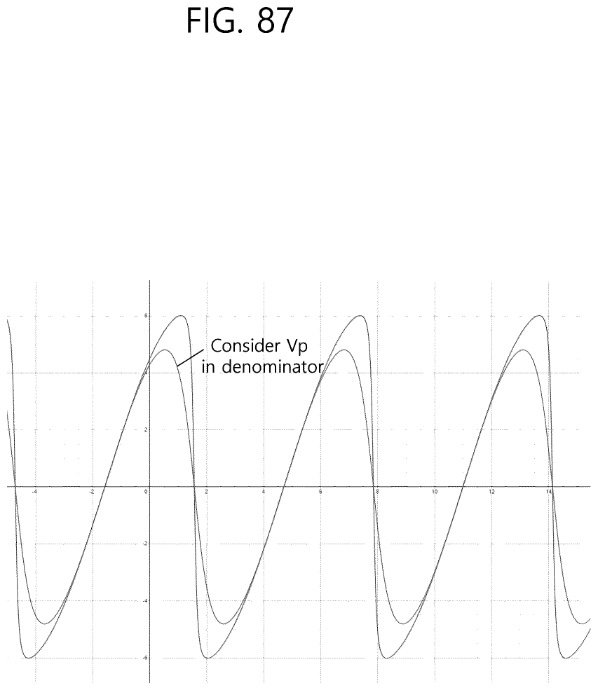

FIG. 87 is a diagram illustrating a current waveform flowing through an electrode when a sinusoidal plasma potential is synchronized with a sinusoidal drive voltage.

Referring to FIGS. 85 to 87, when a driving voltage applied to an electrode is a low-frequency sinusoidal wave, electrode current I_{G} is given as follow:

### [Treatment in Sinusoidal Wave]

$${V}_{s} - {V}_{p} = - {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )} ]}^{2} \qquad [ Equation 60 ]$$

$${V}_{s} - {V}_{p} = - {( \frac{{d}_{1}}{{ϵ}_{1}} )}^{2} {ϵ}_{2} {ρ}_{d} + ( {V}_{G} - {V}_{p} + \frac{{d}_{1}}{{ϵ}_{1}} {ρ}_{i} ) + \frac{{d}_{1}}{{ϵ}_{1} 2} \sqrt{2 {ϵ}_{2} {ρ}_{d}} \sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )}$$

$${I}_{G} = {C}_{1} \frac{d}{d} ( {V}_{G} - {V}_{s} )$$

$${I}_{G} = {C}_{1} \frac{{dV}_{G}}{dt} - {C}_{1} [ \frac{{dV}_{G}}{dt} + \frac{{d}_{1}}{{ϵ}_{1}} {J}_{i} - [ \frac{{d}_{1}}{{ϵ}_{1}} \frac{\sqrt{2 {ϵ}_{2} {ρ}_{d}} ( \frac{{dV}_{G}}{dt} + \frac{{d}_{1}}{{ϵ}_{1}} {J}_{i} - \frac{{dV}_{p}}{dt} )}{\sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )}} ] ]$$

$${J}_{G} = - {J}_{i} + {c}_{1} [ \frac{{d}_{1}}{{ϵ}_{1}} \frac{\sqrt{2 {ϵ}_{2} {ρ}_{d}} ( \frac{{dV}_{G}}{dt} + \frac{{d}_{1}}{{ϵ}_{1}} {J}_{i} - \frac{{dV}_{p}}{dt} )}{\sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )}} ]$$

$${J}_{G} = - {J}_{i} + [ \frac{\sqrt{2 {ϵ}_{2} {ρ}_{d}} ( V ω cos ω t + \frac{{d}_{1}}{{ϵ}_{1}} {J}_{i} - \frac{{dV}_{p}}{dt} )}{\sqrt{{( \frac{{d}_{1}}{{ϵ}_{1}} \sqrt{2 {ϵ}_{2} {ρ}_{d}} )}^{2} - 4 ( V sin ω t - {V}_{p} + \frac{{d}_{1}}{{ϵ}_{1}} {ρ}_{i} )}} ]$$

When electron current density Je and ion current density Ji are negligible and low-frequency conditions and high-frequency conditions are applied, the following equation is given. An amplitude of the low-frequency sinusoidal wave is V, and an angular frequency is ω.

$${J}_{G} \approx [ \frac{\sqrt{2 {ϵ}_{2} {ρ}_{d}} ( V ω cos ωt - B {ω}_{p} cos {ω}_{p} t )}{\sqrt{{( \frac{{d}_{1}}{{ϵ}_{1}} \sqrt{2 {ϵ}_{2} {ρ}_{d}} )}^{2} - 4 ( V sin ω t - {V}_{p} + \frac{{d}_{1}}{{ϵ}_{1}} {ρ}_{i} )}} ] \qquad [ Equation 61 ]$$

$$if V ω ≫ \frac{{d}_{1}}{{ϵ}_{1}} {J}_{i} ; \sqrt{2 {ϵ}_{2} {ρ}_{d}} \sqrt{V} ω ≫ abs ( {J}_{i} )$$

$${V}_{p} = {V}_{p 0} + B sin ( {ω}_{p} t )$$

$$V ω > B {ω}_{p}$$

Current I_{G} or current density J_{G} flowing through an electrode is changed by the change of a plasma potential Vp. In addition, the current I_{G} or current density J_{G} is distorted to resemble a sine wave due to an overcharged target.

When the plasma potential Vp is changed, another sheath is formed on a grounded ground electrode. An area of the electrode is A1, and an area of the ground electrode is A2. Current I_{G2} flowing through the ground electrode is given as follow:

$${I}_{G 2} = {A}_{2} {c}_{sh 2} ( \frac{{dV}_{p}}{dt} )$$

$${V}_{p} = \frac{{ρ}_{d}}{2 {ϵ}_{0}} {d}^{2} \to d = \sqrt{\frac{2 {ϵ}_{0} {V}_{p}}{{ρ}_{d}}}$$

$${I}_{G 2} = {A}_{2} \frac{{ϵ}_{0}}{d} ( \frac{{dV}_{p}}{d t} )$$

$${I}_{G 2} = {A}_{2} \frac{\sqrt{{ϵ}_{0} {ρ}_{d}}}{\sqrt{2 {V}_{p}}} ( \frac{{dV}_{p}}{dt} )$$

$${V}_{p} = {V}_{p 0} + B sin ( ω t )$$

$${I}_{G 2} = {A}_{2} \frac{\sqrt{{ϵ}_{0} {ρ}_{d}}}{\sqrt{2 {V}_{p}}} [ ω B cos ( ω t ) ]$$

When a phase of the current I_{G} flowing through the electrode and plasma and a phase of the current I_{G2} flowing through the plasma and ground electrode match each other, the current I_{G2} flowing through the plasma and ground electrode is given as follow:

$${I}_{G 2} = {A}_{2} \frac{\sqrt{{ϵ}_{0} {ρ}_{d}}}{\sqrt{2} \sqrt{{V}_{p 0} + B sin ( ω t )}} [ ω B cos ( ω t ) ]$$

When the phase of the current I_{G} flowing through the electrode and plasma and the phase of the current I_{G2} flowing through the plasma and ground electrode are changed to compare magnitudes thereof, a result of the comparison may be given as follows:

$${I}_{G} = {A}_{1} [ \frac{\sqrt{2 {ϵ}_{2} {ρ}_{d}} ( V ω cos ω t - B ω cos ω t )}{\sqrt{{( \frac{( {d}_{1}}{{ϵ}_{1}} \sqrt{2 {ϵ}_{2} {ρ}_{d}} )}^{2} - 4 ( V sin ω t - {V}_{p} + \frac{{d}_{1}}{{ϵ}_{1}} {ρ}_{i} )}} ]$$

$${I}_{G 2} = {A}_{2} \frac{\sqrt{{ϵ}_{2} {ρ}_{d}}}{\sqrt{2} \sqrt{{V}_{p 0} - B sin ( ω t )}} [ ω B cos ( ω t ) ]$$

$${A}_{1} [ \frac{\sqrt{2 {ϵ}_{2} {ρ}_{d}} ( V ω cos ω t - B ω cos ω t )}{\sqrt{{( \frac{{d}_{1}}{{ϵ}_{1}} \sqrt{2 {ϵ}_{2} {ρ}_{d}} )}^{2} - 4 ( V sin ω t - {V}_{p} + \frac{{d}_{1}}{{ϵ}_{1}} {ρ}_{i} )}} ] = {A}_{2} \frac{\sqrt{{ϵ}_{2} {ρ}_{d}}}{\sqrt{2} \sqrt{{V}_{p 0} - B sin ( ω t )}} [ ω B cos ( ω t ) ]$$

When a constant term within a square root in the above equation is treated as the same, it is given as follows as:

$${A}_{1} \frac{( V - B ) cos ω t}{\sqrt{2} \sqrt{- ( V - B ) sin ω t + ( V - B )}} \approx {A}_{2} \frac{V cos ω t}{\sqrt{2} \sqrt{- Bsin ω t + B}}$$

$$\frac{V}{B} = {( \frac{{A}_{2}}{{A}_{1}} )}^{2} + 1$$

When an area A2 of the ground electrode is increased, a potential difference between the target and the plasma may be increased. To this end, an auxiliary ground electrode with a large area of bellows structure may be disposed inside a chamber to increase the area A2 of the ground electrode.

The magnitudes of the currents are compared and given as follows:

$${A}_{1} [ \frac{( V ω cos ω t - B ω cos ω t )}{\sqrt{\frac{{( \frac{{d}_{1}}{{ϵ}_{1}} \sqrt{2 {ϵ}_{2} {ρ}_{d}} )}^{2}}{4} - ( V sin ω t - {V}_{p 0} - B sin ω t + \frac{{d}_{1}}{{ϵ}_{1}} {ρ}_{i} )}} ] = {A}_{2} \frac{1}{\sqrt{2} \sqrt{{V}_{p 0} - B sin ( ω t )}} [ ω B cos ( ω t ) ]$$

$$\frac{{A}_{1}}{\sqrt{V - B}} \frac{( V ω cos ω t - B ω cos ω t )}{\sqrt{\frac{{( \frac{{d}_{1}}{{ϵ}_{1}} \sqrt{2 {ϵ}_{2} {ρ}_{d}} )}^{2}}{4 ( V - B )} - sin ω t + \frac{( {V}_{p 0} - \frac{{d}_{1}}{{ϵ}_{1}} {ρ}_{i} )}{V - B}}} = {A}_{2} \frac{B ω cos ω t}{\sqrt{B} \sqrt{- s in ω t + \frac{{V}_{p 0}}{B}}}$$

When the constant term within the square root in the above equation is rearranged, the following equation is given.

$${V}_{p 0} = \frac{B}{V - 2 B} [ \frac{{( \frac{( {d}_{1}}{{ϵ}_{1}} \sqrt{2 {ϵ}_{2} {ρ}_{d}} )}^{2}}{4} - \frac{{d}_{1}}{{ϵ}_{1}} {ρ}_{i} ]$$

The total current IT is equal to the sum of the current I_{G} flowing through the electrode and the current I_{G2} flowing through the ground electrode, and is given by a quasi-sinusoidal waveform as follows:

$${I}_{T} = {A}_{1} [ 2 \frac{\sqrt{2 {ϵ}_{2} {ρ}_{d}} ( V ω cos ω t - B ω cos ω t )}{( \frac{{d}_{1}}{{ϵ}_{1}} \sqrt{2 {ϵ}_{2} {ρ}_{d}} ) - 4 ( V sin ω t - {V}_{p} + \frac{{d}_{1}}{{ϵ}_{1}} {ρ}_{i} )} ] + {A}_{2} \frac{\sqrt{{ϵ}_{0} {ρ}_{d}}}{\sqrt{2} \sqrt{{V}_{p 0} + B sin ( ω t )}} [ ω B cos ( ωt ) ]$$

### [Sinusoidal Ion Energy Distribution]

An ion energy distribution function F is given as follow. N is the number of ion particles, and W is energy of ions. The energy of the ions is given by W=Vp−Vs.

$$\begin{matrix}F & = \frac{d N}{d W} = \frac{dN / dt}{dW / dt} − W = {V}_{s} − {V}_{p}\end{matrix} = − {( \frac{{d}_{1}}{{ϵ}_{1}} )}^{2} {ϵ}_{2} {ρ}_{d} + ( {V}_{G} − {V}_{p} + \frac{{d}_{1}}{{ϵ}_{1}} {ρ}_{i} ) + \frac{{d}_{1}}{{ϵ}_{1} 2} \sqrt{2 {ϵ}_{2} {ρ}_{d}} \sqrt{{( \frac{{d}_{1}}{{ϵ}_{1}} \sqrt{2 {ϵ}_{2} {ρ}_{d}} )}^{2} − 4 ( {V}_{G} − {V}_{p} + \frac{{d}_{1}}{{ϵ}_{1}} {ρ}_{i} )} − \frac{d W}{d t} = \frac{d {V}_{G}}{d t} − \frac{d {V}_{p}}{d t} + \frac{{d}_{1}}{{ϵ}_{1}} {J}_{i} − \frac{{d}_{1}}{{ϵ}_{1}} \sqrt{2 {ϵ}_{2} {ρ}_{d}} \frac{\frac{d {V}_{G}}{d t} − \frac{d {V}_{p}}{d t}}{\sqrt{{( \frac{{d}_{1}}{{ϵ}_{1}} \sqrt{2 {ϵ}_{2} {ρ}_{d}} )}^{2} − 4 ( {V}_{G} − {V}_{p} + \frac{{d}_{1}}{{ϵ}_{1}} {ρ}_{i} )}}$$

$$\sqrt{W} = \frac{1}{2} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} ) ]}$$

$$2 \sqrt{W} + \frac{{d}_{1}}{{ϵ}_{1}} \sqrt{2 {ϵ}_{2} {ρ}_{d}} = \sqrt{{( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )}$$

$$\frac{d W}{d t} = \frac{− d {V}_{G}}{d t} + \frac{d {V}_{p}}{d t} − \frac{{d}_{1}}{{ϵ}_{1}} {J}_{i} + \frac{{d}_{1}}{{ϵ}_{1}} \sqrt{2 {ϵ}_{2} {ρ}_{d}} \frac{\frac{d {V}_{G}}{d t} − \frac{d {V}_{p}}{d t}}{2 \sqrt{W} + \frac{{d}_{1}}{{ϵ}_{1}} \sqrt{2 {ϵ}_{2} {ρ}_{d}}}$$

When the applied voltage of the electrode 18 is a sinusoidal wave and the plasma potential Vp is also a sinusoidal wave, a time derivative of the ion energy (dw/dt) is given as follow:

$${V}_{G} = Vsin ω t ; {V}_{p} = A + B sin ω t$$

$$\frac{d {V}_{G}}{d t} = V ω cos ω t ; \frac{d {V}_{p}}{d t} = B ω cos ω t$$

$$\frac{dW}{dt} = - ω ( V - B ) cos ω t - \frac{{d}_{1}}{{ϵ}_{1}} {J}_{i} + \frac{{d}_{1}}{{ϵ}_{1}} \sqrt{2 {ϵ}_{2} {ρ}_{d}} \frac{ω ( V - B ) cos ω t}{2 \sqrt{W} + \frac{{d}_{1}}{{ϵ}_{1}} \sqrt{2 {ϵ}_{2} {ρ}_{d}}}$$

$${[ 2 \sqrt{W} + \frac{{d}_{1}}{{ϵ}_{1}} \sqrt{2 {ϵ}_{2} {ρ}_{d}} ]}^{2} = {( \frac{{d}_{1}}{{ϵ}_{1}} \sqrt{2 {ϵ}_{2} {ρ}_{d}} )}^{2} - 4 ( {V}_{G} - {V}_{p} + \frac{{d}_{1}}{{ϵ}_{1}} {ρ}_{i} )$$

$$( V - B ) sin ω t - A + \frac{{d}_{1}}{{ε}_{1}} {ρ}_{i} = \frac{{( \frac{{d}_{1}}{{ϵ}_{1}} \sqrt{2 {ϵ}_{2} {ρ}_{d}} )}^{2}}{4} - \frac{{[ 2 \sqrt{W} + \frac{{d}_{1}}{{ϵ}_{1}} \sqrt{2 {ϵ}_{2} {ρ}_{c i}} ]}^{2}}{4}$$

$$( V - B ) sin ω t = A - \frac{{d}_{1}}{{ϵ}_{1}} {ρ}_{i} + \frac{{( \frac{{d}_{1}}{{ϵ}_{1}} \sqrt{2 {ϵ}_{2} {ρ}_{d}} )}^{2}}{4} - \frac{{[ 2 \sqrt{W} + \frac{( {d}_{1}}{{ϵ}_{1}} \sqrt{2 {ϵ}_{2} {ρ}_{d}} ]}^{2}}{4}$$

$$\begin{matrix}( V - B ) cos ω t = ( V - B ) \sqrt{1 - {sin}^{2} ω t} \\ = \sqrt{{( V - B )}^{2} - {[ ( V - B ) sin ω t ]}^{2}}\end{matrix}$$

$$( V - B ) cos ω t = ( V - B ) \sqrt{1 - {sin}^{2} ω t} = \sqrt{{( V - B )}^{2} - {[ A - \frac{{d}_{1}}{{ϵ}_{1}} {ρ}_{i} + \frac{{( \frac{{d}_{1}}{{ϵ}_{1}} \sqrt{2 {ϵ}_{2} {ρ}_{d}} )}^{2}}{4} - \frac{{[ 2 \sqrt{W} + \frac{{d}_{1}}{{ϵ}_{1}} \sqrt{2 {ϵ}_{2} {ρ}_{d}} ]}^{2}}{4} ]}^{2}}$$

$$\frac{d W}{d t} = - \sqrt{{ω ( V - B )}^{2} - {[ A - \frac{{d}_{1}}{{ϵ}_{1}} {ρ}_{i} + \frac{{( \frac{{d}_{1}}{{ϵ}_{1}} \sqrt{2 {ϵ}_{2} {ρ}_{d}} )}^{2}}{4} - \frac{{[ 2 \sqrt{W} + \frac{{d}_{1}}{{ε}_{1}} \sqrt{2 {ϵ}_{2} {ρ}_{d}} ]}^{2}}{4} ]}^{2}} - \frac{{d}_{1}}{{ϵ}_{1}} {J}_{i} + \frac{{d}_{1}}{{ϵ}_{1}} \sqrt{2 {ϵ}_{2} {ρ}_{d}} \frac{\sqrt{{( V - B )}^{2} - {[ A - \frac{{d}_{1}}{{ϵ}_{1}} {ρ}_{i} + \frac{{( \frac{{d}_{1}}{{ϵ}_{1}} \sqrt{2 {ϵ}_{2} {ρ}_{d}} )}^{2}}{4} - \frac{{[ 2 \sqrt{W} + \frac{{d}_{1}}{{ϵ}_{1}} \sqrt{2 {ϵ}_{2} {ρ}_{d}} ]}^{2}}{4} ]}^{2}}}{2 \sqrt{W} + \frac{{d}_{1}}{{ϵ}_{1}} \sqrt{2 {ϵ}_{2} {ρ}_{d}}}$$

$$F = \frac{d N}{d W} = \frac{dN / dt}{dW / dt}$$

$$\frac{d W}{d t} = - ω ( V - B ) \sqrt{1 - {\frac{1}{{( V - B )}^{2}} [ A - \frac{{d}_{1}}{{ϵ}_{1}} {ρ}_{i} + \frac{{( \frac{{d}_{1}}{{ε}_{1}} \sqrt{2 {ϵ}_{2} {ρ}_{d}} )}^{2}}{4} - \frac{{[ 2 \sqrt{W} + \frac{{d}_{1}}{{ε}_{1}} \sqrt{2 {ϵ}_{2} {ρ}_{d}} ]}^{2}}{4} ]}^{2}} - \frac{{d}_{1}}{{ϵ}_{1}} {J}_{i} + \frac{{d}_{1}}{{ε}_{1}} \sqrt{2 {ϵ}_{2} {ρ}_{d}} \frac{( V - B ) \sqrt{1 - {\frac{1}{{( V - B )}^{2}} [ A - \frac{{d}_{1}}{{ϵ}_{1}} {ρ}_{i} + \frac{{( \frac{{d}_{1}}{{ϵ}_{1}} \sqrt{2 {ϵ}_{2} {ρ}_{d}} )}^{2}}{4} - \frac{{[ 2 \sqrt{W} + \frac{{d}_{1}}{{ϵ}_{1}} \sqrt{2 {ϵ}_{2} {ρ}_{d}} ]}^{2}}{4} ]}^{2}}}{2 \sqrt{W} + \frac{{d}_{1}}{{ϵ}_{1}} \sqrt{2 {ϵ}_{2} {ρ}_{d}}}$$

An ion energy distribution f is calculated and represented as follows:

$$( V - B ) ≡ \frac{Δ {E}_{i}}{2}$$

$${E}_{i} = A - \frac{{d}_{1}}{{ϵ}_{1}} {ρ}_{i} + \frac{{( \frac{{d}_{1}}{{ϵ}_{1}} \sqrt{2 {ϵ}_{2} {ρ}_{d}} )}^{2}}{4}$$

$$Δ {E}_{i} = 2 ( V - B ) ∝ \frac{2 V}{ω {τ}_{i}}$$

$${τ}_{i} = 1 / {ω}_{i}$$

$${ω}_{i} = \sqrt{\frac{{q}^{2} {n}_{1}}{{ϵ}_{0} M}}$$

$$\frac{d W}{d t} = ω \frac{Δ {E}_{i}}{2} \sqrt{1 - {\frac{4}{Δ {E}_{i}^{2}} [ {E}_{i} - \frac{{[ 2 \sqrt{W} + \frac{{d}_{1}}{{ϵ}_{1}} \sqrt{2 {ϵ}_{2} {ρ}_{d}} ]}^{2}}{4} ]}^{2}} ( 1 - \frac{\frac{{d}_{1}}{{ε}_{1}} \sqrt{2 {ϵ}_{2} {ρ}_{d}}}{2 \sqrt{W} + \frac{{d}_{1}}{{ϵ}_{1}} \sqrt{2 {ϵ}_{2} {ρ}_{d}}} ) + \frac{{d}_{1}}{{ε}_{1}} {J}_{i}$$

$$F = \frac{{J}_{i}}{ω \frac{Δ {E}_{i}}{2} \sqrt{1 - {\frac{4}{Δ {E}_{i}^{2}} [ {E}_{i} - \frac{{[ 2 \sqrt{W} + \frac{{d}_{1}}{{ϵ}_{1}} \sqrt{2 {ϵ}_{2} {ρ}_{d}} ]}^{2}}{4} ]}^{2}} ( 1 - \frac{\frac{{d}_{1}}{{ε}_{1}} \sqrt{2 {ϵ}_{2} {ρ}_{d}}}{2 \sqrt{W} + \frac{{d}_{1}}{{ϵ}_{1}} \sqrt{2 {ϵ}_{2} {ρ}_{d}}} ) + \frac{{d}_{1}}{{ϵ}_{1}} {J}_{i}}$$

$$F = \frac{{J}_{i}}{[ \frac{{ϵ}_{1}}{{d}_{1} {J}_{i}} ω \frac{Δ {E}_{i}}{2} \sqrt{1 - {\frac{4}{Δ {E}_{i}^{2}} [ {E}_{i} - \frac{{[ 2 \sqrt{W} + \frac{{d}_{1}}{{ϵ}_{1}} \sqrt{2 {ϵ}_{2} {ρ}_{d}} ]}^{2}}{4} ]}^{2}} ( 1 - \frac{\frac{{d}_{1}}{{ϵ}_{1}} \sqrt{2 {ϵ}_{2} {ρ}_{d}}}{2 \sqrt{W} + \frac{{d}_{1}}{{ε}_{1}} \sqrt{2 {ϵ}_{2} {ρ}_{d}}} ) + 1 ] \frac{{d}_{1}}{{ϵ}_{1}} {J}_{i}}$$

Ion energy W is determined by the potential of the target and the plasma potential, and the ion energy distribution F has two peaks in the case of a sinusoidal wave. When the angular frequency ω of the sinusoid wave is close to or greater than the ion plasma angular frequency ωi, linewidth ΔEi of the ion energy distribution may decrease.

When the angular frequency ω of the applied voltage is smaller than the ion plasma angular frequency ωi (typically several MHz), the ion energy distribution function is given by the above equation.

However, when the angular frequency ω of the sinusoidal wave is close to or greater than the ion plasma angular frequency ωi, the linewidth ΔEi of the ion energy distribution is decreased to narrow a gap between the two peaks.

A plasma apparatus according to an example embodiment of the present disclosure has a structure in which an electrode, a dielectric layer, and a target are stacked. A method for controlling a target voltage of the plasma apparatus includes operations of applying a sinusoidal voltage to the electrode and measuring currents I_{G} and J_{G} flowing through the electrode over time and fitting the currents I_{G} and J_{G} to extract a charged amount ρi charged on the target and plasma charge density ρd.

The plasma contacting the target has a plasma potential Vp varying over time, and the plasma potential Vp may be measured or calculated by fitting the current flowing through the electrode.

In the method for controlling a target voltage, the potential Vs of the target may be calculated using the plasma potential Vp. The method may further include an operation of calculating the energy of ions incident on the target using the potential of the target. The method for controlling the target voltage may further include an operation of controlling the plasma potential Vp of the plasma contacting the target. The control of the plasma potential Vp may be performed by applying a voltage to an additional electrode.

The method for controlling the target voltage may further include an operation of controlling the plasma charge density by controlling a plasma power supply generating the plasma.

A plasma apparatus according to an example embodiment of the present disclosure has a structure in which an electrode, a dielectric layer, and a target are stacked. A method for controlling a target voltage of the plasma apparatus includes operations of applying a sinusoidal voltage to the electrode and measuring the current flowing through the electrode over time, calculating plasma charge density, and fitting current to extract an amount of charges charged on the target.

A ratio of the applied voltage to the plasma potential is determined using a ratio of an area of an electrode A1 to an area of a ground electrode A2. For example, when A1/A2=1, V/B=2. A plasma potential Vp is given by Vpo+B sin ωt, and Vpo is set to B (Vpo=B). When the currents I_{G} and J_{G} of the electrode are fitted, the plasma charge density ρ_{d} and the charge ρi on the target are determined. Accordingly, the potential Vs of the target is determined. Vp−Vs is ion energy. An ion energy distribution is determined by the equation calculated above.

The plasma charge density may be measured by applying a DC pulse wave, fitting a current waveform, or using an additional charge density measurement device. The plasma potential may be additionally measured using a Langmuir probe or a plasma potential measurement device.

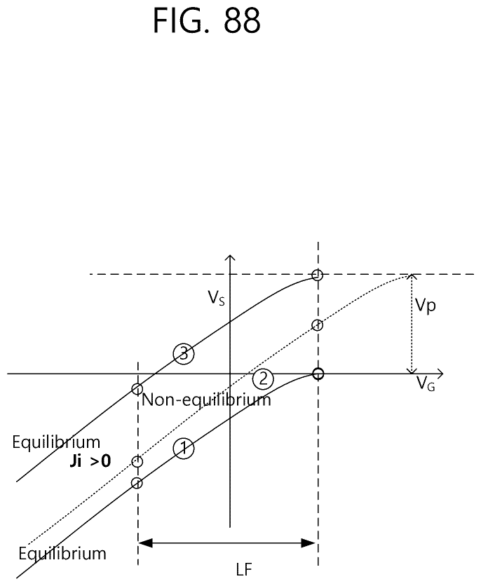

FIG. 88 is a diagram illustrating a potential of a target when sinusoidal plasma potential is synchronized with a sinusoidal drive voltage.

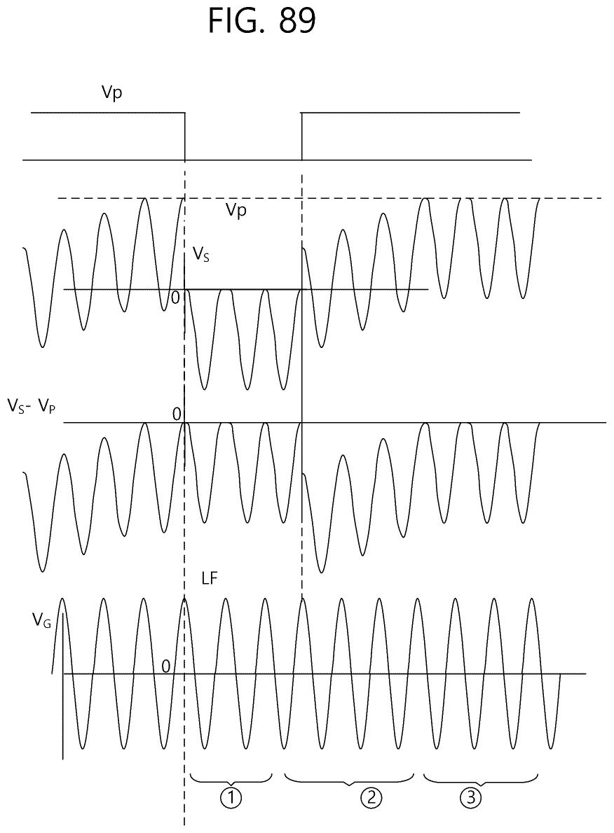

FIG. 89 is a diagram illustrating a potential of a target over time when a sinusoidal plasma potential is synchronized with a sinusoidal drive voltage.

Referring to FIGS. 88 and 89, a plasma potential Vp has a value of zero for a predetermined period and a positive value for the remaining periods. Accordingly, the plasma potential Vp alternates with a predetermined period. A period of the sinusoidal applied voltage is much shorter than a period of the plasma potential Vp.

When the plasma potential Vp has a value of zero, the potential Vs of the target follows curve 1 in an equilibrium state. When the plasma potential Vp has a positive value, the potential Vs of the target follows curve 3 in the equilibrium state. When the plasma potential Vp has a value of zero and the applied voltage is a sinusoidal wave, the potential Vs of the target follows curve 1. When the plasma potential Vp has a value of zero, the charge on the target is Qᵢ₀=−c₁V₀^{+.} When the plasma potential Vp transitions rapidly from zero to a positive value, the target follows the non-equilibrium curve 2 while maintaining a charged amount of the target.

In the non-equilibrium state of curve 2, the target does not reach the equilibrium state as the sinusoidal applied voltage oscillates. However, as the ion current density Ji is continuously injected and the potential Vs of the target reaches the plasma potential Vp, electrons are rapidly introduced, and thus the target reaches the equilibrium state along curve 3.

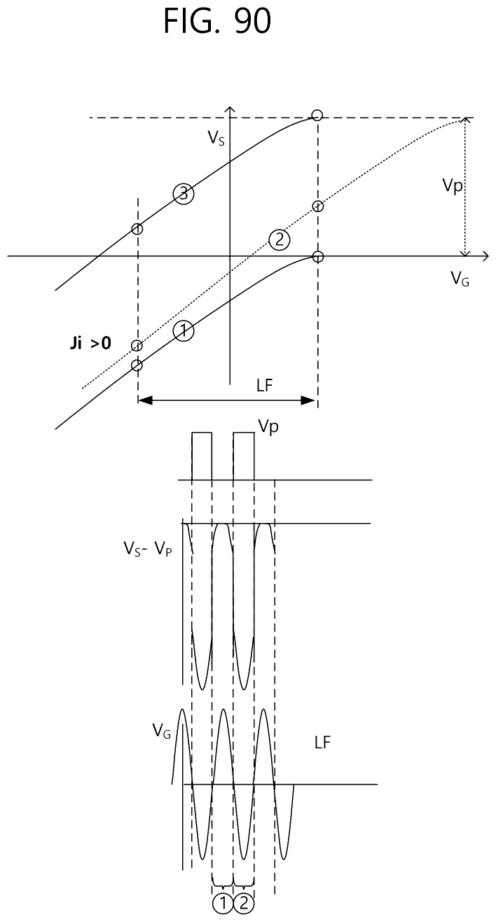

FIG. 90 is a diagram illustrating a potential of a target when a sinusoidal plasma potential is synchronized with a sinusoidal drive voltage.

Referring to FIG. 90, a plasma potential Vp has a value of zero for a predetermined period and a positive value for the remaining period. Accordingly, a plasma potential Vp alternates with a predetermined period. A period of the sinusoidal applied voltage is synchronized with a period of the plasma potential Vp.

When the plasma potential Vp has a value of zero, the potential of the target follows curve 1 in the equilibrium state. When the plasma potential Vp has a positive value, a potential Vs of the target follows curve 3 in an equilibrium state. When the plasma potential Vp has a value of zero, the applied sinusoidal voltage is synchronized and has a positive value, and the potential Vs of the target follows curve 1 in the equilibrium state. When the plasma potential Vp has a positive value, the applied sinusoidal voltage is synchronized and has a negative value, and the potential Vs of the target follows curve 3 in the equilibrium state.

When the plasma potential Vp has a value of zero, the charged amount of the target is Qᵢ₀=−c₁V₀^{+.} When the plasma potential Vp transitions rapidly from zero to a positive value, the target follows the non-equilibrium curve 2 while maintaining a charged amount thereof.

When the plasma potential Vp has a value of zero in the next period and the applied voltage has a positive value, the charged amount of the target is charged to Qᵢ₀=−c₁V₀⁺and returns to curve 1.

### [Method for Changing Plasma Potential]

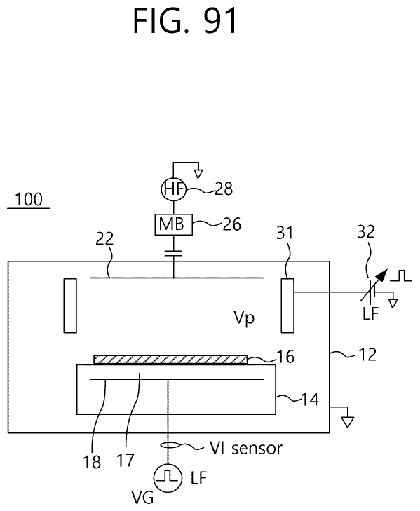

FIGS. 91 to 94 are conceptual diagrams, each illustrating a plasma apparatus modifying a plasma potential.

Referring to FIG. 91, a plasma processing apparatus includes a plasma chamber 12, a high-frequency power supply (HF) 28 connected to a first electrode 22 disposed inside the plasma chamber 12 to generate plasma, a target holder 14 disposed inside the plasma chamber 12 and including a second electrode 18/a dielectric layer 17/a target 16, a third electrode 31 exposed inside the plasma chamber 12, and an auxiliary low-frequency power supply 32 for periodically controlling the plasma potential of the third electrode to a high state and a low state.

A first electrode 22 is disposed in an upper portion of the first electrode 22, and the high-frequency power supply 28 is connected to the first electrode to generate plasma. The target holder 14 is disposed at the bottom of the chamber, and a second electrode 18 is disposed inside the target holder. A low-frequency waveform may be applied to the second electrode by the low-frequency power supply.

A ring-shaped third electrode is disposed inside the chamber to independently control a plasma potential. When a pulse auxiliary voltage is applied to a third electrode using an auxiliary low-frequency power supply, the plasma potential may be controlled over time. An auxiliary voltage may be a pulse waveform with both a positive value and a negative value. The auxiliary voltage may be synchronized with the low-frequency pulse waveform generated by the low-frequency power supply. The third electrode 31 is used to control the plasma potential (slope voltage).

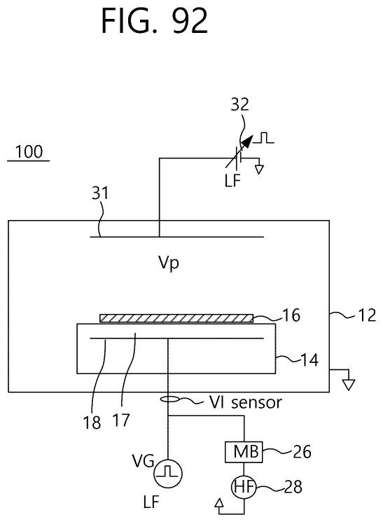

Referring to FIG. 92, a plasma processing apparatus includes a plasma chamber 12, an auxiliary low-frequency power supply 32 connected to a first electrode 31 disposed inside the plasma chamber 12 to control a plasma potential Vp that periodically has a high state and a low state, a target holder 14 disposed inside the plasma chamber 12 and including a second electrode 18/a dielectric layer 17/a target 16, a low-frequency power supply LF connected to the second electrode 18, and a high-frequency power supply HF connected to the second electrode 18 to generate plasma.

The first electrode is disposed in an upper portion of the chamber, and a pulsed auxiliary low-frequency voltage may be applied to the first electrode. A target holder is disposed in a lower portion of the chamber, and a second electrode is disposed inside the target holder. A low-frequency waveform and a high-frequency waveform may be applied simultaneously to the second electrode. The low-frequency waveform is generated by the low-frequency power supply LF, and the high-frequency waveform is generated by the high-frequency power supply HF. The high-frequency power supply HF is used to generate the plasma, and the low-frequency power supply LF may be used to control a potential of the target. The low-frequency power supply LF may be synchronized with the auxiliary low-frequency power supply 32.

The first electrode 31 is used to control the plasma potential Vp (slope voltage).

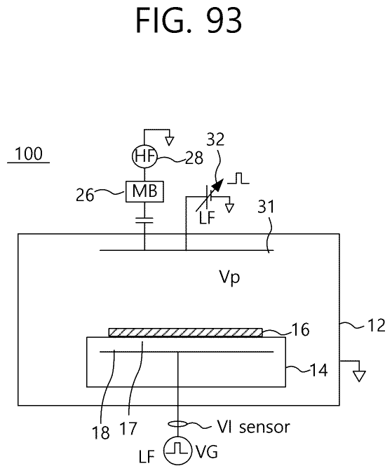

Referring to FIG. 93, a plasma processing apparatus includes a plasma chamber 12, a high-frequency power supply HF connected to a first electrode 31 disposed inside the chamber to generate plasma, an auxiliary low-frequency power supply 32 connected to the first electrode to control the plasma potential Vp that periodically has a high state and a low state, a target holder 14 disposed inside the chamber and including a second electrode 18/a dielectric layer 17/a target 16, and a low-frequency power supply LF connected to the second electrode 18 to control a voltage of the target.

A first electrode is disposed in an upper portion of the chamber, and a high-frequency power supply HF and a pulsed auxiliary low-frequency power supply 32 are connected to the first electrode. A target holder is disposed in a lower portion of the chamber, and a second electrode is disposed inside the target holder. A low-frequency pulse waveform may be applied to the second electrode by the low-frequency power supply LF. The high-frequency power supply HF is used to generate the plasma. The auxiliary voltage is generated by the auxiliary low-frequency power supply 32. The auxiliary voltage is synchronized with the pulse waveform of the low-frequency power supply LF and is used to control the plasma potential Vp with a pulse waveform having a positive value and a negative value.

The first electrode 31 is used to control the plasma potential Vp (slope voltage).

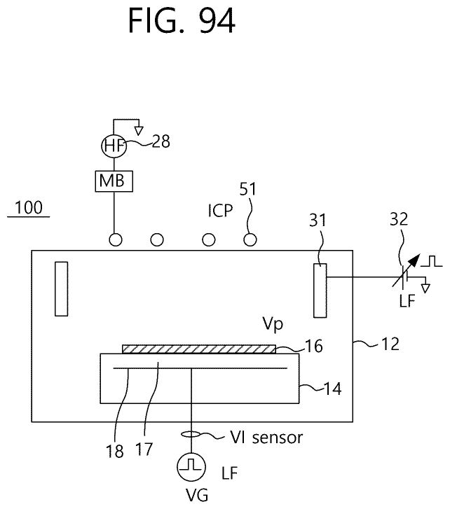

Referring to FIG. 94, a plasma processing apparatus includes a plasma chamber 12, a high-frequency power supply HF connected to an antenna 51 disposed outside the chamber to generate inductively-coupled plasma, an auxiliary low-frequency power supply 32 connected to an auxiliary electrode 31 disposed inside the chamber to control the plasma potential Vp that periodically has a high state and a low state, a target holder 14 disposed inside the chamber and including an electrode 18/a dielectric layer 17/a target 16, and a low-frequency power supply LF connected to the electrode 18 to control a voltage of the target.

An antenna 51 for inductively-coupled plasma is disposed in an upper portion of the chamber, and a high-frequency power supply is connected to the antenna. A target holder is disposed in a lower portion of the chamber, and an electrode 18 is disposed inside the target holder. A low-frequency voltage waveform may be applied to an electrode. The high-frequency power supply HF is used to generate the plasma. The auxiliary voltage applied to the auxiliary electrode 31 is generated by the low-frequency power supply. The auxiliary voltage may be a pulse waveform with both a positive value and a negative value. The auxiliary voltage may be synchronized with the low-frequency voltage waveform of the low-frequency power supply applied to the electrode.

The auxiliary electrode 31 is used to control the plasma potential Vp (slope voltage).

### [Treatment of Electrostatic Electrode]

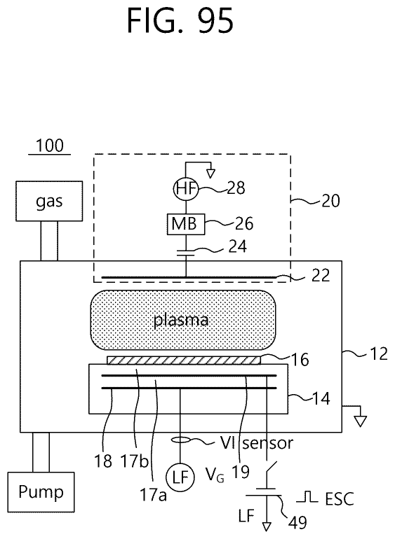

FIG. 95 is a conceptual diagram illustrating a plasma system including an electrostatic electrode and an electrode.

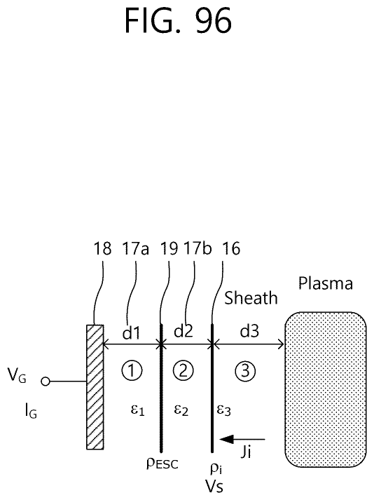

FIG. 96 is a conceptual diagram illustrating an electrode, a first dielectric, an electrostatic electrode, a second dielectric, and a plasma sheath.

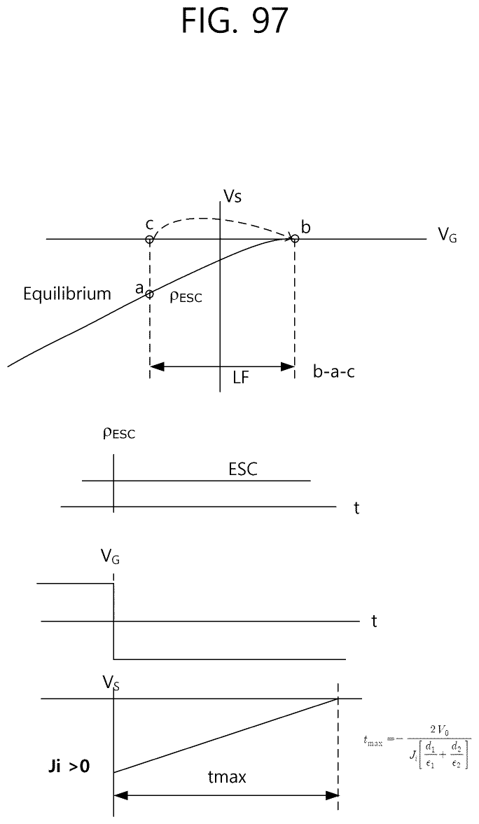

FIG. 97 is a graph illustrating a potential of a target based on an applied voltage of an electrode.

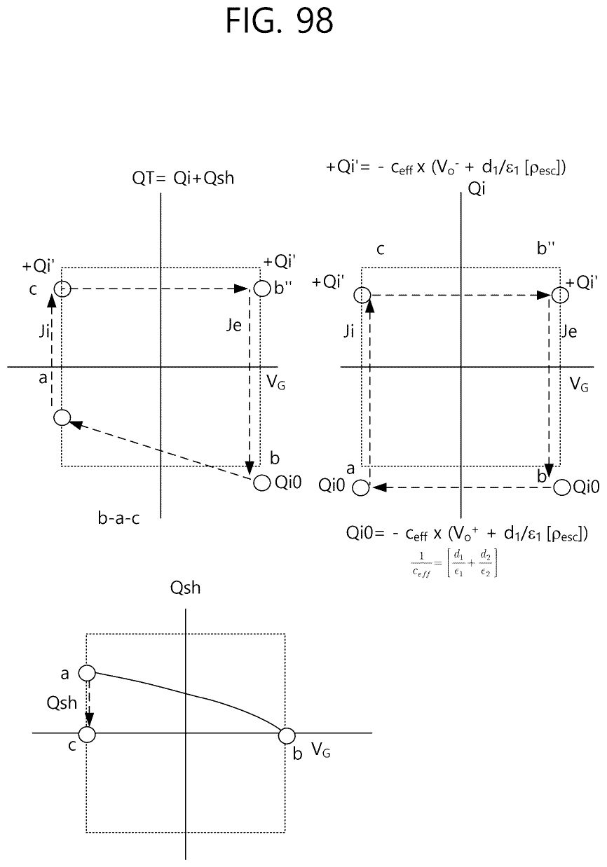

FIG. 98 is a diagram illustrating a charged amount of a target based on an applied voltage of an electrode.

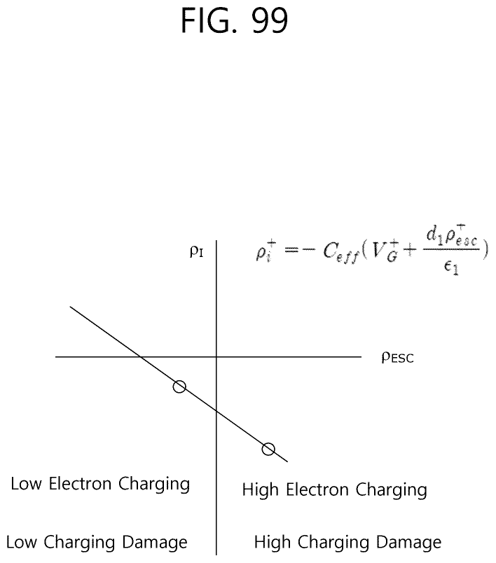

FIG. 99 is a diagram illustrating a charged amount of a target based on a charged amount of an electrostatic electrode.

Referring to FIGS. 95 to 99, a plasma processing apparatus includes a plasma chamber 12, a plasma source 20 for forming plasma in the plasma chamber 12, a target holder 14 disposed inside the chamber and including an electrode 18/a first dielectric layer 17a/an electrostatic electrode 19/a second dielectric layer 17b/a target 16, a low-frequency power supply LF connected to the electrode 18, and an electrostatic electrode power supply 49 connected to the electrostatic electrode 19. The voltage waveform of the electrostatic electrode 19 is synchronized with the voltage waveform of the low-frequency power supply LF to control the potential of the target 18.

A driving voltage V_{G} is applied to the electrode 18, and the target 16 is a semiconductor or a conductor, and the target 16 has a surface on which electrons or positive ions are accumulated. A plasma sheath is formed between the plasma and the target 16. The plasma sheath may be treated as a space with a positive space charge. A thickness d3 of the plasma sheath changes depending on a voltage V_{G}. The first dielectric 17a is a first region, the second dielectric 17b is a second region, and the plasma sheath is a third region. The electrostatic electrode 19 is disposed between first and second dielectrics.

A thickness of the first dielectric 17a is d1. A thickness of the second dielectric 17b is d2. A thickness of the target 16 is negligible. A thickness of the electrostatic electrode 19 is negligible. A thickness of the plasma sheath is d3. A voltage of the target 16 is Vs. Surface charge density of the target 16 is ρᵢ. Surface charge density of the electrostatic electrode is ρ_{esc}. A dielectric constant of the first region is ε1, a dielectric constant of the second region is ε2, and a dielectric constant of the plasma sheath 3 may be a dielectric constant of vacuum.

A general solutions of the voltage V1 in the first region, a general solution of the voltage V2 in the second region, and a general solution in the third region are given as follows. Also, an electric field ε1 in the first region, an electric field ε2 in the second region, and an electric field ε3 in the third region are given as follows. An origin of the coordinate system is an electrode. x is coordinates of a rectangular coordinate system.

### [Matrix Model]

$${V}_{1} = {A}_{1} x + {A}_{2} \to \vec{{E}_{1}} = - {A}_{1} \qquad [ Equation 62 ]$$

$${V}_{2} = {B}_{1} x + {B}_{2} \to \vec{{E}_{2}} = - {B}_{1}$$

$${V}_{3} = \frac{{ρ}_{d}}{2 {ϵ}_{3}} {x}^{2} + {C}_{1} x + {C}_{2} \to \vec{{E}_{3}} = \frac{{ρ}_{d} x}{{ϵ}_{3}} - {C}_{1}$$

where volume charge density in the plasma sheath is ρ_{d}. A1, A2, B1, B2, C1, and C2 are unknowns.

When boundary conditions and initial conditions are used, A1, A2, B1, B2, C1, and C2 are given as follows. It was assumed that the electric field ε3 has a value of zero at a boundary between the plasma and the plasma sheath, as the initial condition.

$${A}_{1} = \frac{{ρ}_{e s c} + {ρ}_{i} + {ρ}_{d} {d}_{3}}{{ϵ}_{1}} \qquad [ Equation 63 ]$$

$${A}_{2} = {V}_{G}$$

$${B}_{1} = \frac{{ρ}_{d} {d}_{3} + {ρ}_{i}}{{ϵ}_{2}}$$

$${B}_{2} = \frac{{d}_{1}}{{ϵ}_{1}} [ {ρ}_{e s c} + {ρ}_{i} + {ρ}_{d} {d}_{3} ] - \frac{{d}_{1}}{{ϵ}_{2}} [ {ρ}_{i} + {ρ}_{d} {d}_{3} ] + {V}_{G}$$

$${C}_{1} = \frac{{ρ}_{d}}{{ϵ}_{3}} ( {d}_{1} + {d}_{2} + {d}_{3} )$$

$${C}_{2} = \frac{[ {ρ}_{i} + {ρ}_{e s c} + {ρ}_{d} {d}_{3} ] {d}_{1}}{{ϵ}_{1}} + {V}_{G} + \frac{{d}_{2}}{{ϵ}_{2}} [ {ρ}_{i} + {ρ}_{d} {d}_{3} ] - \frac{{ρ}_{d}}{2 {ϵ}_{3}} ( {d}_{1} + {d}_{2} ) ( {d}_{1} + {d}_{2} + 2 {d}_{3} )$$

An electric field in each region is given as follows:

$$\vec{{E}_{1}} = - \frac{{ρ}_{e s c} + {ρ}_{i} + {ρ}_{d} {d}_{3}}{{ϵ}_{1}} \qquad [ Equation 64 ]$$

$$\vec{{E}_{2}} = - \frac{{ρ}_{d} {d}_{3} + {ρ}_{i}}{{ε}_{2}}$$

$$\vec{{E}_{3}} = \frac{{ρ}_{d} x}{{ϵ}_{3}} - \frac{{ρ}_{d}}{{ϵ}_{3}} ( {d}_{1} + {d}_{2} + {d}_{3} )$$

A surface potential Vs of the target 16 is given as follows:

$${V}_{s} = {V}_{G} + \frac{{d}_{1}}{{ϵ}_{1}} [ {ρ}_{e s c} ] + [ \frac{{d}_{1}}{{ϵ}_{1}} + \frac{{d}_{2}}{{ϵ}_{2}} ] {ρ}_{i} + [ \frac{{d}_{1}}{{ϵ}_{1}} + \frac{{d}_{2}}{{ϵ}_{2}} ] {ρ}_{d} {d}_{3} \qquad [ Equation 65 ]$$

When the thickness of the plasma sheath has a value of zero, it may be represented as a simple capacitor as follows:

$$\frac{{ρ}_{e s c} {d}_{1}}{{ϵ}_{1}} + [ \frac{{d}_{1}}{{ϵ}_{1}} + \frac{{d}_{2}}{{ϵ}_{2}} ] {ρ}_{i} = - {V}_{G}^{+} at {d}_{3} = 0 \qquad [ Equation 66 ]$$

A thickness d3 of the plasma sheath and a surface potential Vs of the target 16 are given as follows:

$$- {V}_{s} = \frac{{ρ}_{d}}{2 {ϵ}_{3}} {d}_{3}^{2} \to {d}_{3} = \sqrt{\frac{- 2 {ϵ}_{3} {V}_{s}}{{ρ}_{d}}} \qquad [ Equation 67 ]$$

$${V}_{s} = {V}_{G} + \frac{{d}_{1}}{{ϵ}_{1}} [ {ρ}_{e s c} ] + [ \frac{{d}_{1}}{{ϵ}_{1}} + \frac{{d}_{2}}{{ϵ}_{2}} ] {ρ}_{i} + [ \frac{{d}_{1}}{{ϵ}_{1}} + \frac{{d}_{2}}{{ϵ}_{2}} ] {ρ}_{d} {d}_{3}$$

$${V}_{s} = {V}_{G} + \frac{{d}_{1}}{{ϵ}_{1}} [ {ρ}_{e s c} ] + [ \frac{{d}_{1}}{{ϵ}_{1}} + \frac{{d}_{2}}{{ϵ}_{2}} ] {ρ}_{i} + [ \frac{{d}_{1}}{{ϵ}_{1}} + \frac{{d}_{2}}{{ϵ}_{2}} ] \sqrt{- 2 {ϵ}_{3} {V}_{s} {ρ}_{d}}$$

$$- {V}_{s} = {\frac{1}{4} [ - [ \frac{{d}_{1}}{{ϵ}_{1}} + \frac{{d}_{2}}{{ϵ}_{2}} ] \sqrt{2 {ϵ}_{3} {ρ}_{d}} + \sqrt{{( [ \frac{{d}_{1}}{{ϵ}_{1}} + \frac{{d}_{2}}{e {}_{2}} ] \sqrt{2 {ϵ}_{3} {ρ}_{d}} )}^{2} - 4 ( {V}_{G} + [ \frac{{d}_{1}}{{ϵ}_{1}} + \frac{{d}_{2}}{{ϵ}_{2}} ] {ρ}_{i} + \frac{{d}_{1} {ρ}_{e s c}}{{ϵ}_{1}} )} ]}^{2}$$

$${V}_{s} = - {( [ \frac{{d}_{1}}{{ϵ}_{1}} + \frac{{d}_{2}}{{ϵ}_{2}} ] )}^{2} {ϵ}_{3} {ρ}_{d} + ( {V}_{G} + [ \frac{{d}_{1}}{{ϵ}_{1}} + \frac{{d}_{2}}{{ϵ}_{2}} ] {ρ}_{i} + \frac{{d}_{1} {ρ}_{e s c}}{{ϵ}_{1}} ) + [ \frac{{d}_{1}}{{ϵ}_{1}} + \frac{{d}_{2}}{{ϵ}_{2}} ] \frac{1}{2} \sqrt{2 {ϵ}_{3} {ρ}_{d}} \sqrt{{( [ \frac{{d}_{1}}{{ϵ}_{1}} + \frac{{d}_{2}}{{ϵ}_{2}} ] \sqrt{2 {ϵ}_{3} {ρ}_{d}} )}^{2} - 4 ( {V}_{G} + [ \frac{{d}_{1}}{{ϵ}_{1}} + \frac{{d}_{2}}{{ϵ}_{2}} ] {ρ}_{i} + \frac{{d}_{1} {ρ}_{e s c}}{{ϵ}_{1}} )}$$

$$\frac{1}{{c}_{eff}} ≡ [ \frac{{d}_{1}}{{ϵ}_{1}} + \frac{{d}_{2}}{{ϵ}_{2}} ]$$

When a bipolar pulse with a sufficiently large negative voltage is applied to the electrode 18, maximum time tmax at which current I_{G} flowing through the electrode 18 becomes zero is given as follows:

$$( {V}_{G} + \frac{{d}_{1}}{{ϵ}_{1}} {ρ}_{e s c} + [ \frac{{d}_{1}}{{ϵ}_{1}} + \frac{{d}_{2}}{{ϵ}_{2}} ] {ρ}_{i} ) = {V}_{0} + X {t}_{max} + \frac{{d}_{1}}{{ϵ}_{1}} {ρ}_{e s c} + [ \frac{{d}_{1}}{{ϵ}_{1}} + \frac{{d}_{2}}{{ϵ}_{2}} ] ( {ρ}_{i o} + {J}_{i} {τ}_{max} ) = 0 \qquad [ Equation 68 ]$$

$${t}_{max} = - \frac{{V}_{0} + [ \frac{{d}_{1}}{{ϵ}_{1}} + \frac{{d}_{2}}{{ϵ}_{2}} ] {ρ}_{i 0} + \frac{{d}_{1}}{{ϵ}_{1}} {ρ}_{e s c}}{X + [ \frac{{d}_{1}}{{ϵ}_{1}} + \frac{{d}_{2}}{{ϵ}_{2}} ] {J}_{i}}$$

$${ρ}_{i 0} = - {c}_{e f f} ( {V}_{G}^{+} + \frac{{d}_{1}}{{ϵ}_{1}} {ρ}_{e s c} )$$

$${t}_{max} = - \frac{2 {V}_{0}}{{J}_{i} [ \frac{{d}_{1}}{{ϵ}_{1}} + \frac{{d}_{2}}{{ϵ}_{2}} ]} if X = 0 , {V}_{0} < 0$$

When a positive voltage is applied to the electrode 18 and the electrostatic electrode is charged with a positive charge ρ_{esc}, the surface charge density ρᵢ or charged amount of the target 16 is proportional to effective capacitance Ceff, proportional to the charged amount ρ_{esc} of the electrostatic electrode 19, proportional to the thickness d1 of the first region, and inversely proportional to the first dielectric constant ε1 of the first region. Therefore, to increase the surface charge density ρi of the target, the charge pes of the electrostatic electrode 19 should be positive, d1 should be increased, and the first dielectric constant ε1 should be decreased. For example, a material having a low dielectric constant, such as quartz, is used for the first dielectric constant, a material having a high dielectric constant, such as aluminum oxide, is used for the second dielectric constant, and d1 is set to be close to the total thickness of the dielectric (d1+d2). In the case of having such a structure, the surface charge density ρi of the target may be increased by the charged amount ρ_{esc} of the electrostatic electrode. The surface charge density ρi of the target increases electrostatic force.

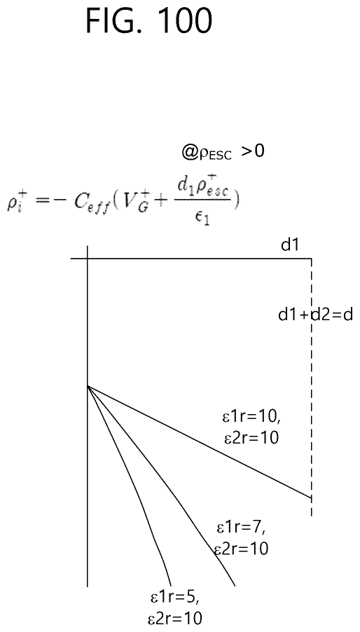

FIG. 100 is a diagram illustrating surface charge density ρi of a target based on a thickness d1 of a first region when an electrostatic electrode has a positive charged amount ρ_{esc}.

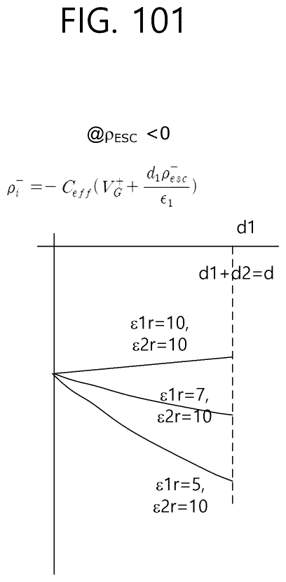

FIG. 101 is a diagram illustrating surface charge density ρi of a target based on a thickness d1 of a first region when an electrostatic electrode has a negative charged amount ρ_{esc}.

Referring to FIGS. 100 and 101, when a positive applied voltage is applied to the electrode 18 and the positive charge ρ_{esc} of the electrostatic electrode 19 is decreased, the surface charge density ρi or the charged amount of the target 16 is decreased. In this case, damage caused by electrons charged on the target may be suppressed, but the electrostatic force may be decreased.

When damage caused by electrons charged on the target 16 is desired to be suppressed, the surface charge density ρi or the charged amount of the target 16 may be decreased. To this end, a material having a high dielectric constant, such as aluminum oxide, is used for the first dielectric constant ε1 of the first dielectric 17a, a material having a high dielectric constant, such as aluminum oxide, is used for the second dielectric constant ε2 of the second dielectric 17b, and d1 is set to be smaller than the total thickness (d1+d2) of the dielectric.

When a positive applied voltage is applied to the electrode 18 and the electrostatic electrode 19 is charged with a negative charged amount ρ_{esc}, the characteristics vary depending on a relative magnitude of the positive applied voltage and the voltage of the electrostatic electrode 19. When the positive applied voltage is larger than a voltage of the electrostatic electrode 19, the surface charge density ρi or the charged amount of the target 16 is proportional to the charge pes, of the electrostatic electrode 19, proportional to the thickness d1 of the first region, and inversely proportional to the first dielectric constant ε1 of the first region.

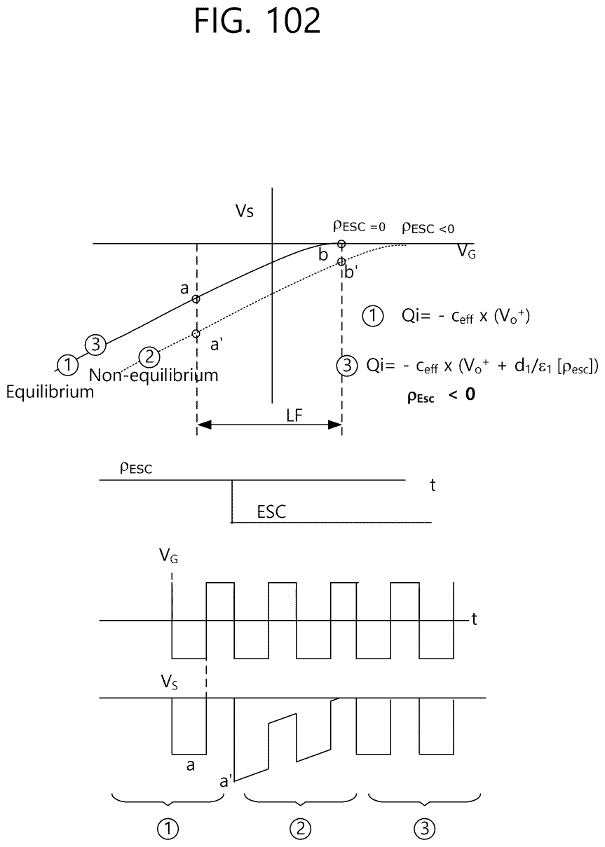

FIG. 102 is a diagram illustrating a potential of a target when a charged amount of an electrostatic electrode changes over time.

Referring to FIG. 102, a potential Vs of a target 16 is given as follows:

$$- {V}_{s} = {\frac{1}{4} [ - [ \frac{{d}_{1}}{{ϵ}_{1}} + \frac{{d}_{2}}{{ϵ}_{2}} ] \sqrt{2 {ϵ}_{3} {ρ}_{d}} + \sqrt{{( [ \frac{{d}_{1}}{{ϵ}_{1}} + \frac{{d}_{2}}{e {}_{2}} ] \sqrt{2 {ϵ}_{3} {ρ}_{d}} )}^{2} - 4 ( {V}_{G} + [ \frac{{d}_{1}}{{ϵ}_{1}} + \frac{{d}_{2}}{{ϵ}_{2}} ] {ρ}_{i} + \frac{{d}_{1} {ρ}_{e s c}}{{ϵ}_{1}} )} ]}^{2}$$

When an electrostatic voltage (electrostatic charge) has a predetermined value, the charged amount ρi on the target 16 for making the potential Vs of the target 16 zero at a positive applied voltage is given as follows:

$$\frac{1}{{c}_{e f f}} ≡ [ \frac{{d}_{1}}{{ϵ}_{1}} + \frac{{d}_{2}}{{ϵ}_{2}} ] \qquad [ Equation 69 ]$$

$${V}_{G}^{+} + \frac{{ρ}_{i}}{{c}_{e f f}} + \frac{{d}_{1} {ρ}_{e s c}}{{ϵ}_{1}} = 0$$

$${ρ}_{i} = - {c}_{e f f} ( {V}_{G}^{+} + \frac{{d}_{1} {ρ}_{e s c}}{{ϵ}_{1}} )$$

Accordingly, the potential Vs of the target 16 in an equilibrium state is given as follows:

$${V}_{s} = - {\frac{1}{4} [ - \frac{1}{{c}_{e f f}} \sqrt{2 {ϵ}_{3} {ρ}_{d}} + \sqrt{{( \frac{1}{{c}_{e f f}} \sqrt{2 {ϵ}_{3} {ρ}_{d}} )}^{2} - 4 ( {V}_{G} + \frac{1}{{c}_{e f f}} {ρ}_{i} + \frac{{d}_{1} {ρ}_{e s c}}{{ϵ}_{1}} )} ]}^{2} \qquad [ Equation 70 ]$$

$${V}_{s} = - {\frac{1}{4} [ - \frac{1}{{c}_{e f f}} \sqrt{2 {ϵ}_{3} {ρ}_{d}} + \sqrt{{( \frac{1}{{c}_{e f f}} \sqrt{2 {ϵ}_{3} {ρ}_{d}} )}^{2} - 4 ( {V}_{G} - {V}_{G}^{+} )} ]}^{2}$$

The electrostatic voltage (electrostatic charge) may have a value of zero in a predetermined region, and the electrostatic voltage (electrostatic charge) may have a negative value in the remaining region. The applied voltage is a bipolar pulse.

When the electrostatic voltage electrostatic charge has a value of zero, the potential Vs of the target 16 moves along curve 1 in the equilibrium state. Also, when the electrostatic voltage (electrostatic charge) has a negative value, the potential Vs of the target 16 moves along curve 3 in the equilibrium state.

Initially, when the electrostatic voltage electrostatic charge has a value of zero and rapidly transitions to a predetermined negative value at a specific time, a charged amount pH of the target 16 is given as follows:

$${V}_{G}^{+} + \frac{{ρ}_{i 1}}{{c}_{e f f}} = 0 \qquad [ Equation 71 ]$$

$${ρ}_{i 1} = - {c}_{e f f} ( {V}_{G}^{+} )$$

In this case, the potential Vs of the target 16 follows curve 2 and is given as follows:

$${V}_{s} = - {\frac{1}{4} [ - \frac{1}{{c}_{e f f}} \sqrt{2 {ϵ}_{3} {ρ}_{d}} + \sqrt{{( \frac{1}{{c}_{e f f}} \sqrt{2 {ϵ}_{3} {ρ}_{d}} )}^{2} - 4 ( {V}_{G} - {V}_{G}^{+} + \frac{{d}_{1} {ρ}_{esc}}{{ϵ}_{1}} )} ]}^{2}$$

Since the charged amount of the target 16 does not have an equilibrium value, the potential Vs of the target 16 moves along curve 2.

Ultimately, when the charge of the target 16 changes due to the injection of ion current density Ji after several periods of the applied voltage, the potential Vs of the target 16 moves along curve 3 in the equilibrium state.

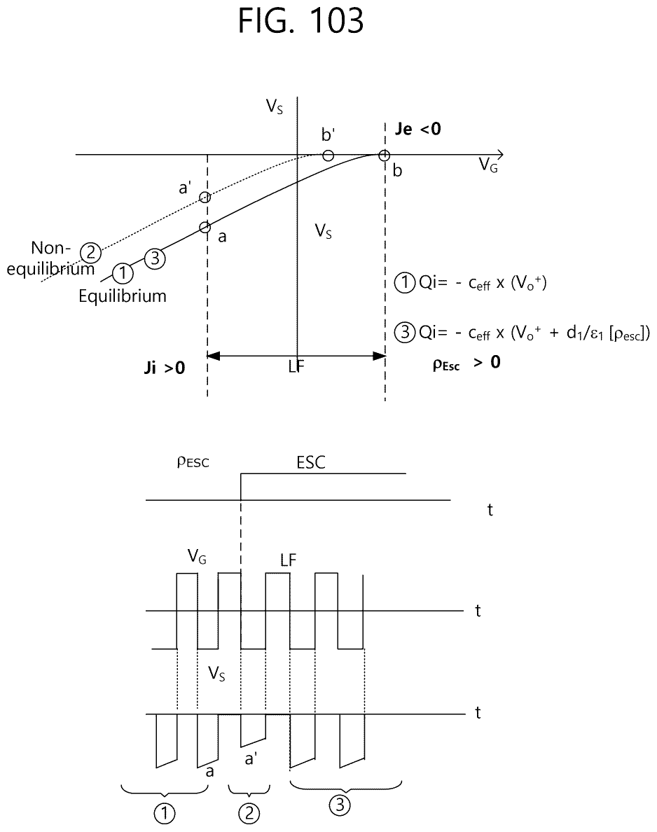

FIG. 103 is a graph illustrating a potential of a target based on an applied voltage of an electrode.

Referring to FIG. 103, an electrostatic voltage (electrostatic charge) may have a value of zero in a predetermined region, and the electrostatic voltage (electrostatic charge) may have a positive value in the remaining region. The applied voltage is a bipolar pulse.

When the electrostatic voltage electrostatic charge has a value of zero, the potential Vs of the target moves along curve 1 in an equilibrium state. Also, when the electrostatic voltage electrostatic charge has a negative value, the potential Vs of the target moves along curve 3 in the equilibrium state.

Initially, when the electrostatic voltage (electrostatic charge) has a value of zero and suddenly transitions to a predetermined positive value at a specific time, a charged amount of the target 16 is given as follows:

$${V}_{G}^{+} + \frac{{ρ}_{i 1}}{{c}_{e f f}} = 0 \qquad [ Equation 72 ]$$

$${ρ}_{i 1} = - {c}_{e f f} ( {V}_{G}^{+} )$$

In this case, the potential Vs of the target 16 follows curve 2 and is given as follows:

$${V}_{s} = - {\frac{1}{4} [ - \frac{1}{{c}_{e f f}} \sqrt{2 {ϵ}_{3} {ρ}_{d}} + \sqrt{{( \frac{1}{{c}_{e f f}} \sqrt{2 {ϵ}_{3} {ρ}_{d}} )}^{2} - 4 ( {V}_{G} - {V}_{G}^{+} + \frac{{d}_{1} {ρ}_{esc}}{{ϵ}_{1}} )} ]}^{2}$$

Since the charged amount of the target 16 does not have an equilibrium value, the potential Vs of the target 16 moves along curve 2. Ultimately, after a single period of the applied voltage, the potential Vs of the target 16 moves along curve 3 in the equilibrium state due to the injection of electron current Ie.

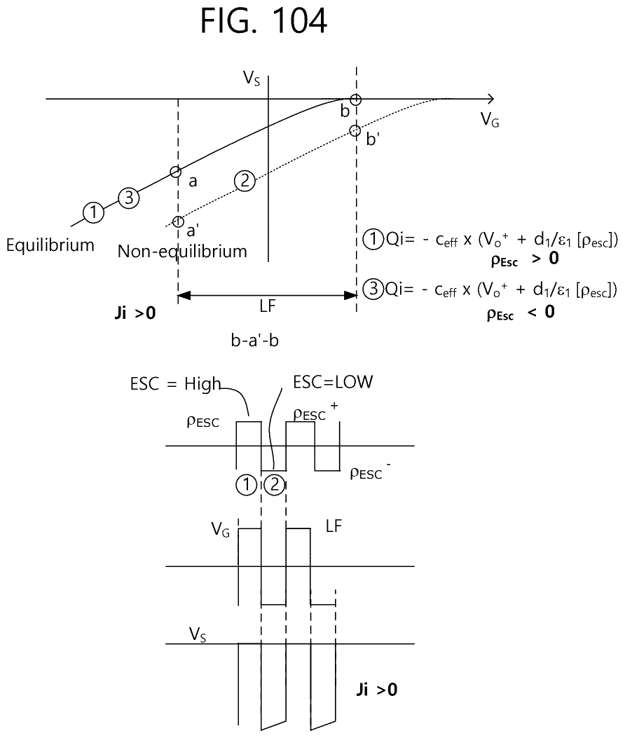

FIG. 104 is a diagram illustrating a potential of a target based on an applied voltage of an electrode.

Referring to FIG. 104, an electrostatic voltage (electrostatic charge) may have a negative value in a predetermined region, and the electrostatic voltage (electrostatic charge) may have a positive value in the remaining region. An applied voltage is a bipolar pulse. The applied voltage may be synchronized with the electrostatic voltage (electrostatic charge).

When the electrostatic voltage (electrostatic charge) is positive, the potential Vs of the target moves along curve 1 in the equilibrium state. Also, when the electrostatic voltage (electrostatic charge) has a negative value, the potential Vs of the target moves along curve 3 in the equilibrium state.

Initially, when the electrostatic voltage electrostatic charge is positive and suddenly transitions to a predetermined negative value at a specific time, a charged amount of the target 16 is given as follows:

$${V}_{G}^{+} + \frac{{ρ}_{i}}{{c}_{e f f}} + \frac{{d}_{1} {ρ}_{e s c}^{+}}{{ϵ}_{1}} = 0 \qquad [ Equation 73 ]$$

$${ρ}_{e s c}^{+} = - {c}_{e f f} ( {V}_{G}^{+} + \frac{{d}_{1} {ρ}_{e s c}^{+}}{{ϵ}_{1}} )$$

In this case, the potential Vs of the target 16 follows curve 2 and is given as follows:

$${V}_{s} = - {\frac{1}{4} [ - \frac{1}{{c}_{e f f}} \sqrt{2 {ϵ}_{3} {ρ}_{d}} + \sqrt{{( \frac{1}{{c}_{e f f}} \sqrt{2 {ϵ}_{3} {ρ}_{d}} )}^{2} - 4 ( {V}_{G} - {V}_{G}^{+} - \frac{{d}_{1} {ρ}_{esc}^{+}}{{ϵ}_{1}} + \frac{{d}_{1} {ρ}_{esc}^{-}}{{ϵ}_{1}} )} ]}^{2}$$

Therefore, the charged amount of the target 16 does not have an equilibrium value, so that the potential Vs of the target 16 moves along curve 2. Ultimately, after the next period of the applied voltage, the potential Vs of the target 16 moves along curve 1 in the equilibrium state due to the injection of electron current.

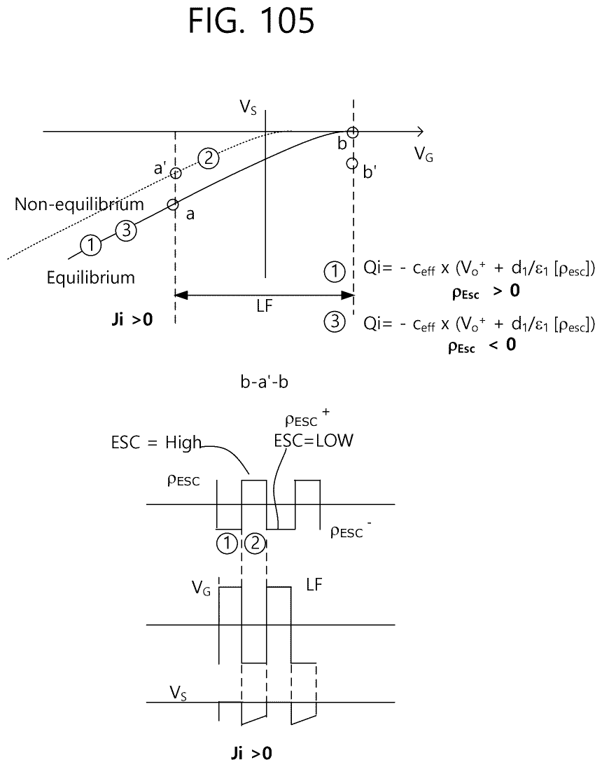

FIG. 105 is a diagram illustrating a potential of a target based on an applied voltage of an electrode.

Referring to FIG. 105, an electrostatic voltage (electrostatic charge) may have a negative value in a predetermined region, and the electrostatic voltage (electrostatic charge) may have a positive value in the remaining region. An applied voltage is a bipolar pulse. The applied voltage may be synchronized with the electrostatic voltage (electrostatic charge).

When the electrostatic voltage (electrostatic charge) is negative, a potential Vs of the target moves along curve 1 in an equilibrium state. Also, when the electrostatic voltage electrostatic charge is positive, the potential Vs of the target moves along curve 3 in the equilibrium state.

Initially, when the electrostatic voltage electrostatic charge is negative and suddenly transitions to a predetermined positive value at a specific time, a charged amount of target 16 is given as follows:

$${V}_{G}^{+} + \frac{{ρ}_{i}^{-}}{{c}_{e f f}} + \frac{{d}_{1} {ρ}_{esc}^{-}}{{ϵ}_{1}} = 0 \qquad [ Equation 74 ]$$

$${ρ}_{i}^{-} = - {c}_{e f f} ( {V}_{G}^{+} + \frac{{d}_{1} {ρ}_{esc}^{-}}{{ϵ}_{1}} )$$

In this case, the potential Vs of the target 16 follows curve 2 and is given as follows:

$${V}_{s} = - {\frac{1}{4} [ - \frac{1}{{c}_{e f f}} \sqrt{2 {ϵ}_{3} {ρ}_{d}} + \sqrt{{( \frac{1}{{c}_{e f f}} \sqrt{2 {ϵ}_{3} {ρ}_{d}} )}^{2} - 4 ( {V}_{G} - {V}_{G}^{+} - \frac{{d}_{1} {ρ}_{esc}^{-}}{{ϵ}_{1}} + \frac{{d}_{1} {ρ}_{esc}^{+}}{{ϵ}_{1}} )} ]}^{2}$$

Therefore, the charged amount of the target 16 does not have an equilibrium value, so that the potential Vs of the target 16 moves along curve 2.

Ultimately, after a single period of the applied voltage, the potential Vs of the target 16 moves along curve 1 in the equilibrium state due to the injection of electron current

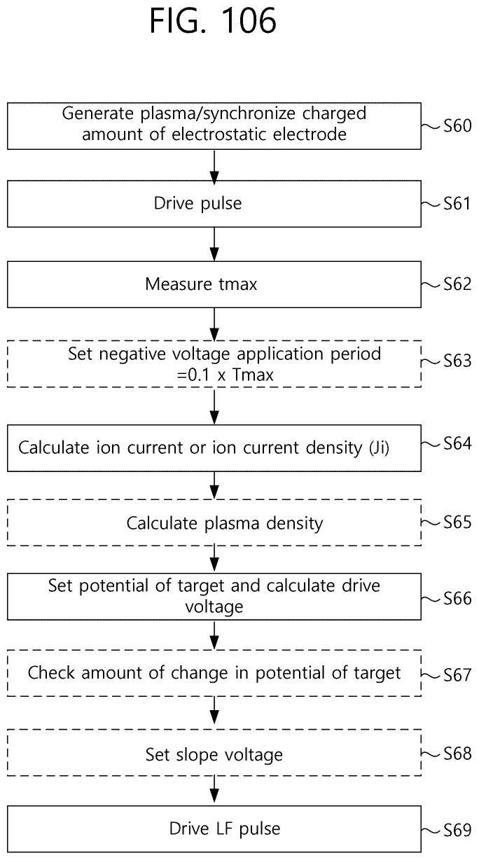

FIG. 106 is a flowchart illustrating a method for controlling a voltage of a target.

Referring to FIG. 106, plasma is generated and synchronized with a charged amount of an electrostatic electrode and a driving voltage (S60). Then, a bipolar pulse voltage is applied to the electrode (S61). A negative pulse period is set sufficiently large to measure maximum time tmax when current flowing through the electrode becomes zero (S62). The ion current density Ji is calculated using a relationship between the maximum time tmax and ion current density (S64). Time during which a negative voltage is applied at the driving voltage is set to be sufficiently smaller than the maximum time tmax. Plasma density is calculated using the ion current density (S65). A voltage of a target is set (S66). The voltage of the target determines ion energy. A waveform of the driving voltage corresponding to the voltage of the target is determined (S66). A change in the voltage of the target, caused by the ion current density, is checked (S67). A slope voltage correcting the change in the voltage of the target, caused by the ion current density, is determined (S68). A low-frequency pulse waveform is driven (S69).

The electrostatic voltage (electrostatic charge) may have a positive value in a predetermined region, and the electrostatic voltage (electrostatic charge) may have a slope in the remaining region. An applied voltage is a bipolar pulse. The applied voltage may be synchronized with the electrostatic voltage (electrostatic charge).

The electrostatic voltage (electrostatic charge) may have a slope and is given as follows:

$${ρ}_{E S C} ( r ) = - \frac{{ϵ}_{1}}{{d}_{1}} \frac{1}{{c}_{e f f}} {J}_{i} t \qquad [ Equation 75 ]$$

The electrostatic voltage (electrostatic charge) may have a positive value in a predetermined region, and the electrostatic voltage (electrostatic charge) may have a slope at a negative value in the remaining region. An applied voltage is a bipolar pulse. The applied voltage may be synchronized with the electrostatic voltage (electrostatic charge).

The electrostatic voltage (electrostatic charge) may have a slope and is given as follows:

$${ρ}_{E S C} ( t ) = - \frac{{ϵ}_{1}}{{d}_{1}} \frac{1}{{c}_{e f f}} {J}_{i} t \qquad [ Equation 76 ]$$

When a time variation of the charged amount of the electrostatic electrode is negligible, the current I_{G} flowing through the electrode 18 is given as follows:

$${I}_{G} = \frac{d ( {ρ}_{G} A )}{dt} = - \frac{d [ {ρ}_{i} + {ρ}_{d} {d}_{3} + {ρ}_{esc} ] A}{dt} \qquad [ Equation 77 ]$$

$${I}_{G} = A \frac{\frac{d}{dt} ( {V}_{G} - {V}_{s} )}{[ \frac{{d}_{1}}{{ϵ}_{1}} + \frac{{d}_{2}}{{ϵ}_{2}} ]}$$

$${V}_{s} = - {( [ \frac{{d}_{1}}{{ϵ}_{1}} + \frac{{d}_{2}}{{ϵ}_{2}} ] )}^{2} {ϵ}_{3} {ρ}_{d} + ( {V}_{G} + [ \frac{{d}_{1}}{{ϵ}_{1}} + \frac{{d}_{2}}{{ϵ}_{2}} ] {ρ}_{i} + \frac{{d}_{1} {ρ}_{esc}}{{ϵ}_{1}} ) + [ \frac{{d}_{1}}{{ϵ}_{1}} + \frac{{d}_{2}}{{ϵ}_{2}} ] \frac{1}{2} \sqrt{2 {ϵ}_{3} {ρ}_{d}} \sqrt{{( [ \frac{{d}_{1}}{{ϵ}_{1}} + \frac{{d}_{2}}{{ϵ}_{2}} ] \sqrt{2 {ϵ}_{3} {ρ}_{d}} )}^{2} - 4 ( {V}_{G} + [ \frac{{d}_{1}}{{ϵ}_{1}} + \frac{{d}_{2}}{{ϵ}_{2}} ] {ρ}_{i} + \frac{{d}_{1} {ρ}_{esc}}{{ϵ}_{1}} )}$$

A time derivative of the potential Vs of the target is given as follows in the case of a bipolar pulse.

$${V}_{G} = {V}_{G 0} + Xt$$

$${ρ}_{i} = {ρ}_{i 0} + {J}_{i} t$$

$$\frac{{dV}_{s}}{dt} = ( X + [ \frac{{d}_{1}}{{ϵ}_{1}} + \frac{{d}_{2}}{{ϵ}_{2}} ] {J}_{i} ) [ 1 - [ \frac{{d}_{1}}{{ϵ}_{1}} + \frac{{d}_{2}}{{ϵ}_{2}} ] \frac{\sqrt{2 {ϵ}_{3} {ρ}_{d}}}{\sqrt{{( [ \frac{{d}_{1}}{{ϵ}_{1}} + \frac{{d}_{2}}{{ϵ}_{2}} ] \sqrt{2 {ϵ}_{3} {ρ}_{d}} )}^{2} - 4 ( {V}_{G} + [ \frac{{d}_{1}}{{ϵ}_{1}} + \frac{{d}_{2}}{{ϵ}_{2}} ] {ρ}_{i} + \frac{{d}_{1} {ρ}_{esc}}{{ϵ}_{1}} )}} ]$$

When a time variation of the charged amount of the electrostatic electrode is negligible, the current I_{G} flowing through the electrode 18 is given as follows:

$${I}_{G} = A \frac{\frac{d}{dt} ( {V}_{G} - {V}_{s} )}{[ \frac{{d}_{1}}{{ϵ}_{1}} + \frac{{d}_{2}}{{ϵ}_{2}} ]} \qquad [ Equation 78 ]$$

$${I}_{G} = AX [ \frac{\sqrt{2 {ϵ}_{3} {ρ}_{d}}}{\sqrt{{( [ \frac{{d}_{1}}{{ϵ}_{1}} + \frac{{d}_{2}}{{ϵ}_{2}} ] \sqrt{2 {ϵ}_{3} {ρ}_{d}} )}^{2} - 4 ( {V}_{G} + [ \frac{{d}_{1}}{{ϵ}_{1}} + \frac{{d}_{2}}{{ϵ}_{2}} ] {ρ}_{i} + \frac{{d}_{1} {ρ}_{esc}}{{ϵ}_{1}} )}} ] - {AJ}_{i} [ 1 - [ [ \frac{{d}_{1}}{{ϵ}_{1}} + \frac{{d}_{2}}{{ϵ}_{2}} ] \frac{\sqrt{2 {ϵ}_{3} {ρ}_{d}}}{\sqrt{{( [ \frac{{d}_{1}}{{ϵ}_{1}} + \frac{{d}_{2}}{{ϵ}_{2}} ] \sqrt{2 {ϵ}_{3} {ρ}_{d}} )}^{2} - 4 ( {V}_{G} + [ \frac{{d}_{1}}{{ϵ}_{1}} + \frac{{d}_{2}}{{ϵ}_{2}} ] {ρ}_{i} + \frac{{d}_{1} {ρ}_{esc}}{{ϵ}_{1}} )}} ] ]$$

The change ΔVs in the potential Vs of the target 16 is given as follows:

$${V}_{s} = - {\frac{1}{4} [ - \frac{1}{{c}_{eff}} \sqrt{2 {ϵ}_{3} {ρ}_{d}} + \sqrt{{( \frac{1}{{c}_{eff}} \sqrt{2 {ϵ}_{3} {ρ}_{d}} )}^{2} - 4 ( {V}_{G} + \frac{1}{{c}_{eff}} {ρ}_{i} + \frac{{d}_{1} {ρ}_{esc}}{{ϵ}_{1}} )} ]}^{2}$$

$$Δ {V}_{s} = {V}_{s} ( t = τ ) - {V}_{s} ( t = 0 )$$

$$Δ {V}_{s} = ( X + \frac{{J}_{i}}{{c}_{eff}} ) τ [ 1 - \frac{1}{{c}_{eff}} \frac{\sqrt{2 {ϵ}_{2} {ρ}_{d}}}{\sqrt{{( \frac{1}{{c}_{eff}} \sqrt{2 {ϵ}_{2} {ρ}_{d}} )}^{2} - 4 ( {V}_{G} + \frac{{d}_{1} {ρ}_{esc}}{{ϵ}_{1}} + \frac{1}{{c}_{eff}} {ρ}_{i} )}} ]$$

Even in the case of a sinusoidal waveform, a similar calculation may be performed as in the previous case.

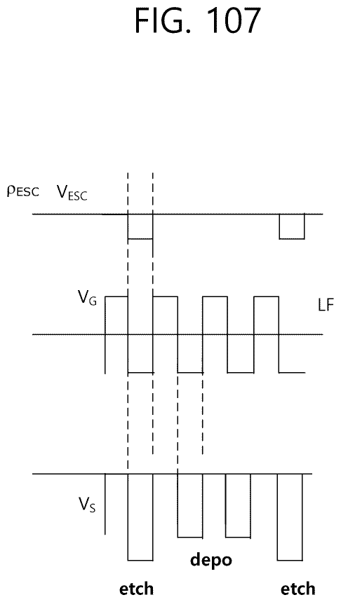

FIG. 107 is a diagram illustrating a potential of a target based on an applied voltage of an electrode when a charged amount of an electrostatic electrode has a pulse form.

Referring to FIG. 107, a charged amount ρ_{esc} of the electrostatic electrode 19 has a pulse form and is synchronized with the applied voltage V_{G}. When the charged amount ρ_{esc} of the electrostatic electrode 19 has a predetermined negative value, the potential Vs of the target may be synchronized and decreased. Accordingly, the potential Vs of the target may sequentially repeated etching and deposition over time.

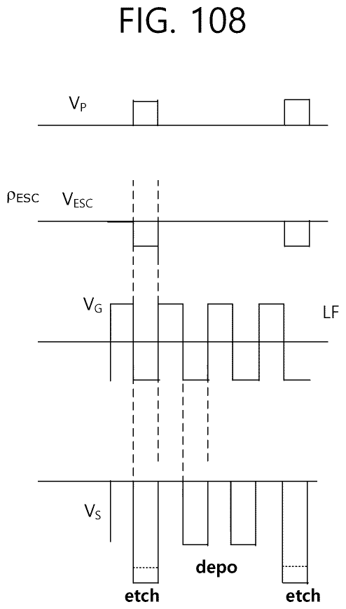

FIG. 108 is a diagram illustrating the potential of a target based on an applied voltage of an electrode when the charged amount of the electrostatic electrode has a pulse form.

Referring to FIG. 108, a plasma potential Vp and a charged amount ρ_{esc} of the electrostatic electrode 19 have a pulse form and are synchronized with an applied voltage V_{G}. When the charged amount pes of the electrostatic electrode 19 has a predetermined negative value, a potential Vs of the target may be synchronized and decreased. Accordingly, the potential Vs of the target may sequentially repeated etching and deposition over time.

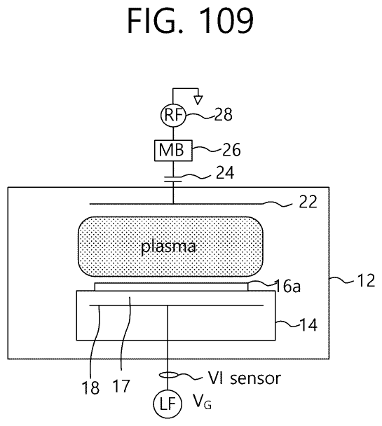

FIG. 109 is a conceptual diagram illustrating a plasma apparatus according to an example embodiment of the present disclosure.

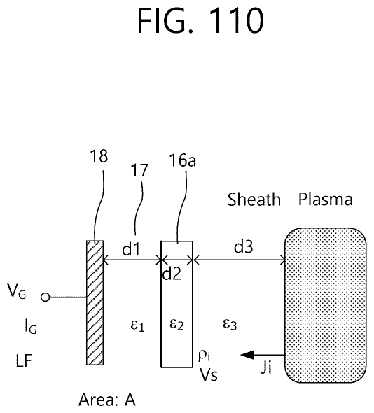

FIG. 110 is a conceptual diagram illustrating an electrode, a dielectric, a target, and plasma.

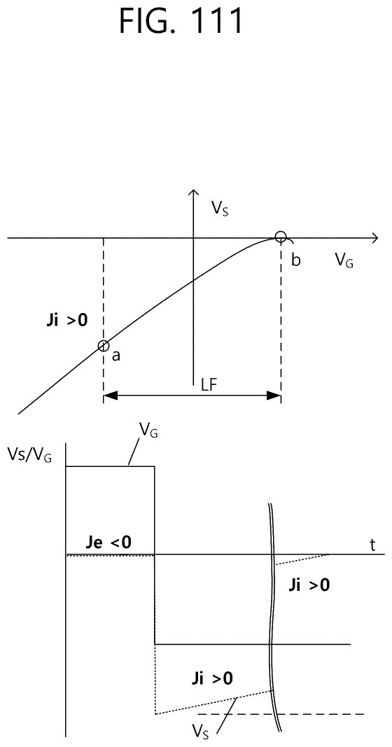

FIG. 111 is a diagram illustrating a potential of a target based on an applied voltage of the electrode in the structure of FIG. 110.

Referring to FIGS. 109 to 111, a plasma system 100 includes a chamber 12, a plasma source 20 generating plasma in the chamber 12, and a target holder 14 mounting a target 16a. The target 16a may be an insulator or a dielectric.

A driving voltage V_{G} is applied to the electrode 18, and the target 16a is a dielectric and has a surface on which electrons or positive ions are accumulated. A plasma sheath is formed between the plasma and the target 16a. The plasma sheath may be treated as a space having a positive space charge. A thickness d3 of the plasma sheath varies depending on the voltage V_{G}. The first dielectric 17 is a first region, the target 16a is a second region, and the plasma sheath is a third region.

A thickness of the first dielectric 17 is d1. A thickness of the target 16a is d2. A thickness of the plasma sheath is d3. A voltage of the target 16 is Vs. Surface charge density of the target 16a is ρi. A dielectric constant of the first region may be ε1, a dielectric constant of the second region, the target 16, may be ε2, and a dielectric constant of the plasma sheath 3 may be a dielectric constant of vacuum. An area of the electrode and the target is A.

A general solutions of a voltage V1 in the first region, a general solution of the voltage V2 in the second region, and a general solution in the third region are given as follows. Also, an electric field ε1 in the first region, an electric field ε2 in the second region, and an electric field ε3 in the third region are given as follows. An origin of the coordinate system is an electrode. x is coordinates of a rectangular coordinate system.

### [Matrix Model]

### [Dielectric Target]

$$- {V}_{s} = \frac{{ρ}_{d}}{2 {ϵ}_{3}} {d}_{3}^{2} \to {d}_{3} = \sqrt{\frac{- 2 {ϵ}_{3} {V}_{s}}{{ρ}_{d}}} \qquad [ Equation 79 ]$$

$${V}_{s} = {V}_{G} + [ \frac{{d}_{1}}{{ϵ}_{1}} + \frac{{d}_{2}}{{ϵ}_{2}} ] {ρ}_{i} + [ \frac{{d}_{1}}{{ϵ}_{1}} + \frac{{d}_{2}}{{ϵ}_{2}} ] {ρ}_{d} {d}_{3}$$

$${V}_{s} = {V}_{G} + [ \frac{{d}_{1}}{{ϵ}_{1}} + \frac{{d}_{2}}{{ϵ}_{2}} ] {ρ}_{i} + [ \frac{{d}_{1}}{{ϵ}_{1}} + \frac{{d}_{2}}{{ϵ}_{2}} ] \sqrt{- 2 {ϵ}_{3} {V}_{s} {ρ}_{d}}$$

A surface potential Vs of the target 16a is given as follows:

$${V}_{s} = - {( [ \frac{{d}_{1}}{{ϵ}_{1}} + \frac{{d}_{2}}{{ϵ}_{2}} ] )}^{2} {ϵ}_{3} {ρ}_{d} + ( {V}_{G} + [ \frac{{d}_{1}}{{ϵ}_{1}} + \frac{{d}_{2}}{{ϵ}_{2}} ] {ρ}_{i} ) + [ \frac{{d}_{1}}{{ϵ}_{1}} + \frac{{d}_{2}}{{ϵ}_{2}} ] \frac{1}{2} \sqrt{2 {ϵ}_{3} {ρ}_{d}} \sqrt{{( [ \frac{{d}_{1}}{{ϵ}_{1}} + \frac{{d}_{2}}{{ϵ}_{2}} ] \sqrt{2 {ϵ}_{3} {ρ}_{d}} )}^{2} - 4 ( {V}_{G} + [ \frac{{d}_{1}}{{ϵ}_{1}} + \frac{{d}_{2}}{{ϵ}_{2}} ] {ρ}_{i} )}$$

$$\frac{1}{{c}_{eff}} = [ \frac{{d}_{1}}{{ϵ}_{1}} + \frac{{d}_{2}}{{ϵ}_{2}} ]$$

$${V}_{s} = - {( \frac{1}{{c}_{eff}} )}^{2} {ϵ}_{3} {ρ}_{d} + ( {V}_{G} + \frac{1}{{c}_{eff}} {ρ}_{i} ) + \frac{1}{{c}_{eff}} \frac{1}{2} \sqrt{2 {ϵ}_{3} {ρ}_{d}} \sqrt{{( \frac{1}{{c}_{eff}} \sqrt{2 {ϵ}_{3} {ρ}_{d}} )}^{2} - 4 ( {V}_{G} + \frac{1}{{c}_{eff}} {ρ}_{i} )}$$

An absolute value of the surface potential Vs of the target 16a decreases as the thickness d2 of the target 16a increases, and an absolute value of the potential Vs of the target decreases as the dielectric constant ε2 of the target 16a decreases.

The maximum time tmax is given as follows:

$$( {V}_{G} + \frac{1}{{c}_{eff}} {ρ}_{i} ) = {V}_{0} + {Xt}_{max} + \frac{1}{{c}_{eff}} ( {ρ}_{i 0} + {J}_{i} {t}_{max} ) = 0$$

$${t}_{max} = - \frac{{V}_{0} + \frac{1}{{c}_{eff}} {ρ}_{i 0}}{X + \frac{1}{{c}_{eff}} {J}_{i}}$$

The current I_{G} flowing through the electrode 18 is given as follows:

$${I}_{G} = {Ac}_{eff} \frac{d}{dt} ( {V}_{G} - {V}_{s} ) \qquad [ Equation 80 ]$$

$${I}_{G} = {Ac}_{eff} X - {Ac}_{eff} ( X + \frac{{J}_{i}}{{c}_{eff}} ) [ 1 - \frac{1}{{c}_{eff}} \frac{\sqrt{2 {ϵ}_{3} {ρ}_{d}}}{\sqrt{{( \frac{1}{{c}_{eff}} \sqrt{2 {ϵ}_{3} {ρ}_{d}} )}^{2} - 4 ( {V}_{G} + \frac{1}{{c}_{eff}} {ρ}_{i} )}} ]$$

A change ΔVs in the potential Vs of the target is given as follows:

$$Δ {V}_{s} = {V}_{s} ( t = τ ) - {V}_{s} ( t = 0 ) \qquad [ Equation 81 ]$$

$$Δ {V}_{s} = ( X + \frac{{J}_{i}}{{c}_{eff}} ) τ [ 1 - \frac{1}{{c}_{eff}} \frac{\sqrt{2 {ϵ}_{3} {ρ}_{d}}}{\sqrt{{( \frac{1}{{c}_{eff}} \sqrt{2 {ϵ}_{3} {ρ}_{d}} )}^{2} - 4 ( {V}_{G} + \frac{1}{{c}_{eff}} {ρ}_{i} )}} ]$$

When the target is sputtered by ions, the thickness of the target may decrease. In this case, the absolute value of the potential Vs of the target may increase. Therefore, the applied voltage may be controlled such that the potential Vs of the target is maintained to be constant.

When the target is sputtered by ions, the thickness of the target may decrease. In this case, a position of the plasma sheath may vary. Therefore, the applied voltage may be controlled such that the position of the plasma sheath is maintained to be constant.

The change in the plasma potential Vp and the change in the electrostatic electrode may be equivalently applied. The operation method described in FIGS. 38 to 41 may be applied. Even in the case of sinusoidal wave, a similar calculation may be performed.

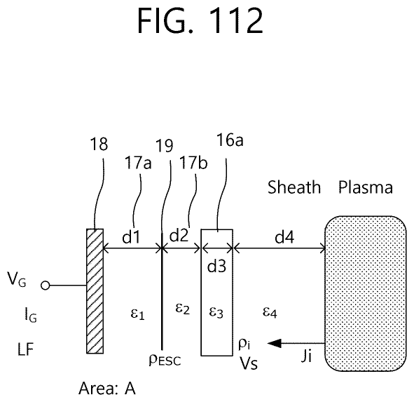

FIG. 112 is a conceptual diagram illustrating a plasma system including an electrostatic electrode.

Referring to FIG. 112, a plasma system 100 includes a chamber 12, a plasma source 20 generating plasma in the chamber 12, and a target holder 14 mounting a target 16a. The target 16a may be an insulator or a dielectric.

A driving voltage V_{G} is applied to the electrode 18, and the target 16a is a dielectric and has a surface on which electrons or positive ions are accumulated. A plasma sheath is formed between the plasma and the target 16a. The plasma sheath may be treated as a space having a positive space charge. A thickness d3 of the plasma sheath varies depending on the voltage V_{G}. A first dielectric 17a is a first region, a second dielectric 17b is a second region, and an electrostatic electrode 19 is disposed between the first dielectric 17a and the second dielectric 17b. A thickness of an electrostatic electrode is negligible. The target 16a is a third region, and the plasma sheath is a fourth region. A is an area of the target and the electrode.

A thickness of the first dielectric 17a is d1. A thickness of the electrostatic electrode 19 is negligible. A charged amount of the electrostatic electrode is ρ_{esc}. A thickness of the second dielectric 17b is d2. A thickness of the target 16a is d3. A thickness of the plasma sheath is d4. A voltage of the target 16a is Vs. Surface charge density of the target 16a is ρi. A dielectric constant of the first region may be ε1, a dielectric constant of the second region, the target 16a, may be ε2, and a dielectric constant of the plasma sheath 3 may be a dielectric constant of vacuum.

The surface potential Vs of the target 16a is given as follows:

$$\frac{1}{{c}_{eff}} ≡ [ \frac{{d}_{1}}{{ϵ}_{1}} + \frac{{d}_{2}}{{ϵ}_{2}} + \frac{{d}_{3}}{{ϵ}_{3}} ] \qquad [ Equation 82 ]$$

$${V}_{s} = - {\frac{1}{4} [ - \frac{1}{{c}_{eff}} \sqrt{2 {ϵ}_{4} {ρ}_{d}} + \sqrt{{( \frac{1}{{c}_{eff}} \sqrt{2 {ϵ}_{4} {ρ}_{d}} )}^{2} - 4 ( {V}_{G} + \frac{1}{{c}_{eff}} {ρ}_{i} + {ρ}_{esc} ( \frac{{d}_{1}}{{ϵ}_{1}} ) )} ]}^{2}$$

The maximum time tmax is given as follows:

$$( {V}_{G} + [ \frac{{d}_{1}}{{ϵ}_{1}} ] {ρ}_{esc} + ( \frac{1}{{c}_{eff}} ) {ρ}_{i} ) = {V}_{0} + {Xt}_{max} + [ \frac{{d}_{1}}{{ϵ}_{1}} ] {ρ}_{esc} + ( \frac{1}{{c}_{eff}} ) ( {ρ}_{i 0} + {J}_{i} {t}_{max} ) = 0 \qquad [ Equation 83 ]$$

$${t}_{max} = - \frac{{V}_{0} + \frac{1}{{c}_{eff}} {ρ}_{i 0} + {ρ}_{esc} [ \frac{{d}_{1}}{{ϵ}_{1}} ]}{X + \frac{1}{{c}_{eff}} {J}_{i}}$$

The current I_{G} flowing through the electrode 18 is given as follows:

$${I}_{G} = {Ac}_{eff} \frac{d}{dt} ( {V}_{G} - {V}_{s} ) \qquad [ Equation 84 ]$$

$${I}_{G} = {Ac}_{eff} \frac{{dV}_{G}}{dt} - {Ac}_{eff} ( \frac{{dV}_{G}}{dt} + \frac{{J}_{i}}{{c}_{eff}} ) [ 1 - \frac{1}{{c}_{eff}} \frac{\sqrt{2 {ϵ}_{4} {ρ}_{d}}}{\sqrt{{( \frac{1}{{c}_{eff}} \sqrt{2 {ϵ}_{4} {ρ}_{d}} )}^{2} - 4 ( {V}_{G} + \frac{1}{{c}_{eff}} {ρ}_{i} + {ρ}_{esc} ( \frac{{d}_{1}}{{ϵ}_{1}} ) )}} ]$$

$${I}_{G} = {Ac}_{eff} X - {Ac}_{eff} ( X + \frac{{J}_{i}}{{c}_{eff}} ) [ 1 - \frac{1}{{c}_{eff}} \frac{\sqrt{2 {ϵ}_{4} {ρ}_{d}}}{\sqrt{{( \frac{1}{{c}_{eff}} \sqrt{2 {ϵ}_{4} {ρ}_{d}} )}^{2} - 4 ( {V}_{G} + \frac{1}{{c}_{eff}} {ρ}_{i} + {ρ}_{esc} ( \frac{{d}_{1}}{{ϵ}_{1}} ) )}} ]$$

A change ΔVs in the potential Vs of the target 16a is given as follows:

$$Δ {V}_{s} = {V}_{s} ( t = τ ) - {V}_{s} ( t = 0 ) \qquad [ Equation 85 ]$$

$$Δ {V}_{s} = ( X + \frac{{J}_{i}}{{c}_{eff}} ) τ [ 1 - \frac{1}{{c}_{eff}} \frac{\sqrt{2 {ϵ}_{4} {ρ}_{d}}}{\sqrt{{( \frac{1}{{c}_{eff}} \sqrt{2 {ϵ}_{4} {ρ}_{d}} )}^{2} - 4 ( {V}_{G} + \frac{1}{{c}_{eff}} {ρ}_{i} )}} ]$$

When the target is sputtered by ions, a thickness of the target may decrease. In this case, an absolute value of the potential Vs of the target may increase. Therefore, an applied voltage may be controlled such that the potential Vs of the target is maintained to be constant.

When the target is sputtered by ions, a thickness of the target may decrease. In this case, a position of the plasma sheath may vary. Therefore, the applied voltage may be controlled such that the position of the plasma sheath is maintained to be constant.

A variable capacitor Cv may be additionally connected in series to the electrode 18. When the target 16 is sputtered over time and the thickness d3 of the target 16 decreases, the capacitance Cv of the variable capacitor may be decreased over time to maintain the same potential Vs of the target 16 or to maintain the same sputtering rate.

A sinusoidal waveform, a slope voltage, measurement of maximum time, measurement of current, a change in plasma potential, and a change in electrostatic electrode may be equivalently applied. The operation method described in FIGS. 38 to 41 may be applied.

[Connection through Capacitor in Dielectric Target]

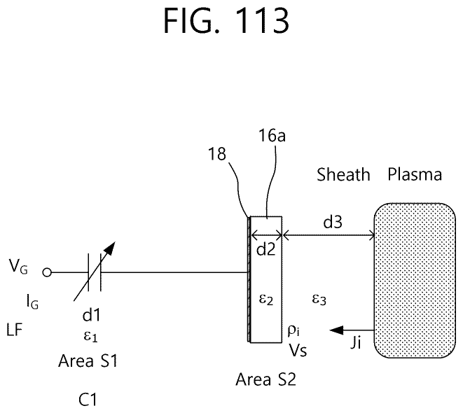

FIG. 113 is a conceptual diagram illustrating a plasma system including a variable capacitor.

Referring to FIG. 113, a plasma system 100 includes a chamber 12, a plasma source 20 generating plasma in the chamber 12, and a target holder 14 mounting a target 16a. The target 16a may be an insulator or a dielectric.

A plasma apparatus may have a structure in which a variable capacitor C1, an electrode 18, and a target 16a are connected in series. A method for controlling a target voltage includes operations of applying a low-frequency pulse voltage V_{G} to the variable capacitor C1 and controlling capacitance of the variable capacitor C1 to control a voltage Vs of the dielectric target 16a. The electrode 18 may be removed.

The variable capacitor C1 may be a capacitor having capacitance (C1=ε1S1/d1). The capacitor C1 may be a variable capacitor. A potential Vs of the target 16a with an area S2 is changed as follows:

The potential Vs of the target 16a is given as follows:

$${V}_{s} = {V}_{G} + {ρ}_{i} [ \frac{{d}_{2}}{{ϵ}_{2}} + ( \frac{{S}_{2}}{{C}_{1}} ) ] + [ \frac{{d}_{2}}{{ϵ}_{2}} + ( \frac{{S}_{2}}{{C}_{1}} ) ] \sqrt{- 2 {ϵ}_{3} {V}_{s} {ρ}_{d}} \qquad [ Equation 86 ]$$

$$\frac{1}{{c}_{eff}} = [ \frac{{d}_{2}}{{ϵ}_{2}} + ( \frac{{S}_{2}}{{C}_{1}} ) ]$$

$$- {V}_{s} = \frac{1}{4} [ - \frac{1}{{c}_{eff}} \sqrt{2 {ϵ}_{3} {ρ}_{d}} + {\sqrt{{( \frac{1}{{c}_{eff}} \sqrt{2 {ϵ}_{3} {ρ}_{d}} )}^{2} - 4 ( {V}_{G} + \frac{1}{{c}_{eff}} {ρ}_{i} ) ]}}^{2}$$

The maximum time tmax is given as follows:

$$( {V}_{G} + ( \frac{1}{{c}_{eff}} ) {ρ}_{i} ) = {V}_{0} + {Xt}_{max} + ( \frac{1}{{c}_{eff}} ) ( {ρ}_{i 0} + {J}_{i} {t}_{max} ) = 0$$

$${t}_{max} = - \frac{{V}_{0} + \frac{1}{{c}_{eff}} {ρ}_{i 0}}{X + \frac{1}{{c}_{eff}} {J}_{i}}$$

The current I_{G} flowing through the electrode 18 or the variable capacitor C1 is given as follows:

$${Q}_{G} = - {S}_{2} [ {ρ}_{i} + {ρ}_{d} {d}_{3} ]$$

$${V}_{s} = {V}_{G} + [ \frac{{d}_{2}}{{ϵ}_{2}} + ( \frac{{S}_{2}}{{C}_{1}} ) ] [ {ρ}_{i} + {ρ}_{d} {d}_{3} ]$$

$${Q}_{G} = {S}_{2} \frac{[ {V}_{G} - {V}_{s} ]}{[ \frac{{d}_{2}}{{ϵ}_{2}} + ( \frac{{S}_{2}}{{C}_{1}} ) ]}$$

$${I}_{G} = {S}_{2} {c}_{eff} \frac{d}{dt} ( {V}_{G} - {V}_{s} )$$

$${I}_{G} = {S}_{2} {c}_{eff} \frac{{d V}_{G}}{dt} - {S}_{2} {c}_{eff} ( \frac{{d V}_{G}}{dt} + \frac{{J}_{i}}{{c}_{eff}} ) [ 1 - \frac{1}{{c}_{eff}} \frac{\sqrt{2 {ϵ}_{3} {ρ}_{d}}}{\sqrt{{( \frac{1}{{c}_{eff}} \sqrt{2 {ϵ}_{3} {ρ}_{d}} )}^{2} - 4 ( {V}_{G} + \frac{1}{{c}_{eff}} {ρ}_{i} )}} ]$$

$${I}_{G} = {S}_{2} {c}_{eff} X - {S}_{2} {c}_{eff} ( X + \frac{{J}_{i}}{{c}_{eff}} ) [ 1 - \frac{1}{{c}_{eff}} \frac{\sqrt{2 {ϵ}_{3} {ρ}_{d}}}{\sqrt{{( \frac{1}{{c}_{eff}} \sqrt{2 {ϵ}_{3} {ρ}_{d}} )}^{2} - 4 ( {V}_{G} + \frac{1}{{c}_{eff}} {ρ}_{i} )}} ]$$

A change ΔVs in the potential Vs of the target is given as follows:

$${Δ V}_{s} = {V}_{s} ( t = τ ) - {V}_{s} ( t = 0 )$$

$$Δ {V}_{s} = ( X + \frac{{J}_{i}}{{c}_{eff}} ) τ [ 1 - \frac{1}{{c}_{eff}} \frac{\sqrt{2 {ϵ}_{3} {ρ}_{d}}}{\sqrt{{( \frac{1}{{c}_{eff}} \sqrt{2 {ϵ}_{3} {ρ}_{d}} )}^{2} - 4 ( {V}_{G} + \frac{1}{{c}_{eff}} {ρ}_{i} )}} ]$$

When the target 16a is sputtered over time and the thickness d2 decreases, the capacitance C1 of the variable capacitor may be decreased over time to maintain the same potential Vs of the target 16a or to maintain the same sputtering rate.

In addition, when the variable capacitor C1 is adjusted at a predetermined slope voltage X1, a change ΔVs in the potential of the target object may be zero.

When the target is sputtered by ions, a thickness of the target may decrease. In this case, a position of the plasma sheath may vary. Therefore, an applied voltage may be controlled such that the position of the plasma sheath is maintained to be constant.

A sinusoidal waveform, a slope voltage, measurement of maximum time, measurement of current, a change in plasma potential, and a change in electrostatic electrode may be equivalently applied. The operation method described in FIGS. 38 to 41 may be applied.

[Treatment of target, conductor, when replacing dielectric with capacitor]

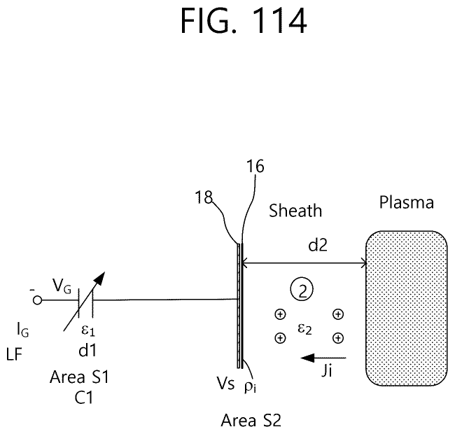

FIG. 114 is a conceptual diagram illustrating a plasma system including a variable capacitor.

Referring to FIG. 114, a plasma system 100 includes a chamber 12, a plasma source 20 generating plasma in the chamber 12, and a target holder 14 mounting a target 16a. The target 16a may be a conductor or a semiconductor. A plasma apparatus may have a structure in which a variable capacitor C1, an electrode 18, and a target 16a are connected in series. A method for controlling a target voltage includes operations of applying a low-frequency pulse voltage V_{G} to the variable capacitor C1 and controlling capacitance of the variable capacitor C1 to control a voltage of the conductive target. The electrode 18 may be removed.

The variable capacitor C1 may have capacitance (C1=ε1S1/d1). The capacitor C1 may be a variable capacitor. A potential Vs of the target 16a having an area S2 is changed as follows:

The potential Vs of the target 16a is given as follows:

$${V}_{s} = {V}_{G} + \frac{{d}_{1}}{{ϵ}_{1}} [ {ρ}_{i} + {ρ}_{d} {d}_{2} ] ( \frac{{s}_{2}}{{s}_{1}} ) \qquad [ Equation 87 ]$$

$${V}_{s} = {V}_{G} + \frac{{d}_{1}}{{ϵ}_{1}} {ρ}_{i} ( \frac{{S}_{2}}{{S}_{1}} ) + ( \frac{{S}_{2}}{{S}_{1}} ) \sqrt{- 2 {ϵ}_{2} {V}_{s} {ρ}_{d}}$$

$${V}_{s} = {V}_{G} + {ρ}_{i} ( \frac{{S}_{2}}{{C}_{1}} ) + ( \frac{{S}_{2}}{{C}_{1}} ) \sqrt{- 2 {ϵ}_{2} {V}_{s} {ρ}_{d}}$$

$$- {V}_{s} = {\frac{1}{4} [ - ( \frac{{S}_{2}}{{C}_{1}} ) \sqrt{2 {ϵ}_{2} {ρ}_{d}} + \sqrt{{( \frac{{S}_{2}}{{C}_{1}} \sqrt{2 {ϵ}_{2} {ρ}_{d}} )}^{2} - 4 ( {V}_{G} + \frac{{S}_{2}}{{C}_{1}} {ρ}_{i} )} ]}^{2}$$

In the potential Vs of the target 16 connected in series to the capacitor C1, capacitance per unit area (ε1/d1) is converted into a value of the capacitance of the capacitor C1 divided by an area S2 of the target 16 (ε1/d1S1/S2). When the capacitance of the capacitor C1 is changed, the potential Vs of the target 16 may be changed.

The maximum time tmax is given as follows:

$$( {V}_{G} + \frac{{S}_{2}}{{C}_{1}} {ρ}_{i} ) = {V}_{0} + {Xt}_{max} + \frac{{S}_{2}}{{C}_{1}} ( {ρ}_{i 0} + {J}_{i} {t}_{max} ) = 0 \qquad [ Equation 88 ]$$

$${t}_{max} = - \frac{{V}_{0} + \frac{{S}_{2}}{{C}_{1}} {ρ}_{i 0}}{X + \frac{{S}_{2}}{{C}_{1}} {J}_{i}}$$

The current I_{G} flowing through the capacitor C1 or the electrode 18 is given as follows:

$$QG = - {S}_{2} [ {ρ}_{i} + {ρ}_{d} {d}_{2} ] \qquad [ Equation 89 ]$$

$${V}_{S} = {V}_{G} + \frac{{d}_{1}}{{ϵ}_{1}} [ {ρ}_{i} + {ρ}_{d} {d}_{2} ] ( \frac{{S}_{2}}{{S}_{1}} )$$

$$QG = {C}_{1} [ {V}_{G} - {V}_{s} ]$$

$${I}_{G} = {C}_{1} \frac{d}{dt} ( {V}_{G} - {V}_{s} )$$

$${I}_{G} = {C}_{1} \frac{d}{dt} ( {V}_{G} - {V}_{s} )$$

$${I}_{G} = {C}_{1} \frac{{d V}_{G}}{dt} - {C}_{1} ( \frac{{d V}_{G}}{dt} + \frac{{S}_{2} {J}_{i}}{{C}_{1}} ) [ 1 - \frac{{S}_{2}}{{C}_{1}} \frac{\sqrt{2 {ϵ}_{2} {ρ}_{d}}}{\sqrt{{( \frac{{S}_{2}}{{C}_{1}} \sqrt{2 {ϵ}_{2} {ρ}_{d}} )}^{2} - 4 ( {V}_{G} + \frac{{S}_{2}}{{C}_{1}} {ρ}_{i} )}} ]$$

$$\frac{{d V}_{s}}{dt} = ( X + \frac{{S}_{2} {J}_{i}}{{C}_{1}} ) [ 1 - \frac{{S}_{2}}{{C}_{1}} \frac{\sqrt{2 {ϵ}_{2} {ρ}_{d}}}{\sqrt{{( \frac{{S}_{2}}{{C}_{1}} \sqrt{2 {ϵ}_{2} {ρ}_{d}} )}^{2} - 4 ( {V}_{G} + \frac{{S}_{2}}{{C}_{1}} {ρ}_{i} )}} ]$$

$${I}_{G} = {C}_{1} \frac{d}{dt} ( {V}_{G} - {V}_{s} )$$

$${I}_{G} = {C}_{1} X - {C}_{1} ( X + \frac{{S}_{2} {J}_{i}}{{C}_{1}} ) [ 1 - \frac{{S}_{2}}{{C}_{1}} \frac{\sqrt{2 {ϵ}_{2} {ρ}_{d}}}{\sqrt{{( \frac{{S}_{2}}{{C}_{1}} \sqrt{2 {ϵ}_{2} {ρ}_{d}} )}^{2} - 4 ( {V}_{G} + \frac{{S}_{2}}{{C}_{1}} {ρ}_{i} )}} ]$$

$${I}_{G} = {S}_{2} \frac{\sqrt{2 {ϵ}_{2} {ρ}_{d}}}{\sqrt{{( \frac{{S}_{2}}{{C}_{1}} \sqrt{2 {ϵ}_{2} {ρ}_{d}} )}^{2} - 4 ( {V}_{G} + \frac{{S}_{2}}{{C}_{1}} {ρ}_{i} )}} X - ( {J}_{i} {S}_{2} ) [ 1 - \frac{{S}_{2}}{{C}_{1}} \frac{\sqrt{2 {ϵ}_{2} {ρ}_{d}}}{\sqrt{{( \frac{{S}_{2}}{{C}_{1}} \sqrt{2 {ϵ}_{2} {ρ}_{d}} )}^{2} - 4 ( {V}_{G} + \frac{{S}_{2}}{{C}_{1}} {ρ}_{i} )}} ]$$

A change in the potential ΔVs of the target is given as follows:

$${Δ V}_{s} = {V}_{s} ( t = τ ) - {V}_{s} ( t = 0 )$$

$$Δ {V}_{s} = ( X + \frac{{S}_{2} {J}_{i}}{{C}_{1}} ) τ [ 1 - \frac{{S}_{2}}{{C}_{1}} \frac{\sqrt{2 {ϵ}_{2} {ρ}_{d}}}{\sqrt{{( \frac{{S}_{2}}{{C}_{1}} \sqrt{2 {ϵ}_{2} {ρ}_{d}} )}^{2} - 4 ( {V}_{G} + \frac{{S}_{2}}{{C}_{1}} {ρ}_{i} )}} ]$$

For example, in an ion implantation system or an etching system, when the capacitance of the variable capacitor C1 is adjusted, ion energy or sheath thickness may be controlled at a fixed applied voltage.

When the target is sputtered by ions, a thickness of the target may decrease. In this case, a position of the plasma sheath may vary. Therefore, an applied voltage or the variable capacitor C1 may be controlled such that the position of the plasma sheath is maintained to be constant.

In addition, when the variable capacitor C1 is adjusted at a predetermined slope voltage X1, the potential Vs of the target may be controlled and the change in the potential ΔVs of the target may be zero.

A sinusoidal waveform, a slope voltage, measurement of maximum time, measurement of current, a change in plasma potential, and a change in electrostatic electrode may be equivalently applied. The operation method described in FIGS. 38 to 41 may be applied.

### [When Further Including Dielectric 17 and Series Capacitor C4]

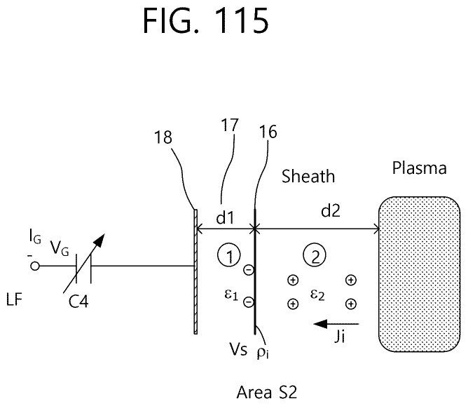

FIG. 115 is a conceptual diagram illustrating a plasma system including a variable capacitor.

Referring to FIG. 115, a plasma system 100 includes a chamber 12, a plasma source 20 generating plasma in the chamber 12, and a target holder 14 mounting a target 16. The target 16 may be a conductor or a semiconductor. A plasma apparatus may have a structure in which a variable capacitor C4, an electrode 18, a dielectric 17, and a target 16 are connected in series. A method for controlling a target voltage includes operations of applying a low-frequency pulse voltage V_{G} to the variable capacitor C4 and controlling capacitance of the variable capacitor C4 to control a voltage of the conductive target 16. An area of the target 16 is S2.

The dielectric 17 has a dielectric constant of ε1 and a thickness of d1. When a series variable capacitor C4 is connected in series to the electrode 18, a potential Vs of the conductor including semiconductor target 16 is given as follows:

The potential Vs of the target 16 is given as follows:

$${V}_{s} = {V}_{G} + {ρ}_{i} [ \frac{{d}_{1}}{{ϵ}_{1}} + ( \frac{{S}_{2}}{{C}_{4}} ) ] + [ \frac{{d}_{1}}{{ϵ}_{1}} + ( \frac{{S}_{2}}{{C}_{4}} ) ] \sqrt{- 2 {ϵ}_{2} {V}_{s} {ρ}_{d}} \qquad [ Equation 90 ]$$

$$\frac{1}{{c}_{eff}} = [ \frac{{d}_{1}}{{ϵ}_{1}} + ( \frac{{S}_{2}}{{C}_{4}} ) ]$$

$$- {V}_{s} = \frac{1}{4} [ - \frac{1}{{c}_{eff}} \sqrt{2 {ϵ}_{2} {ρ}_{d}} + {\sqrt{{( \frac{1}{{c}_{eff}} \sqrt{2 {ϵ}_{2} {ρ}_{d}} )}^{2} - 4 ( {V}_{G} + \frac{1}{{c}_{eff}} {ρ}_{i} ) ]}}^{2}$$

The maximum time tmax is given as follows:

$$( {V}_{G} + \frac{1}{{c}_{eff}} {ρ}_{i} ) = {V}_{0} + {Xt}_{max} + \frac{1}{{c}_{eff}} ( {ρ}_{i 0} + {J}_{i} {t}_{max} ) = 0$$

$${t}_{max} = - \frac{{V}_{0} + \frac{1}{{c}_{eff}} {ρ}_{i 0}}{X + \frac{1}{{c}_{eff}} {J}_{i}}$$

The current I_{G} flowing through the variable capacitor C4 or the electrode 18 is given as follows:

$${Q}_{G} = - {S}_{2} [ {ρ}_{i} + {ρ}_{d} {d}_{2} ]$$

$${V}_{s} = {V}_{G} + [ {ρ}_{i} + {ρ}_{d} {d}_{2} ] ( \frac{{d}_{1}}{{ϵ}_{1}} + \frac{{S}_{2}}{{C}_{4}} )$$

$${Q}_{G} = {S}_{2} \frac{[ {V}_{G} - {V}_{S} ]}{[ \frac{{d}_{1}}{{ϵ}_{1}} + ( \frac{{S}_{2}}{{C}_{4}} ) ]}$$

$${I}_{G} = \frac{{S}_{2}}{( \frac{{d}_{1}}{{ϵ}_{1}} + \frac{{S}_{2}}{{C}_{4}} )} \frac{d}{dt} ( {V}_{G} - {V}_{S} )$$

$${I}_{G} = {S}_{2} {c}_{eff} \frac{d}{dt} ( {V}_{G} - {V}_{S} )$$

$${I}_{G} = {S}_{2} {c}_{eff} \frac{{d V}_{G}}{dt} - {S}_{2} {c}_{eff} ( \frac{{d V}_{G}}{dt} + \frac{{J}_{i}}{{c}_{eff}} ) [ 1 - \frac{1}{{c}_{eff}} \frac{\sqrt{2 {ϵ}_{3} {ρ}_{d}}}{\sqrt{{( \frac{1}{{c}_{eff}} \sqrt{2 {ϵ}_{3} {ρ}_{d}} )}^{2} - 4 ( {V}_{G} + \frac{1}{{c}_{eff}} {ρ}_{i} )}} ]$$

$$\frac{{d V}_{s}}{dt} = ( X + \frac{{J}_{i}}{{c}_{eff}} ) [ 1 - \frac{1}{{c}_{eff}} \frac{\sqrt{2 {ϵ}_{2} {ρ}_{d}}}{\sqrt{{( \frac{1}{{c}_{eff}} \sqrt{2 {ϵ}_{2} {ρ}_{d}} )}^{2} - 4 ( {V}_{G} + \frac{1}{{c}_{eff}} {ρ}_{i} )}} ]$$

$${I}_{G} = {S}_{2} {c}_{eff} \frac{d}{dt} ( {V}_{G} - {V}_{S} )$$

$${I}_{G} = {S}_{2} {c}_{eff} X - {S}_{2} {c}_{eff} ( X + \frac{{J}_{i}}{{c}_{eff}} ) [ 1 - \frac{1}{{c}_{eff}} \frac{\sqrt{2 {ϵ}_{3} {ρ}_{d}}}{\sqrt{{( \frac{1}{{c}_{eff}} \sqrt{2 {ϵ}_{3} {ρ}_{d}} )}^{2} - 4 ( {V}_{G} + \frac{1}{{c}_{eff}} {ρ}_{i} )}} ]$$

A change in the potential ΔVs of the target is given as follows:

$${Δ V}_{s} = {V}_{s} ( t = τ ) - {V}_{s} ( t = 0 )$$

$$Δ {V}_{s} = ( X + \frac{{J}_{i}}{{c}_{eff}} ) τ [ 1 - \frac{1}{{c}_{eff}} \frac{\sqrt{2 {ϵ}_{2} {ρ}_{d}}}{\sqrt{{( \frac{1}{{c}_{eff}} \sqrt{2 {ϵ}_{2} {ρ}_{d}} )}^{2} - 4 ( {V}_{G} + \frac{1}{{c}_{eff}} {ρ}_{i} )}} ]$$

The variable capacitor C4 is a variable capacitor, and when capacitance of the variable capacitor C4 is changed, the potential Vs of the target 16 may be changed.

In an ion implantation system or an etching system, when the capacitance of the series capacitor C4 is adjusted, ion energy or sheath thickness may be controlled at a fixed applied voltage.

In addition, when the variable capacitor C4 is adjusted at a predetermined slope voltage X1, a potential of the target may be changed and the change in the potential ΔVs of the target may be zero.

A sinusoidal waveform, a slope voltage, measurement of maximum time, measurement of current, a change in plasma potential, and a change in electrostatic electrode may be equivalently applied. The operation method described in FIGS. 38 to 41 may be applied.

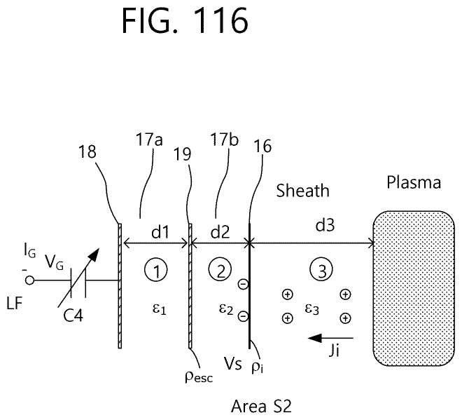

FIG. 116 is a conceptual diagram illustrating a plasma system including a variable capacitor.

Referring to FIG. 116, a plasma system 100 includes a chamber 12, a plasma source 20 generating plasma in the chamber 12, and a target holder 14 mounting a target 16. The target 16 may be a conductor or a semiconductor.

A driving voltage V_{G} is applied to the variable capacitor C4, and the target 16 is a conductor and has a surface on which electrons or positive ions are accumulated. A plasma sheath is formed between the plasma and the target 16. The plasma sheath may be treated as a space having a positive space charge. A thickness d3 of the plasma sheath varies depending on the voltage V_{G}. A first dielectric 17a is a first region, a second dielectric 17b is a second region, and an electrostatic electrode 19 is disposed between the first dielectric 17a and the second dielectric 17b. Thicknesses of the electrostatic electrode 19 and the electrode 18 are negligible. The plasma sheath is a third region. S2 is an area of the target and the electrode.

A thickness of the first dielectric 17a is d1, and a thickness of the electrostatic electrode 19 is negligible. A charged amount of the electrostatic electrode is ρ_{esc}. A thickness of the second dielectric 17b is d2, and a thickness of the plasma sheath is d3. A voltage of the target 16 is Vs, and surface charge density of the target 16 is ρi. A dielectric constant of the first region is ε1, a dielectric constant of the second region is ε2, and a dielectric constant 3 of the plasma sheath may be a dielectric constant of a vacuum.

A surface potential Vs of the target 16 is given as follows:

$${Q}_{G} = - {S}_{2} [ {ρ}_{i} + {ρ}_{d} {d}_{3} + {ρ}_{esc} ] \qquad [ Equation 91 ]$$

$${V}_{s} = {V}_{G} + [ {ρ}_{i} + {ρ}_{d} {d}_{3} ] ( \frac{{d}_{1}}{{ϵ}_{1}} + \frac{{S}_{2}}{{C}_{4}} + \frac{{d}_{2}}{{ϵ}_{2}} ) + {ρ}_{esc} [ \frac{{d}_{1}}{{ϵ}_{1}} + ( \frac{{S}_{2}}{{C}_{4}} ) ]$$

$${Q}_{G} = {S}_{2} \frac{[ {V}_{G} - {V}_{s} - {ρ}_{esc} \frac{{S}_{2}}{{C}_{4}} ]}{( \frac{{d}_{1}}{{ϵ}_{1}} + \frac{{S}_{2}}{{C}_{4}} + \frac{{d}_{2}}{{ϵ}_{2}} )}$$

$$\frac{1}{{c}_{eff}} = ( \frac{{d}_{1}}{{ϵ}_{1}} + \frac{{S}_{2}}{{C}_{4}} + \frac{{d}_{2}}{{ϵ}_{2}} )$$

$${V}_{s} = {V}_{G} + {ρ}_{i} [ \frac{{d}_{1}}{{ϵ}_{1}} + \frac{{S}_{2}}{{C}_{4}} + \frac{{d}_{2}}{{ϵ}_{2}} ] + [ \frac{{d}_{1}}{{ϵ}_{1}} + \frac{{S}_{2}}{{C}_{4}} + \frac{{d}_{2}}{{ϵ}_{2}} ] \sqrt{- 2 {ϵ}_{3} {V}_{s} {ρ}_{d}} {ρ}_{esc} [ \frac{{d}_{1}}{{ϵ}_{1}} + \frac{{S}_{2}}{{C}_{4}} ]$$

$${V}_{s} = - \frac{1}{4} [ - \frac{1}{{c}_{eff}} \sqrt{2 {ϵ}_{4} {ρ}_{d}} + {\sqrt{{( \frac{1}{{c}_{eff}} \sqrt{2 {ϵ}_{4} {ρ}_{d}} )}^{2} - 4 ( {V}_{G} + \frac{1}{{c}_{eff}} {ρ}_{i} + {ρ}_{esc} [ \frac{{d}_{1}}{{ϵ}_{1}} + \frac{{S}_{2}}{{C}_{4}} ] ) ]}}^{2}$$

The maximum time tmax is given as follows:

$$( {V}_{G} + {ρ}_{esc} [ \frac{{d}_{1}}{{ϵ}_{1}} + \frac{{S}_{2}}{{C}_{4}} ] + \frac{1}{{c}_{eff}} {ρ}_{i} ) = {V}_{0} + {Xt}_{max} + {ρ}_{esc} [ \frac{{d}_{1}}{{ϵ}_{1}} + \frac{{S}_{2}}{{C}_{4}} ] + \frac{1}{{c}_{eff}} ( {ρ}_{i 0} + {J}_{i} {τ}_{max} ) = 0 \qquad [ Equation 92 ]$$

$${t}_{max} = - \frac{{V}_{0} + \frac{1}{{c}_{eff}} {ρ}_{i 0} + {ρ}_{esc} [ \frac{{d}_{1}}{{ϵ}_{1}} + \frac{{S}_{2}}{{C}_{4}} ]}{X + \frac{1}{{c}_{eff}} {J}_{i}}$$

When a time variation of a charged amount of the electrostatic electrode is negligible, the current I_{G} flowing through the electrode 18 is given as follows:

$${I}_{G} = {S}_{2} {c}_{eff} \frac{d}{dt} ( {V}_{G} - {V}_{S} ) \qquad [ Equation 93 ]$$

$${I}_{G} = {S}_{2} {c}_{eff} X - {S}_{2} {c}_{eff} ( X + \frac{{J}_{i}}{{c}_{eff}} ) [ 1 - \frac{1}{{c}_{eff}} \frac{\sqrt{2 {ϵ}_{4} {ρ}_{d}}}{\sqrt{{( \frac{1}{{c}_{eff}} \sqrt{2 {ϵ}_{4} {ρ}_{d}} )}^{2} - 4 ( {V}_{G} + \frac{1}{{c}_{eff}} {ρ}_{i} + {ρ}_{esc} [ \frac{{d}_{1}}{{ϵ}_{1}} + \frac{{S}_{2}}{{C}_{4}} ] )}} ]$$

A change ΔVs in the potential Vs of the target 16a is given as follows:

$${Δ V}_{S} = {V}_{S} ( t = τ ) - {V}_{S} ( t = 0 ) \qquad [ Equation 94 ]$$

$${Δ V}_{s} = ( X + \frac{{J}_{i}}{{c}_{eff}} ) τ [ 1 - \frac{1}{{c}_{eff}} \frac{\sqrt{2 {ϵ}_{4} {ρ}_{d}}}{\sqrt{{( \frac{1}{{c}_{eff}} \sqrt{2 {ϵ}_{4} {ρ}_{d}} )}^{2} - 4 ( {V}_{G} + \frac{1}{{c}_{eff}} {ρ}_{i} + {ρ}_{esc} [ \frac{{d}_{1}}{{ϵ}_{1}} + \frac{{S}_{2}}{{C}_{4}} ] )}} ]$$

The series capacitor C4 is a variable capacitor, and when capacitance of the series capacitor C4 is changed, the potential Vs of the target 16 may be changed.

In an ion implantation system or an etching system, when the capacitance of the series capacitor C4 is adjusted, ion energy or sheath thickness may be controlled at a fixed applied voltage.

In addition, when the variable capacitor C4 is adjusted at a predetermined ramp voltage X1, the potential of the target may be changed and the change in the potential ΔVs of the target may be zero.

A sinusoidal waveform, a slope voltage, measurement of maximum time, measurement of current, a change in plasma potential, and a change in electrostatic electrode may be equivalently applied. The operation method described in FIGS. 38 to 41 may be applied.

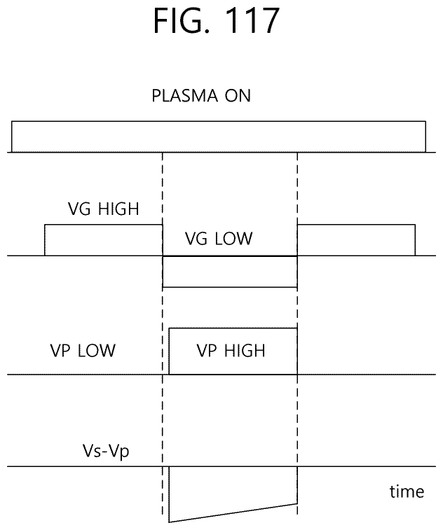

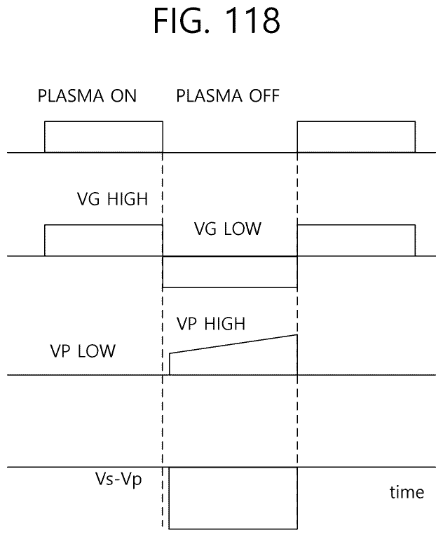

FIGS. 117 and 118 are conceptual diagrams illustrating a method for controlling a target voltage according to example embodiments of the present disclosure.

Referring to FIGS. 117 and 118, in a plasma apparatus 100 including a structure in which an electrode, a dielectric layer, and a target are stacked, a plasma potential Vp of plasma adjacent to the target 16 is controlled to increase over time by an auxiliary electrode 31 controlling the plasma potential, controlling a potential difference (Vs−Vp) between a potential Vs of the target and the plasma potential Vp.

Referring to FIG. 117, the plasma is continuously generated by a high-frequency power supply. The applied voltage V_{G} applied to the electrode 18 is a pulse DC voltage, and the plasma potential Vp may be synchronized with a negative period of the pulse DC voltage. For example, the plasma potential Vp is synchronized with the applied voltage V_{G} having a slight time delay. The plasma potential Vp may be controlled by a voltage waveform of the auxiliary electrode 31 disposed in the chamber. Accordingly, the potential difference (Vs−Vp) between the potential Vp of the target and the plasma potential may increase over time due to introduction of ion currents Ii and Ji.

In addition, when the plasma potential Vp has a slope voltage Y, the potential difference (Vs−Vp) between a potential of the target and a plasma potential may be constant over time due to introduction of the ion current Ji.

In addition, when the applied voltage V_{G} applied to the electrode 18 has a first slope voltage X, the plasma potential Vp may have a second slope voltage Y corresponding to the ion current and the first slope voltage X.

$${V}_{G} = {V}_{G 0} + Xt ; {V}_{p} = {V}_{p 0} + Yt$$

$$Y = X + \frac{{J}_{i}}{{c}_{eff}}$$

where ceff is effective capacitance per unit area between the target and the low-frequency power supply or an electrode.

In addition, the change in the plasma potential Vp may not be synchronized with the applied voltage V_{G}.

An operation method of a plasma apparatus including an electrode/dielectric layer/target structure includes operations of applying a first DC pulse voltage V_{G} including a first slope voltage X to an electrode, and applying a second DC pulse voltage Vc including a second slope voltage Y to an auxiliary electrode controlling the plasma potential to change a plasma potential of plasma adjacent to the target overtime. The first DC pulse voltage Vc may be synchronized with the second DC pulse voltage Vc. Y=X+Ji/ceff, where ceff is effective capacitance per unit area between the target and the electrode, and Ji is ion current density incident on the target.

Referring to FIG. 118, plasma is generated in the form of a pulse by a high-frequency power supply. The plasma may have a turn-on period and a turn-off period. In the turn-on period of the plasma, a voltage V_{G} applied to the electrode 18 has a period having a positive value and may charge the target with negative charges. In the turn-on period of the plasma, the plasma potential Vp may have a low value.

In the turn-off period of the plasma, the voltage V_{G} applied to the electrode 18 has a period having a negative value and may decrease a potential of the negatively charged target to a negative value. As the ion currents Ii and Ji are introduced into the target, the potential of the target increases. The plasma potential Vp ma have a slope period increasing over time such that the potential difference (Vs−Vp) between the potential Vs of the target and the plasma potential Vp is constant over time despite the introduction of the ion currents Ii and Ji, and may be controlled by the voltage waveform of the auxiliary electrode 31 disposed in the chamber.

The voltage V_{G} applied to the electrode 18 is a pulse DC voltage, and the plasma potential Vp may be synchronized with the negative period of the pulsed DC voltage. For example, the plasma potential Vp may be synchronized with the applied voltage V_{G} having a slight time delay. The plasma potential Vp may have a slope period increasing over time, and may be controlled by the voltage waveform of the auxiliary electrode 31 disposed in the chamber.

### [Current Waveform]

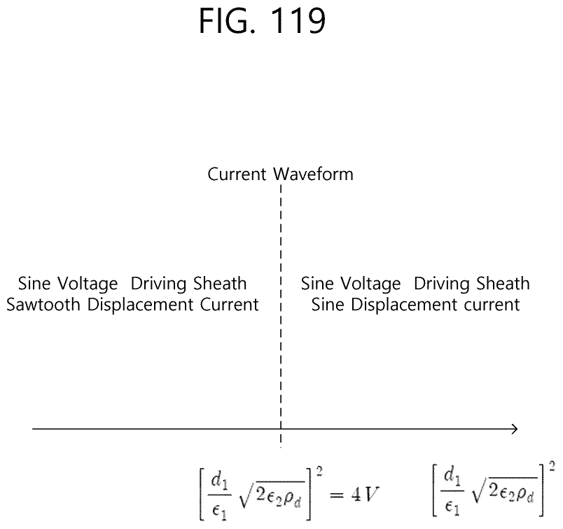

FIG. 119 is a conceptual diagram distinguishing waveforms of displacement current under conditions according to an example embodiment of the present disclosure.

Referring to FIG. 119, a waveform of displacement current may be classified into a sawtooth waveform and a quasi-sinusoidal waveform.

When

$${[ \frac{{d}_{1}}{{ϵ}_{1}} \sqrt{2 {ϵ}_{2} {ρ}_{d}} ]}^{2} > 4 V ,$$

the displacement current has a quasi-sinusoidal waveform.

When

$${[ \frac{{d}_{1}}{{ϵ}_{1}} \sqrt{2 {ϵ}_{2} {ρ}_{d}} ]}^{2} < 4 V ,$$

the displacement current has a sawtooth waveform.

The displacement current may be distinguished into a sawtooth waveform and a quasi-sinusoidal waveform, based on

$${[ \frac{{d}_{1}}{{ϵ}_{1}} \sqrt{2 {ϵ}_{2} {ρ}_{d}} ]}^{2} = 4 V ,$$

When having parasitic capacitance C4, parasitic capacitance connected to the electrode 118 may allow additional displacement current connected in parallel to the electrode 118 to flow. Accordingly, when the parasitic capacitance C4 satisfies the following condition, the displacement current is transformed into a quasi-sinusoidal waveform. A is an area of the target 16.

$${J}_{G} = - {J}_{i} + [ \frac{\sqrt{2 {ϵ}_{2} {ρ}_{d}} ( V ω cos ω t + \frac{{d}_{1}}{{ϵ}_{1}} {J}_{1} - \frac{{dV}_{p}}{dt} )}{\sqrt{{( \frac{{d}_{1}}{{ϵ}_{1}} \sqrt{2 {ϵ}_{2} {ρ}_{d}} )}^{2} - 4 ( V sin ω t - {V}_{p} + \frac{{d}_{1}}{{ϵ}_{1}} {ρ}_{i} )}} ] + V ω \frac{{C}_{4}}{A} cos ι t + {J}_{e}$$

The displacement current flowing through the plasma sheath may be set to be larger than the displacement current flowing through the parasitic capacitor C4.

$$\begin{matrix}\frac{\sqrt{2 {ϵ}_{2} {ρ}_{d}} ( V ω cos ω t )}{\sqrt{{( \frac{{d}_{1}}{{ϵ}_{1}} \sqrt{2 {ϵ}_{2} {ρ}_{d}} )}^{2} - 4 ( V sin ω t - {V}_{p} + \frac{{d}_{1}}{{ϵ}_{1}} {ρ}_{i} )}} > V ω \frac{{C}_{4}}{A} cos ω t \\ \frac{\sqrt{2 {ϵ}_{2} {ρ}_{d}}}{\sqrt{( \frac{{d}_{1}}{{ϵ}_{1}} \sqrt{2 {ϵ}_{2} {ρ}_{d}} ) - 4 ( V sin ω t - {V}_{p} + \frac{{d}_{1}}{{ϵ}_{1}} {ρ}_{i} )}} > \frac{{ϵ}_{4}}{{d}_{4}}\end{matrix}$$

Accordingly, the parasitic capacitance per unit area C4, caused by a distance d4 between a lower portion of the electrode 118 and a grounded electrode housing (not illustrated) and a dielectric constant ε4 of a dielectric disposed between the lower portion of the electrode 118 and the grounded electrode housing, may be designed to be smaller than effective capacitance of the plasma sheath (a left-hand side of the above equation). For example, parasitic capacitance per unit area ε4/d4 may be 10\hat{ }7 [F/m\hat{ }2] or less. The dielectric constant ε4 of the dielectric disposed between the lower portion of the electrode 118 and the grounded electrode housing may be smaller than the dielectric constant ε1 of an upper electrode. The distance d4 between the lower portion of the electrode 118 and the grounded electrode housing may be larger than a distance d1 between the electrode 118 and the target 116. The distance d4 between the lower portion of the electrode 118 and the grounded electrode housing may be larger than a plasma sheath distance d2 between the target 116 and the plasma. Preferably, may be more than 10 times larger than the parasitic capacitance per unit area ε4/d4.

$$\sqrt{2 {ϵ}_{2} {ρ}_{d}} > \sqrt{V} ( \frac{{ϵ}_{4}}{{d}_{4}} )$$

### [Voltage Damping Condition Based on Ion Current]

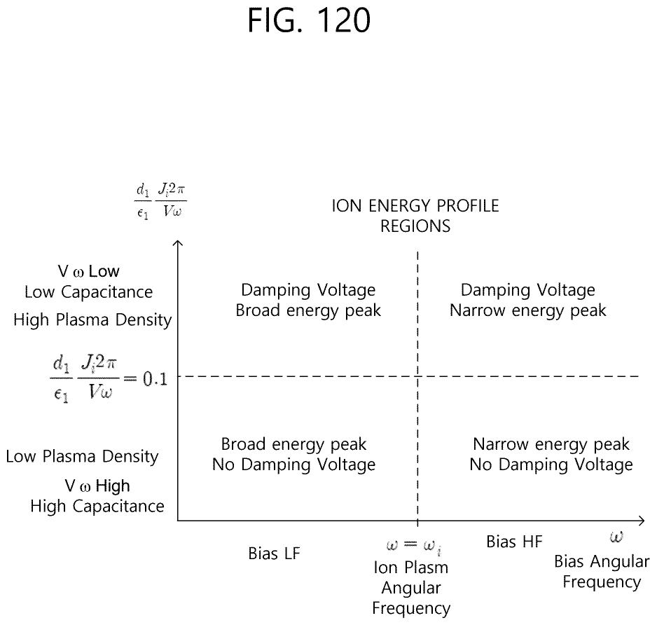

FIG. 120 is a conceptual diagram classifying ion energy distributions for each region based on ion current density Ji according to an example embodiment of the present disclosure.

Referring to FIG. 120, potential (Vs) characteristics of a target based on ion current density Ji and angular frequency ω are given as follows:

$$\begin{matrix}{V}_{S} = {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )} ]}^{2} \\ {V}_{S} = - {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} ( {ρ}_{i 0} + {J}_{i} t ) )} ]}^{2} \\ {V}_{S} = - {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( V cos ( π ) - V + \frac{{d}_{1}}{{ϵ}_{1}} ( \frac{{J}_{i} π}{ω} ) )} ]}^{2} \\ {V}_{S} = - {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 V [ cos ( π ) - 1 + \frac{{d}_{1}}{{ϵ}_{1}} ( \frac{{J}_{i} π}{ω V} )} ]}^{2}\end{matrix}$$

In the above equation, a damping condition in which the potential Vs of the target decreases due to the ion current density Ji is given as follows:

$$\begin{matrix}\frac{{d}_{1}}{{ϵ}_{1}} ( \frac{{J}_{i} π}{ω V} ) \leq 1 \\ \frac{{d}_{1}}{{ϵ}_{1}} ( \frac{{J}_{i} π}{ω V} ) \leq 0.1\end{matrix}$$

When the above condition is satisfied, the potential Vs of the target is hardly damped. On the other hand, when an angular frequency ω of a bias power supply is larger than an ion plasma angular frequency ωi, a value between two peaks is reduced to have a narrow energy width.

Accordingly, in a coordinate system of the angular frequency ω of the bias power supply and the damping condition, an ion energy distribution may be divided into four regions.

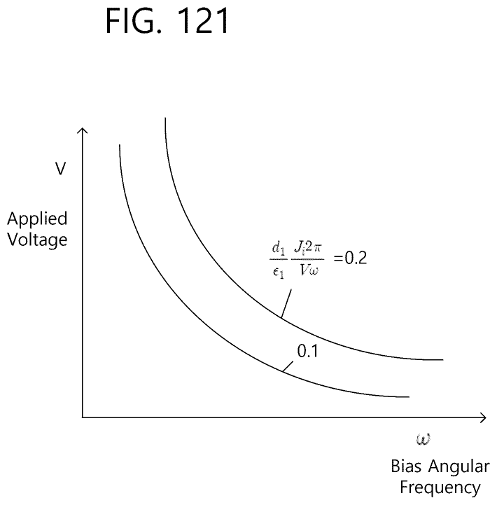

FIG. 121 is a graph illustrating damping conditions based on an angular frequency ω of a bias power supply and an applied voltage V.

Referring to FIG. 121, when an applied voltage is increased, the angular frequency ω of the bias power supply is decreased to satisfy the same damping condition (=0.1)

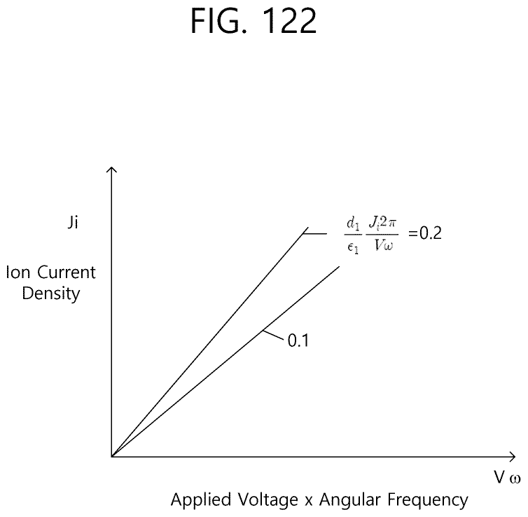

FIG. 122 is a graph illustrating damping conditions based on the product of an angular frequency ω of a bias power supply and an applied voltage V, and ion current density Ji.

Referring to FIG. 122, Vω is proportional to the ion current density Ji to satisfy the damping condition (=0.1).

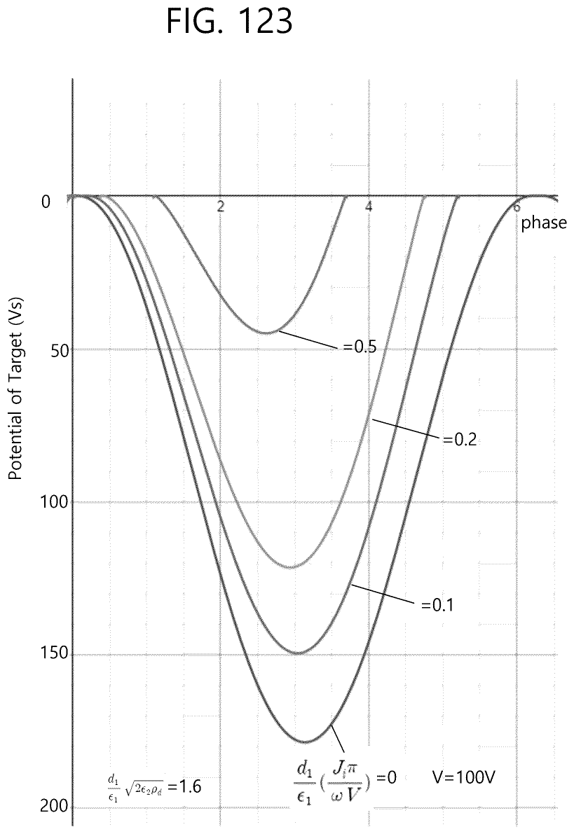

FIG. 123 is a diagram illustrating a waveform of a potential Vs of a target based on ion current density at a sinusoidal applied voltage.

Referring to FIG. 123, damping characteristics of the potential Vs of the target over time t based on ion current density are given as follows:

$$\begin{matrix}{V}_{S} = - {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} ( {ρ}_{i 0} + {J}_{i} t ) )} ]}^{2} \\ {V}_{S} = - {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} ( {ρ}_{i 0} ) + \frac{{d}_{1}}{{ϵ}_{1}} {J}_{i} t ) )} ]}^{2} \\ {V}_{S} = - {\frac{1}{4} [ - \frac{{d}_{1}}{{ϵ}_{1}} \sqrt{2 {ϵ}_{2} {ρ}_{d}} + \sqrt{{( \frac{{d}_{1}}{{ϵ}_{1}} \sqrt{2 {ϵ}_{2} {ρ}_{d}} )}^{2} - 4 V ( - 1 - 1 + \frac{{d}_{1}}{{ϵ}_{1}} ( \frac{{J}_{i} t}{V} ) )} ]}^{2} \\ \frac{{d}_{1}}{{ϵ}_{1}} ( \frac{{J}_{i} {t}_{th}}{V} ) \leq 1 \\ \frac{{d}_{1}}{{ϵ}_{1}} ( \frac{{J}_{i} {t}_{th}}{V} ) \leq 0.1\end{matrix}$$

For example, when an applied voltage is a sinusoidal wave, the potential Vs of the target changes, like a rectifier voltage, as the ion current density increases.

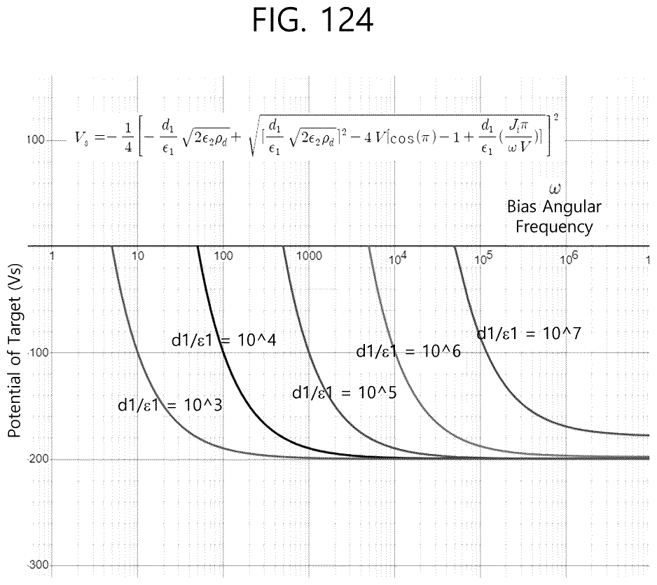

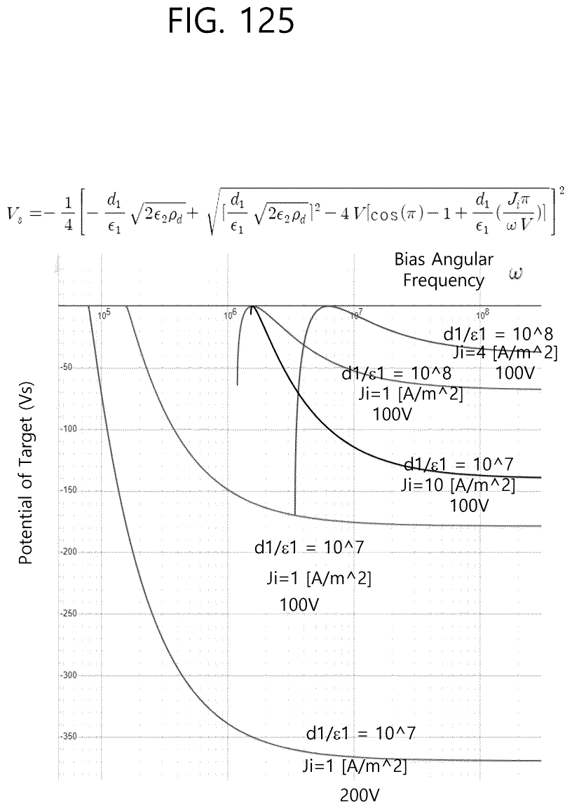

FIGS. 124 and 125 are diagrams illustrating a potential of a target based on capacitance per unit area (ε1/d1) between the target and an electrode at a sinusoidal applied voltage.

Referring to FIG. 124, an amplitude V of an applied voltage is 100V Capacitance per unit area (ε1/d1) is 10\hat{ }(−7), 10\hat{ }(−6), 10\hat{ }(−5), 10\hat{ }(−4), and 10\hat{ }(−3) [F/m\hat{ }2], respectively. Ji is 1 [A/m\hat{ }2]. As the capacitance per unit area (ε1/d1) increases, an absolute value of a potential Vs of a target increases with an angular frequency and converges to a constant value.

An angular frequency ω, at which the absolute value of the potential Vs of the target becomes zero, is in inverse proportion to the capacitance per unit area (ε1/d1).

$$( {d}_{1} / {ε}_{1} ) [ ( {J}_{i} π ) / ( V ω ) ] = 2$$

When the capacitance per unit area (ε1/d1) is sufficiently decreased to approach the capacitance of a sheath, the potential Vs of the target is decreased. Accordingly, the capacitance per unit area (ε1/d1) and the angular frequency may have an optimal value.

Referring to FIG. 125, the capacitance per unit area (ε1/d1) is 10\hat{ }−7 and 10\hat{ }−8 [F/m\hat{ }2]. Ji is 1 and 10 [A/m\hat{ }2]. An amplitude V of the applied voltage is 100V and 200V.

An undamped condition is determined by the ion current density Ji, the amplitude V of the applied voltage, the angular frequency ω, and the capacitance per unit area (ε1/d1).

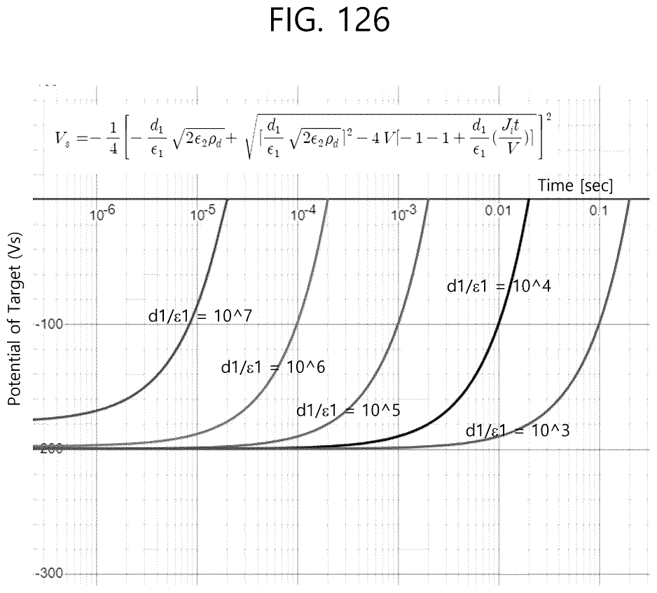

FIG. 126 is a diagram illustrating a potential Vs of a target based on capacitance per unit area (ε1/d1) between the target and an electrode at a bipolar DC pulse applied voltage.

Referring to FIG. 126, an amplitude V of the applied voltage is 100V. Capacitance per unit area (ε1/d1) is 10\hat{ }−7, 10\hat{ }−6, 10\hat{ }−5, 10\hat{ }−4, and 10\hat{ }−3 [F/m\hat{ }2], respectively. Ji is 1 [A/m\hat{ }2]. The amplitude of the applied voltage V is 100V.

For example, when the applied voltage is a bipolar DC pulse, the damping condition is given as follows. A voltage application time tₜₕ is an application time during which damping is negligible at a negative voltage.

$$\begin{matrix}\frac{{d}_{1}}{{ϵ}_{1}} ( \frac{{J}_{i} π}{ω V} ) \leq 1 \\ \frac{{d}_{1}}{{ϵ}_{1}} ( \frac{{J}_{i} π}{ω V} ) \leq 0.1\end{matrix}$$

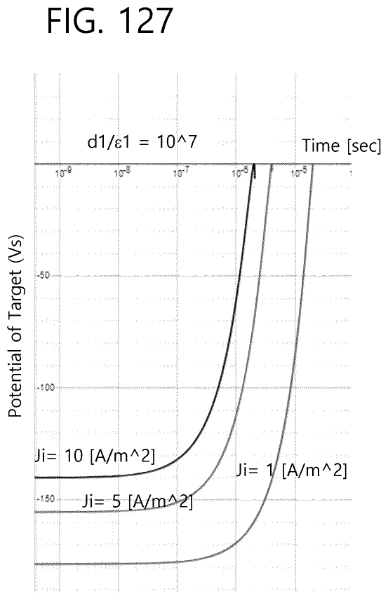

FIG. 127 is a diagram illustrating a potential Vs of a target based on ion current density at a bipolar DC pulse applied voltage.

Referring to FIG. 127, an amplitude V of an applied voltage is 100V Capacitance per unit area (ε1/d1) is 10\hat{ }−7 [F/m\hat{ }2]. Ji is 1, 5, and 10 [A/m\hat{ }2]. The amplitude of the applied voltage V is 100V.

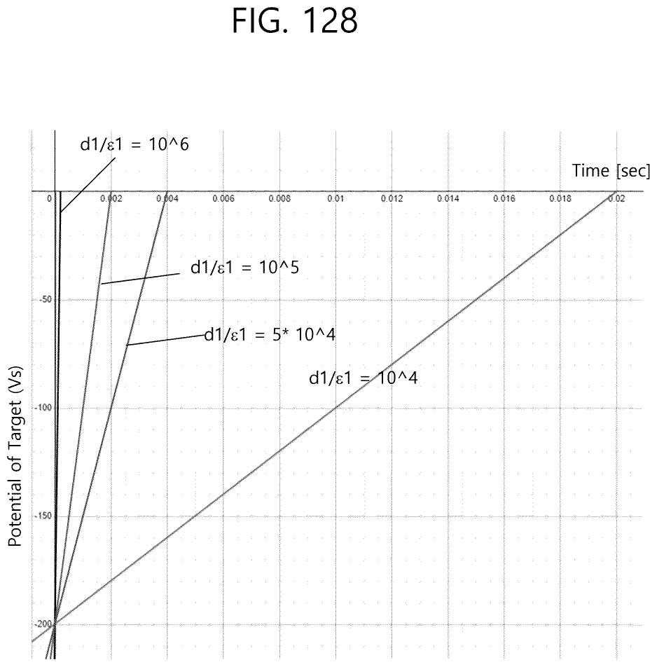

FIG. 128 is a diagram illustrating a potential Vs of a target based on capacitance per unit area (ε1/d1) at a bipolar DC pulse applied voltage.

Referring to FIG. 128, an amplitude V of an applied voltage is 100V. Capacitance per unit area (ε1/d1) is 10\hat{ }−6, 10\hat{ }−5, 5×10\hat{ }−4, and 10\hat{ }−4 [F/m\hat{ }2], respectively. Ji is 1 [A/m\hat{ }2]. The amplitude of the applied voltage V is 100V

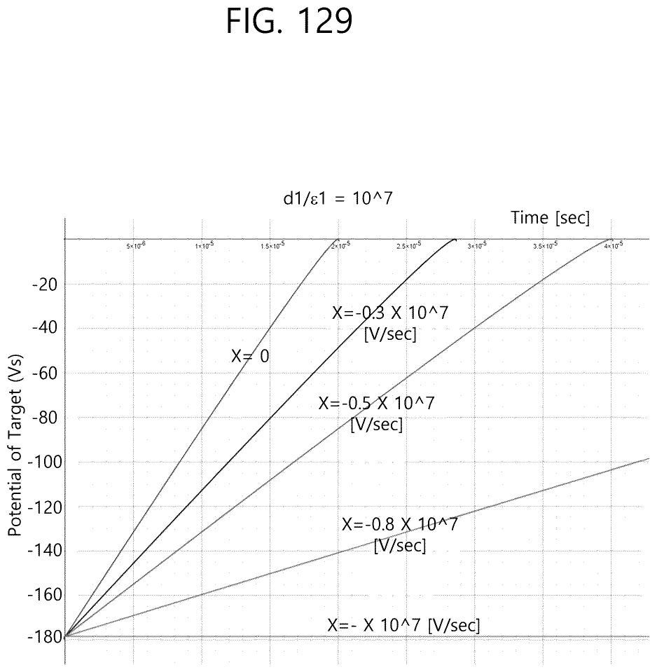

FIG. 129 is a diagram illustrating a potential Vs of a target based on a slope voltage (X=dV/dt) at a bipolar DC pulse applied voltage.

Referring to FIG. 129, an amplitude V of an applied voltage is 100V. Capacitance per unit area (ε1/d1) is 10\hat{ }−7 [F/m\hat{ }2]. Ji is 1 [A/m\hat{ }2]. A slope voltage (X=dV/dt) is 0, −0.3×10\hat{ }7, −0.5×10\hat{ }7, −0.8×10\hat{ }7, and −10\hat{ }7 [V/sec].

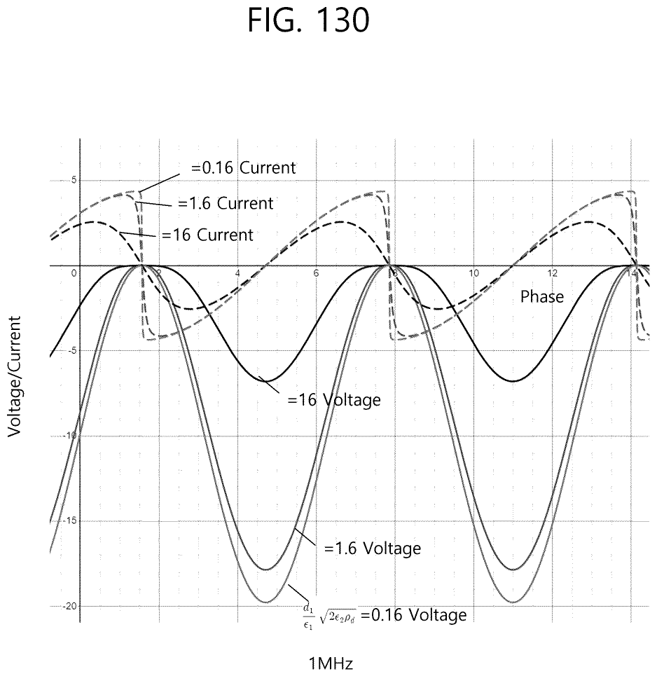

FIG. 130 is a diagram illustrating a waveform of a potential Vs and a current waveform of a target at a sinusoidal applied voltage based on conditions.

Referring to FIG. 130, a current waveform and a voltage waveform are illustrated under the conditions of (d1/ε1)sqrt(2ε2 ρd)=1.6, 0.16, and 16. When (d1/ε1)sqrt(2ε2 ρd) is increased to 5 or more, the current waveform has a quasi-sinusoidal waveform. When (d1/ε1)sqrt(2ε2 ρd) is decreased, the current waveform has a sawtooth-like waveform. An operating frequency is 1 MHz, and the applied voltage V is 100V

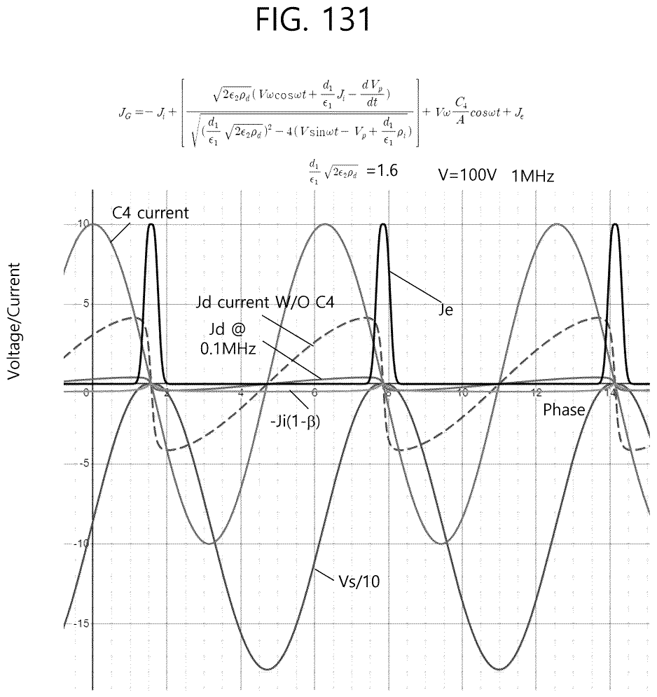

FIG. 131 is a diagram illustrating a waveform of a potential Vs and a current waveform of a target at a sinusoidal applied voltage based on conditions.

Referring to FIG. 131, a current waveform and a voltage waveform are illustrated under the condition of (d1/ε1)sqrt(2ε2 ρd)=1.6. Electron current Je, ion current Ji, displacement current Jd, and displacement current caused by parasitic capacitance are displayed. An operating frequency is 1 MHz, and the applied voltage V is 100V

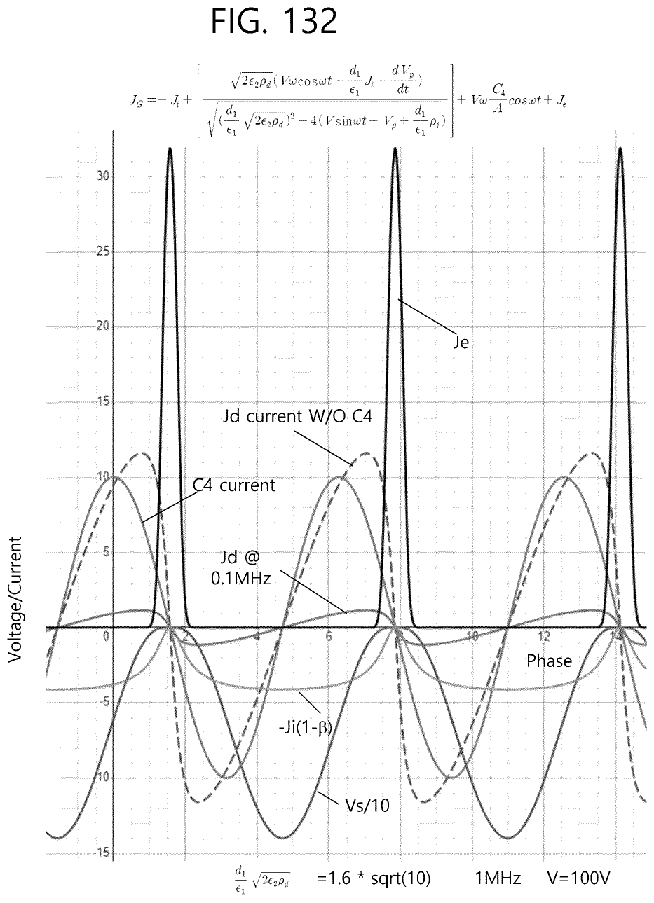

FIG. 132 is a diagram illustrating a waveform of a potential Vs and a current waveform of a target under a sinusoidal applied voltage based on conditions.

Referring to FIG. 132, a current waveform and a voltage waveform are illustrated under the condition of (d1/ε1)sqrt(2ε2 ρd)=1.6 sqrt(10). Electron current Je, ion current Ji, displacement current Jd, and displacement current caused by parasitic capacitor are displayed. An operating frequency is 1 MHz, and the applied voltage V is 100 V. An increase in the ion current Ji (1.6 sqrt(10)) leads to an increase in the electron current Je.

In summary, the selection of plasma density, frequency, and capacitance may satisfy the following conditions.

### [Selection of Operating Conditions]

### 1) Voltage Drop Condition

$$\frac{{d}_{1}}{{ϵ}_{1}} \sqrt{2 {ϵ}_{2} {ρ}_{d}} \leq 5$$

### 2) Voltage Damping Condition Caused by Ion Current

In the case of a sinusoidal wave, the voltage damping condition is given as follows:

$$\frac{{d}_{1}}{{ϵ}_{1}} {J}_{i} ( \frac{π}{ω V} ) \leq 0.1$$

In the case of a DC pulse waves, the voltage damping condition is given as follows:

$$\frac{{d}_{1}}{{ϵ}_{1}} ( \frac{{J}_{i} {t}_{th}}{V} ) \leq 0.1$$

### 3) Broad Energy Condition Between Peaks in an Ion Energy Distribution

$$ω < {ω}_{i}$$

### 4) Sawtooth Waveform Condition of Varying Current

$${[ \frac{{d}_{1}}{{ϵ}_{1}} \sqrt{2 {ϵ}_{2} {ρ}_{d}} ]}^{2} < 4 V$$

### 5) Reduction of Parasitic Displacement Current Caused by Parasitic Capacitance C4

$$\frac{\sqrt{2 {ϵ}_{2} {ρ}_{d}} ( V ω cos ω t )}{\sqrt{{( \frac{{d}_{1}}{{ϵ}_{1}} \sqrt{2 {ϵ}_{2} {ρ}_{d}} )}^{2} - 4 ( V sin ω t - {V}_{p} + \frac{{d}_{1}}{{ϵ}_{1}} {ρ}_{i} )}} > V ω \frac{{C}_{4}}{A} cos ω t$$

The present disclosure may be applied to plasma etching, plasma deposition, plasma sputtering, plasma cleaning, and plasma surface treatment apparatuses. Furthermore, the present disclosure may be applied to a bias power supply or a power supply for plasma generation in plasma apparatuses.

A target of the present disclosure may include a substrate, a semiconductor substrate, a dielectric substrate, a sputtering target, a focus ring, an edge ring, an electrode for plasma generation, or an electrode for a plasma diagnostic device.

Although the present disclosure and its advantages have been described in detail, it should be understood that various changes, substitutions and alterations can be made herein without departing from the spirit and scope of the disclosure as defined by the following claims.

1. A method for controlling a voltage of a target in a plasma apparatus having a structure in which an electrode, a dielectric, and the target are stacked, the method comprising:
applying an applied voltage V_{G} of a bipolar pulse to the electrode to find a maximum time tmax at which current flowing through the electrode becomes zero in a negative voltage region; and
calculating ion current density Ji incident on the target exposed to plasma using the maximum time tmax.

2. The method as set forth in claim 1, wherein
the ion current density Ji may be given as follow:
$${t}_{max} = - ( \frac{{V}_{0} - {V}_{G}^{+}}{{J}_{1}} ) {c}_{1}$$
where Vo is a measured voltage applied to the electrode, V_{G}⁺ is a positive applied voltage applied to the electrode, and c1 is capacitance per unit area of a dielectric between the electrode and the target.

3. The method as set forth in claim 1, further comprising:
setting a potential Vs of the target based on the ion current density Ji.

4. The method as set forth in claim 3, wherein
the potential Vs of the target may be given as follow:
$$\begin{matrix}{V}_{s} = - {( \frac{{d}_{1}}{{ϵ}_{1}} )}^{2} {ϵ}_{2} {ρ}_{4} + ( {V}_{G} + \frac{{d}_{1}}{{ϵ}_{1} 2} \sqrt{2 {ϵ}_{2} {ρ}_{d}} \sqrt{{( \frac{{d}_{1}}{{ϵ}_{1}} \sqrt{2 {ϵ}_{2} {ρ}_{d}} )}^{2} - 4 ( {V}_{G} + \frac{{d}_{2}}{{ϵ}_{1}} {ρ}_{1}} ) \\ {ρ}_{d} = JJ ( 0.61 {u}_{B} )\end{matrix}$$
wherein ρd is charge density of plasma, V_{G} is an applied voltage applied to the electrode, u_{B} is Bohm speed, d1 is a thickness of the dielectric layer, ε1 is the dielectric constant of the dielectric layer, ε2 is a dielectric constant of a plasma sheath region. ρi is initial surface charge density accumulated on the target at a positive applied voltage.

5. The method as set forth in claim 4, further comprising:
calculating a voltage variation ΔVS of the target at the applied voltage V_{G}.
$$Δ {V}_{s} = ( X + \frac{{d}_{1} {J}_{1}}{{ϵ}_{1}} ) τ [ 1 - \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{1} )}} ]$$
where X is a voltage fluctuation dV/dt depending on a time interval τ in a negative period of the applied voltage V_{G}.

6. The method as set forth in claim 1, further comprising:
applying a drive voltage of a bipolar waveform having an applied time of a negative applied voltage, shorter than the maximum time tmax.

7. The method as set forth in claim 3, wherein
the potential Vs of the target is given as follow:
$$\begin{matrix}{V}_{G} = {V}_{G} + \frac{{d}_{1} {ρ}_{i}}{{ϵ}_{1}} + \frac{{d}_{1}}{{ϵ}_{1}} {\{ 2 {ρ}_{0} {ϵ}_{2} [ 2 \frac{\sqrt{- {aV}_{s} + 1}}{a} - 2 \frac{1}{a} + \frac{{kT}_{e}}{q} [ {e}^{( q \frac{{V}_{t}}{{kT}_{e}} )} - 1 ] \}}^{1 / 2} \\ a = \frac{2 q}{{Mu}_{B}^{2}} \\ {u}_{B} = {( k , {T}_{e} / M )}^{1 / 2}\end{matrix}$$
where Te is an electron temperature, k is a Boltzmann constant, q is an absolute value of electron charge, and M is an ion mass.

8. The method as set forth in claim 3, wherein
the potential VS of the target may be given as follow:
$$- {V}_{e} = {\frac{1}{4} [ \frac{{d}_{1} α}{{ϵ}_{1}} + \sqrt{{( \frac{{d}_{1} α}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{1} )} ]}^{2}$$
where α is 0.3 to 0.5, ρ_{d} is charge density of plasma, V_{G} is an applied voltage applied to the electrode, d1 is a thickness of the dielectric layer, ε1 is a dielectric constant of a dielectric layer, ε2 is a dielectric constant of a plasma sheath region, and ρi is an initial surface charge density accumulated on the target at a positive drive voltage.

9. The method as set forth in claim 4, wherein
$$\begin{matrix}\frac{{d}_{1}}{{ϵ}_{1}} \sqrt{2 {ϵ}_{2} {ρ}_{d}} < 1 \\ \frac{{d}_{1}}{{ϵ}_{1}} \sqrt{2 {ϵ}_{2} {ρ}_{d}} < 0.1\end{matrix}$$

10. The method as set forth in claim 4, wherein
$$\begin{matrix}β = \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{1} )}} \\ β < 0.4\end{matrix}$$

11. The method as set forth in claim 1, wherein
current I_{G} flowing through the electrode and a maximum time tmax at which the current I_{G} becomes zero are given as follow:
$${t}_{i} = - ( {V}_{s 0} - {V}_{f} ) \frac{{C}_{1}}{{I}_{G 0}}$$
where Vₛ₀ is an initial voltage of the target, C1 is capacitance of the dielectric, V_{f} is a floating potential, and I_{G0} is current flowing through the electrode at a negative applied voltage.

12. The method as set forth in claim 1, wherein
the current I_{G} flowing through the electrode is given as follow:
$$\begin{matrix}= {C}_{1} β X + {I}_{G 0} \\ β = \frac{{d}_{1}}{{ϵ}_{1}} \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{1} )}} \\ {I}_{G 0} = - I ( 1 - β ) \\ {I}_{G} = {C}_{1} β X - L ( 1 - β )\end{matrix}$$
where X is a slope voltage applied in a negative applied voltage period, C1 is capacitance of the dielectric, ρ_{d} is charge density of plasma, V_{G} is an applied voltage applied to the electrode, d1 is a thickness of a dielectric layer, ε1 is a dielectric constant of the dielectric layer, ε2 is a dielectric constant of a plasma sheath region, and ρi is density of initial surface charges accumulated on the target at a positive drive voltage.

13. The method as set forth in claim 12, wherein
$$β < 0.4$$

14. The method as set forth in claim 1, wherein
an initial charged amount Qᵢ per unit area that is charged at a positive applied voltage of the target may be given as follow:
$${Q}_{i} = - \frac{{ϵ}_{1}}{{d}_{1}} {V}_{0}^{+}$$

15. The method as set forth in claim 1, wherein
the following condition is satisfied at a positive applied voltage V_{G}⁺ of the target:
$$\frac{( {d}_{1} / {ϵ}_{1} ) {J}_{1} τ}{2 {V}_{G}^{+}} < 0.1$$
wherein d1 is a thickness of the dielectric layer, ε1 is a dielectric constant of the dielectric layer, ε2 is a dielectric constant of a plasma sheath region. τ is a time period in which a negative applied voltage is applied.

16. The method as set forth in claim 1, further comprising:
calculating charge density ρ_{d} of plasma.
$$\begin{matrix}β ≡ \frac{\sqrt{2 {ϵ}_{2} {ρ}_{d}}}{\sqrt{{( \frac{{d}_{1}}{{ϵ}_{1}} \sqrt{2 {ϵ}_{2} {ρ}_{d}} )}^{2} - 4 ( {V}_{G} + \frac{{d}_{1}}{{ϵ}_{1}} {ρ}_{i} )}} \\ {ρ}_{d} = \frac{4 {β}^{2}}{2 {ϵ}_{2} [ {{β}^{2} ( \frac{{d}_{1}}{{ϵ}_{1}} )}^{2} - 1 ]}\end{matrix}$$
where ρ_{d} is charge density of plasma, d1 is a thickness of a dielectric layer, ε1 is a dielectric constant of the dielectric layer, ε2 is a dielectric constant of a plasma sheath region, V_{G} is ae negative applied voltage, and ρi is density of initial surface charges accumulated on the target at a positive drive voltage.

17. The method as set forth in claim 1, further comprising:
applying a drive voltage of a bipolar waveform having an applied time of a negative applied voltage, shorter than the maximum time tmax; and
synchronizing a high-frequency sinusoidal wave with a negative voltage period of the drive voltage and applying the synchronized sinusoidal wave to the electrode.
